(19) United States
(12) Patent Application Publication
(10) Pub. No.: US 2025/0063936 A1
(43) Pub. Date: Feb. 20, 2025

(54) ORGANIC ELECTROLUMINESCENT MATERIALS AND DEVICES

(71) Applicant: Universal Display Corporation, Ewing, NJ (US)

(72) Inventors: Tyler FLEETHAM, Yardley, PA (US); Eric A. MARGULIES, Philadelphia, PA (US); Jui-Yi TSAI, Newtown, PA (US); Sean Michael RYNO, Yardley, PA (US); Wei-Chun SHIH, Lawrenceville, NJ (US)

(73) Assignee: Universal Display Corporation, Ewing, NJ (US)

(21) Appl. No.: 18/780,684

(22) Filed: Jul. 23, 2024

Related U.S. Application Data
(63) Continuation-in-part of application No. 18/297,676, filed on Apr. 10, 2023.
(63) Continuation-in-part of application No. 18/669,896, filed on May 21, 2024.
(63) Continuation-in-part of application No. 18/669,672, filed on May 21, 2024.
(63) Continuation-in-part of application No. 18/669,652, filed on May 21, 2024.
(60) Provisional application No. 63/548,955, filed on Feb. 2, 2024.
(60) Provisional application No. 63/603,188, filed on Nov. 28, 2023.
(60) Provisional application No. 63/516,684, filed on Jul. 31, 2023.
(60) Provisional application No. 63/627,346, filed on Jan. 31, 2024.
(60) Provisional application No. 63/597,621, filed on Nov. 9, 2023.
(60) Provisional application No. 63/515,918, filed on Jul. 27, 2023.

(51) Int. Cl. H10K 85/30; C07F 15/00; C09K 11/02; C09K 11/06; H10K 50/11; H10K 50/80; H10K 85/60; H10K 101/30

(52) U.S. Cl. CPC H10K 85/342; C07F 15/0033; C09K 11/02; C09K 11/06; H10K 85/622; H10K 85/654; H10K 85/6572; H10K 85/6576; C09K 2211/1007; C09K 2211/1029; C09K 2211/1044; C09K 2211/1059; C09K 2211/1088; C09K 2211/185; H10K 50/11; H10K 50/868; H10K 2101/30

(57) ABSTRACT

A compound E1 capable of functioning as an emitter an organic light emitting device (OLED) at room temperature is provided. The compound is a metal coordination complex; the metal coordination complex comprises a first ligand, L_{A}, that comprises a first group; and the metal coordination complex comprises a covalent bond between the metal and the first group; wherein the transition dipole moment (TDM) of the emissive state of the complex has a vector, wherein an angle formed between the TDM vector and the covalent bond between the metal and the first group is less than or equal to 40°, and wherein an excited state of the metal coordination complex has a LC character localized on the first group of greater than or equal to 45%. Formulations, OLEDs, and consumer products containing the compound are also provided.

### CROSS-REFERENCE TO RELATED APPLICATIONS

This application is a continuation-in-part of co-pending U.S. patent application Ser. No. 18/297,676, filed Apr. 10, 2023, Ser. No. 18/669,896, filed May 21, 2024, Ser. No. 18/669,672, filed on May 21, 2024, and Ser. No. 18/669,652, filed on May 21, 2024. This applications also claims priority under 35 U.S.C. § 119(e) to U.S. Provisional Applications No. 63/548,955, filed on Feb. 2, 2024, No. 63/603,188, filed on Nov. 28, 2023, No. 63/516,684, filed on Jul. 31, 2023, No. 63/627,346, filed on Jan. 31, 2024, No. 63/597,621, filed on Nov. 9, 2023, and No. 63/515,918, filed on Jul. 27, 2023. The entire contents of all of the above referenced applications are incorporated herein by reference.

### FIELD

The present disclosure generally relates to organic or metal coordination compounds and formulations and their various uses including as emitters, sensitizers, charge transporters, or exciton transporters in devices such as organic light emitting diodes and related electronic devices and consumer products.

### BACKGROUND

Opto-electronic devices that make use of organic materials are becoming increasingly desirable for various reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, organic scintillators, and organic photodetectors. For OLEDs, the organic materials may have performance advantages over conventional materials.

OLEDs make use of thin organic films that emit light when voltage is applied across the device. OLEDs are becoming an increasingly interesting technology for use in applications such as displays, illumination, and backlighting.

One application for emissive molecules is a full color display. Industry standards for such a display call for pixels adapted to emit particular colors, referred to as “saturated” colors. In particular, these standards call for saturated red, green, and blue pixels. Alternatively, the OLED can be designed to emit white light. In conventional liquid crystal displays emission from a white backlight is filtered using absorption filters to produce red, green and blue emission. The same technique can also be used with OLEDs. The white OLED can be either a single emissive layer (EML) device or a stack structure. Color may be measured using CIE coordinates, which are well known to the art.

### SUMMARY

In one aspect, the present disclosure provides a compound E1 capable of functioning as an emitter in an OLED at room temperature. The compound is a metal coordination complex that comprises a first ligand, L_{A}, that comprises a first group; and the metal coordination complex comprises a covalent bond between the metal and the first group; wherein the transition dipole moment (TDM) of the emissive state of the complex has a vector, wherein an angle formed between the TDM vector and the covalent bond between the metal and the first group is less than or equal to 40°, and wherein an excited state of the metal coordination complex has a ligand-centered (LC) character localized on the first group of greater than or equal to 45%.

In another aspect, the present disclosure provides a compound E1′ capable of functioning as a phosphorescent emitter in an organic light emitting device at room temperature, wherein the compound is a metal coordination complex comprising a metal and a first group; the first group comprises a continuous moiety comprising at least three rings; and the first group contains at least 70% of the electron density of a LUMO of the compound.

In yet another aspect, the present disclosure provides a formulation comprising the compound E1 or E1′ capable of functioning as an emitter as described herein.

In yet another aspect, the present disclosure provides an OLED having an organic layer comprising the compound E1 or E1′ capable of functioning as an emitter as described herein.

In yet another aspect, the present disclosure provides a consumer product comprising an OLED with an organic layer comprising the compound E1 or E1′ capable of functioning as an emitter as described herein.

### BRIEF DESCRIPTION OF THE DRAWINGS

FIG. 1 shows an organic light emitting device.

FIG. 2 shows an inverted organic light emitting device that does not have a separate electron transport layer.

FIG. 3 is a chart showing capacitance versus voltage.

FIG. 4 shows a graph of modeled P-polarized photoluminescence as a function of angle for emitters with different vertical dipole ratio (VDR) values.

### DETAILED DESCRIPTION

### A. Terminology

Unless otherwise specified, the below terms used herein are defined as follows:

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “NIR”, “red”, “green”, “blue”, “yellow” layer, material, region, or device refers to a layer, a material, a region, or a device that emits light in the wavelength range of about 700-1500 nm, 580-700 nm, 500-600 nm, 400-500 nm, 540-600 nm, respectively, or a layer, a material, a region, or a device that has a highest peak in its emission spectrum in the respective wavelength region. In some arrangements, separate regions, layers, materials, or devices may provide separate “deep blue” and “light blue” emissions. As used herein, the “deep blue” emission component refers to an emission having a peak emission wavelength that is at least about 4 nm less than the peak emission wavelength of the “light blue” emission component. Typically, a “light blue” emission component has a peak emission wavelength in the range of about 465-500 nm, and a “deep blue” emission component has a peak emission wavelength in the range of about 400-470 nm, though these ranges may vary for some configurations.

In some arrangements, a color altering layer that converts, modifies, or shifts the color of the light emitted by another layer to an emission having a different wavelength is provided. Such a color altering layer can be formulated to shift wavelength of the light emitted by the other layer by a defined amount, as measured by the difference in the wavelength of the emitted light and the wavelength of the resulting light. In general, there are two classes of color altering layers: color filters that modify a spectrum by removing light of unwanted wavelengths, and color changing layers that convert photons of higher energy to lower energy. For example, a “red” color filter can be present in order to filter an input light to remove light having a wavelength outside the range of about 580-700 nm. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material, region, or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.3731, 0.6245]; [0.6270, 0.3725]; |
| | Interior: [0.3700, 0.4087]; [0.2886, 0.4572] |

The terms “halo,” “halogen,” and “halide” are used interchangeably and refer to fluorine, chlorine, bromine, and iodine.

The term “acyl” refers to a substituted carbonyl group (—C(O)—Rₛ).

The term “ester” refers to a substituted oxycarbonyl (—O—C(O)—Rₛ or —C(O)—O—Rₛ) group.

The term “ether” refers to an —OR, group.

The terms “sulfanyl” or “thio-ether” are used interchangeably and refer to a —SRₛ group.

The term “selenyl” refers to a —SeRₛ group.

The term “sulfinyl” refers to a —S(O)—Rₛ group.

The term “sulfonyl” refers to a —SO₂—Rₛ group.

The term “phosphino” refers to a group containing at least one phosphorus atom bonded to the relevant structure. Common examples of phosphino groups include, but are not limited to, groups such as a —P(Rₛ)₂ group or a —PO(Rₛ)₂ group, wherein each Rₛ can be same or different.

The term “silyl” refers to a group containing at least one silicon atom bonded to the relevant structure. Common examples of silyl groups include, but are not limited to, groups such as a —Si(Rₛ)₃ group, wherein each Rₛ can be same or different.

The term “germyl” refers to a group containing at least one germanium atom bonded to the relevant structure. Common examples of germyl groups include, but are not limited to, groups such as a —Ge(Rₛ)₃ group, wherein each Rₛ can be same or different.

The term “boryl” refers to a group containing at least one boron atom bonded to the relevant structure. Common examples of boryl groups include, but are not limited to, groups such as a —B(Rₛ)₂ group or its Lewis adduct —B(Rₛ)₃ group, wherein Rₛ can be same or different.

In each of the above, Rₛ can be hydrogen or a substituent selected from the group consisting of the general substituents as defined in this application. Preferred Rₛ is selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, and combination thereof. More preferably Rₛ is selected from the group consisting of alkyl, cycloalkyl, aryl, heteroaryl, and combination thereof.

The term “alkyl” refers to and includes both straight and branched chain alkyl groups having an alkyl carbon atom bonded to the relevant structure. Preferred alkyl groups are those containing from one to fifteen carbon atoms, preferably one to nine carbon atoms, and includes methyl, ethyl, propyl, 1-methylethyl, butyl, 1-methylpropyl, 2-methylpropyl, pentyl, 1-methylbutyl, 2-methylbutyl, 3-methylbutyl, 1,1-dimethylpropyl, 1,2-dimethylpropyl, 2,2-dimethylpropyl, and the like. Additionally, the alkyl group can be further substituted.

The term “cycloalkyl” refers to and includes monocyclic, polycyclic, and spiro alkyl groups having a ring alkyl carbon atom bonded to the relevant structure. Preferred cycloalkyl groups are those containing 3 to 12 ring carbon atoms and includes cyclopropyl, cyclopentyl, cyclohexyl, bicyclo[3.1.1]heptyl, spiro[4.5]decyl, spiro[5.5]undecyl, adamantyl, and the like. Additionally, the cycloalkyl group can be further substituted.

The terms “heteroalkyl” or “heterocycloalkyl” refer to an alkyl or a cycloalkyl group, respectively, having at least one carbon atom replaced by a heteroatom. Optionally the at least one heteroatom is selected from O, S, N, P, B, Si, Ge and Se, preferably, O, S or N. Additionally, the heteroalkyl or heterocycloalkyl group can be further substituted.

The term “alkenyl” refers to and includes both straight and branched chain alkene groups. Alkenyl groups are essentially alkyl groups that include at least one carbon-carbon double bond in the alkyl chain with one carbon atom from the carbon-carbon double bond that is bonded to the relevant structure. Cycloalkenyl groups are essentially cycloalkyl groups that include at least one carbon-carbon double bond in the cycloalkyl ring. The term “heteroalkenyl” as used herein refers to an alkenyl group having at least one carbon atom replaced by a heteroatom. Optionally the at least one heteroatom is selected from O, S, N, P, B, Si, Ge, and Se, preferably, O, S, or N. Preferred alkenyl, cycloalkenyl, or heteroalkenyl groups are those containing two to fifteen carbon atoms. Additionally, the alkenyl, cycloalkenyl, or heteroalkenyl group can be further substituted.

The term “alkynyl” refers to and includes both straight and branched chain alkyne groups. Alkynyl groups are essentially alkyl groups that include at least one carbon-carbon triple bond in the alkyl chain with one carbon atom from the carbon-carbon triple bond that is bonded to the relevant structure. Preferred alkynyl groups are those containing two to fifteen carbon atoms. Additionally, the alkynyl group can be further substituted.

The terms “aralkyl” or “arylalkyl” are used interchangeably and refer to an aryl-substituted alkyl group having an alkyl carbon atom bonded to the relevant structure. Additionally, the aralkyl group can be further substituted.

The term “heterocyclic group” refers to and includes aromatic and non-aromatic cyclic groups containing at least one heteroatom. Optionally the at least one heteroatom is selected from O, S, Se, N, P, B, Si, Ge, and Se, preferably, O, S, N, or B. Hetero-aromatic cyclic groups may be used interchangeably with heteroaryl. Preferred hetero-non-aromatic cyclic groups are those containing 3 to 10 ring atoms, preferably those containing 3 to 7 ring atoms, which includes at least one hetero atom, and includes cyclic amines such as morpholino, piperidino, pyrrolidino, and the like, and cyclic ethers/thio-ethers, such as tetrahydrofuran, tetrahydropyran, tetrahydrothiophene, and the like. Additionally, the heterocyclic group can be further substituted or fused.

The term “aryl” refers to and includes both single-ring and polycyclic aromatic hydrocarbyl groups. The polycyclic rings may have two or more rings in which two carbons are common to two adjoining rings (the rings are “fused”). Preferred aryl groups are those containing six to thirty carbon atoms, preferably six to twenty-four carbon atoms, six to eighteen carbon atoms, and more preferably six to twelve carbon atoms. Especially preferred is an aryl group having six carbons, ten carbons, twelve carbons, fourteen carbons, or eighteen carbons. Suitable aryl groups include phenyl, biphenyl, triphenyl, triphenylene, tetraphenylene, naphthalene, anthracene, phenalene, phenanthrene, pyrene, chrysene, perylene, and azulene, preferably phenyl, biphenyl, triphenyl, triphenylene, and naphthalene. Additionally, the aryl group can be further substituted or fused, such as, without limitation, fluorene.

The term “heteroaryl” refers to and includes both single-ring aromatic groups and polycyclic aromatic ring systems that include at least one heteroatom. The heteroatoms include, but are not limited to O, S, Se, N, P, B, Si, Ge, and Se. In many instances, O, S, N, or B are the preferred heteroatoms. Hetero-single ring aromatic systems are preferably single rings with 5 or 6 ring atoms, and the ring can have from one to six heteroatoms. The hetero-polycyclic ring systems can have two or more aromatic rings in which two atoms are common to two adjoining rings (the rings are “fused”) wherein at least one of the rings is a heteroaryl. The hetero-polycyclic aromatic ring systems can have from one to six heteroatoms per ring of the polycyclic aromatic ring system. Preferred heteroaryl groups are those containing three to thirty carbon atoms, preferably three to twenty-four carbon atoms, three to eighteen carbon atoms, and more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, selenophenodipyridine, azaborine, borazine, 5λ²,9λ²-diaza-13b-boranaphtho[2,3,4-de]anthracene, 5λ²-benzo[d]benzo[4,5]imidazo[3,2-a]imidazole, and 5,9-dioxa-13b-boranaphtho[3,2,1-de]anthracene; preferably dibenzothiophene, dibenzofuran, dibenzoselenophene, carbazole, indolocarbazole, imidazole, pyridine, triazine, benzimidazole, 5λ²,9λ²-diaza-13b-boranaphtho[2,3,4-de]anthracene, 5λ²-benzo[d]benzo[4,5]imidazo[3,2-a]imidazole, and 5,9-dioxa-13b-boranaphtho[3,2,1-de]anthracene. Additionally, the heteroaryl group can be further substituted or fused.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, benzimidazole, 5l²,9l²-diaza-13b-boranaphtho[2,3,4-de]anthracene, 5λ²-benzo[d]benzo[4,5]imidazo[3,2-a]imidazole, 5,9-dioxa-13b-boranaphtho[3,2,1-de]anthracene, and the respective aza-analogs of each thereof are of particular interest.

In many instances, the General Substituents are selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof.

In some instances, the Preferred General Substituents are selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

In some instances, the More Preferred General Substituents are selected from the group consisting of deuterium, fluorine, alkyl, cycloalkyl, alkoxy, aryloxy, amino, silyl, germyl, boryl, aryl, heteroaryl, nitrile, sulfanyl, and combinations thereof.

In some instances, the Even More Preferred General Substituents are selected from the group consisting of deuterium, fluorine, alkyl, cycloalkyl, silyl, aryl, heteroaryl, nitrile, and combinations thereof.

In yet other instances, the Most Preferred General Substituents are selected from the group consisting of deuterium, alkyl, cycloalkyl, aryl, heteroaryl, and combinations thereof.

The terms “substituted” and “substitution” refer to a substituent other than H that is bonded to the relevant position, e.g., a carbon or nitrogen. For example, when R¹ represents mono-substitution, then one R must be other than H (i.e., a substitution). Similarly, when R¹ represents di-substitution, then two of R¹ must be other than H. Similarly, when R¹ represents zero or no substitution, R¹, for example, can be a hydrogen for all available valencies of ring atoms, as in carbon atoms for benzene and the nitrogen atom in pyrrole, or simply represents nothing for ring atoms with fully filled valencies, e.g., the nitrogen atom in pyridine. The maximum number of substitutions possible in a ring structure will depend on the total number of available valencies in the ring atoms.

As used herein, “combinations thereof” indicates that one or more members of the applicable list are combined to form a known or chemically stable arrangement that one of ordinary skill in the art can envision from the applicable list. For example, an alkyl and deuterium can be combined to form a partial or fully deuterated alkyl group; a halogen and alkyl can be combined to form a halogenated alkyl substituent; and a halogen, alkyl, and aryl can be combined to form a halogenated arylalkyl. In one instance, the term substitution includes a combination of two to four of the listed groups. In another instance, the term substitution includes a combination of two to three groups. In yet another instance, the term substitution includes a combination of two groups. Preferred combinations of substituent groups are those that contain up to fifty atoms that are not hydrogen or deuterium, or those which include up to forty atoms that are not hydrogen or deuterium, or those that include up to thirty atoms that are not hydrogen or deuterium. In many instances, a preferred combination of substituent groups will include up to twenty atoms that are not hydrogen or deuterium.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[f,h]quinoxaline and dibenzo[f,h]quinoline. One of ordinary skill in the art can readily envision other nitrogen analogs of the aza-derivatives described above, and all such analogs are intended to be encompassed by the terms as set forth herein.

As used herein, “deuterium” refers to an isotope of hydrogen. Deuterated compounds can be readily prepared using methods known in the art. For example, U.S. Pat. No. 8,557,400, Patent Pub. No. WO 2006/095951, and U.S. Pat. Application Pub. No. US 2011/0037057, which are hereby incorporated by reference in their entireties, describe the making of deuterium-substituted organometallic complexes. Further reference is made to Ming Yan, et al., Tetrahedron 2015, 71, 1425-30 and Atzrodt et al., Angew. Chem. Int. Ed. (Reviews) 2007, 46, 7744-65, which are incorporated by reference in their entireties, describe the deuteration of the methylene hydrogens in benzyl amines and efficient pathways to replace aromatic ring hydrogens with deuterium, respectively.

As used herein, any specifically listed substituent, such as, without limitation, methyl, phenyl, pyridyl, etc. includes undeuterated, partially deuterated, and fully deuterated versions thereof. Similarly, classes of substituents such as, without limitation, alkyl, aryl, cycloalkyl, heteroaryl, etc. also include undeuterated, partially deuterated, and fully deuterated versions thereof. Unless otherwise specified, atoms in chemical structures without valences fully filled by H or D should be considered to include undeuterated, partially deuterated, and fully deuterated versions thereof. For example, the chemical structure of [symbol] implies to include C₆H₆, C₆D₆, C₆H₃D₃, and any other partially deuterated variants thereof. Some common basic partially or fully deuterated group include, without limitation, CD₃, CD₂C(CH₃)₃, C(CD₃)₃, and C₆D₅.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In some instances, a pair of substituents in the molecule can be optionally joined or fused into a ring. The preferred ring is a five to nine-membered carbocyclic or heterocyclic ring, includes both instances where the portion of the ring formed by the pair of substituents is saturated and where the portion of the ring formed by the pair of substituents is unsaturated. In yet other instances, a pair of adjacent substituents can be optionally joined or fused into a ring. As used herein, “adjacent” means that the two substituents involved can be on the same ring next to each other, or on two neighboring rings having the two closest available substitutable positions, such as 2, 2′ positions in a biphenyl, or 1, 8 position in a naphthalene.

### B. The Compounds of the Present Disclosure

Narrow lineshape emission is a highly desirable property for phosphorescent emitters in order to achieve improved color gamut and viewing angle dependence of displays. Unfortunately, high efficiency, afforded by alignment of the molecular long axis to the emissive TDM vector, is often at odds with achieving narrow emission lineshape. This is primarily due to the fact that achieving narrow emission often involves including a high degree of substitution on the emitter in a direction not well aligned with the TDM vector.

Typically, the design for emitters with low VDR requires extending the geometric long axis to line up with the TDM. Most Ir complexes have a TDM near the Ir—N bond. Conversely, achieving narrow lineshapes can be achieved by further fusing to the ring anionically bound to the Ir. By adding electron deficient moieties to the fused anionically bound ring system, the TDM can be preferentially aligned to point towards the fused ring portion, so the long axis achieved from the fused ring system is better aligned giving lower VDR with narrow lineshape. Using this approach, the emissive compounds described herein are designed to achieve both narrow emission and high efficiency simultaneously.

In one aspect, the present disclosure provides a compound E1 capable of functioning as an emitter in an OLED at room temperature. The compound is a metal coordination complex; the metal coordination complex comprises a first ligand, L_{A}, that comprises a first group; and the metal coordination complex comprises a covalent bond between the metal and the first group; wherein the TDM of the emissive state of the complex has a vector, wherein an angle formed between the TDM vector and the covalent bond between the metal and the first group is less than or equal to 40°, and wherein an excited state of the metal coordination complex has a LC character localized on the first group of greater than or equal to 45%.

In some embodiments, the first group is the ring(s) covalently bound to the metal including the further substituents but does not include ring(s) datively bound to the metal and the further substituents. Thus, for example, in a bidentate phenylpyridine ligand, the first group would be the pyridine ring and substituents attached thereto, but would not include the phenyl ring and substituents attached thereto.

In some embodiments, the excited state of the metal coordination complex has an LC character localized on the first group of greater than or equal to 50%. In some embodiments, the excited state of the metal coordination complex has an LC character localized on the first group of greater than or equal to 55%. In some embodiments, the excited state of the metal coordination complex has an LC character localized on the first group of greater than or equal to 60%. In some embodiments, the excited state of the metal coordination complex has an LC character localized on the first group of greater than or equal to 65%. In some embodiments, the excited state of the metal coordination complex has an LC character localized on the first group of greater than or equal to 70%.

In some embodiments, the angle formed between the TDM vector and the covalent bond between the metal and the first group is less than or equal to 35°. In some embodiments, the angle formed between the TDM vector and the covalent bond between the metal and the first group is less than or equal to 30°. In some embodiments, the angle formed between the TDM vector and the covalent bond between the metal and the first group is less than or equal to 25°. In some embodiments, the angle formed between the TDM vector and the covalent bond between the metal and the first group is less than or equal to 20°. In some embodiments, the angle formed between the TDM vector and the covalent bond between the metal and the first group is less than or equal to 15°. In some embodiments, the angle formed between the TDM vector and the covalent bond between the metal and the first group is less than or equal to 10°. In some embodiments, the angle formed between the TDM vector and the covalent bond between the metal and the first group is less than or equal to 5°.

To determine LC character (ligand centered character), density-functional theory (DFT) calculations can be performed to determine the energy of the lowest triplet (T₁) excited state, and the percentage of metal-to-ligand charge transfer (³MLCT) and LC character involved in T₁ of the compounds. The data can be gathered using the program Gaussian16. Geometries were optimized using B3LYP functional and CEP-31G basis set. Excited state energies can be computed by time-dependent density-functional theory (TDDFT) at the optimized ground state geometries. Tetrahydrofuran (THF) solvent can be simulated using a self-consistent reaction field to further improve agreement with the experiment. Metal-to-ligand charge transfer (³MLCT) and LC contributions can be determined via transition density matrix analysis of the excited states. For TDM determination, the B3LYP functional and DYALL-V2Z_ZORA-J-PT-SEG basis set were used to perform TDDFT calculations with the spin-orbit ZORA Hamiltonian.

The calculations obtained with the above-identified DFT functional set and basis set are theoretical. Computational composite protocols, such as the Gaussian16 with B3LYP and CEP-31G protocol used herein, rely on the assumption that electronic effects are additive and, therefore, larger basis sets can be used to extrapolate to the complete basis set (CBS) limit. However, when the goal of a study is to understand variations in HOMO, LUMO, S₁, T₁, bond dissociation energies, etc. over a series of structurally-related compounds, the additive effects are expected to be similar. Accordingly, while absolute errors from using the B3LYP may be significant compared to other computational methods, the relative differences between the HOMO, LUMO, S₁, T₁, and bond dissociation energy values calculated with B3LYP protocol are expected to reproduce experiment quite well. See, e.g., Hong et al., Chem. Mater. 2016, 28, 5791-98, 5792-93 and Supplemental Information (discussing the reliability of DFT calculations in the context of OLED materials). Moreover, with respect to iridium or platinum complexes that are useful in the OLED art, the data obtained from DFT calculations correlate very well to actual experimental data. See Tavasli et al., J. Mater. Chem. 2012, 22, 6419-29, 6422 (Table 3) (showing DFT calculations closely correlating with actual data for a variety of emissive complexes); Morello, G. R., J. Mol. Model. 2017, 23:174 (studying of a variety of DFT functional sets and basis sets and concluding the combination of B3LYP and CEP-31G is particularly accurate for emissive complexes). The determination of excited state transition character is performed as a post-processing step on the above-mentioned DFT and TDDFT calculations. This analysis allows for decomposition of the excited state into the hole, i.e., where the excitation originates, and the electron, i.e., the final location of the excited state. Additionally, as this analysis is performed on a calculated property it is objective and repeatable; see Mai et al., Coord. Chem. Rev. 2018, 361, 74-97 (discussing the theoretical basis of the excited state decomposition in transition metal complexes). TDMs were calculated using the spin-orbit ZORA Hamiltonian; see Chang et al., Phys. Scr. 1986, 34, 394 and Faas et al., Chem. Phys. Lett. 1995, 246, 632-640. The ZORA Hamiltonian allows for the including of relativistic effects that accounts for the mixing of states with different multiplicities and affords relaxation of the normally forbidden T₁-to-S₀ transition.

In some embodiments, the angle formed between the TDM vector and the covalent bond between the metal and the first group is less than or equal to 15°. In some embodiments, the angle formed between the TDM vector and the covalent bond between the metal and the first group is less than or equal to 10°. In some embodiments, the angle formed between the TDM vector and the covalent bond between the metal and the first group is less than or equal to 5°.

In some embodiments, an excited state of the compound has an LC character localized on the first group of greater than or equal to 58%. In some embodiments, an excited state of the compound has an LC character localized on the first group of greater than or equal to 60%. In some embodiments, an excited state of the compound has an LC character localized on the first group of greater than or equal to 65%. In some embodiments, an excited state of the compound has an LC character localized on the first group of greater than or equal to 70%. In some embodiments, an excited state of the compound has an LC character localized on the first group of greater than or equal to 80%. In some embodiments, an excited state of the compound has an LC character localized on the first group of greater than or equal to 90%.

In some embodiments, the covalent bond between the metal and the first group is an M-C bond, and a natural transition orbital (NTO) electron integral of a ligand fragment comprising the M-C bond is at least 60%. In some embodiments, the covalent bond between the metal and the first group is an M-C bond, and an NTO electron integral of a ligand fragment comprising the M-C bond is at least 65%. In some embodiments, the covalent bond between the metal and the first group is an M-C bond, and an NTO electron integral of a ligand fragment comprising the M-C bond is at least 70%. In some embodiments, the covalent bond between the metal and the first group is a M-C bond, and an NTO electron integral of a ligand fragment comprising the M-C bond is at least 75%. In some embodiments, the covalent bond between the metal and the first group is an M-C bond, and an NTO electron integral of a ligand fragment comprising the M-C bond is at least 80%.

In some embodiments, the compound has a rod-like parameter, R^{R}, of at least 50%. In some embodiments, the compound has a rod-like parameter, R^{R}, of at least 60%. In some embodiments, the compound has a rod-like parameter, R^{R}, of at least 70%. In some embodiments, the compound has a rod-like parameter, R^{R}, of at least 80%.

As used herein, the “rod-like-axis” of a compound is the axis of the Principal Moment of Inertia (PMI) associated with the smallest PMI of the compound. The rod-like-axis can be determined starting by defining a Normalized Principal moments Ratio (NPR) metric space made up of molecular 3D descriptors to give coordinates (NPR1, NPR2), where

$$N P R 1 = \frac{I 1}{I 3} and N P R 2 = \frac{I 2}{I 3}$$

In these calculations, I1, I2, and I3 are the Principal Moments of Inertia for a molecule's given 3D structure in increasing order (I1≤I2≤I3), and can be calculated from a variety of software, such as Schrodinger's Maestro suite. A compound's rod-like parameter R^{R} is defined generally as its proximity in NPR metric space to the value (0, 1), and can quantitatively be written as:

$${R}^{R} = 1.0 - {( {( \frac{{I}_{1}}{{I}_{3}} )}^{2} + 3 {( \frac{{I}_{2}}{{I}_{3}} - 1 )}^{2} )}^{\frac{1}{2}} .$$

In calculating NPR1 and NPR2, noise will exist based on molecular conformations. To minimize this noise, the lowest energy conformation was utilized, where energy is defined as the total energy from some electronic structure calculator.

In some embodiments, the compound has a HOMO energy lower than −5.15 eV. In some embodiments, the compound has a HOMO energy lower than −5.18 eV. In some embodiments, the compound has a HOMO energy lower than −5.20 eV. In some embodiments, the compound has a HOMO energy lower than −5.22 eV.

Device capacitance is a phenomenon that relates to the operation of the device under a high refresh rate (>60 Hz) driving scheme. In general, it is desirable for this capacitance to be minimized to improve turn-on characteristics of the display. Device capacitance can be measured by the RFCV method.

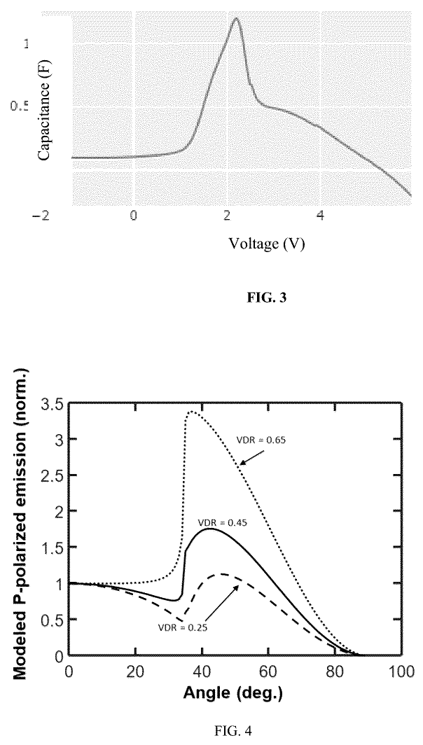

The measurement is performed as follows: an aluminum fixture is utilized for temperature control, shielding, and interconnection to the OLED sample. Signals are routed from internal low resistance contacts to external BNC connections. Device temperature is regulated by an externally controlled thermoelectric element in contact with the OLED device. The external BNC connections are wired to an LCR meter in a shielded two-terminal configuration. Open and short compensations are measured and utilized for subsequent measurements. For each measurement temperature, automation software initiates 4 sequential linear voltage sweeps from −2 VDC to 6 VDC with a stimulus voltage of 0.1 VAC at frequencies of 100 Hz, 500 Hz, 1 kHz, and 10 kHz. The instrument operates as an auto-balancing bridge to measure the complex impedance parameters and reports a parallel modeled capacitance value at each voltage point. The software correlates the measurement data with the unique ID of the OLED device and the datasets are saved for reporting. All data is linearly offset such that the −2V data point is equal to 1×10⁻¹⁰, to account for experimental baseline differences, prior to numerical analysis. An example of a capacitance versus voltage curve is shown in FIG. 3.

Minimizing capacitance may refer to decreasing the peak value of this capacitance curve, increasing the voltage at which the capacitance rises from baseline, decreasing the broadness of the peak, decreasing the area under the curve from −2V to the peak, or decreasing to total area under the curve. One measurement of interest is the Q parameter for capacitance. The Q parameter is defined as the integrated area under the curve from −2V to the peak of the curve.

For purposes of this disclosure, the device structure used for Q measurements is as follows: devices are fabricated by high vacuum (<10⁻⁷ Torr) thermal evaporation (VTE). The anode electrode is 800 Å of indium tin oxide (ITO), which has an active area of 2 mm², as defined by a non-conductive grid. The cathode is 10 Å of LiF followed by 1000 Å of Al. All devices are encapsulated with a glass lid sealed with an epoxy resin in a nitrogen glove box (<1 ppm of H₂O and O₂) immediately after fabrication, with a moisture getter incorporated inside the package.

The organic stack consists of sequentially, from the ITO surface, 100 Å of HATCN as the hole injection layer (HIL), 400 Å of hole transport material HTM as the hole transport layer (HTL), 50 Å of EBL as an electron blocking layer (EBL), 400 Å of H1 doped with 30 wt % H2 and 5 wt % emitter as the emissive layer (EML), 50 Å of H2 as a blocking layer (BL), and 300 Å of 35% ETM in Liq (8-quinolinolato lithium) as the electron transport layer (ETL). As used herein, HATCN, HTM, EBL, H1, H2, and ETM have the following structures:

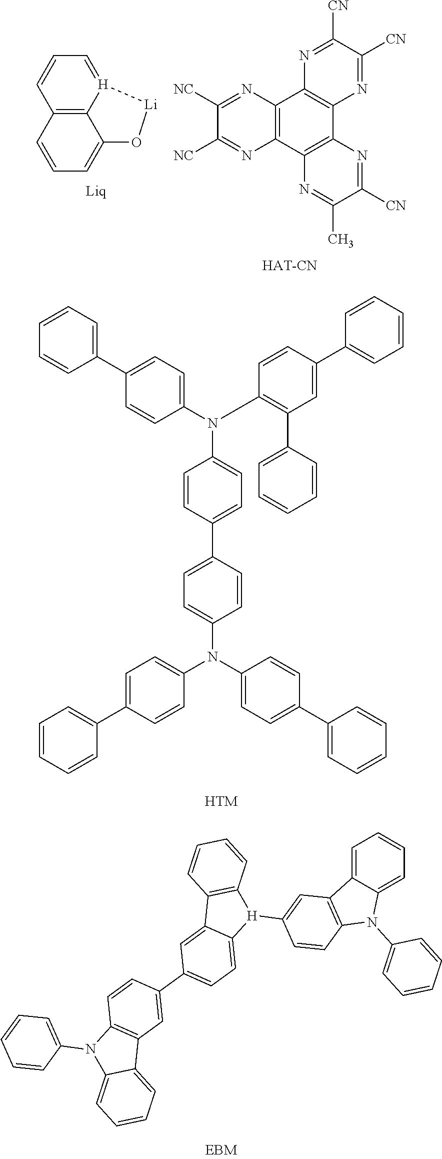

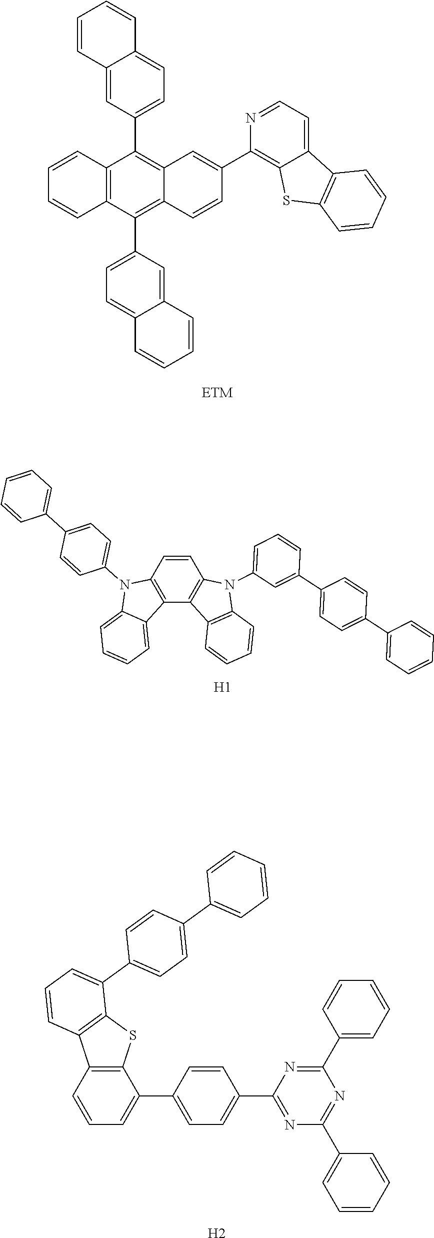

In some embodiments, the compound has a Q parameter less than 1×10⁻⁹ C. In some embodiments, the compound has a Q parameter less than 8×10⁻¹⁰ C. In some embodiments, the compound has a Q parameter less than 6×10⁻¹⁰ C.

In some embodiments, the compound is an iridium coordination complex.

In some embodiments, the compound has a fac-configuration. In some embodiments, the compound has a mer-configuration.

In some embodiments, the compound comprises a substituted or unsubstituted acetylacetonate ligand.

In some embodiments, the compound is a platinum coordination complex.

In some embodiments, the compound comprises a tetradentate ligand. In some embodiments, the compound comprises a square-planar, tetradentate ligand.

In some embodiments, the compound is heteroleptic.

In some embodiments, the compound comprises an emissive ligand. In some embodiments, the emissive ligand is L_{A}.

In some embodiments, the emissive ligand comprises a moiety selected from the group consisting of benzene, pyridine, pyrimidine, pyridazine, pyrazine, triazine, imidazole, pyrazole, pyrrole, oxazole, furan, thiophene, thiazole, triazole, naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, carbazole, aza-carbazole, dibenzofuran, aza-dibenzofuran, dibenzothiophene, aza-dibenzothiophene, quinoxaline, phthalazine, phenanthrene, aza-phenanathrene, anthracene, aza-antracene, phenanthridine, fluorene, and aza-fluorene.

In some embodiments, the emissive ligand comprises a moiety selected from the group consisting of pyridine, imidazole, pyrazole, and imidazole-derived carbene.

In some embodiments, the emissive ligand comprises a moiety selected from the group consisting of carbazole, aza-carbazole, dibenzofuran, aza-dibenzofuran, dibenzothiophene, and aza-dibenzothiophene. In some embodiments, the emissive ligand comprises a dibenzofuran or aza-dibenzofuran moiety.

In some embodiments, the compound comprises an electron-withdrawing group having a Hammett constant larger than 0. In some embodiments, the electron-withdrawing group has a Hammett constant of at least 0.1. at least 0.2, or at least 0.3, or at least 0.4, or at least 0.5, or at least 0.6, or at least 0.7, or at least 0.8, or at least 0.9, or at least 1.0, or at least 1.1.

In some embodiments, the electron-withdrawn group is selected from the group consisting of the structures of the following EWG1 LIST: F, CF₃, CN, COCH₃, CHO, COCF₃, COOMe, COOCF₃, NO₂, SF₃, SiF₃, PF₄, SF₅, OCF₃, SCF₃, SeCF₃, SOCF₃, SeOCF₃, SO₂F, SO₂CF₃, SeO₂CF₃, OSeO₂CF₃, OCN, SCN, SeCN, NC, ⁺N(R^{k2})₃, (R^{k2})₂CCN, (R^{k2})₂CCF₃, CNC(CF₃)₂, BR^{k3}R^{k2}, substituted or unsubstituted dibenzoborole, 1-substituted carbazole, 1,9-substituted carbazole, substituted or unsubstituted carbazole, substituted or unsubstituted pyridine, substituted or unsubstituted pyrimidine, substituted or unsubstituted pyrazine, substituted or unsubstituted pyridoxine, substituted or unsubstituted triazine, substituted or unsubstituted oxazole, substituted or unsubstituted benzoxazole, substituted or unsubstituted thiazole, substituted or unsubstituted benzothiazole, substituted or unsubstituted imidazole, substituted or unsubstituted benzimidazole, ketone, carboxylic acid, ester, nitrile, isonitrile, sulfinyl, sulfonyl, partially and fully fluorinated alkyl, partially and fully fluorinated aryl, partially and fully fluorinated heteroaryl, cyano-containing alkyl, cyano-containing aryl, cyano-containing heteroaryl, isocyanate,

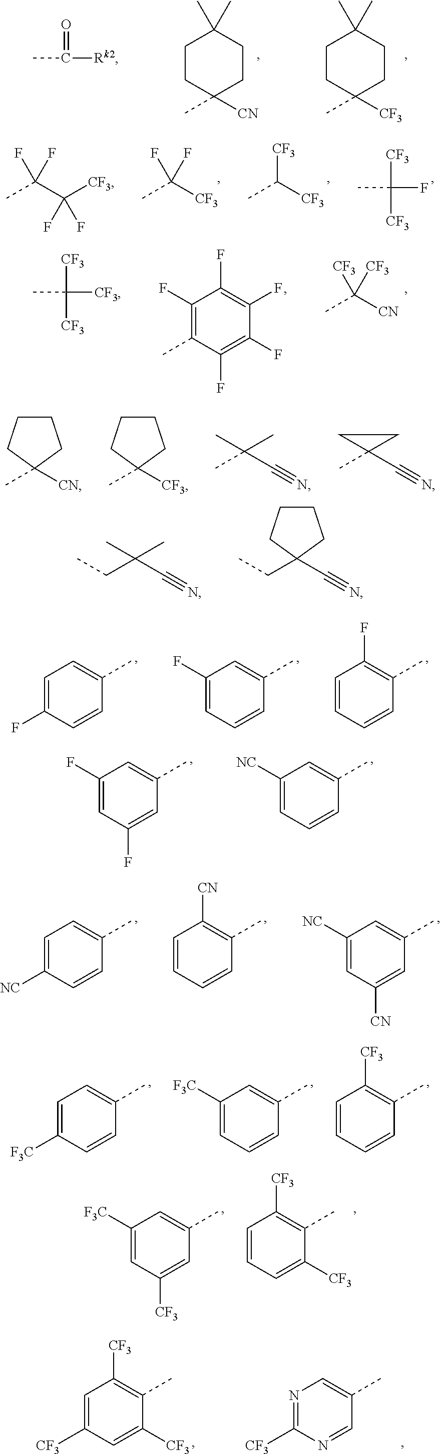

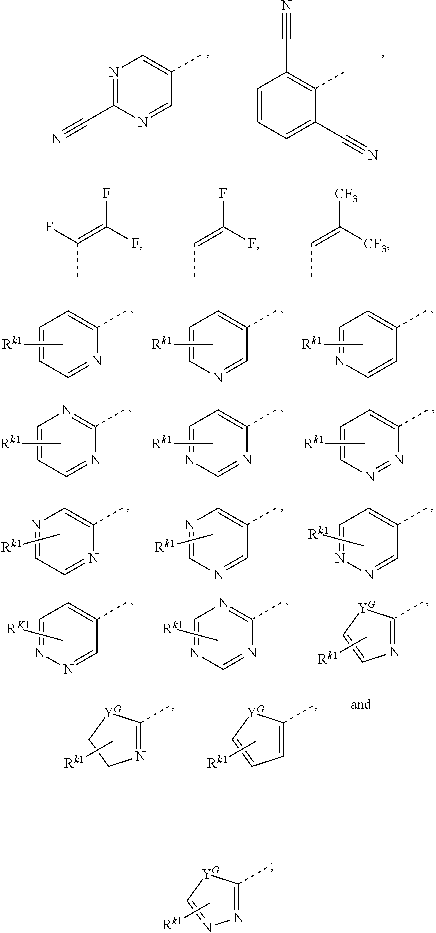

wherein each R^{k1} represents mono to the maximum allowable substitution, or no substitutions;
wherein Y^{G} is selected from the group consisting of BRₑ, NRₑ, PRₑ, O, S, Se, C═O, S═O, SO₂, CRₑR_{f}, SiRₑR_{f}, and GeRₑR_{f}; and
wherein each of R^{k1}, R^{k2}, R^{k3}, Rₑ, and R_{f} is independently a hydrogen or a substituent selected from the group consisting of the General Substituents defined herein.

In some embodiments, the electron-withdrawing group is selected from the group consisting of the structures of the following EWG2 List:

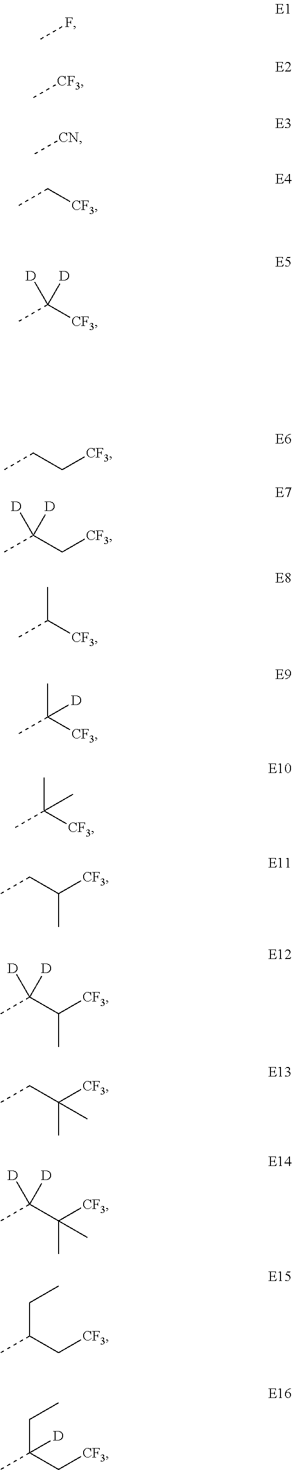

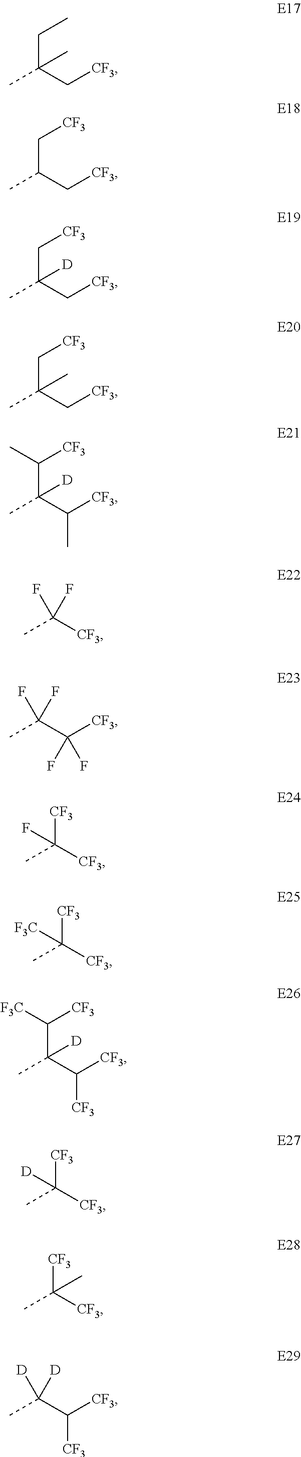

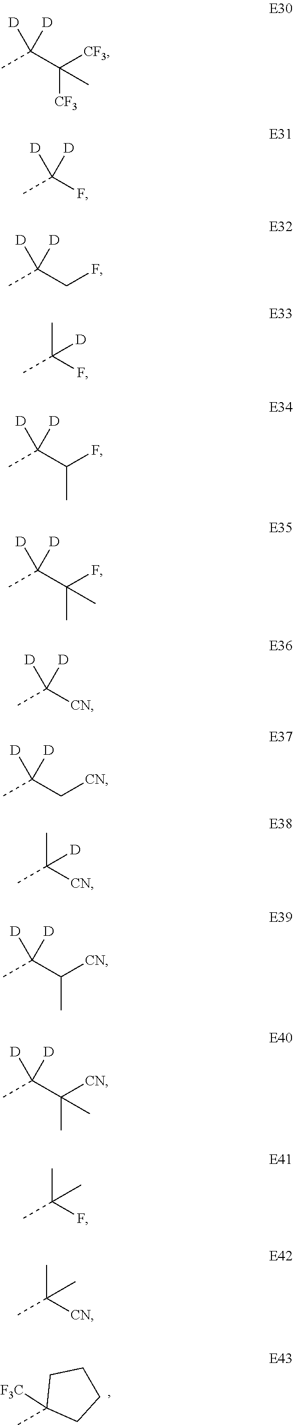

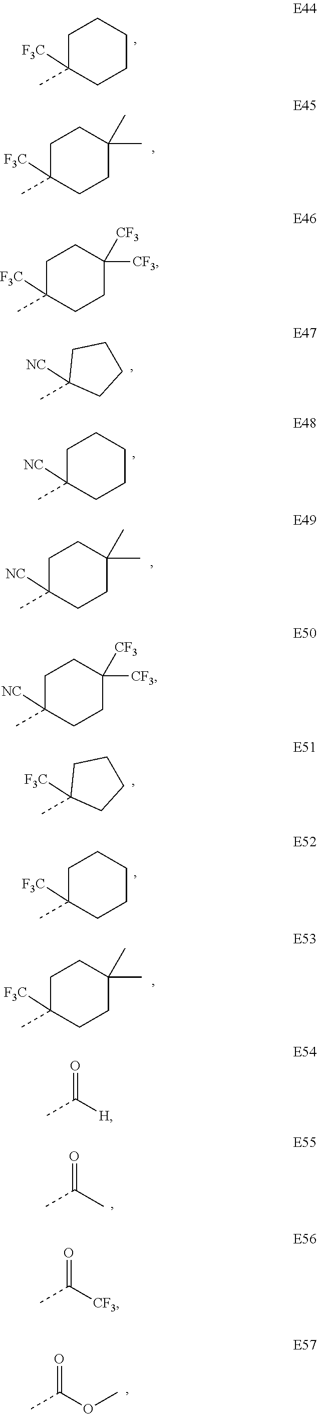

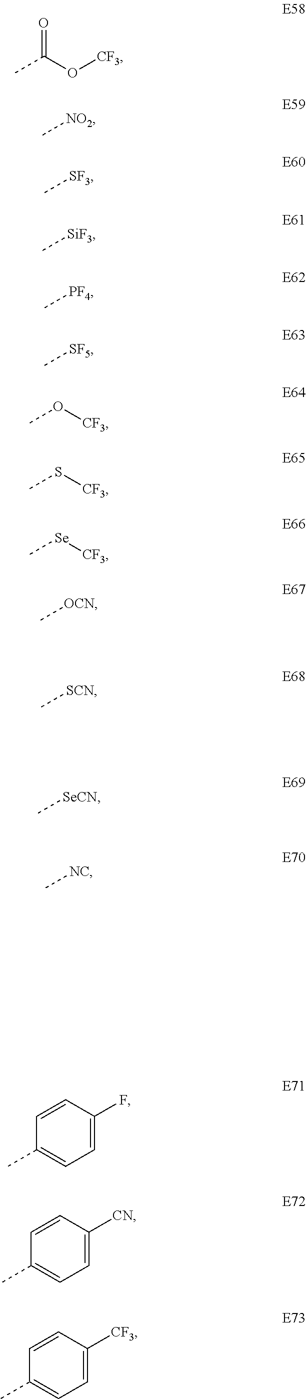

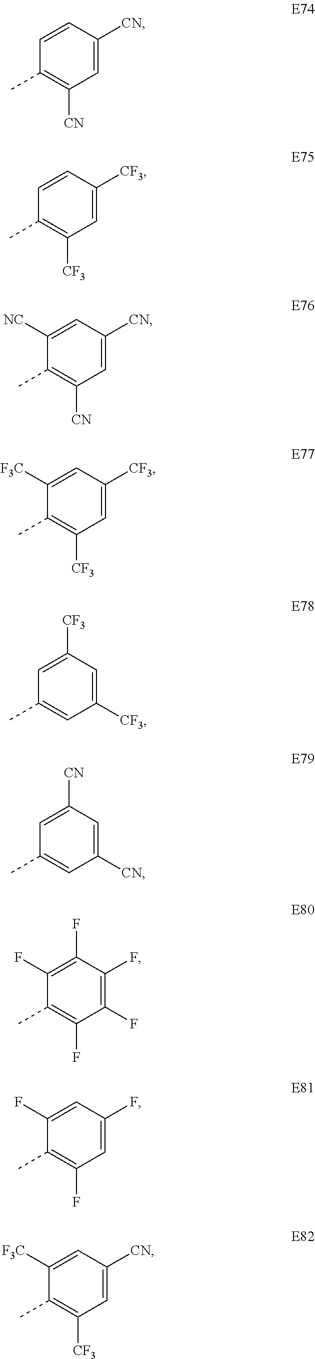

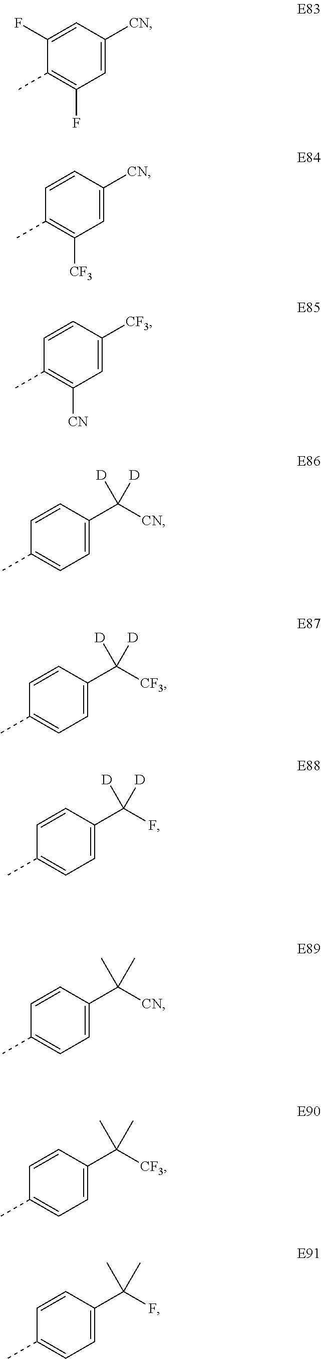

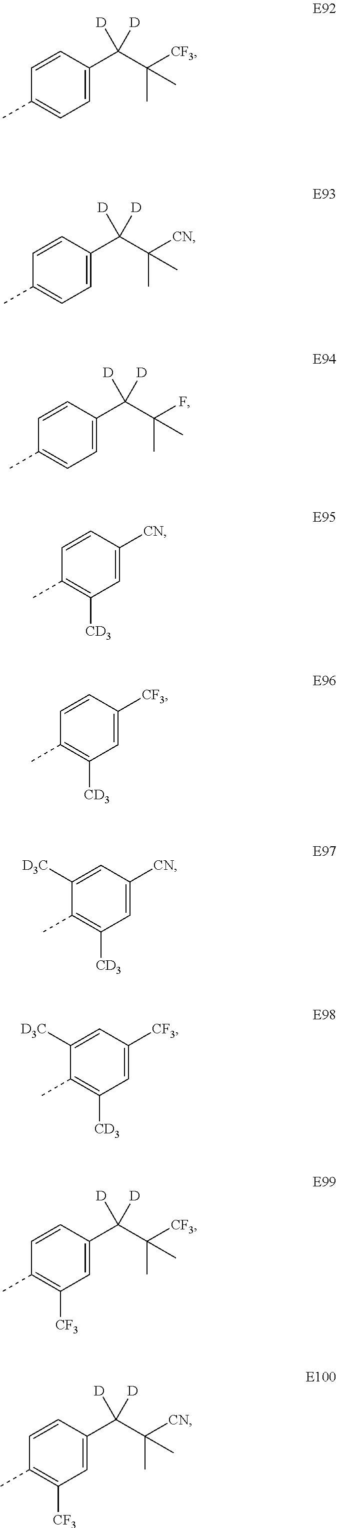

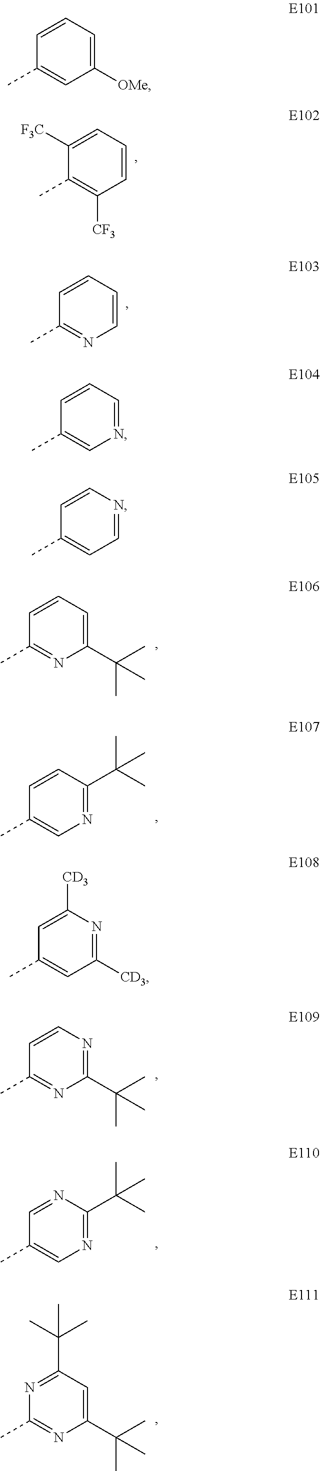

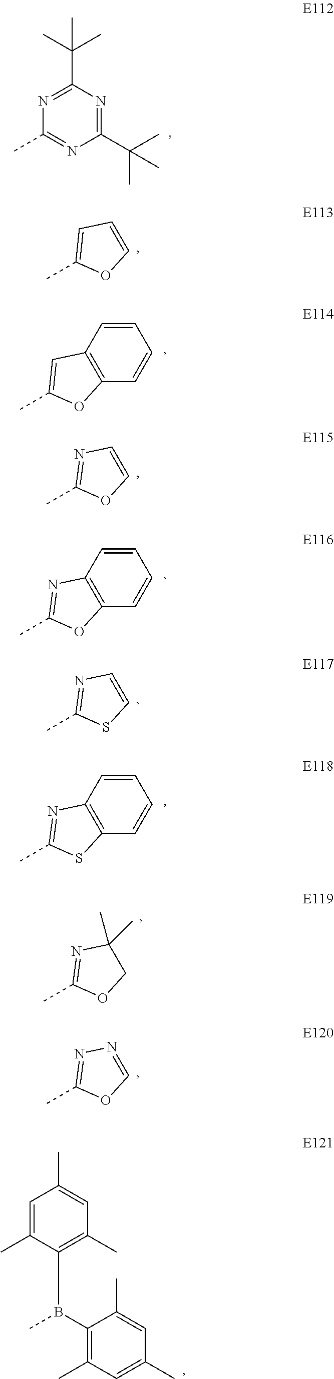

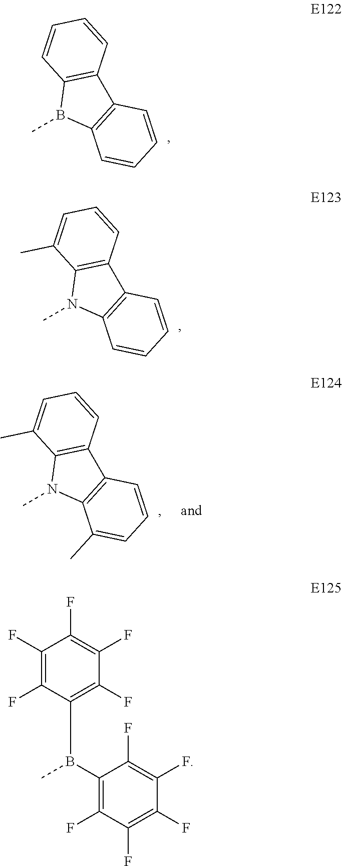

In some embodiments, the electron-withdrawing group is selected from the group consisting of the structures of the following EWG3 LIST:

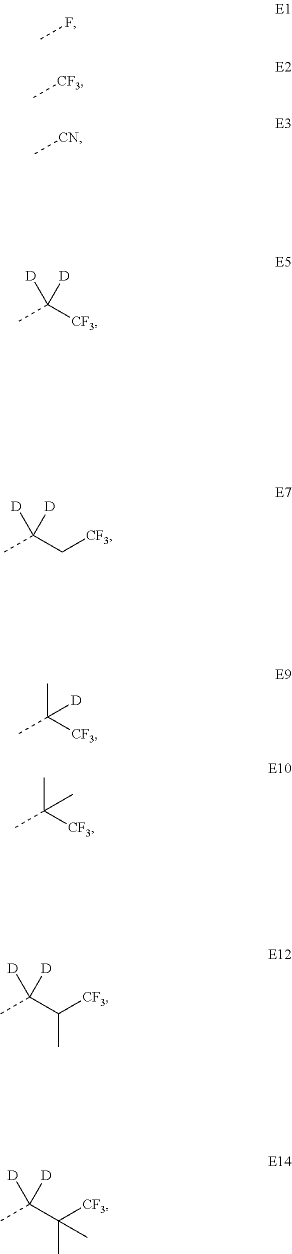

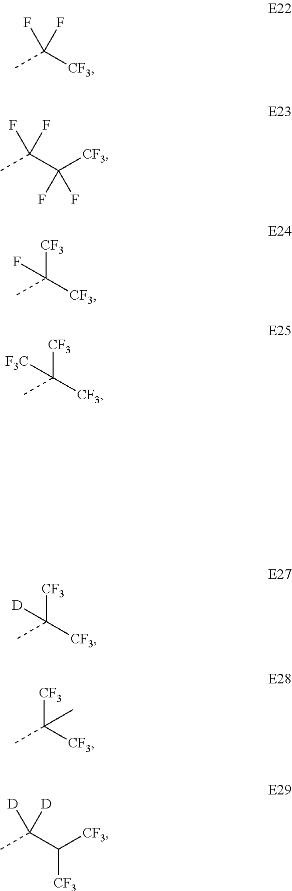

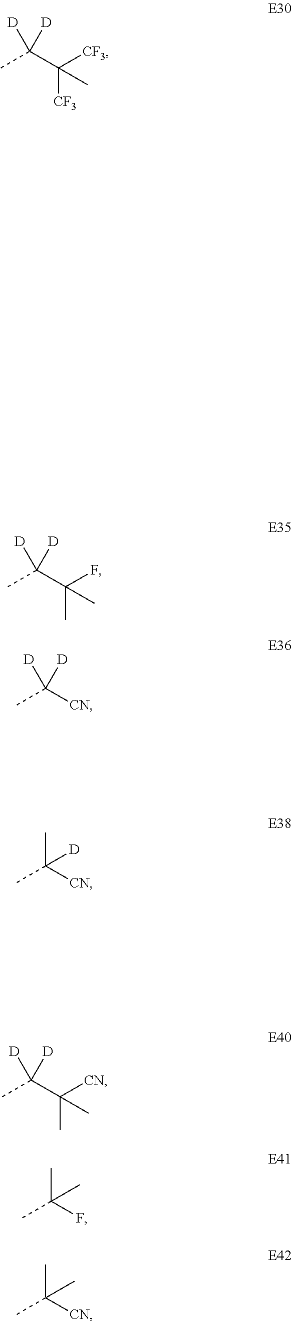

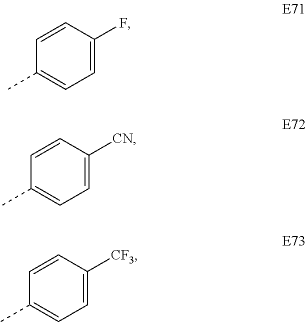

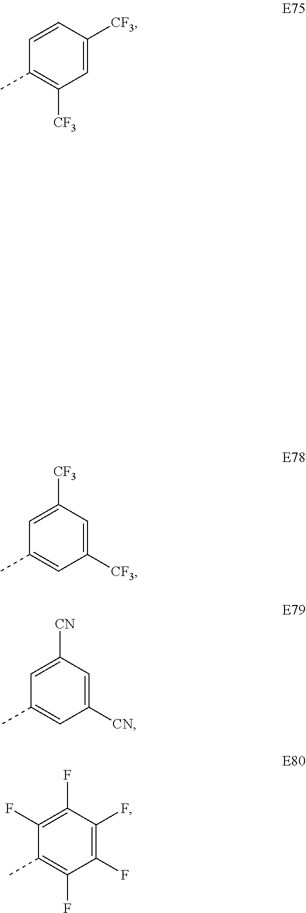

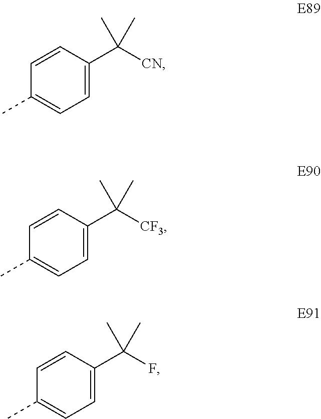

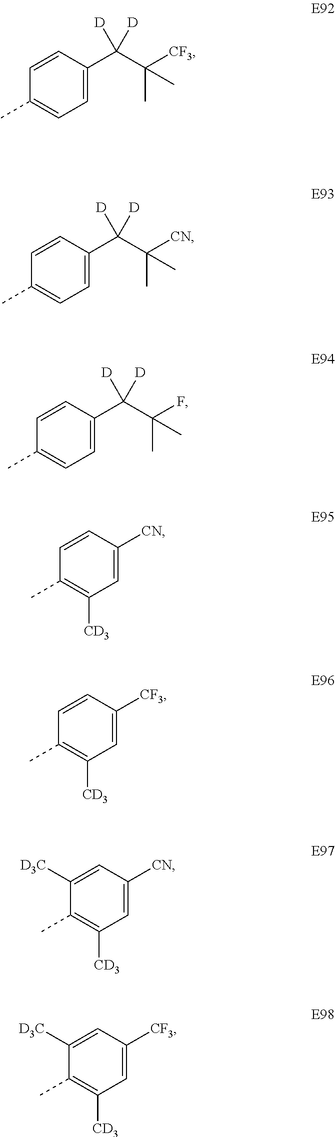

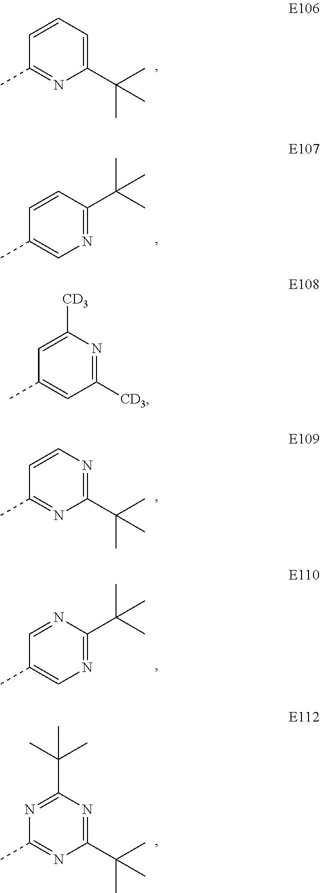

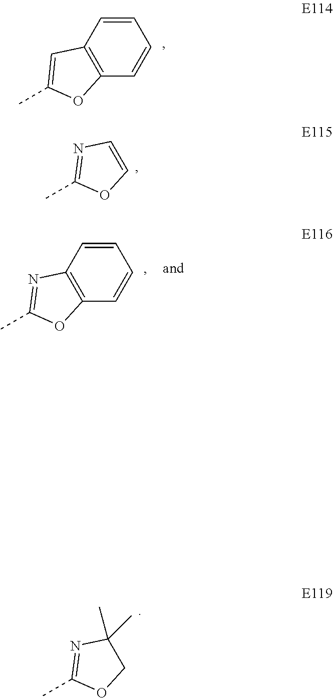

In some embodiments, the electron-withdrawing group is selected from the group consisting of the structures of the following EWG4 LIST:

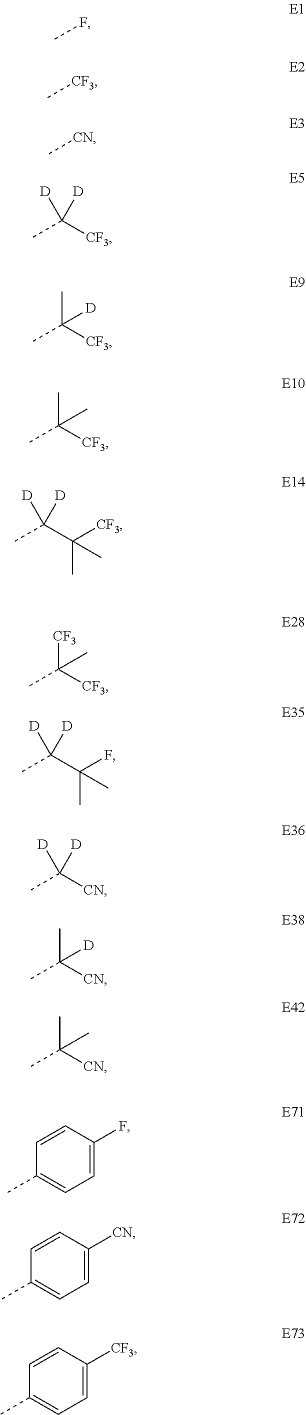

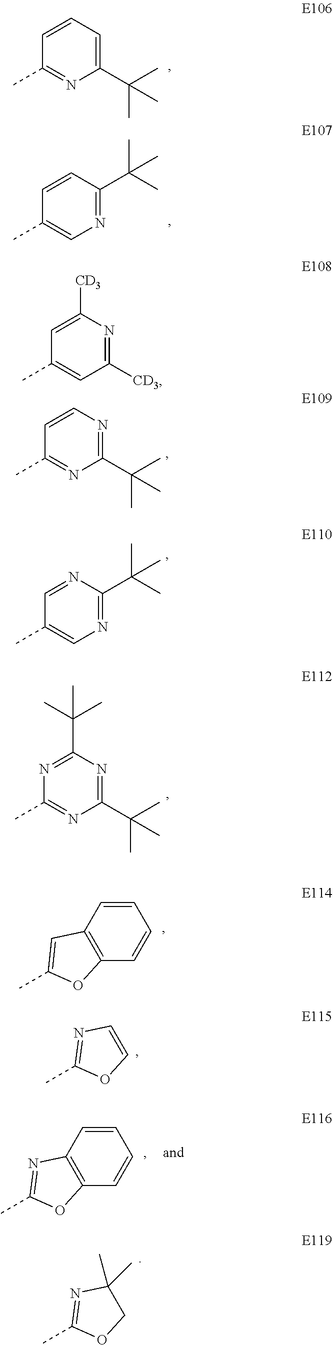

In some embodiments, the electron-withdrawing group is a π-electron deficient electron-withdrawing group. In some embodiments, the π-electron deficient electron-withdrawing group is selected from the group consisting of the structures of the following Pi-EWG LIST: CN, COCH₃, CHO, COCF₃, COOMe, COOCF₃, NO₂, SF₃, SiF₃, PF₄, SF₅, OCF₃, SCF₃, SeCF₃, SOCF₃, SeOCF₃, SO₂F, SO₂CF₃, SeO₂CF₃, OSeO₂CF₃, OCN, SCN, SeCN, NC, ⁺N(R^{k2})₃, BR¹²R¹³, substituted or unsubstituted dibenzoborole, 1-substituted carbazole, 1,9-substituted carbazole, substituted or unsubstituted carbazole, substituted or unsubstituted pyridine, substituted or unsubstituted pyrimidine, substituted or unsubstituted pyrazine, substituted or unsubstituted pyridazine, substituted or unsubstituted triazine, substituted or unsubstituted oxazole, substituted or unsubstituted benzoxazole, substituted or unsubstituted thiazole, substituted or unsubstituted benzothiazole, substituted or unsubstituted imidazole, substituted or unsubstituted benzimidazole, ketone, carboxylic acid, ester, nitrile, isonitrile, sulfinyl, sulfonyl, partially and fully fluorinated aryl, partially and fully fluorinated heteroaryl, cyano-containing aryl, cyano-containing heteroaryl, isocyanate,

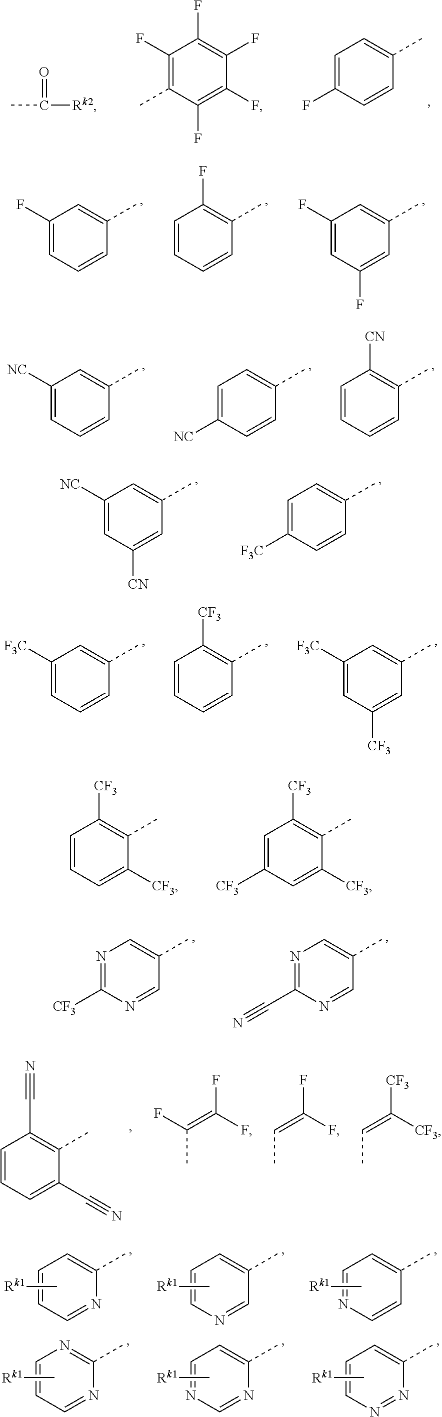

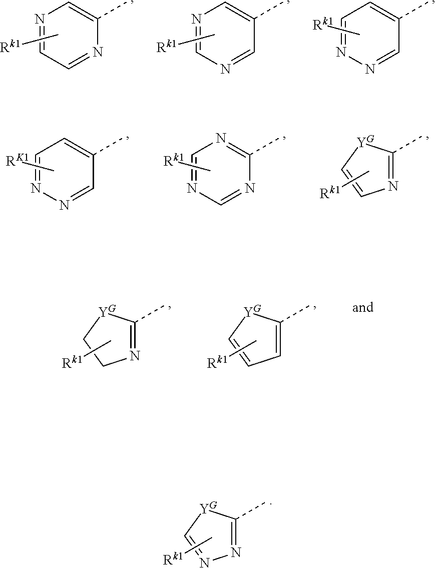

In some embodiments, the compound comprises at least one ancillary ligand, wherein the ancillary ligand comprises the electron-withdrawn group. In some embodiments, the compound comprises at least one emissive ligand, wherein the emissive ligand comprises the electron-withdrawn group.

In some embodiments, the compound comprises at least one emissive ligand, wherein the emissive ligand does not comprise the electron-withdrawn group.

In some embodiments, the compound comprises a first ligand, L_{A}, having the structure of Formula I,

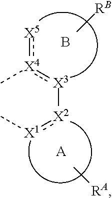

wherein:
each of moiety A and moiety B is independently a monocyclic ring or a polycyclic fused ring system, where the monocyclic ring or each ring of the polycyclic fused ring system is independently a 5-membered or 6-membered carbocyclic or heterocyclic ring;
ring B is the ring comprising X³, X⁴, and X⁵ and is a 5-membered or 6-membered carbocyclic or heterocyclic ring;
each of X¹ to X⁵ is independently C or N;
[symbol] is either a single bond or a double bond;
X¹ forms a covalent bond with the metal;
R^{A} and R^{B} each independently represent mono to the maximum allowable substitution, or no substitution;
each R^{A} and R^{B} is independently a hydrogen or a substituent selected from the group consisting of the General Substituents defined herein; and
any two substituents may be joined or fused to form a ring.

In some embodiments comprising L_{A}, each of X², X³, and X⁵ is C.

In some embodiments comprising L_{A}, X² is C, and X³ and X⁵ are N.

In some embodiments comprising L_{A}, X¹ is C and X² is N.

In some embodiments comprising L_{A}, X¹ is C and X² is carbene C.

In some embodiments comprising L_{A}, each of moiety A and moiety B is independently selected from the group consisting of benzene, pyridine, pyrimidine, pyridazine, pyrazine, triazine, imidazole, imidazole derived carbene, pyrazole, pyrrole, oxazole, furan, thiophene, thiazole, triazole, naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, benzimidazole derived carbene, aza-benzimidazole derived carbene, carbazole, aza-carbazole, dibenzofuran, aza-dibenzofuran, dibenzothiophene, aza-dibenzothiophene, quinoxaline, phthalazine, phenanthrene, aza-phenanathrene, anthracene, aza-antracene, phenanthridine, fluorene, and aza-fluorene.

In some embodiments comprising L_{A}, moiety A is a polycyclic fused ring system. In some such embodiments, moiety A comprises at least 3 fused rings. In some such embodiments, moiety A is selected from the group consisting of carbazole, aza-carbazole, dibenzofuran, aza-dibenzofuran, dibenzothiophene, aza-dibenzothiophene, quinoxaline, phthalazine, phenanthrene, aza-phenanathrene, anthracene, aza-antracene, phenanthridine, fluorene, and aza-fluorene.

In some embodiments comprising L_{A}, moiety A comprises at least 4 fused rings. In some embodiments comprising L_{A}, moiety A comprises at least 5 fused rings.

In some embodiments, at least one R^{A} is an electron-withdrawing group selected from the group consisting of the EWG1 LIST excluding fluoroalkyl. In some embodiments, at least one R^{A} is an electron-withdrawing group selected from the group consisting of the EWG2 LIST excluding fluoroalkyl. In some embodiments, at least one R^{A} is an electron-withdrawing group selected from the group consisting of the EWG3 LIST excluding fluoroalkyl. In some embodiments, at least one R^{A} is an electron-withdrawing group selected from the group consisting of the EWG4 LIST excluding fluoroalkyl. In some embodiments, at least one R^{A} is an electron-withdrawing group selected from the group consisting of the Pi-EWG LIST.

In some embodiments comprising L_{A}, at least one R^{A} is F, CN, aryl substituted by at least one F or CN, and heteroaryl substituted by at least one F or CN.

In some embodiments comprising L_{A}, no R^{A} is an electron-withdrawing group. In some embodiments comprising L_{A}, no R^{A} is selected from the EWG1 LIST.

In some embodiments comprising L_{A}, moiety B is selected from the group consisting of benzene, pyridine, pyrimidine, pyridazine, pyrazine, triazine, imidazole, pyrazole, pyrrole, oxazole, furan, thiophene, thiazole, triazole, naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, and aza-benzimidazole.

In some embodiments comprising L_{A}, moiety B is selected from the group consisting of pyrazole, imidazole-derived carbene, imidazole, benzimidazole-derived carbene, and benzimidazole.

In some embodiments comprising L_{A}, the first ligand L_{A} is selected from the group consisting of the structures of the following LIST 1a:

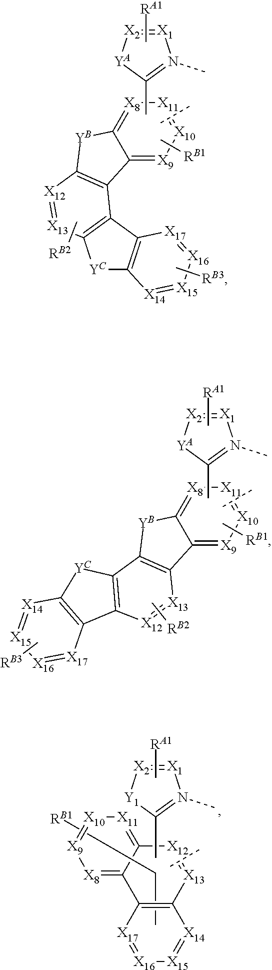

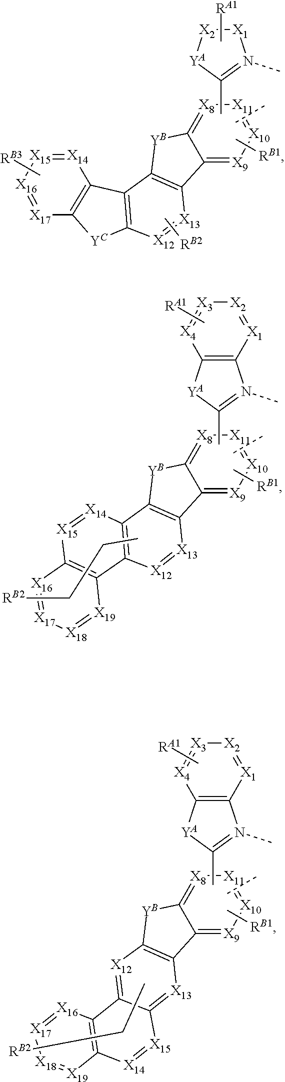

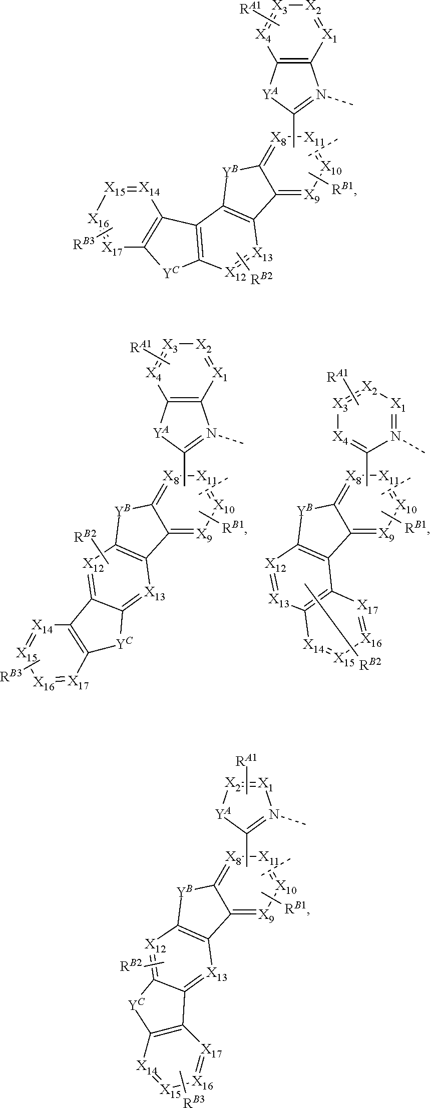

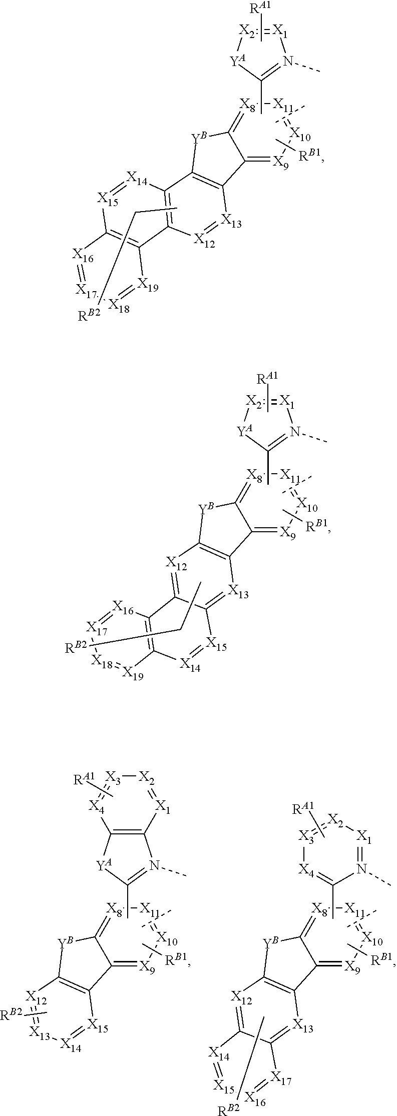

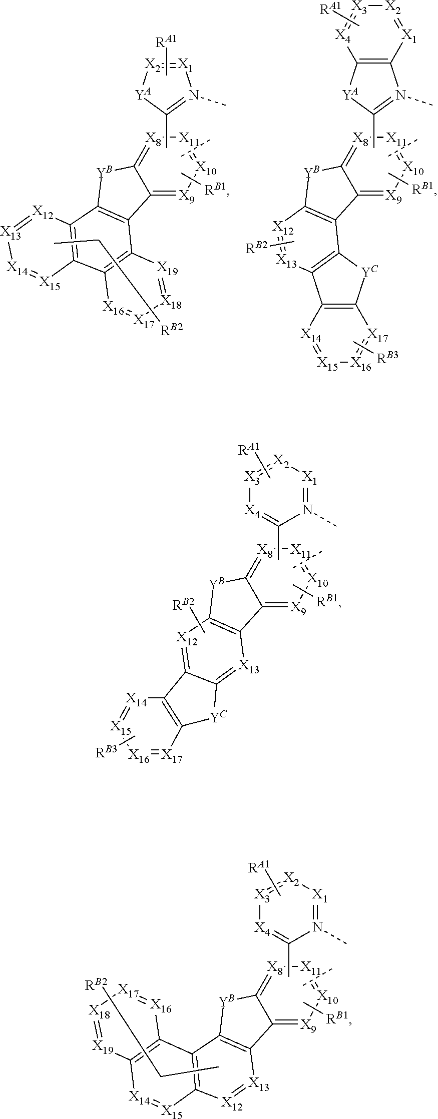

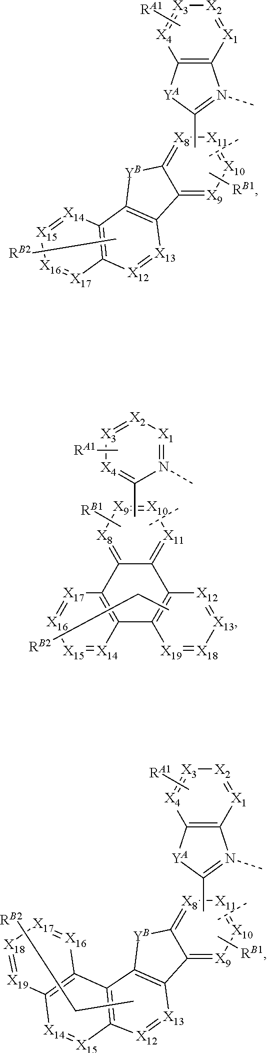

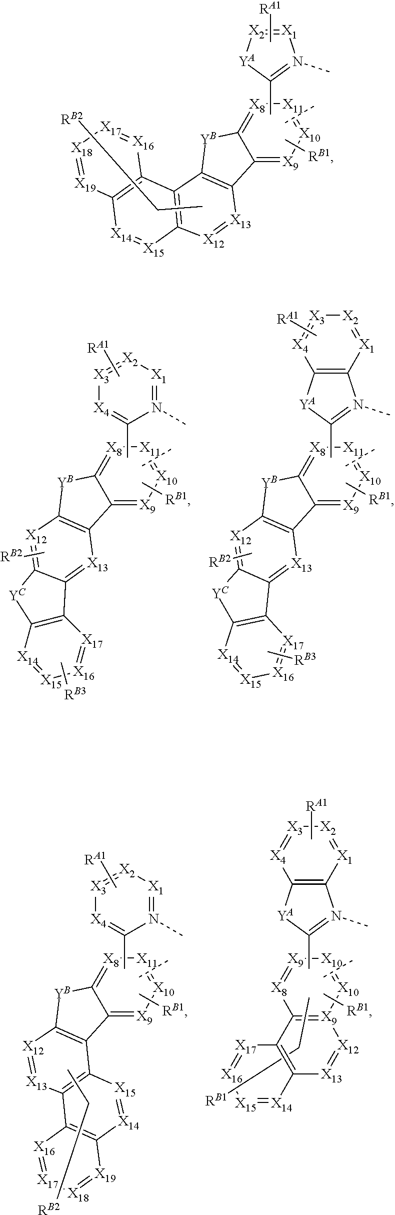

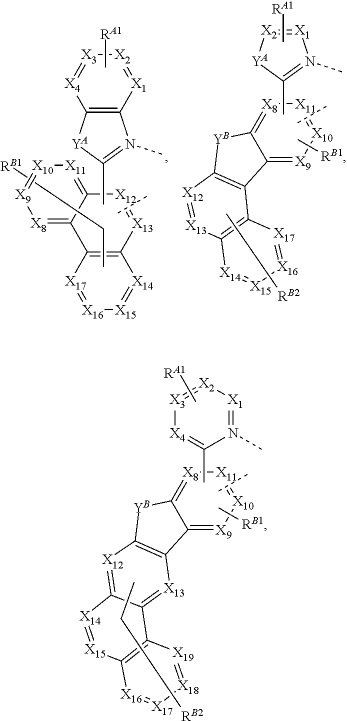

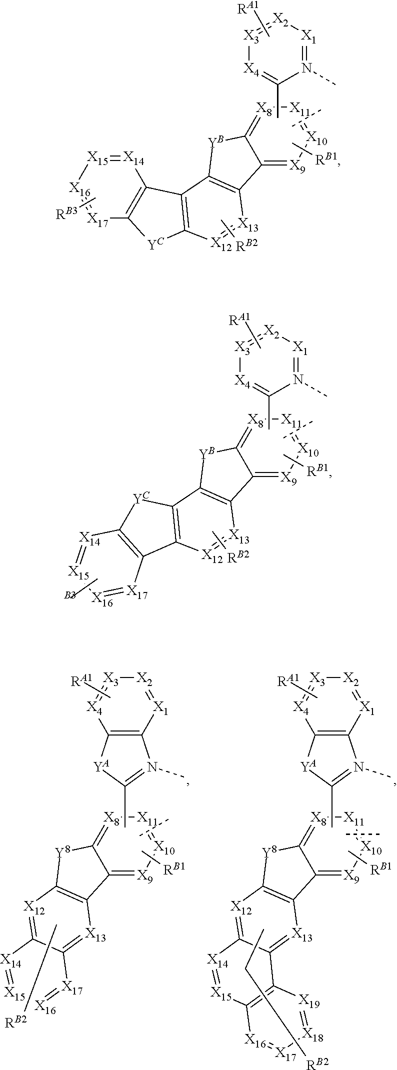

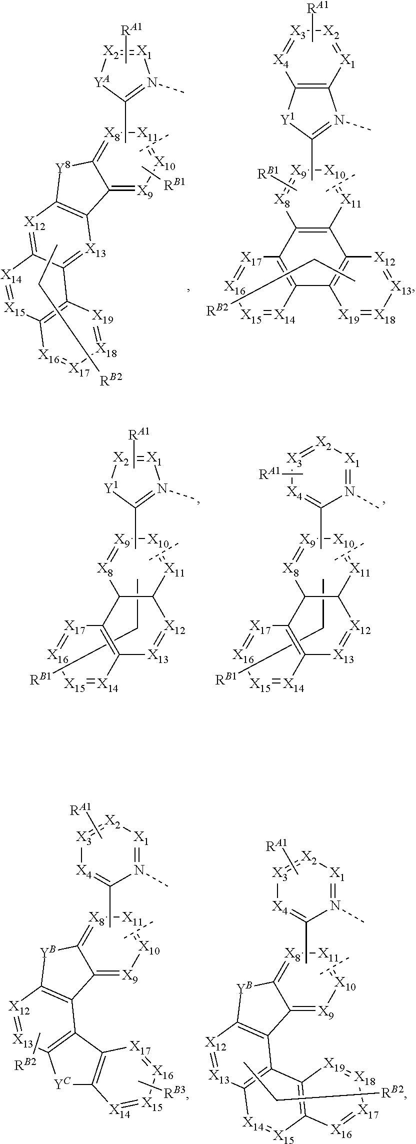

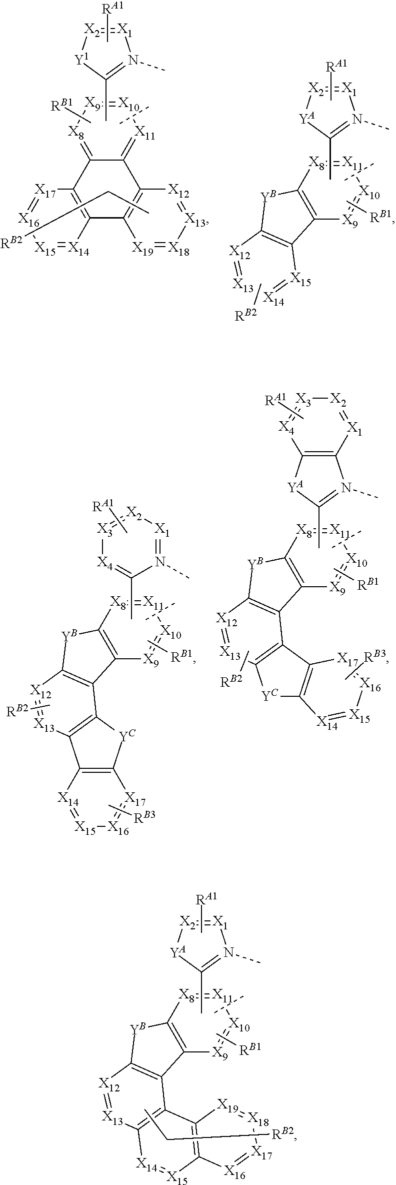

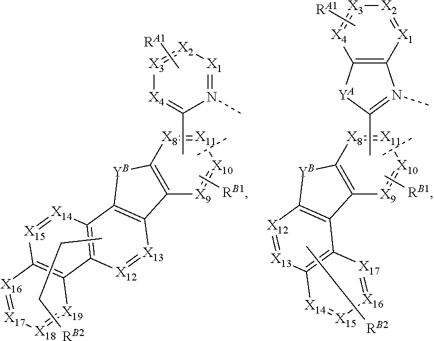

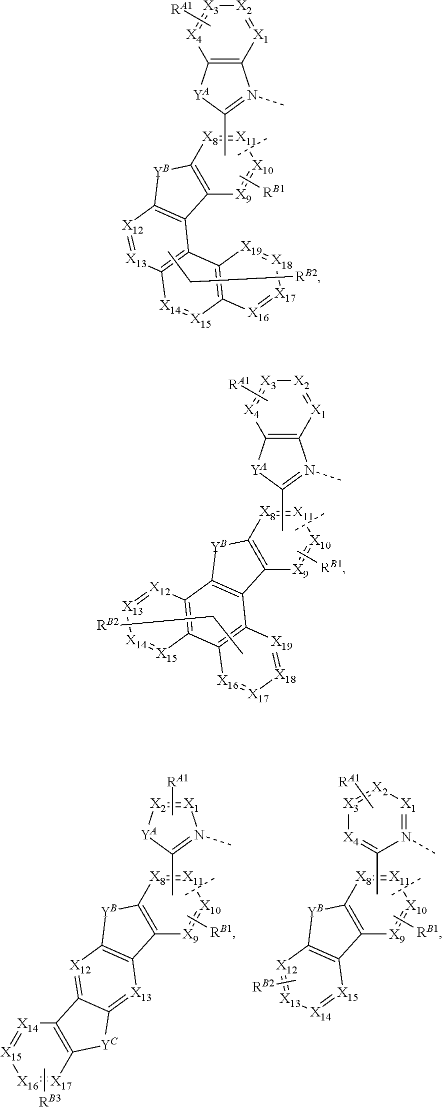

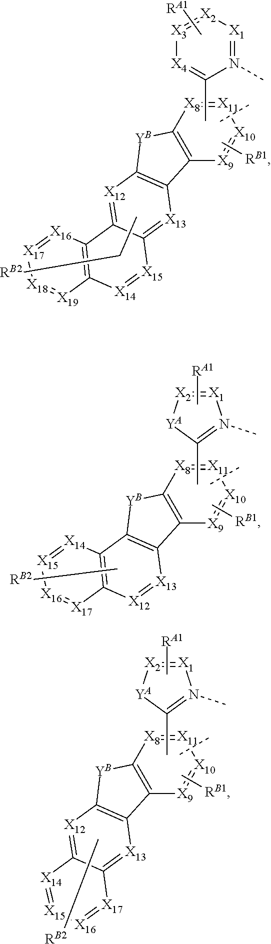

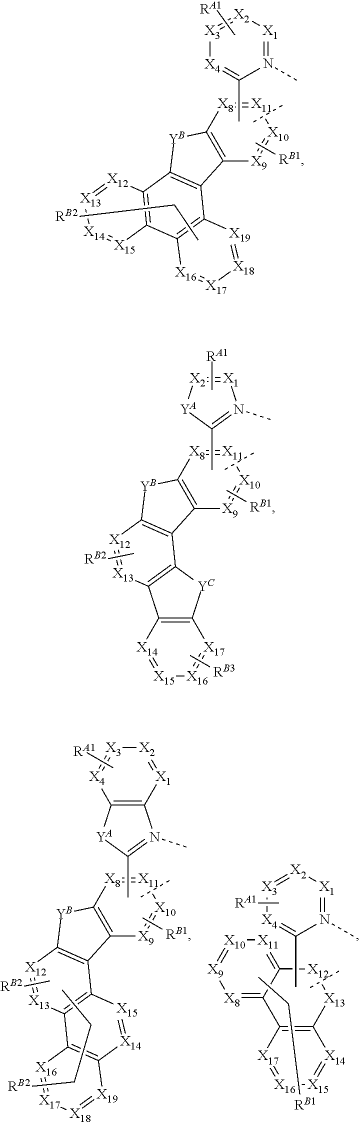

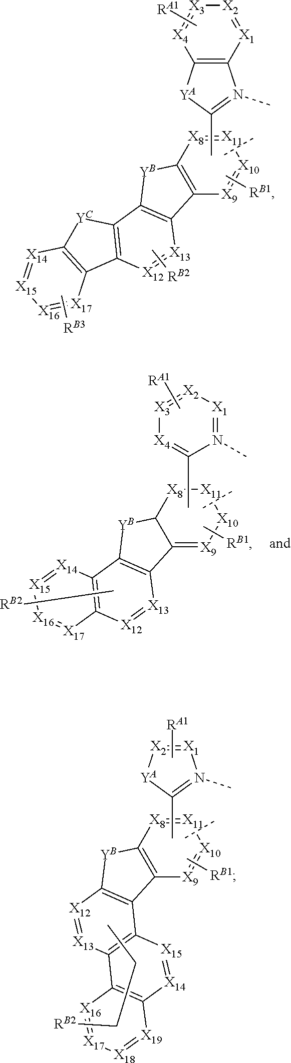

wherein:
X₁ to X₁₉ are each independently C or N;
each of Y₁, Y^{A}, Y^{B}, and Y^{C} is independently selected from the group consisting of BRₑ, NRₑ, PRₑ, O, S, Se, C═O, S═O, SO₂, CRₑR_{f}, SiRₑR_{f}, and GeRₑR_{f};
each R^{A1}, R^{B1}, R^{B2}, and R^{B3} independently represent from mono to the maximum possible number of substitutions, or no substitution;
each R^{A1}, R^{B1}, R^{B2}, R^{B3}, Rₑ, and R_{f} is independently a hydrogen or a substituent selected from the group consisting of the General Substituents defined herein; and
any two substituents can be joined or fused to form a ring.

In some embodiments comprising L_{A}, the first ligand L_{A} is selected from the group consisting of the structures of the following LIST 1b:

[chemical structure]

[chemical structure]

[chemical structure]

wherein:
each of Y^{A}, Y^{B}, and Y^{C} is independently selected from the group consisting of BRₑ, NRₑ, PRₑ, O, S, Se, C═O, S═O, SO₂, CRₑR_{f}, SiRₑR_{f}, and GeRₑR_{f};
each R^{A1}, R^{B1}, R^{B2}, and R^{B3} independently represent from mono to the maximum possible number of substitutions, or no substitution;
each R^{A1}, R^{B1}, R^{B2}, R^{B3}, Rₑ, and R_{f} is independently a hydrogen or a substituent selected from the group consisting of the General Substituents defined herein; and
any two substituents can be joined or fused to form a ring.

In some embodiments comprising L_{A}, the first ligand L_{A} is selected from the group consisting of the structures of the following LIST 1:

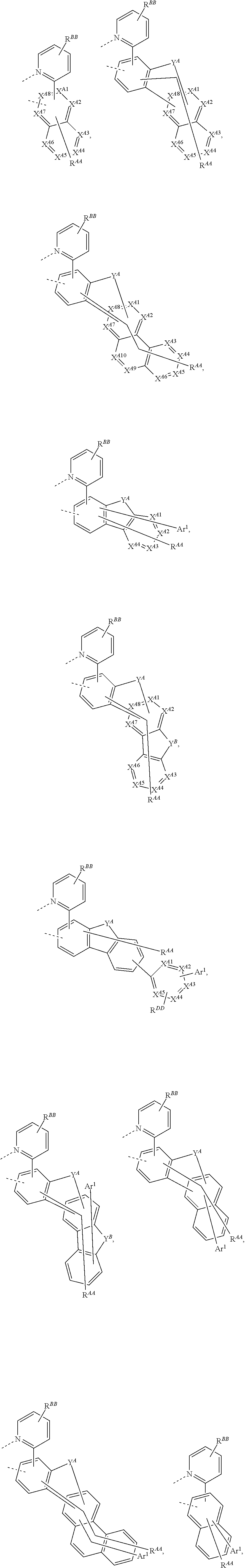

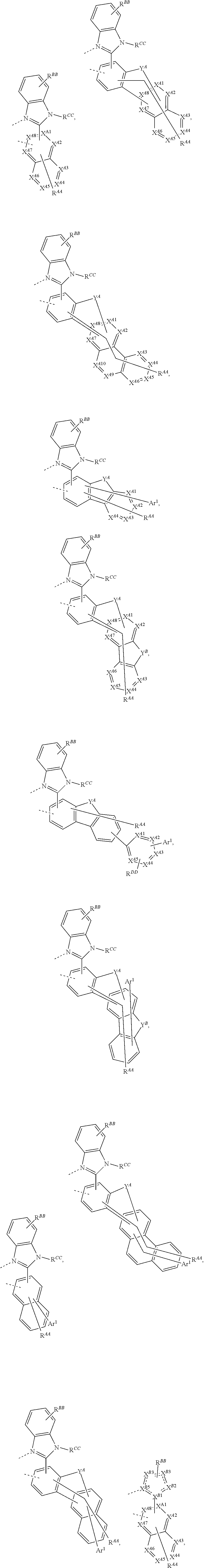

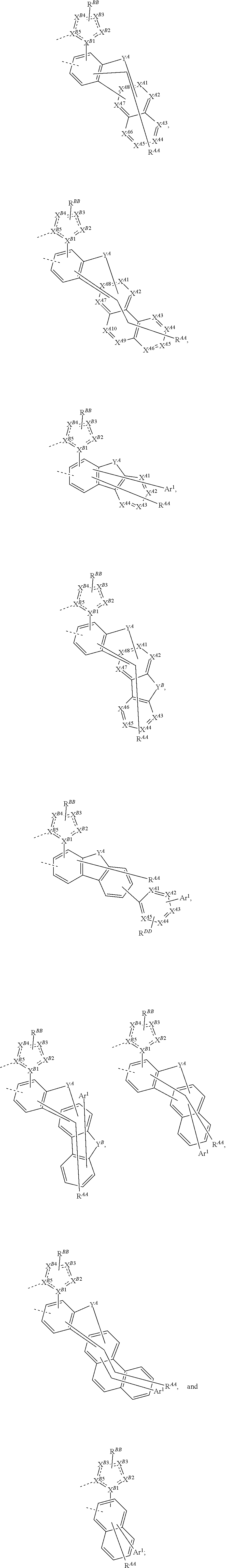

wherein:
each of X^{A1} to X^{A10} is independently C or N, and at least one of X^{A1} to X^{A10} is N;
each of X^{B1} to X^{B5} is independently C or N, and at least two of X^{B1} to X^{B5} are N;
if X^{B5} is C, then X^{B5} is a carbene carbon atom datively bound to the metal;
each of Y^{A} and Y^{B} is independently selected from the group consisting of BR, BRR′, NR, PR, P(O)R, O, S, Se, C═O, C═S, C═Se, C═NR, C═CRR′, S═O, SO₂, CR, CRR′, SiRR′, and GeRR′;
Ar¹ is independently selected from the group consisting of a substituted or unsubstituted aryl, substituted or unsubstituted heteroaryl, and an electron withdrawing group; and
each of R^{AA}, R^{BB}, and R^{DD} independently represents mono-, up to the maximum substitutions, or no substitutions;
each R, R′, R^{AA}, R^{BB}, R^{CC}, and R^{DD} is independently a hydrogen or a substituent selected from the group consisting of the General Substituents defined herein; and
any two adjacent R, R′, R^{AA}, R^{BB}, R^{CC}, R^{DD}, and Ar¹ are optionally joined or fused to form a ring.

In some embodiments comprising structures of LIST 1, at least two of X^{A1} to X^{A10} are N.

In some embodiments, at least one R^{AA}, R^{BB}, R^{CC}, R^{DD}, or Ar¹ is or comprises an electron-withdrawing group from the EWG1 LIST as defined herein. In some embodiments, at least one R^{AA}, R^{BB}, R^{CC}, R^{DD}, or Ar¹ is or comprises an electron-withdrawing group from the EWG2 LIST as defined herein. In some embodiments, at least one R^{AA}, R^{BB}, R^{CC}, R^{DD}, or Ar¹ is or comprises an electron-withdrawing group from the EWG3 LIST as defined herein. In some embodiments, at least one R^{AA}, R^{BB}, R^{CC}, R^{DD}, or Ar¹ is or comprises an electron-withdrawing group from the EWG4 LIST as defined herein. In some embodiments, at least one R^{AA}, R^{BB}, R^{CC}, R^{DD}, or Ar¹ is or comprises an electron-withdrawing group from the Pi-EWG LIST as defined herein.

In some embodiments, at least one R^{AA} is or comprises an electron-withdrawing group from the EWG1 LIST as defined herein. In some embodiments, at least one R^{AA} is or comprises an electron-withdrawing group from the EWG2 LIST as defined herein. In some embodiments, at least one R^{AA} is or comprises an electron-withdrawing group from the EWG3 LIST as defined herein. In some embodiments, at least one R^{AA} is or comprises an electron-withdrawing group from the EWG4 LIST as defined herein. In some embodiments, at least one R^{AA} is or comprises an electron-withdrawing group from the Pi-EWG LIST as defined herein.

In some embodiments, at least one R^{BB} is or comprises an electron-withdrawing group from the EWG1 LIST as defined herein. In some embodiments, at least one R^{BB} is or comprises an electron-withdrawing group from the EWG2 LIST as defined herein. In some embodiments, at least one R^{BB} is or comprises an electron-withdrawing group from the EWG3 LIST as defined herein. In some embodiments, at least one R^{BB} is or comprises an electron-withdrawing group from the EWG4 LIST as defined herein. In some embodiments, at least one R^{BB} is or comprises an electron-withdrawing group from the Pi-EWG LIST as defined herein.

In some embodiments, at least one R^{CC} is or comprises an electron-withdrawing group from the EWG1 LIST as defined herein. In some embodiments, at least one R^{CC} is or comprises an electron-withdrawing group from the EWG2 LIST as defined herein. In some embodiments, at least one R^{CC} is or comprises an electron-withdrawing group from the EWG3 LIST as defined herein. In some embodiments, at least one R^{CC} is or comprises an electron-withdrawing group from the EWG4 LIST as defined herein. In some embodiments, at least one R^{CC} is or comprises an electron-withdrawing group from the Pi-EWG LIST as defined herein.

In some embodiments, at least one R^{DD} is or comprises an electron-withdrawing group from the EWG1 LIST as defined herein. In some embodiments, at least one R^{DD} is or comprises an electron-withdrawing group from the EWG2 LIST as defined herein. In some embodiments, at least one R^{DD} is or comprises an electron-withdrawing group from the EWG3 LIST as defined herein. In some embodiments, at least one R^{DD} is or comprises an electron-withdrawing group from the EWG4 LIST as defined herein. In some embodiments, at least one R^{DD} is or comprises an electron-withdrawing group from the Pi-EWG LIST as defined herein.

In some embodiments, Ar¹ is or comprises an electron-withdrawing group from the EWG1 LIST as defined herein. In some embodiments, Ar¹ is or comprises an electron-withdrawing group from the EWG2 LIST as defined herein. In some embodiments, Ar¹ is or comprises an electron-withdrawing group from the EWG3 LIST as defined herein. In some embodiments, Ar¹ is or comprises an electron-withdrawing group from the EWG4 LIST as defined herein. In some embodiments, Ar¹ is or comprises an electron-withdrawing group from the Pi-EWG LIST as defined herein.

In some embodiments, the first group is joined with another group to form a bidentate ligand.

In some embodiments, the first group is joined with at least one other group to form a tridentate ligand. In some embodiments, the first group is joined with at least one other group to form a tetradentate ligand.

In some embodiments, the first group comprises an aza-substituted ring. In some embodiments, the first group is the combination of moiety A and R^{A}.

In some embodiments, the first group comprises an aza-substituted ring and an electron withdrawing group.

In some embodiments, at least 70% of a LUMO of the compound is localized on the first group. In some embodiments, at least 80% of a LUMO of the compound is localized on the first group. In some embodiments, at least 90% of a LUMO of the compound is localized on the first group. In some embodiments, at least 95% of a LUMO of the compound is localized on the first group.

In some of the above embodiments, the first group is partially or fully deuterated. In some of the above embodiments, the first group is substituted by at least one partially or fully deuterated substituent.

In some of the embodiments, the compound has a formula of M(L_{A})ₓ(L_{B})_{y}(L_{C})_{z} wherein M is the metal; L_{A}, L_{B} and L_{C} are each a bidentate ligand; and wherein x is 1, 2, or 3; y is 0, 1, or 2; z is 0, 1, or 2; and x+y+z is the oxidation state of the metal M. In some embodiments, the compound has a formula selected from the group consisting of Ir(L_{A})₃, Ir(L_{A})(L_{B})₂, Ir(L_{A})₂(L_{B}), Ir(L_{A})₂(L_{C}), and Ir(L_{A})(L_{B})(L_{C}), wherein L_{A}, L_{B}, and L_{C} are different from each other.

In another aspect, a compound E1′ capable of functioning as a phosphorescent emitter in an organic light emitting device at room temperature is provided. The compound is a metal coordination complex comprising a metal and a first group; the first group comprises a continuous moiety comprising at least three rings; and the first group contains at least 70% of the electron density of a LUMO of the compound.

In some embodiments, the compound E1′ may be the compound E1 described herein. It should be understood that all the compound E1 related embodiments should be equally applied to the compound E1′ related embodiments so long as those E1 related embodiments also satisfy the limitations of the E1′ related embodiments. In some embodiments, the first group comprises a continuous moiety comprising at least three fused rings. In some embodiments, the first group comprises a continuous moiety comprising exactly three, four, or five fused rings. In some embodiments, the at least three rings are not fused together, but are directly bonded together in series.

In some embodiments, the continuous moiety can be a polycyclic fused ring structure. In some embodiments, the continuous moiety can be a polycyclic fused ring structure comprising at least three fused rings. In some embodiments, the polycyclic fused ring structure has two 6-membered rings and one 5-membered ring. In some such embodiments, the 5-membered ring is fused to the ring coordinated to metal M and the second 6-membered ring is fused to the 5-membered ring. In some embodiments, the continuous moiety can be selected from the group consisting of dibenzofuran, dibenzothiophene, dibenzoselenophene, and aza-variants thereof. In some such embodiments, the continuous moiety can be further substituted at the ortho- or meta-position of the O, S, or Se atom by a substituent selected from the group consisting of deuterium, fluorine, nitrile, alkyl, cycloalkyl, aryl, heteroaryl, and combinations thereof. In some such embodiments, the aza-variants contain exactly one N atom at the 6-position (ortho to the O, S, or Se) with a substituent at the 7-position (meta to the O, S, or Se).

In some embodiments, the continuous moiety can be a polycyclic fused ring structure comprising at least four fused rings. In some embodiments, the polycyclic fused ring structure comprises three 6-membered rings and one 5-membered ring. In some such embodiments, the 5-membered ring is fused to the ring coordinated to metal M, the second 6-membered ring is fused to the 5-membered ring, and the third 6-membered ring is fused to the second 6-membered ring. In some such embodiments, the third 6-membered ring is further substituted by a substituent selected from the group consisting of deuterium, fluorine, nitrile, alkyl, cycloalkyl, aryl, heteroaryl, and combinations thereof.

In some embodiments, the continuous moiety can be a polycyclic fused ring structure comprising at least five fused rings. In some embodiments, the polycyclic fused ring structure comprises four 6-membered rings and one 5-membered ring or three 6-membered rings and two 5-membered rings. In some embodiments comprising two 5-membered rings, the 5-membered rings are fused together. In some embodiments comprising two 5-membered rings, the 5-membered rings are separated by at least one 6-membered ring. In some embodiments with one 5-membered ring, the 5-membered ring is fused to the ring coordinated to metal M, the second 6-membered ring is fused to the 5-membered ring, the third 6-membered ring is fused to the second 6-membered ring, and the fourth 6-membered ring is fused to the third 6-membered ring.

In some embodiments, the continuous moiety can be an aza version of the polycyclic fused rings described above. In some such embodiments, the continuous moiety can contain exactly one aza N atom. In some such embodiments, the continuous moiety can contain exactly two aza N atoms, which can be in one ring, or in two different rings. In some such embodiments, the ring having aza N atom is separated by at least two other rings from the metal M atom. In some such embodiments, the ring having aza N atom is separated by at least three other rings from the metal M atom. In some such embodiments, each of the ortho positions of the aza N atom is substituted.

In some embodiments, the first group contains at least 75% of the electron density of the LUMO of the compound. In some embodiments, the first group contains at least 80% of the electron density of the LUMO of the compound. In some embodiments, the first group contains at least 85% of the electron density of the LUMO of the compound. In some embodiments, the first group contains at least 90% of the electron density of the LUMO of the compound. In some embodiments, the first group contains at least 95% of the electron density of the LUMO of the compound.

In some embodiments, the compound has a triplet emission spectrum with a full width at half maximum (FWHM) value of 45 nm or less at 22° C. In some embodiments, the compound has a triplet emission spectrum with a FWHM value of 40 nm or less at 22° C. In some embodiments, the compound has a triplet emission spectrum with a FWHM value of 35 nm or less at 22° C. In some embodiments, the compound has a triplet emission spectrum with a FWHM value of 30 nm or less at 22° C. In some embodiments, the compound has a triplet emission spectrum with a FWHM value of 25 nm or less at 22° C. In some embodiments, the compound has a triplet emission spectrum with a FWHM value of 20 nm or less at 22° C. In some embodiments, the compound has a triplet emission spectrum with a FWHM value of 15 nm or less at 22° C. In some embodiments, the compound has a triplet emission spectrum with a FWHM value of 10 nm or less at 22° C.

In some embodiments, the compound has an emission spectrum with an M/T value larger than 0.45. In some embodiments, the compound has an emission spectrum with an M/T value larger than 0.47. In some embodiments, the compound has an emission spectrum with an M/T value larger than 0.50.

As used herein, the MIT ratio relates to the “narrowness” of the emission peak. M represents the area of the main peak, which is defined as the integration of the area of max peak wavelength (λₘₐₓ)+15 nm, while T is total area of the spectrum, which is defined as the integration of entire spectrum. The higher the M/T, the narrower the peak.

In some embodiments, the compound comprises a first ligand coordinated to the metal, and the first ligand comprises the first group; wherein a free-state of the first ligand has a first triplet energy T₁ of E_{L} at 77K; the compound has a first triplet energy T₁ of E at 77K; and the difference in energy between E and E_{L} is ΔE; and ΔE is 250 meV or less.

In some embodiments, ΔE is 200 meV or less. In some embodiments, ΔE is 160 meV or less. In some embodiments, ΔE is 120 meV or less. In some embodiments, ΔE is 100 meV or less. In some embodiments, ΔE is 80 meV or less. In some embodiments, ΔE is 50 meV or less.

In some embodiments, ΔE is at least 10 meV. In some embodiments, ΔE is at least 20 meV.

In some embodiments, the compound has a highest occupied molecular orbital (HOMO) and a combination of the metal and the first group contains at least 70% of the electron density of the HOMO. In some embodiments, the compound has a highest occupied molecular orbital (HOMO) and a combination of the metal and the first group contains at least 75%, or at least 80%, or at least 85%, or at least 90%, or at least 95% of the electron density of the HOMO.

In some embodiments, the first group has HOMO energy less than −5.0 eV.

In some embodiments, the first group has HOMO energy less than −5.05 eV, or less than −5.1 eV, or less than −5.15 eV, or less than −5.2 eV.

In some embodiments, the first group comprises at least one electron-withdrawing group.

In some embodiments, the first group comprises an electron-withdrawing group from the EWG1 LIST as defined herein. In some embodiments, the first group comprises an electron-withdrawing group from the EWG2 LIST as defined herein. In some embodiments, the first group comprises an electron-withdrawing group from the EWG3 LIST as defined herein. In some embodiments, the first group comprises an electron-withdrawing group from the EWG4 LIST as defined herein. In some embodiments, the first group comprises an electron-withdrawing group from the Pi-EWG LIST as defined herein.

In some embodiments, the first group comprises at least one heteroaryl ring. In some embodiments, the first group coordinates to the metal.

In some embodiments, the compound is the metal coordination complex according to any embodiment described herein.

In some embodiments, the compound comprises a covalent bond between the metal and the first group. In some such embodiments, a TDM of the emissive state of the compound has a vector, wherein the angle formed between the TDM vector and the covalent bond between the metal and the first group is less than or equal to 20°, and wherein an excited state of the compound has a LC character localized on the first group of greater than or equal to 45%.

In some such embodiments, the angle formed between the TDM vector and the covalent bond between the metal and the first group is less than or equal to 15°. In some embodiments, the angle formed between the TDM vector and the covalent bond between the metal and the first group is less than or equal to 10°.

In some embodiments, an excited state of the metal coordination complex has an LC character localized on the first group of greater than or equal to 58%.

In some embodiments, the covalent bond between the metal and the first group is an M-C bond, and an NTO electron integral of a ligand fragment comprising the M-C bond is at least 60%.

In some embodiments, the metal coordination complex has a rod-like parameter, R^{R}, of at least 50%.

In some embodiments, the metal coordination complex has a HOMO energy lower than −5.15 eV.

In some embodiments, the metal coordination complex has a Q parameter less than 1×10⁻⁹ C. In some embodiments, the metal coordination complex has a Q parameter less than 8×10⁻¹⁰ C. In some embodiments, the metal coordination complex has a Q parameter less than 6×10⁻¹⁰ C.

In some embodiments, the compound comprises a metal-carbon bond. In some such embodiments, the first group comprises the C that forms a metal-carbon bond.

In some embodiments, the compound comprises a metal-nitrogen bond. In some embodiments, the first group comprises the N that forms the metal-nitrogen bond.

In some embodiments, the compound comprises a metal-oxygen bond. In some embodiments, the first group comprises the O that forms the metal-oxygen bond.

In some embodiments, the compound comprises a metal-carbene bond. In some embodiments, the first group comprises the carbene carbon that forms the metal-carbene bond.

In some embodiments, the metal is selected from the group consisting of Ir, Rh, Re, Ru, Os, Pt, Pd, Au, Ag, and Cu. In some embodiments, the metal is Ir. In some embodiments, the metal is Pt.

In some embodiments, the compound has a neutral charge.

In some embodiments, the compound is homoleptic. In some embodiments, the compound is heteroleptic.

In some embodiments, the compound has an octahedral coordination geometry formed by three bidentate ligands, two tridentate ligands, one tetradentate and one bidentate ligand, or one hexadentate ligand.

In some embodiments, the compound has a square planar coordination geometry formed by two bidentate ligands, or one tetradentate ligand.

In some embodiments, the compound comprises a first ring coordinated to the metal; wherein the first ring is fused with a second ring; and wherein the first group comprises the second ring. In some such embodiments, the compound comprises a first ring covalently bonded to the metal; In some such embodiments, the first and second rings are part of the first group. In some such embodiments, the second ring is fused with a third ring. In some such embodiments, the third ring is fused with a fourth ring.

In some embodiments, the first ring is a five-membered ring. In some embodiments, the first ring is selected from the group consisting of imidazole, imidazole derived carbene, and pyrazole.

In some embodiments, the first ring is a six-membered ring. In some embodiments, the first ring is selected from the group consisting of benzene, pyridine, pyrimidine, pyridazine, pyrazine, triazine, imidazole, pyrazole, pyrrole, oxazole, furan, thiophene, thiazole, and triazole. In some embodiments, the first ring is pyridine. In some embodiments, the first ring is benzene.

In some embodiments, each of first to fourth rings is independently an aryl or heteroaryl ring. In some embodiments, the second ring is a 5-membered ring. In some embodiments, the third ring is a 6-membered ring. In some embodiments, the fourth ring is a 6-membered ring.

In some embodiments, the first group is partially or fully deuterated. In some embodiments, the first group is substituted by at least one partially or fully deuterated substituent.

In some embodiments, the compound has a formula of M(L_{A})ₓ(L_{B})_{y}(L_{C})_{z} wherein M is the metal; L_{A}, L_{B} and L_{C} are each a bidentate ligand; and wherein x is 1, 2, or 3; y is 0, 1, or 2; z is 0, 1, or 2; and x+y+z is the oxidation state of the metal M.

In some embodiments, the compound has a formula selected from the group consisting of Ir(L_{A})₃, Ir(L_{A})(L_{B})₂, Ir(L_{A})₂(L_{B}), Ir(L_{A})₂(L_{C}), and Ir(L_{A})(L_{B})(L_{C}); and wherein L_{A}, L_{B}, and L_{C} are different from each other.

In some embodiments, the compound has a formula of Pt(L_{A})(L_{B}); and wherein L_{A} and L_{B} can be same or different.

In some embodiments, L_{A} and L_{B} are connected to form a tetradentate ligand. In some embodiments, the metal is Pt. In some embodiments, L_{A} and L_{B} are connected to form a tetradentate, square-planar ligand.

In some embodiments, L_{A} and L_{B} are connected at two places to form a macrocyclic tetradentate ligand.

In some embodiments, L_{A} is selected from the group consisting of the structures of the following LIGAND List 1:

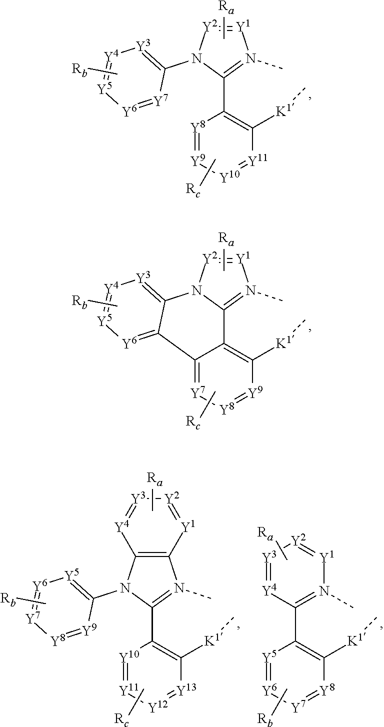

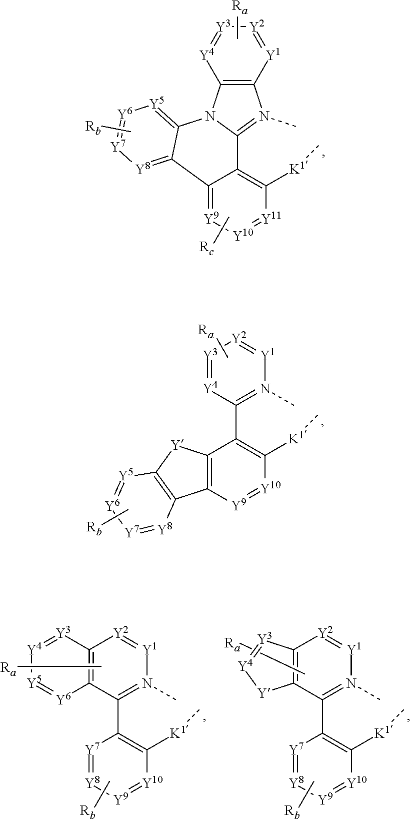

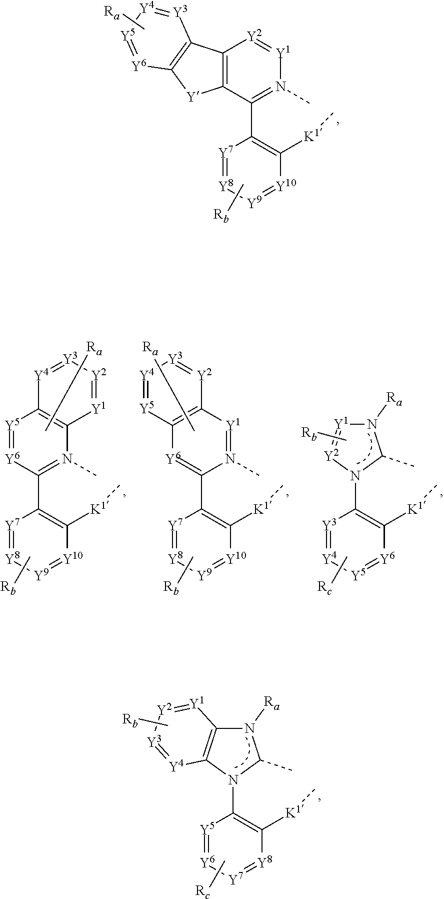

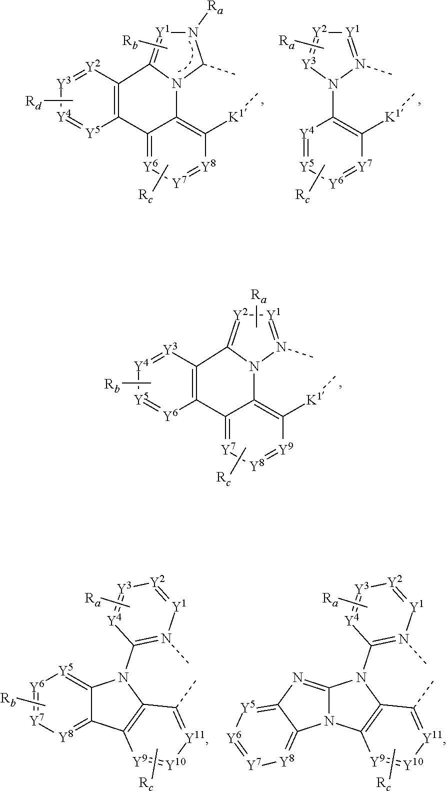

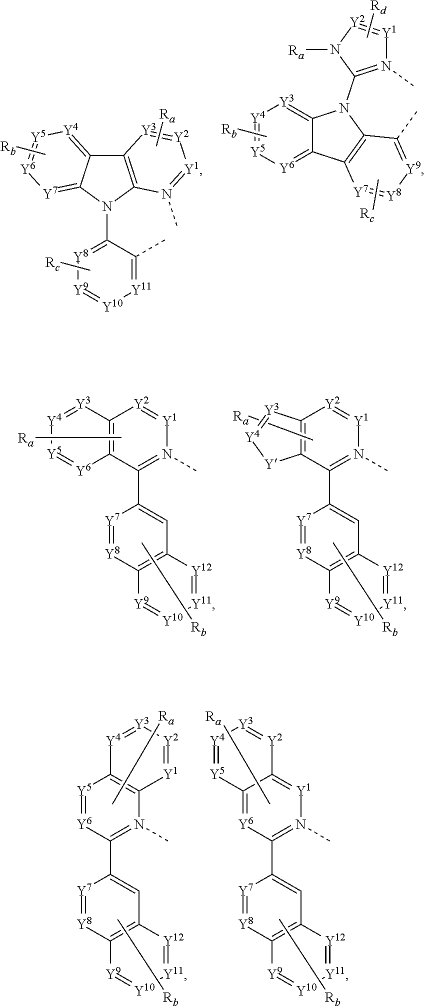

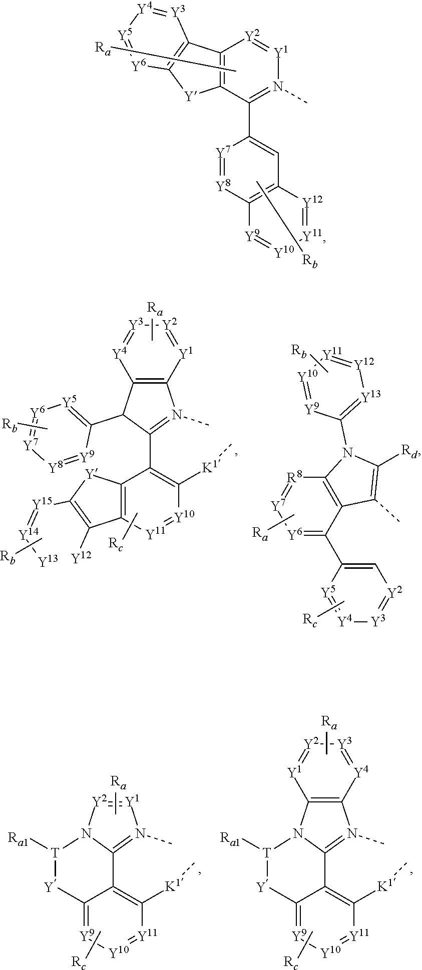

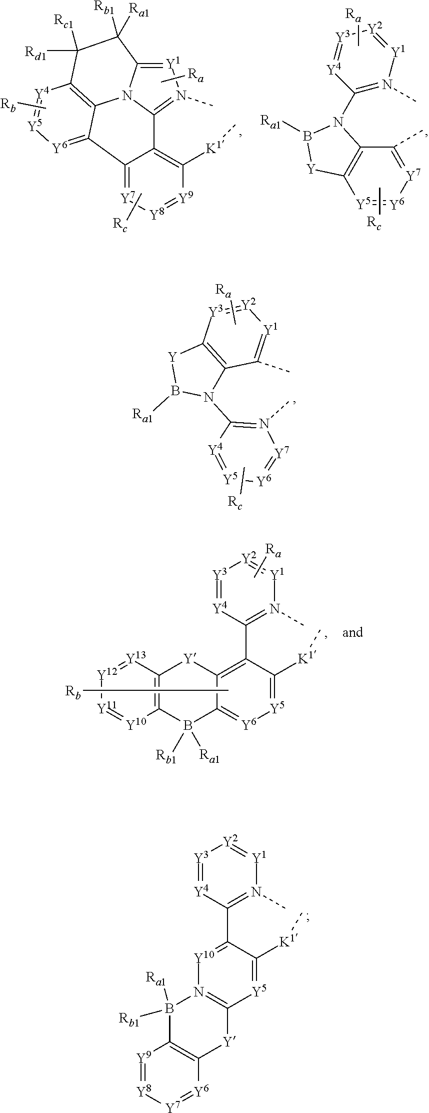

wherein L_{B} and L_{C} are each independently selected from the group consisting of

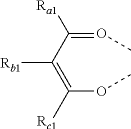

and the LIGAND List 1;
wherein:
   T is selected from the group consisting of B, Al, Ga, and In;
      K^{1′} is selected from the group consisting of a single bond, O, S, NRₑ, PRₑ, BRₑ, CRₑR_{f}, and SiRₑR_{f};
   each of Y¹ to Y¹³ is independently selected from the group consisting of C and N;
   Y′ is selected from the group consisting of BRₑ, BRₑR_{f}, NRₑ, PRₑ, P(O)Rₑ, O, S, Se, C═O, C═S, C═Se, C═NRₑ, C═CRₑR_{f}, S═O, SO₂, CRₑR_{f}, SiRₑR_{f}, and GeRₑR_{f};
   Rₑ and R_{f} can be fused or joined to form a ring;
   each Rₐ, R_{b}, R_{c}, and R_{d} independently represents from mono to the maximum allowed number of substitutions, or no substitution;
   each of Rₐ₁, R_{b1}, R_{c1}, R_{d1}, Rₐ, R_{b}, R_{c}, R_{d}, Rₑ, and R_{f} is independently a hydrogen or a substituent selected from the group consisting of the General Substituents defined herein; and any two substituents of Rₐ₁, R_{b1}, R_{c1}, R_{d1}, Rₐ, R_{b}, R_{c}, and R_{d} can be fused or joined to form a ring or form a multidentate ligand.

In some embodiments, at least one pair of substituents Rₐ, R_{b}, R_{c}, and R_{d} are joined and fused into a ring as part of the first group.

In some embodiments, L_{A} is selected from the group consisting of the structures of the following LIGAND List 2:

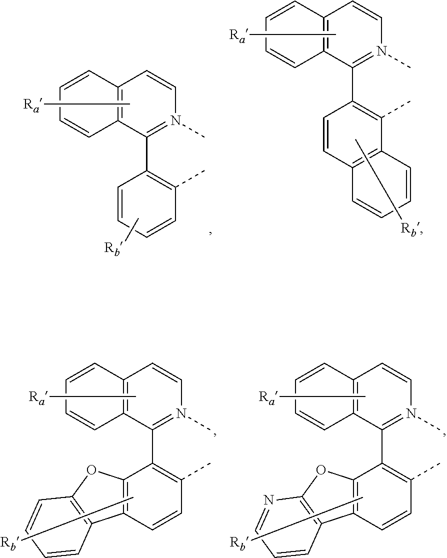

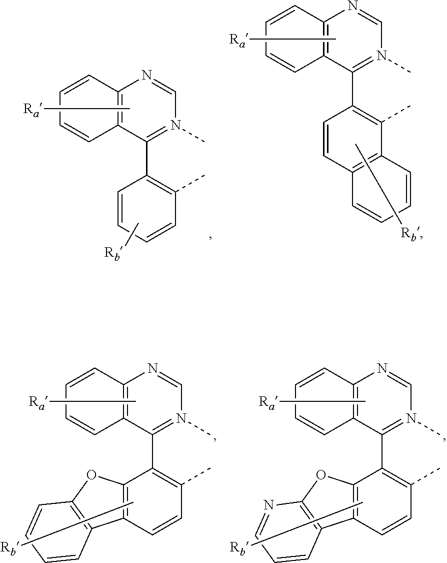

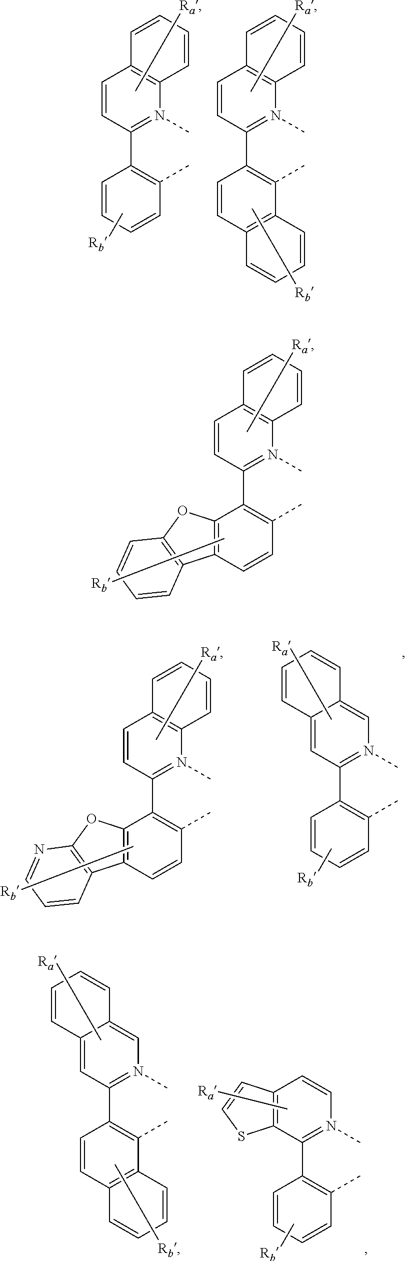

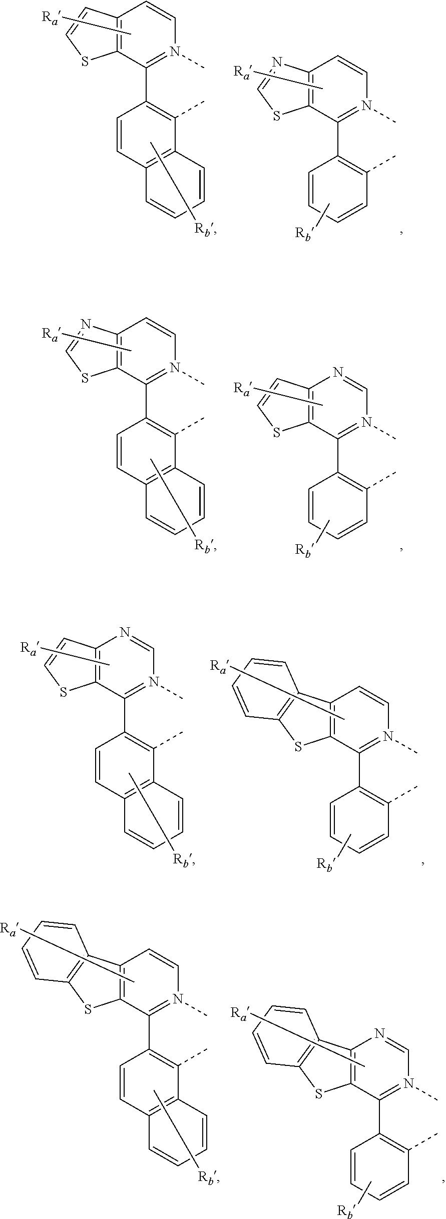

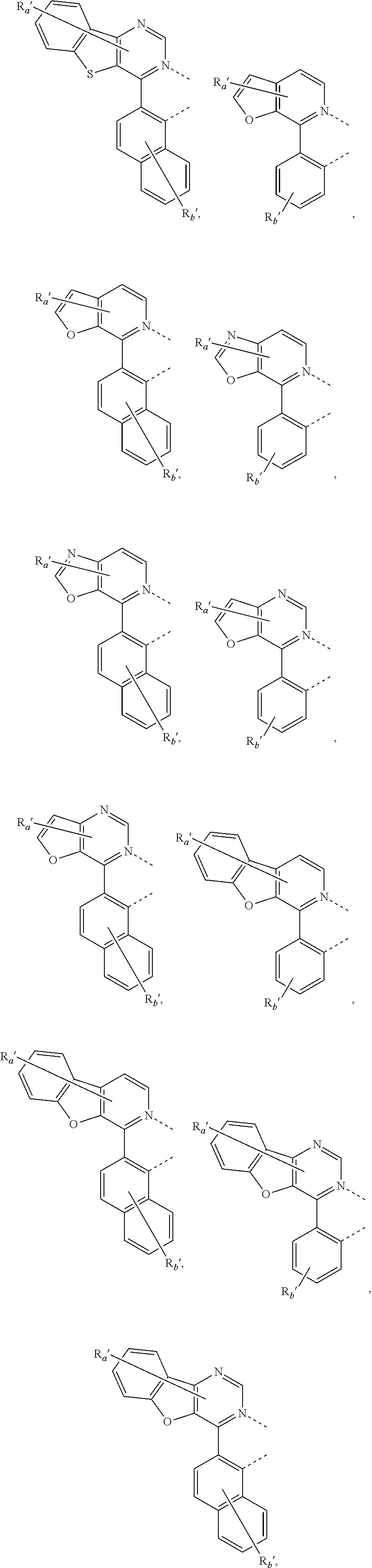

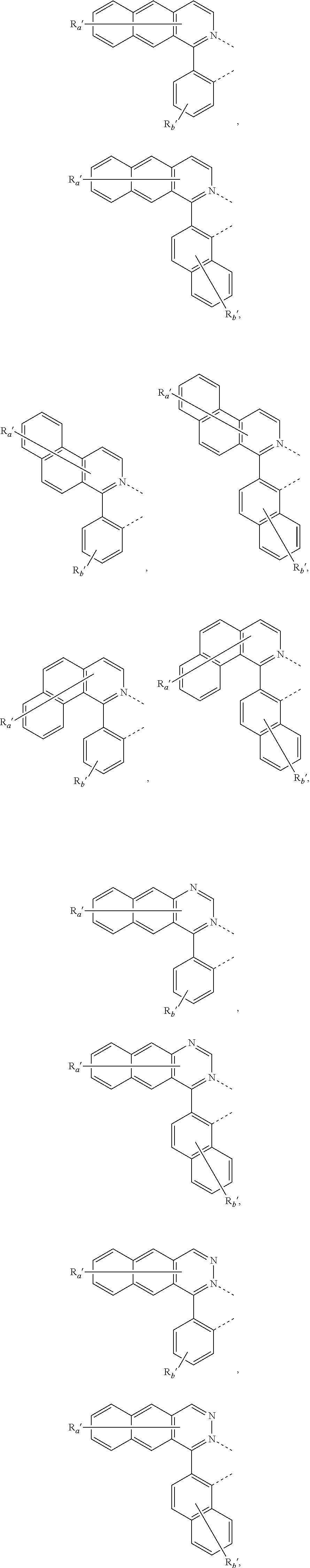

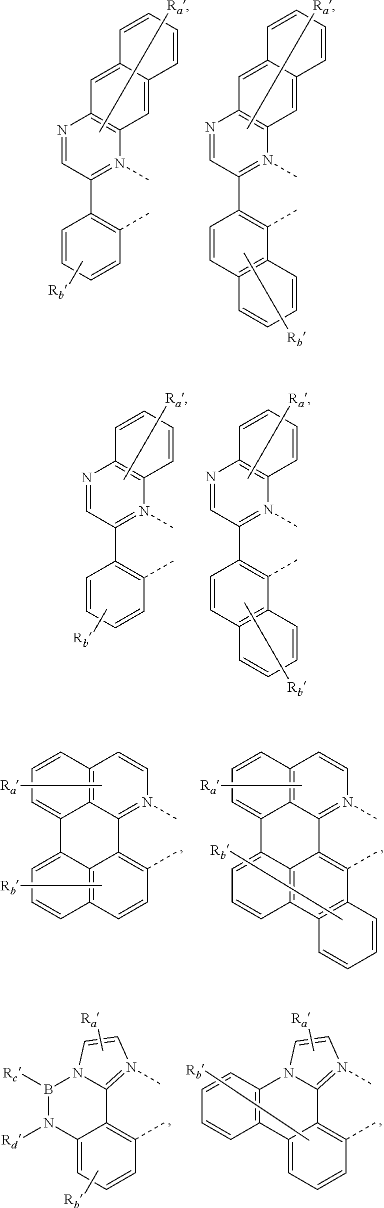

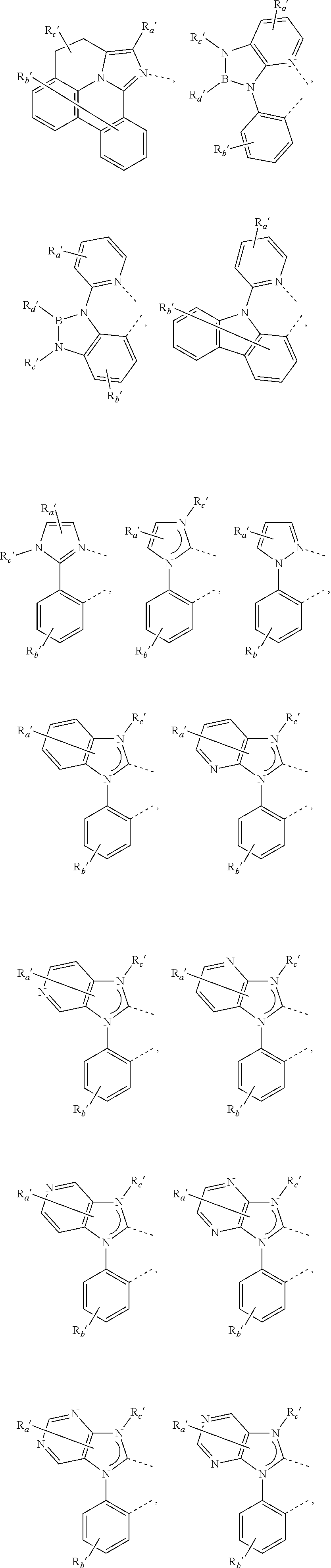

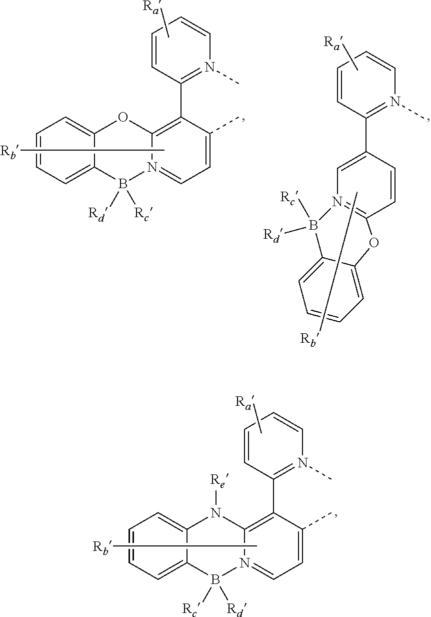

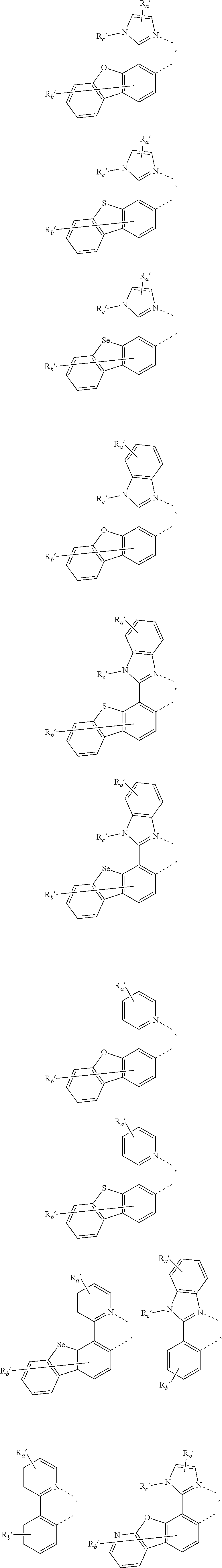

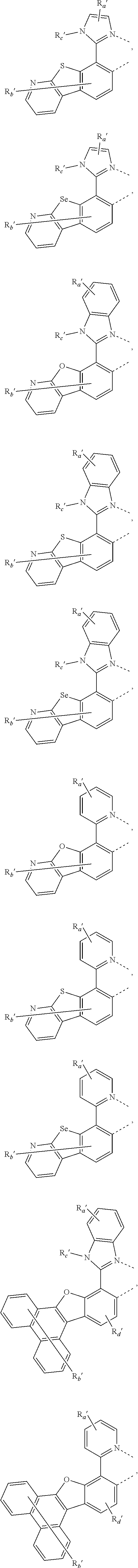

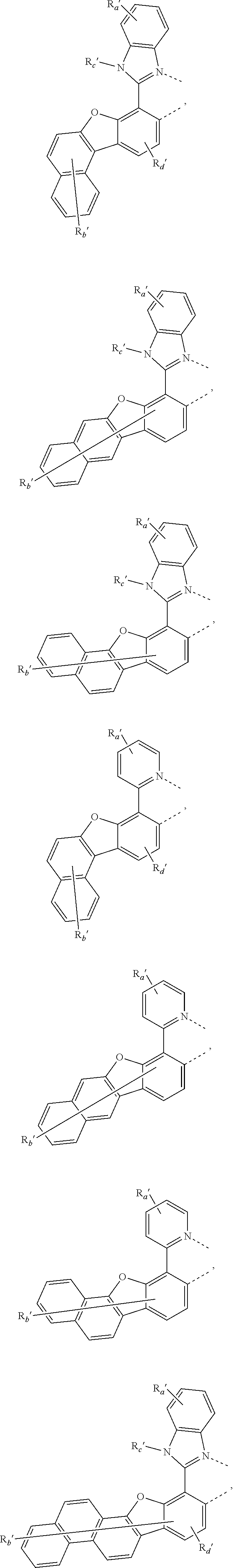

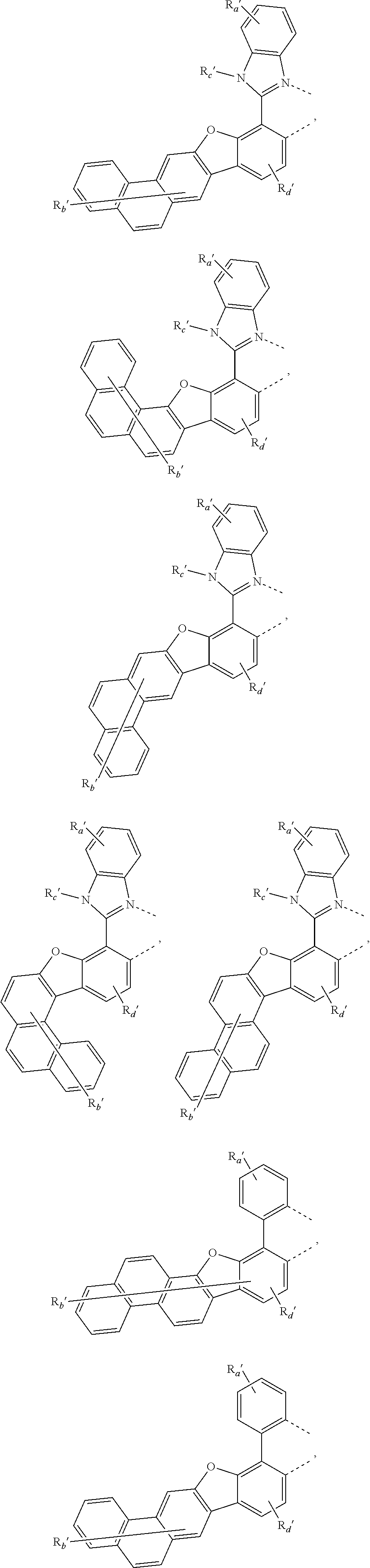

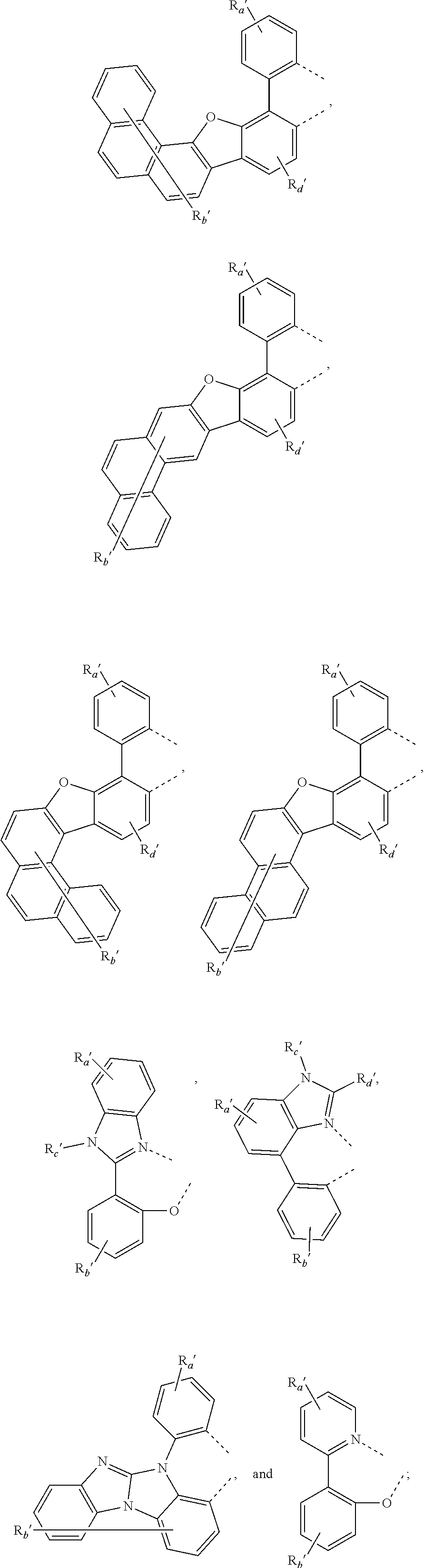

wherein L_{B} and L_{C} are each independently selected from the group consisting of

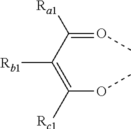

and the LIGAND List 2;
   wherein:
   Rₐ′, R_{b}′, R_{c}′, R_{d}′, and Rₑ′ each independently represents zero, mono, or up to a maximum allowed number of substitution to its associated ring;
   Rₐ′, R_{b}′, R_{c}′, R_{d}′, and Rₑ′ each independently hydrogen or a substituent selected from the group consisting of the General Substituents defined herein; and two substituents of Rₐ′, R_{b}′, R_{c}′, R_{d}′, and Rₑ′ can be fused or joined to form a ring or form a multidentate ligand.

In some embodiments, the compound has a structure selected from the group consisting of the structures of the following LIST 2:

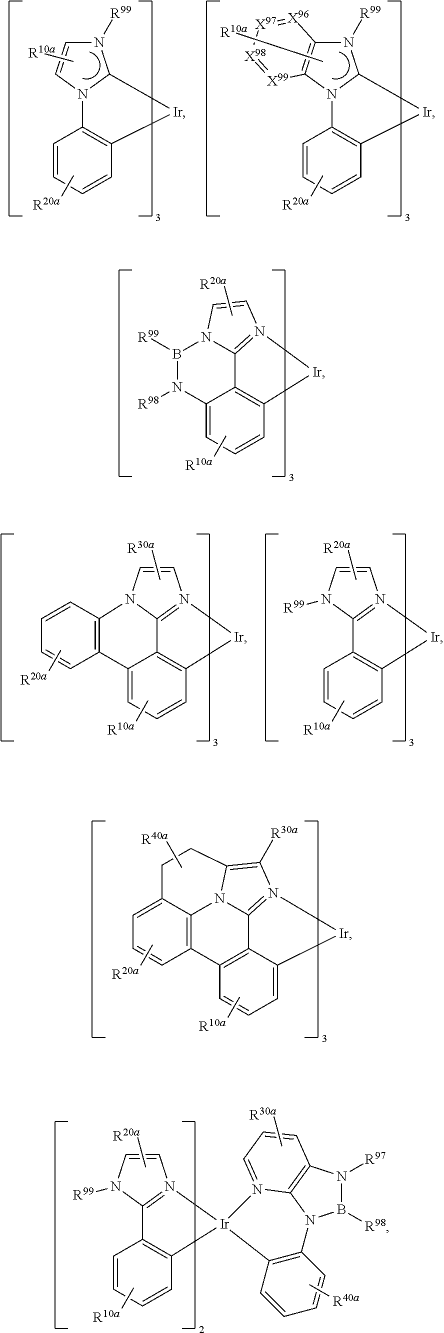

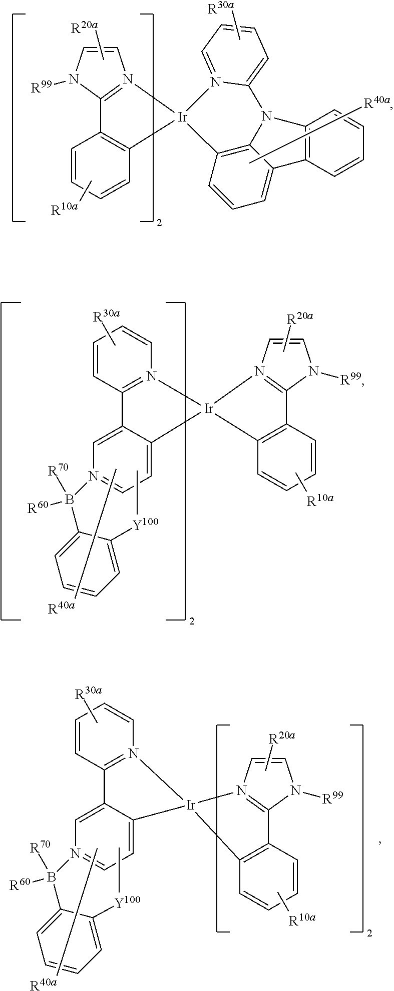

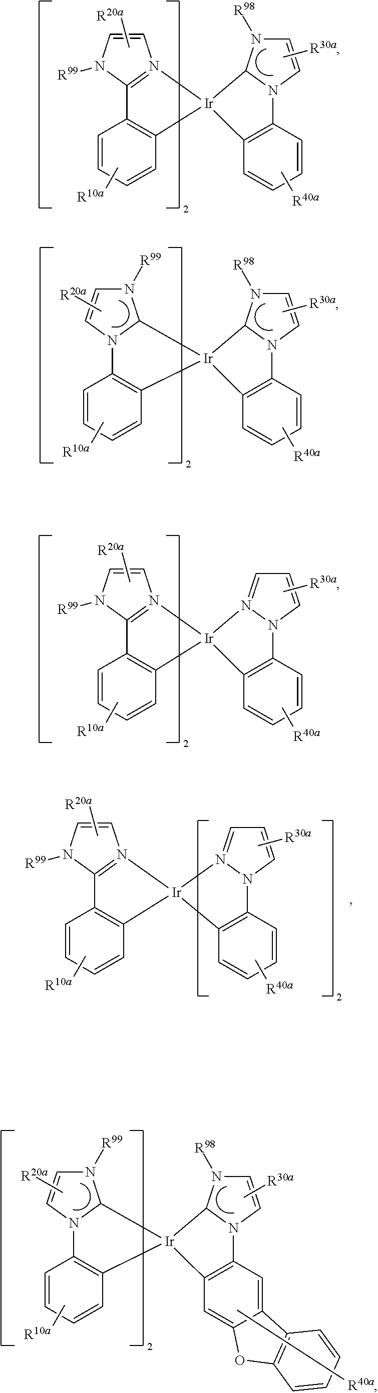

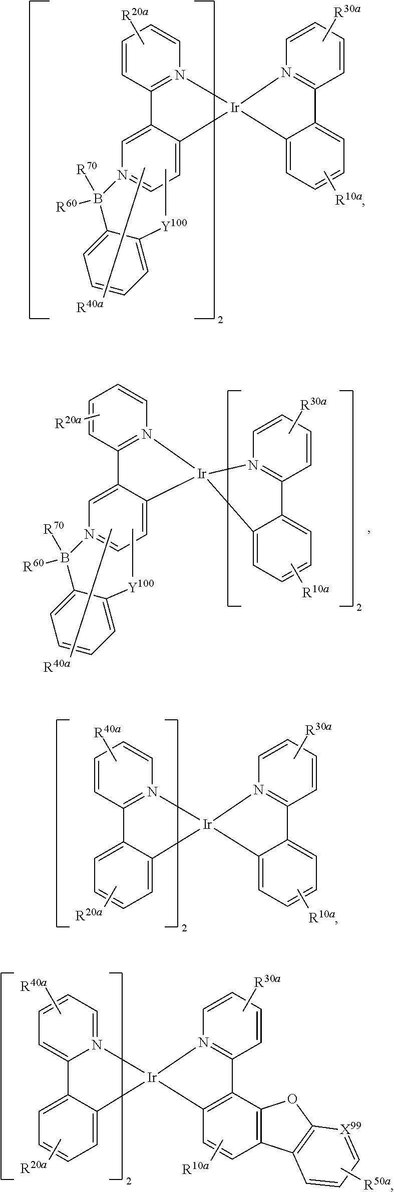

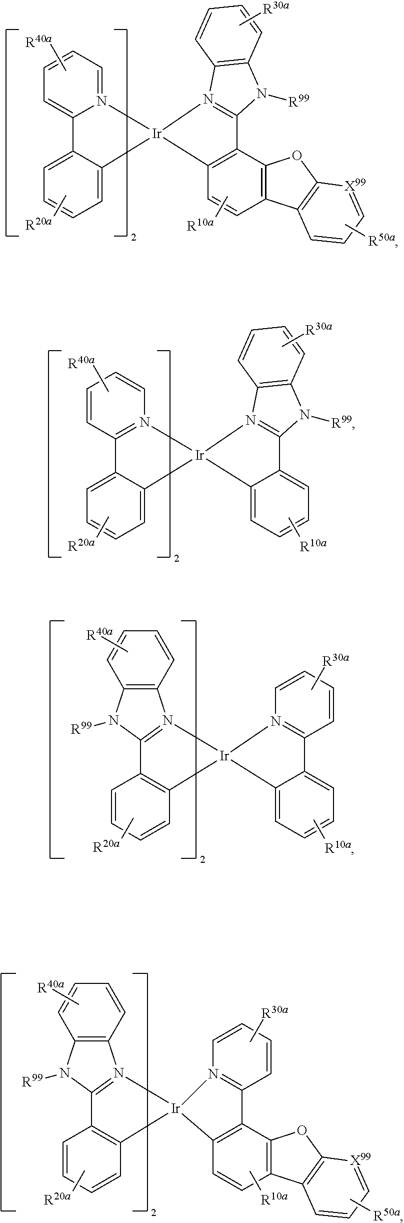

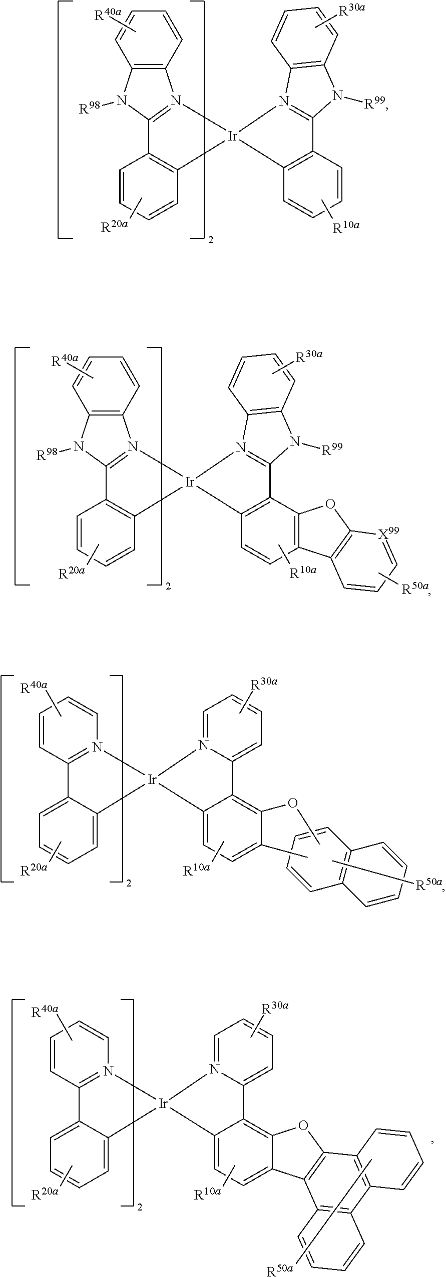

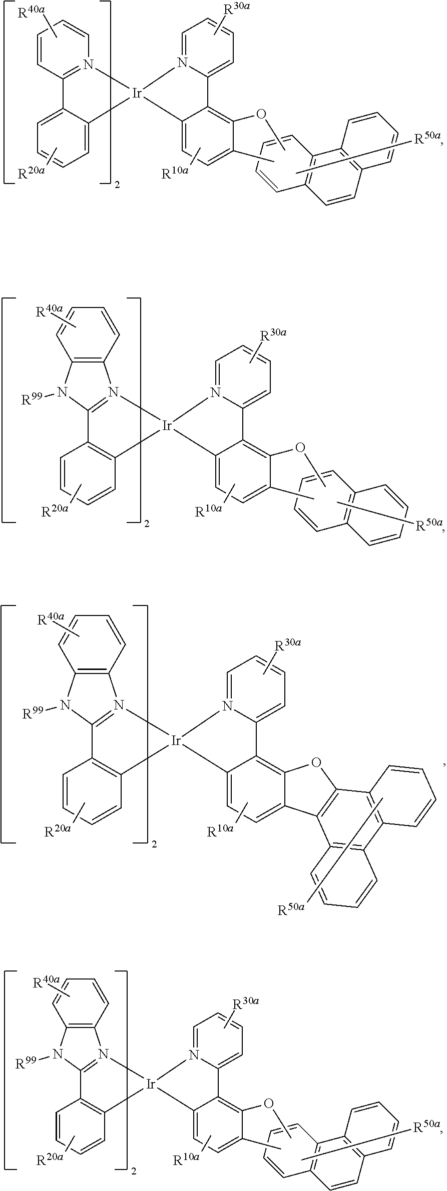

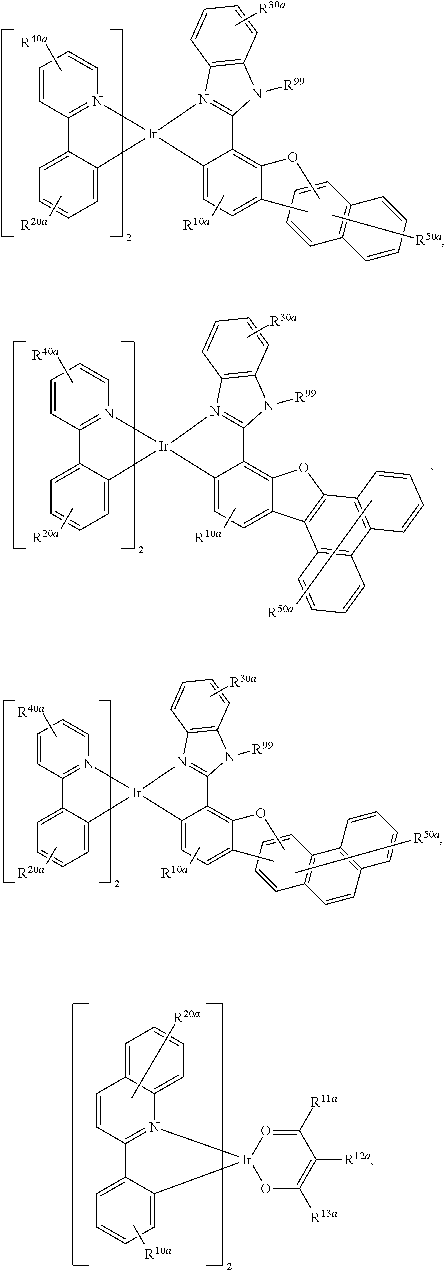

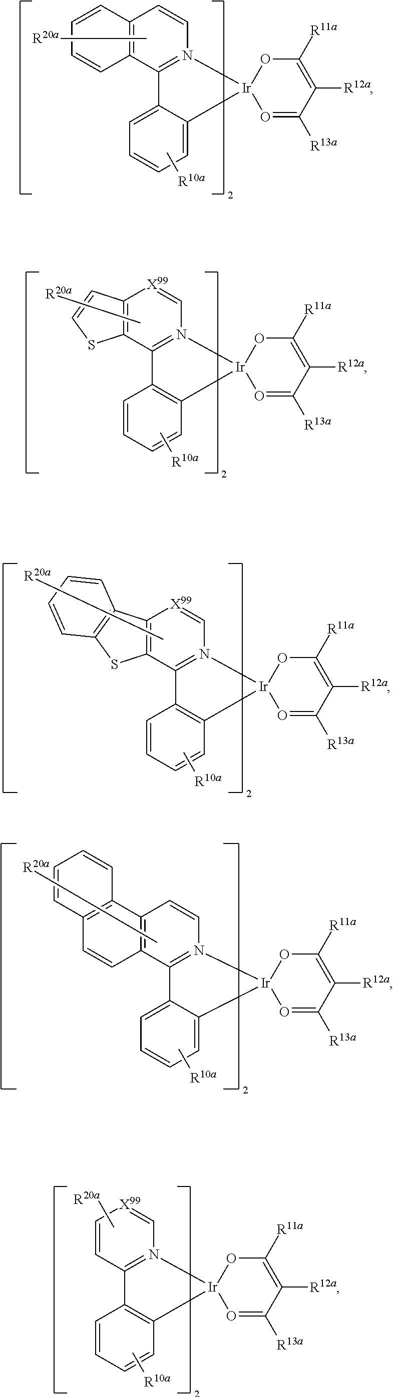

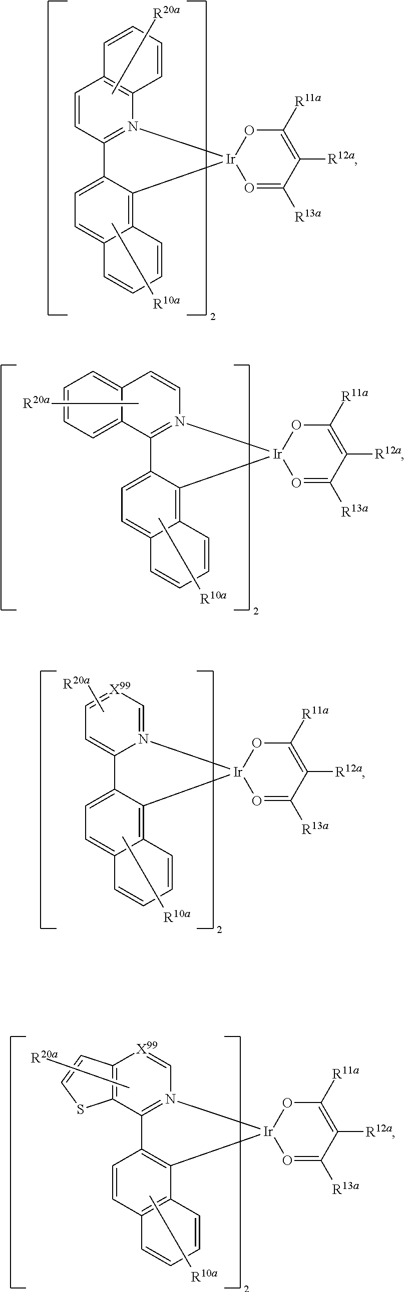

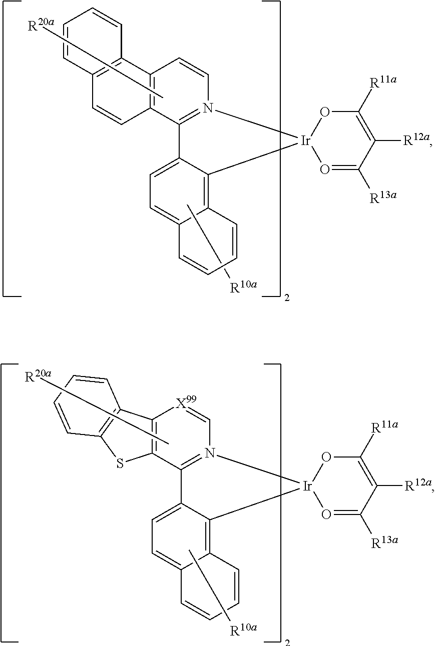

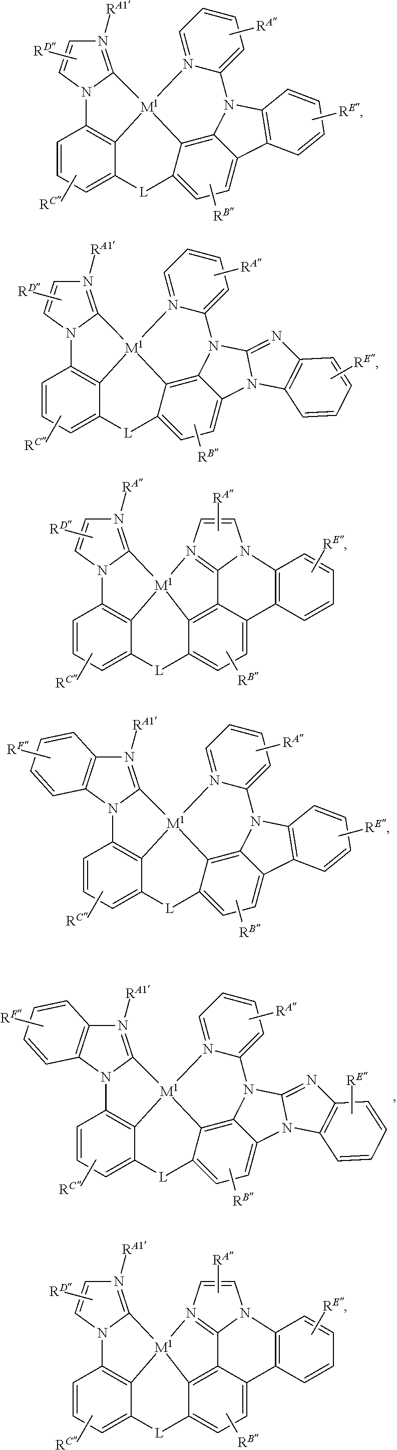

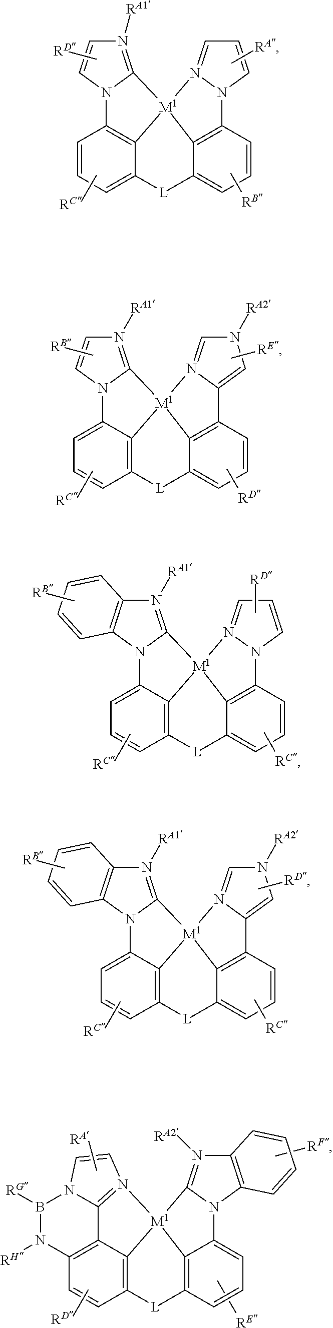

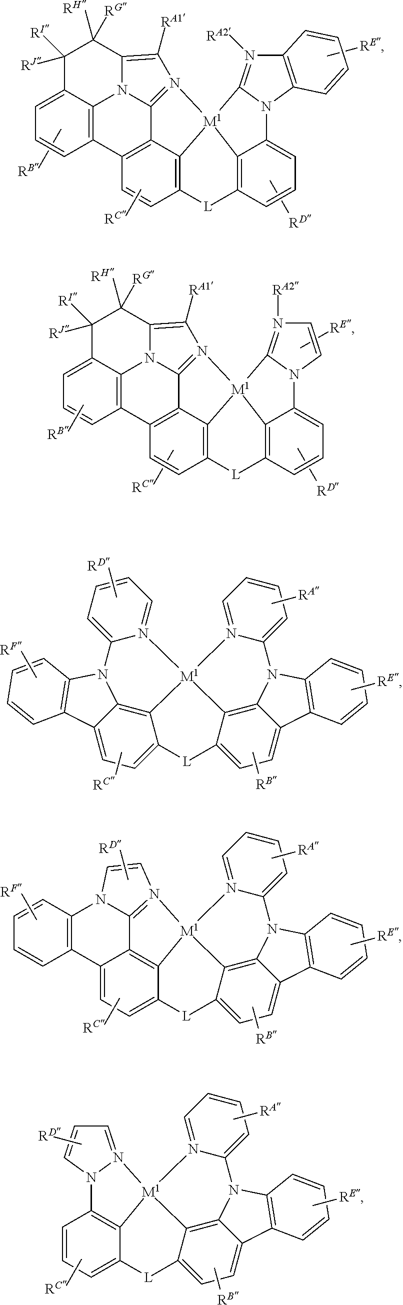

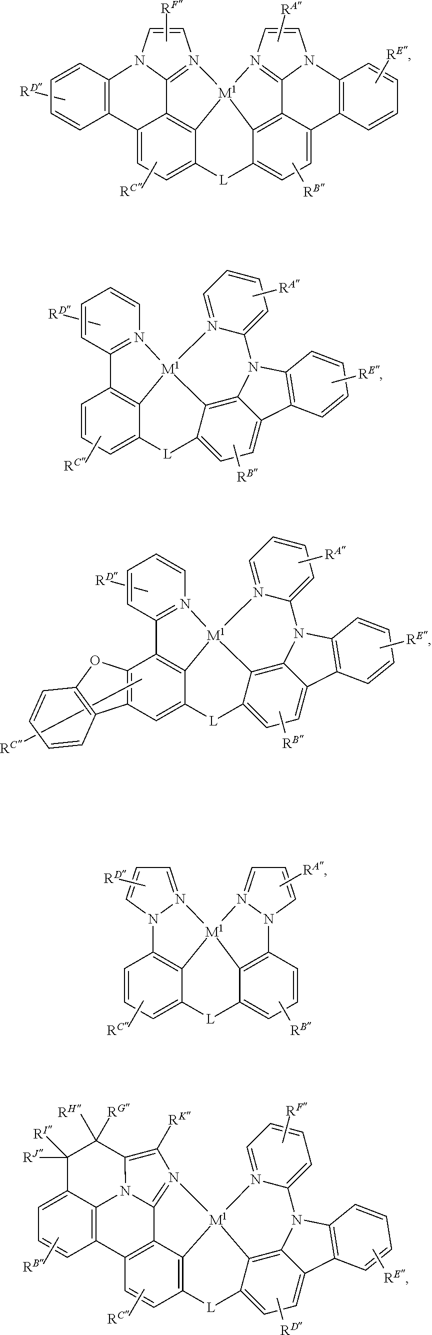

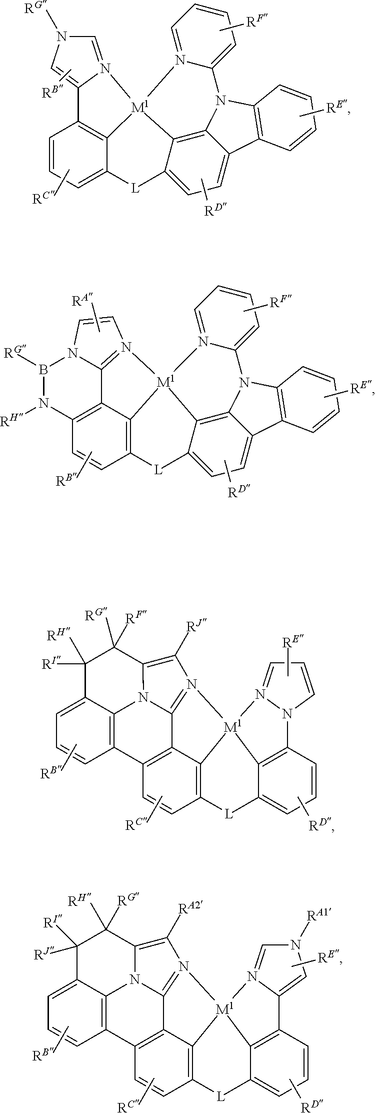

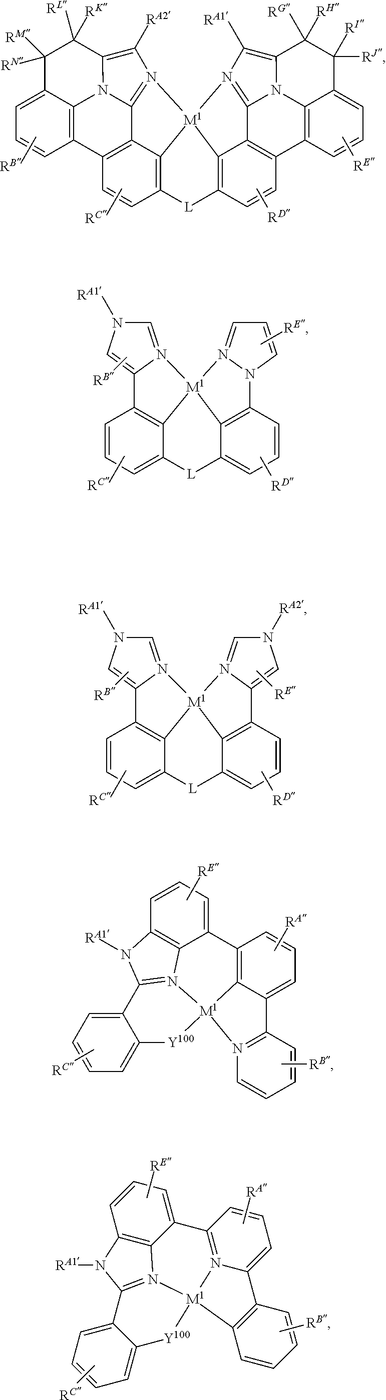

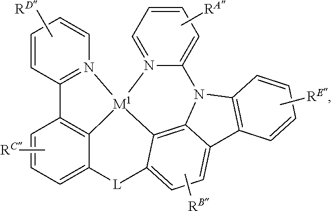

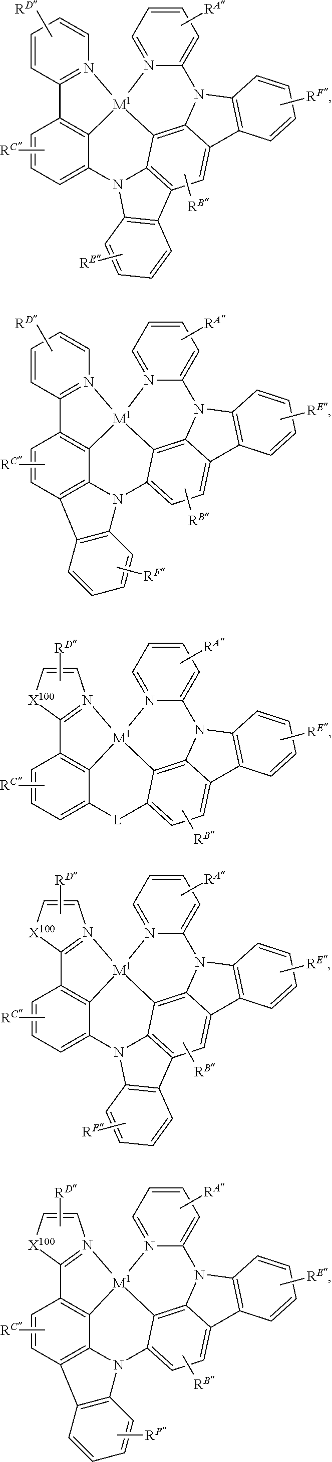

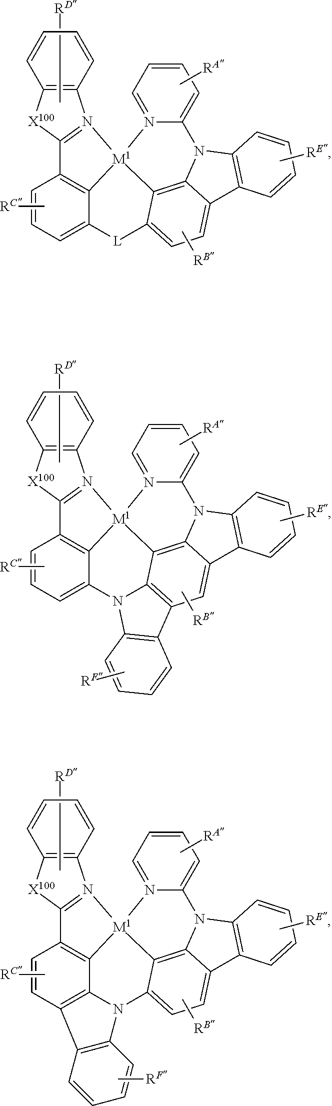

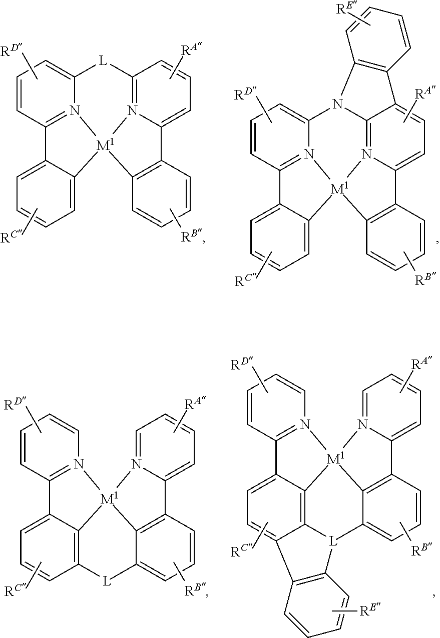

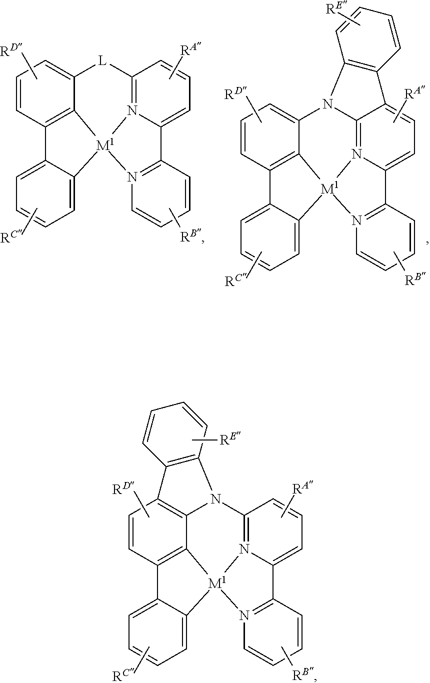

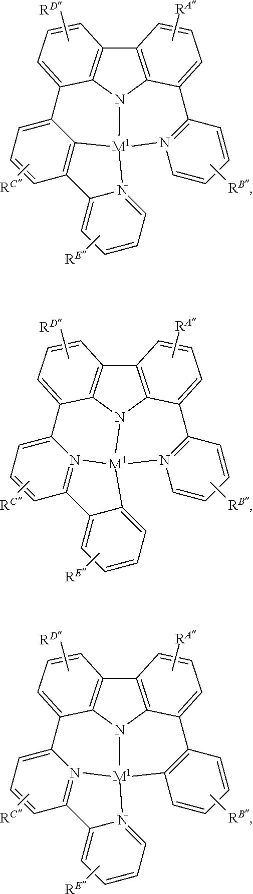

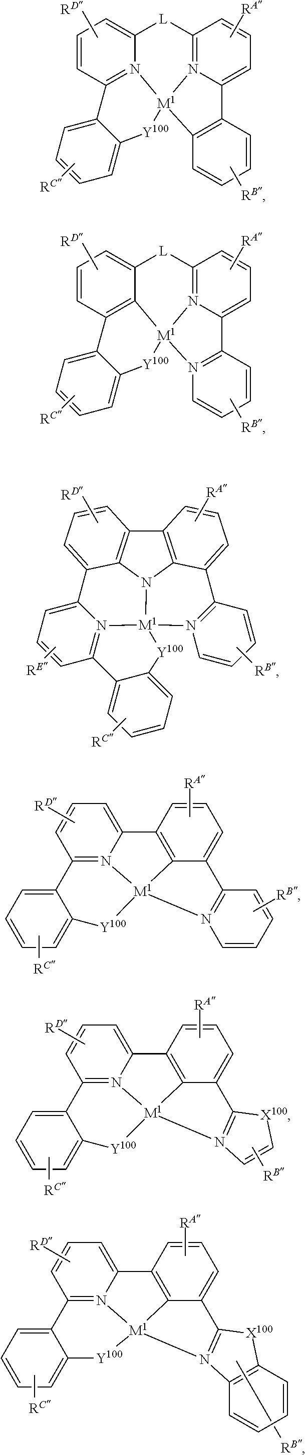

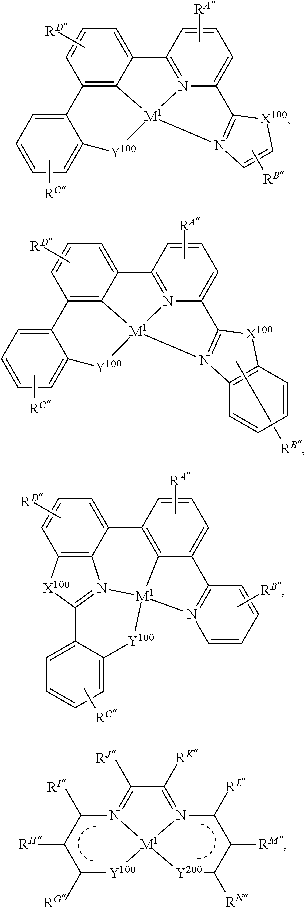

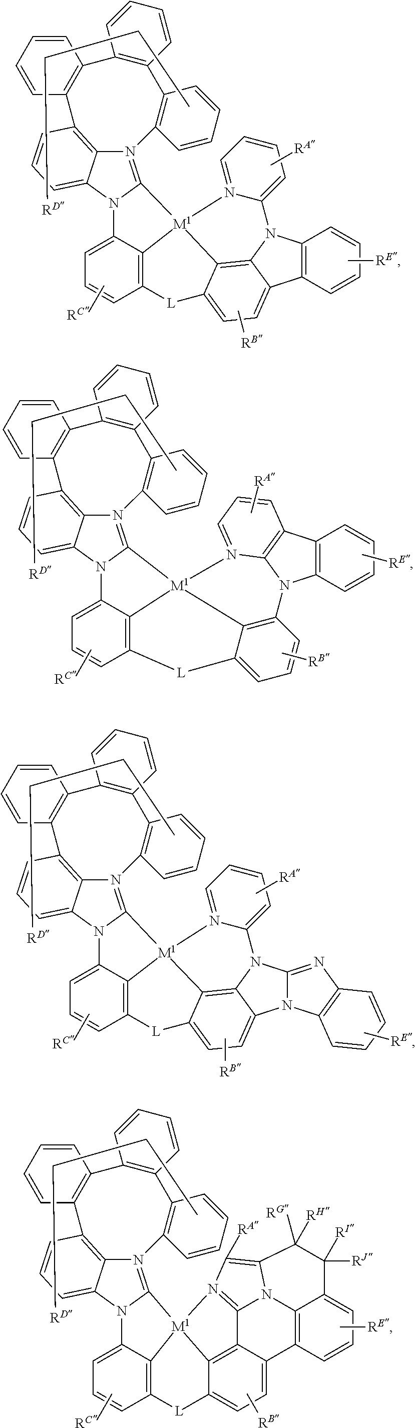

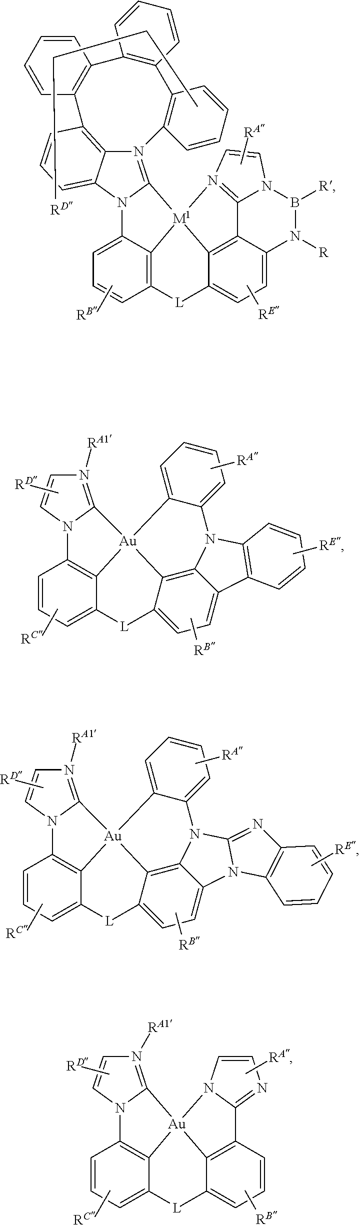

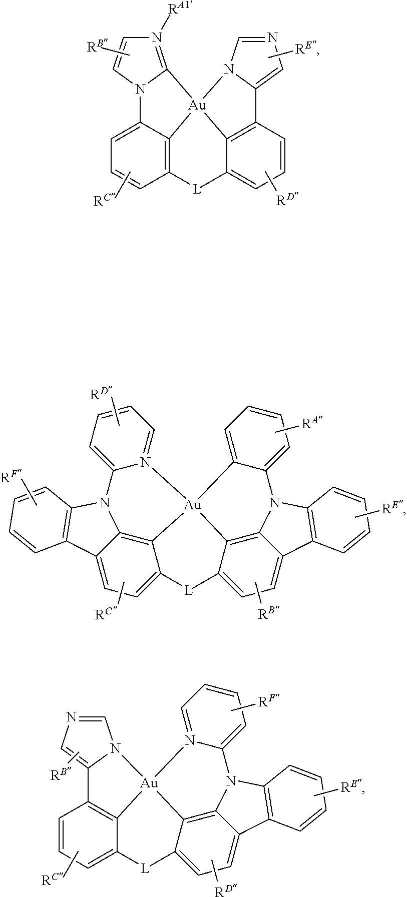

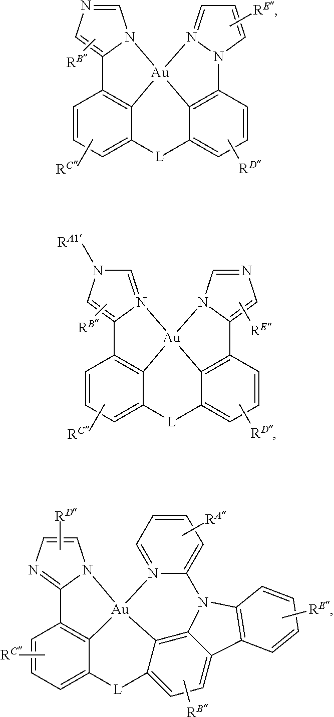

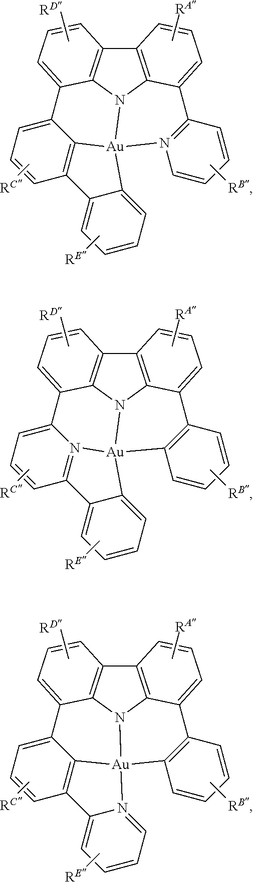

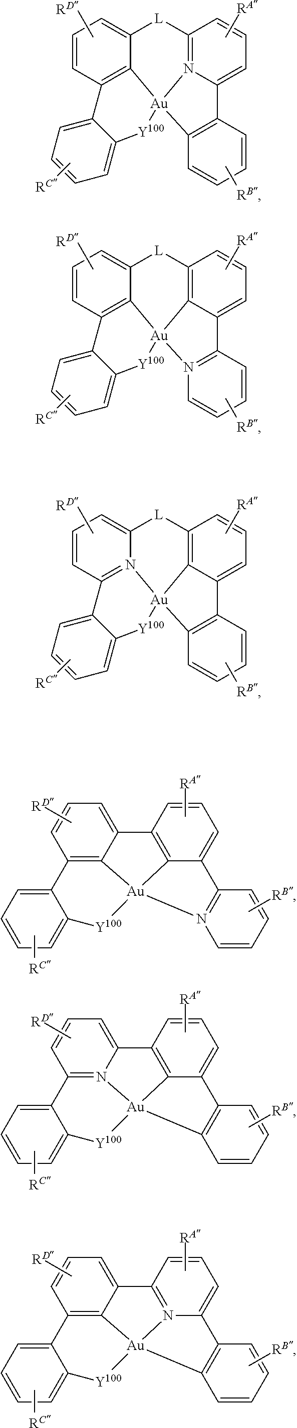

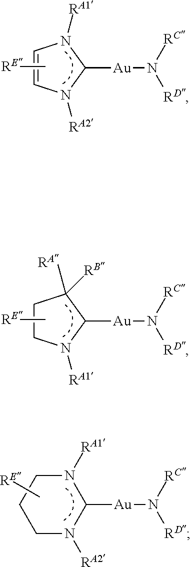

wherein:
M1 is selected from the group consisting of Pt, Pd, and Ni;
each of X⁹⁶ to X⁹⁹ is independently C or N;
each of Y¹⁰⁰ and Y²⁰⁰ is independently selected from the group consisting of a NR″, O, S, and Se;
L is independently selected from the group consisting of a direct bond, BR″, BR″R″′, NR″, PR″, O, S, Se, C═O, C═S, C═Se, C═NR″, C═CR″R″′, S═O, SO₂, CR″, CR″R″′, SiR″R″′, GeR″R″′, alkyl, cycloalkyl, aryl, heteroaryl, and combinations thereof;
X¹⁰⁰ for each occurrence is selected from the group consisting of O, S, Se, NR″, and CR″R″′;
each R^{10a}, R^{20a}, R^{30a}, R^{40a}, R^{50a}, R^{A″}, R^{B″}, R^{C″}, R^{D″}, R^{E″}, and R^{F″} independently represents mono-, up to the maximum substitutions, or no substitutions;
each R, R′, R″, R″′, R^{10a}, R^{11a}, R^{12a}, R^{13a}, R^{20a}, R^{30a}, R^{40a}, R^{50a}, R⁶⁰, R⁷⁰, R⁹⁷, R⁹⁸, R⁹⁹, R^{A1′}, R^{A2′}, R^{A″}, R^{B″}, R^{C″}, R^{D″}, R^{E″}, R^{F″}, R^{G″}, R^{H″}, R^{I″}, R^{J″}, R^{K″}, R^{L″}, R^{M″}, and R^{N″} is independently a hydrogen or a substituent selected from the group consisting of the General Substituents defined herein; and
any two adjacent R, R′, R″, R″′, R^{10a}, R^{11a}, R^{12a}, R^{13a}, R^{20a}, R^{30a}, R^{40a}, R^{50a}, R⁶⁰, R⁷⁰, R⁹⁷, R⁹⁸, R⁹⁹, R^{A1′}, R^{A2′}, R^{A″}, R^{B″}, R^{C″}, R^{D″}, R^{E″}, R^{F″}, R^{G″}, R^{H″}, R^{I″}, R^{J″}, R^{K″}, R^{L″}, R^{M″}, and R^{N″} are optionally joined or fused to form a ring.

In some embodiments, the compound is selected from the group consisting of the following structures:

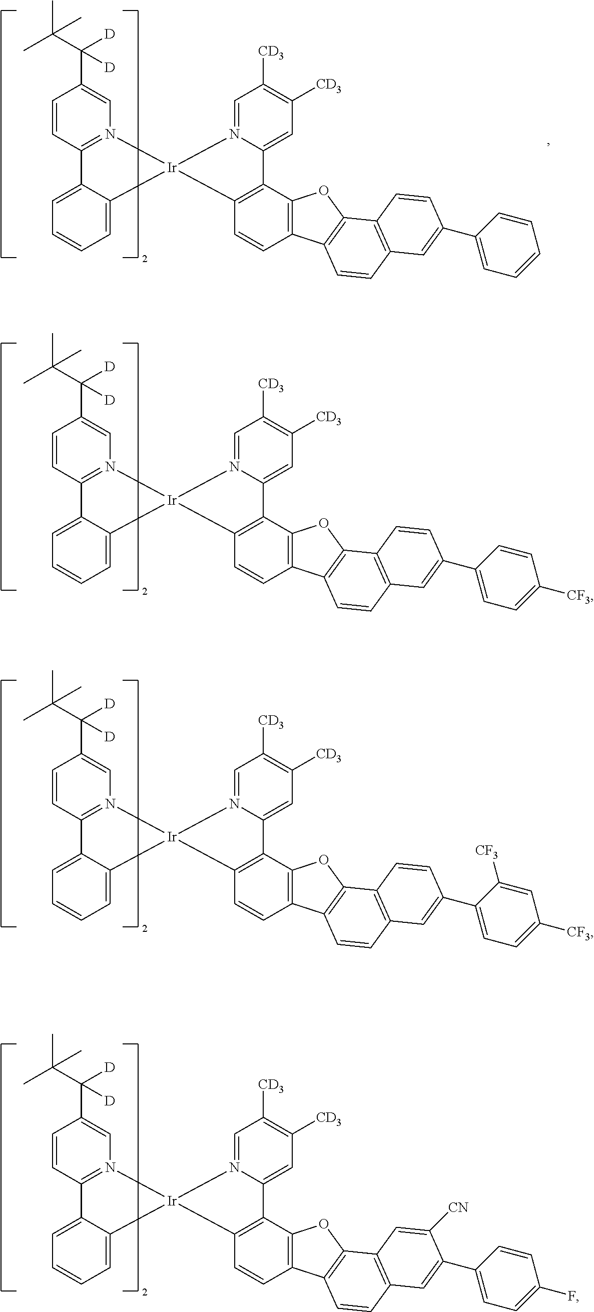

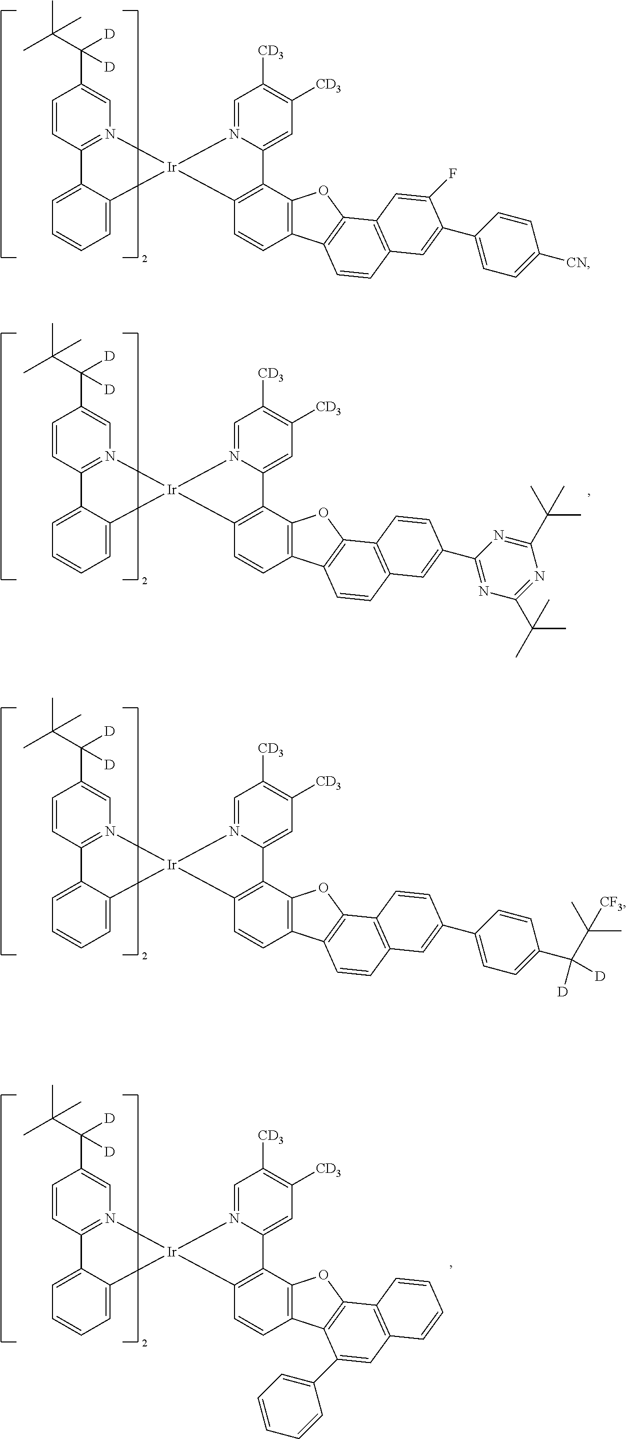

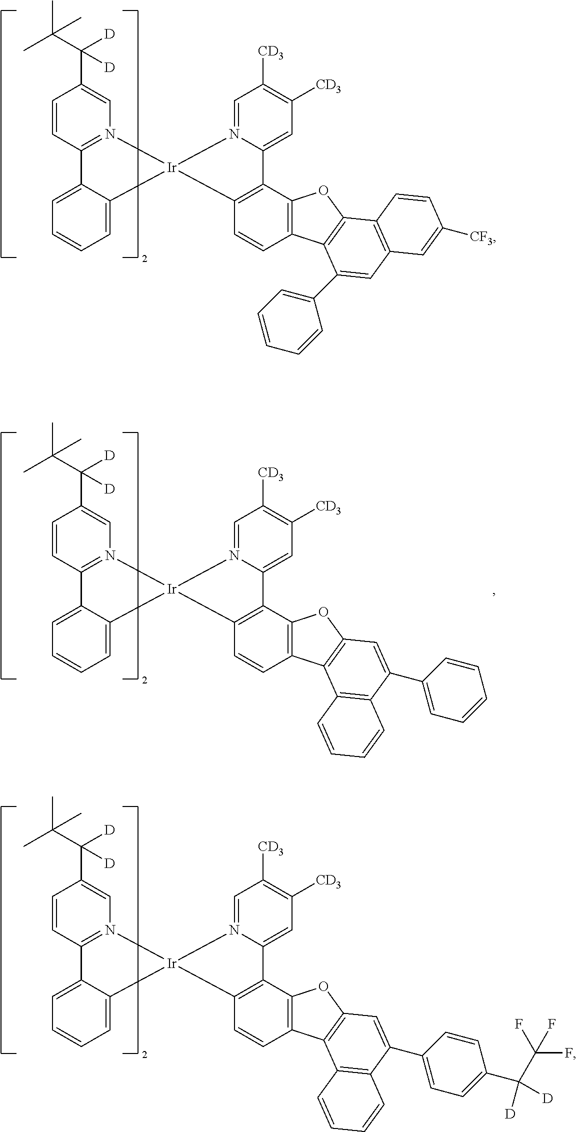

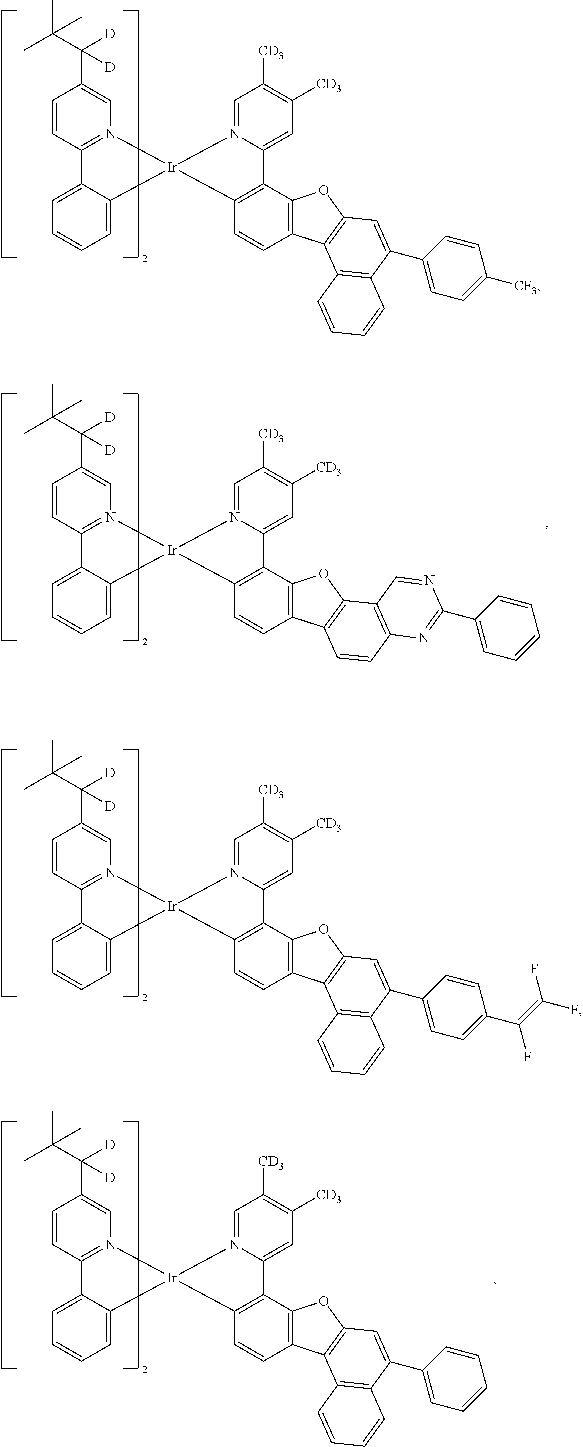

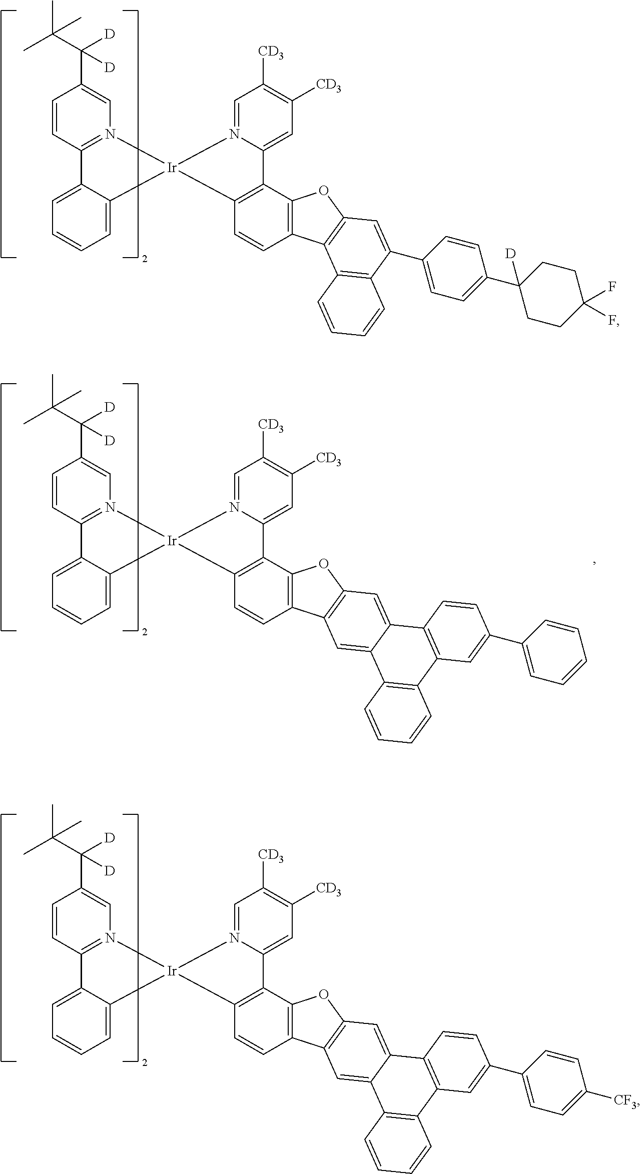

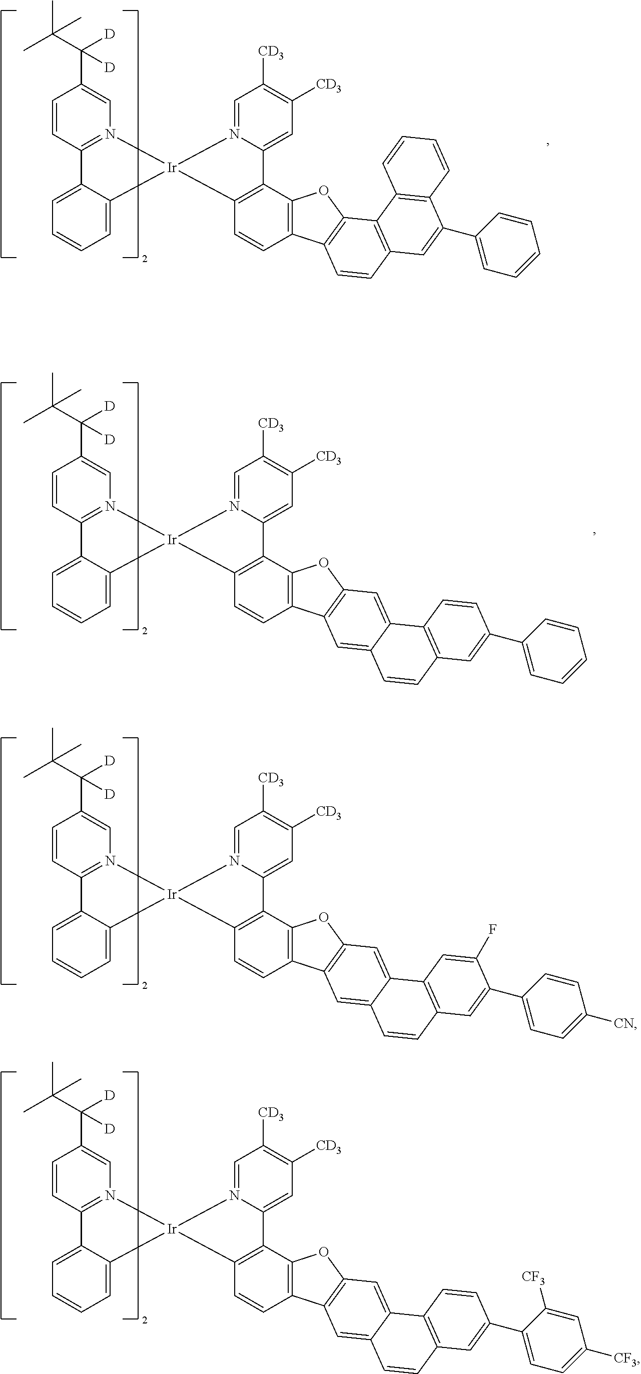

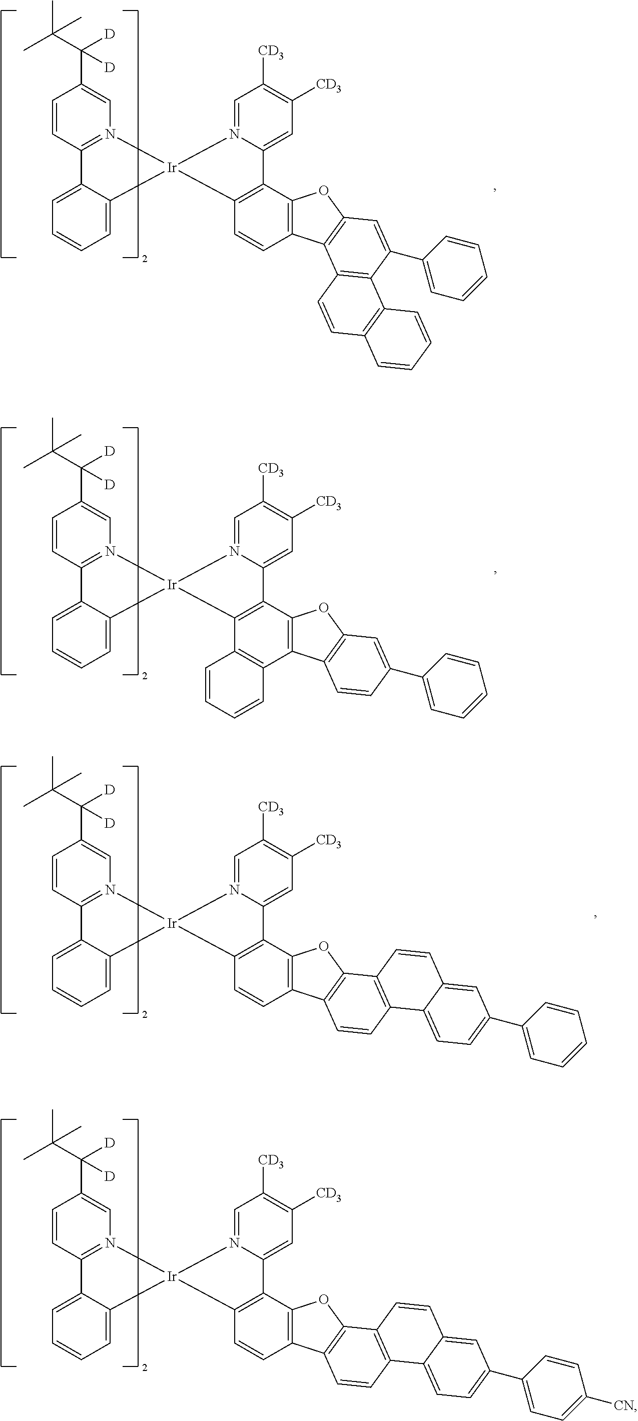

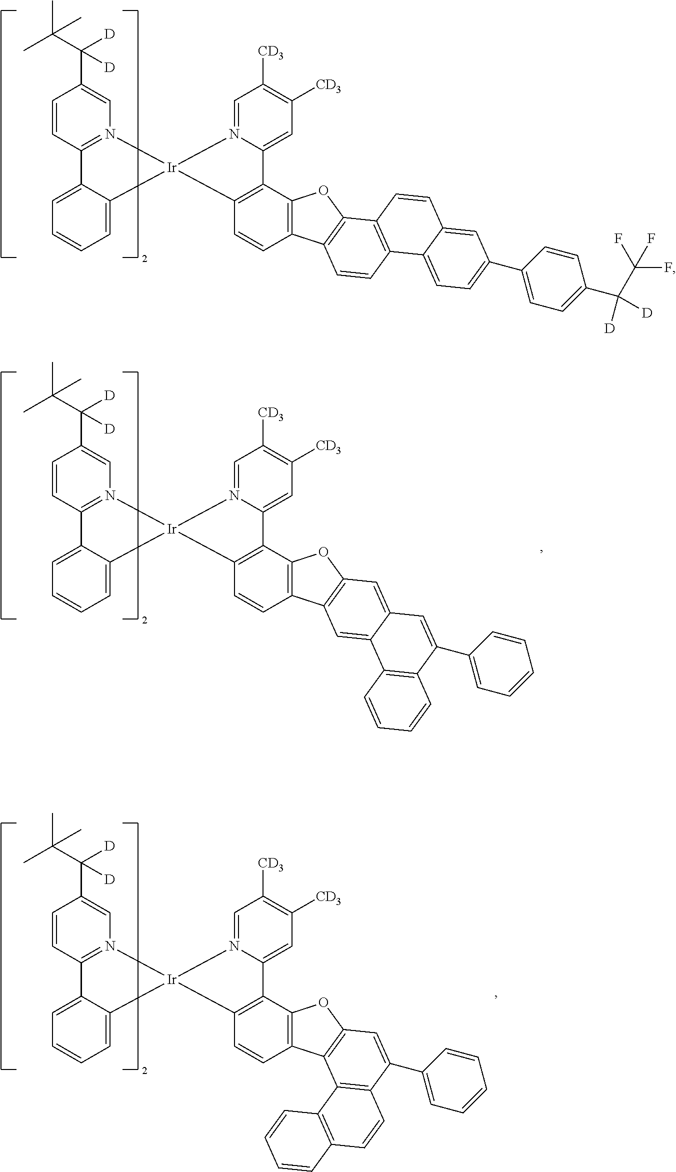

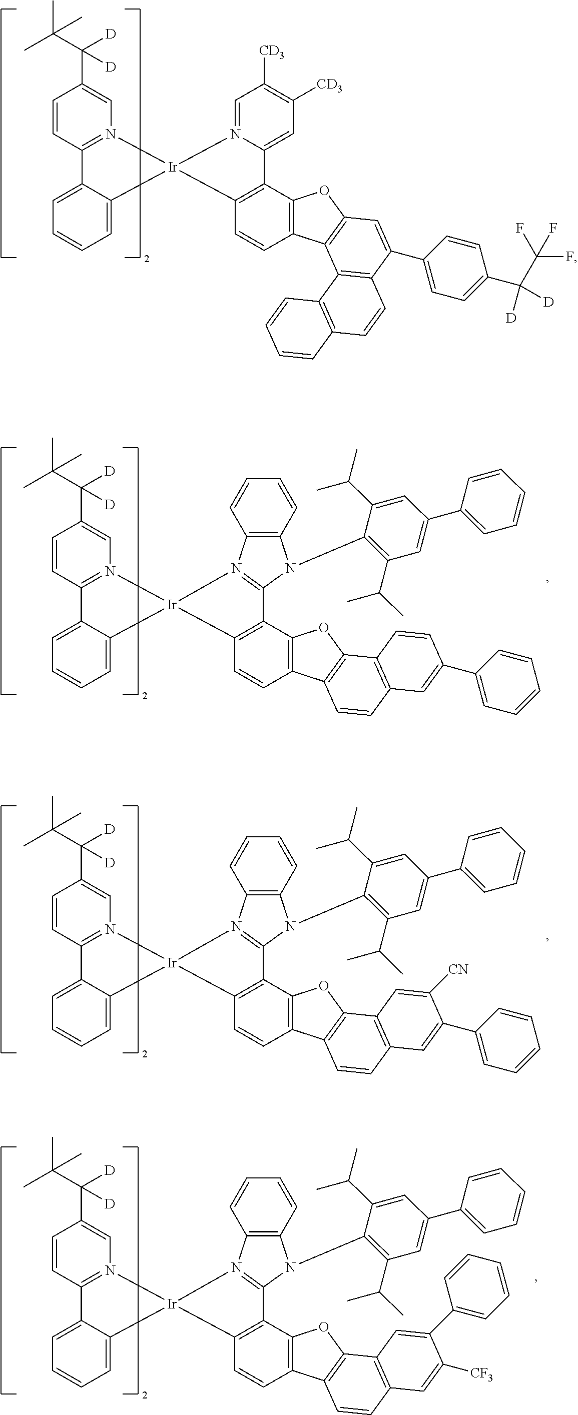

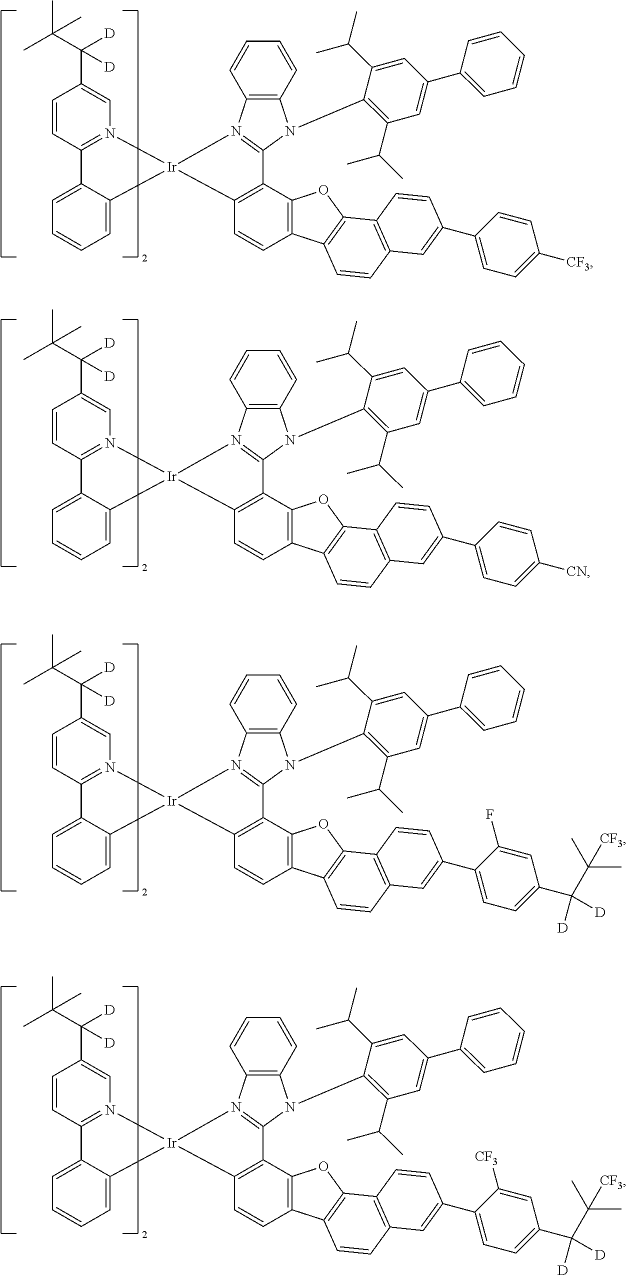

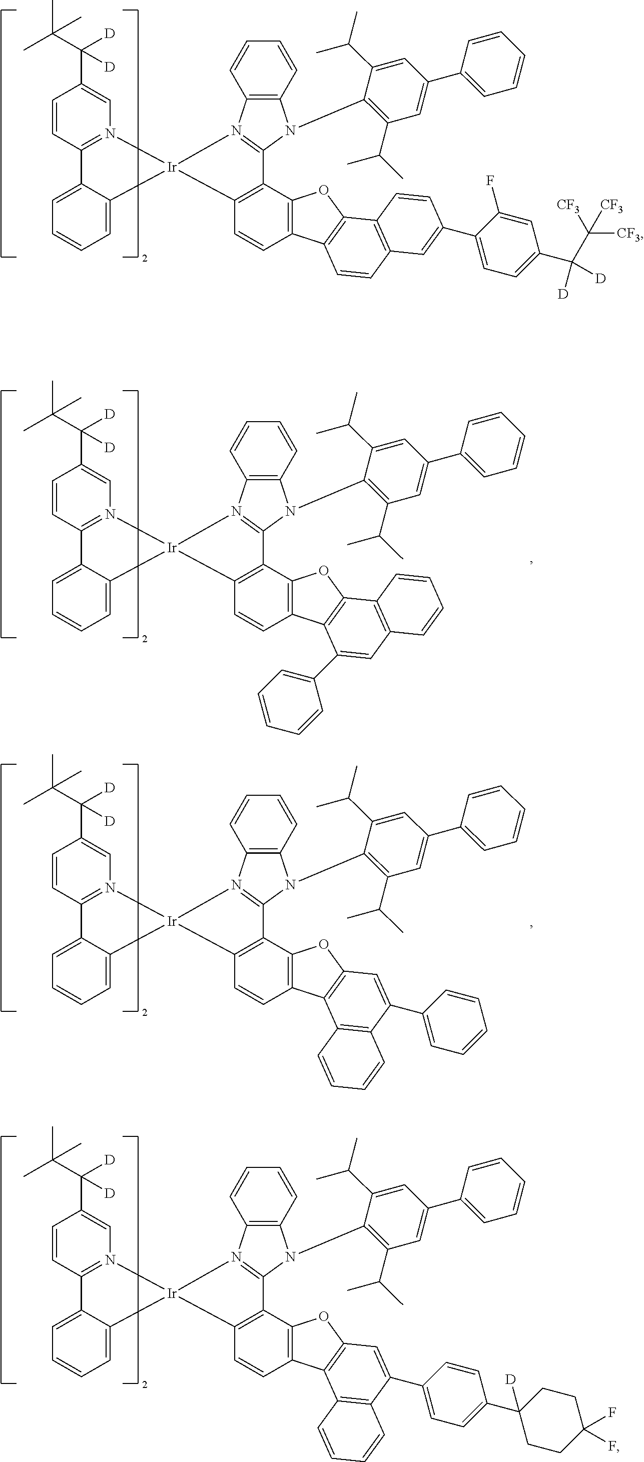

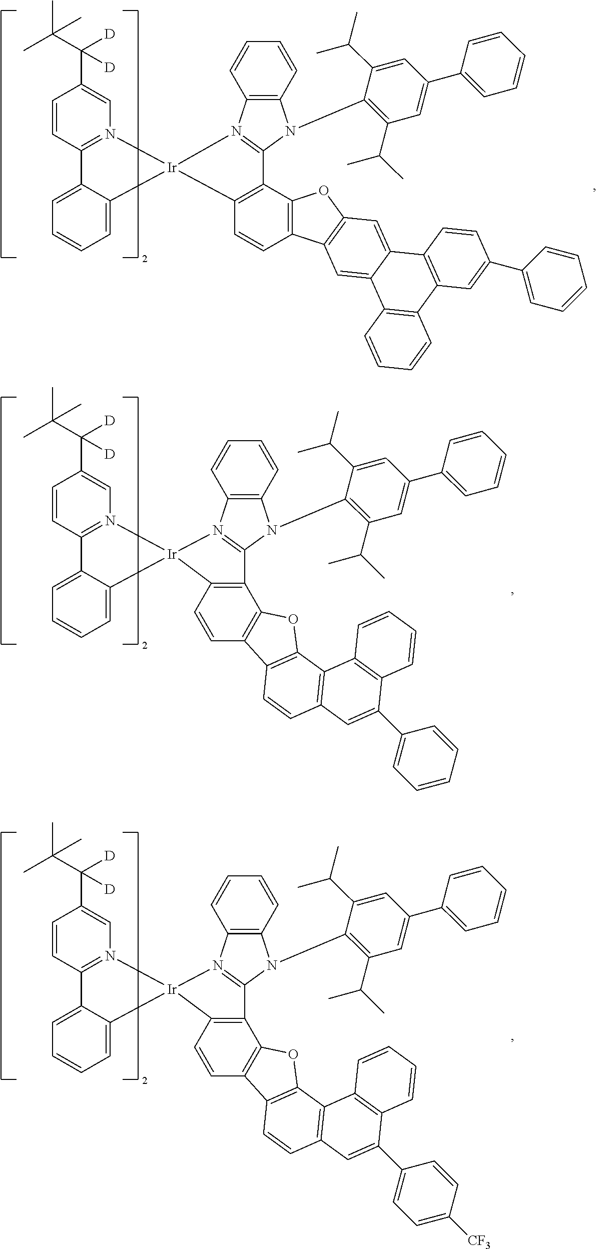

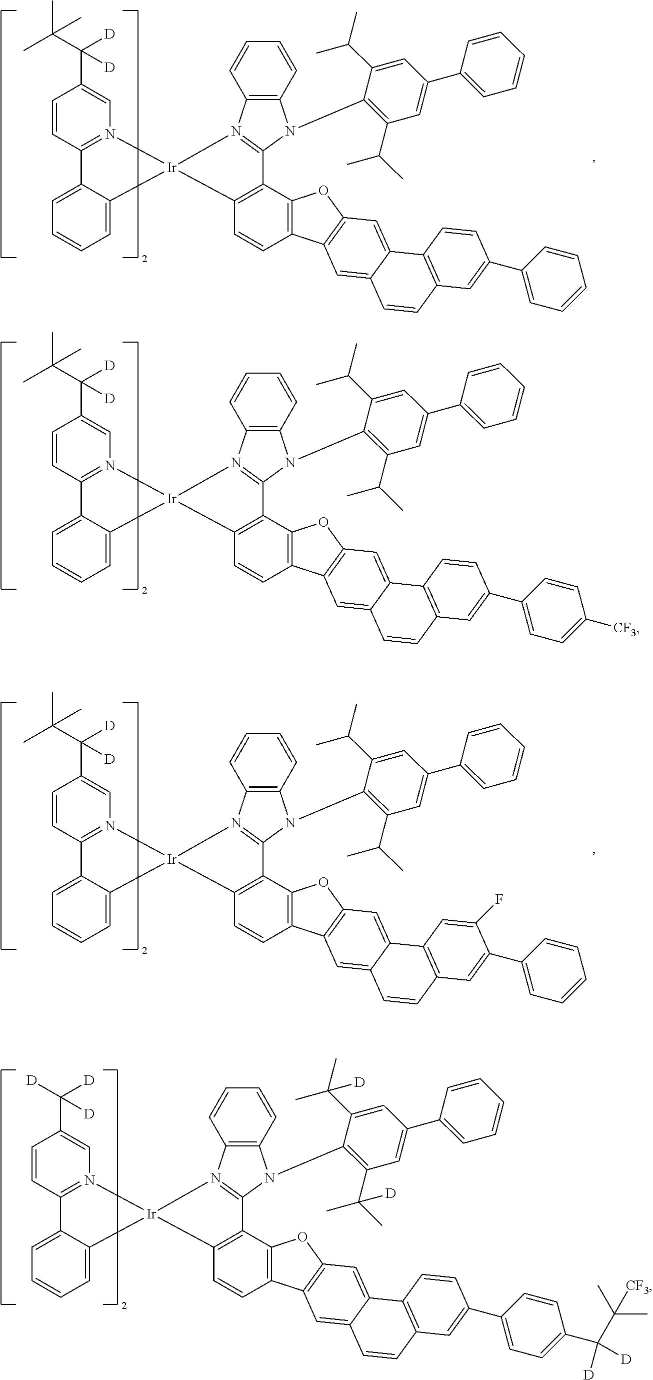

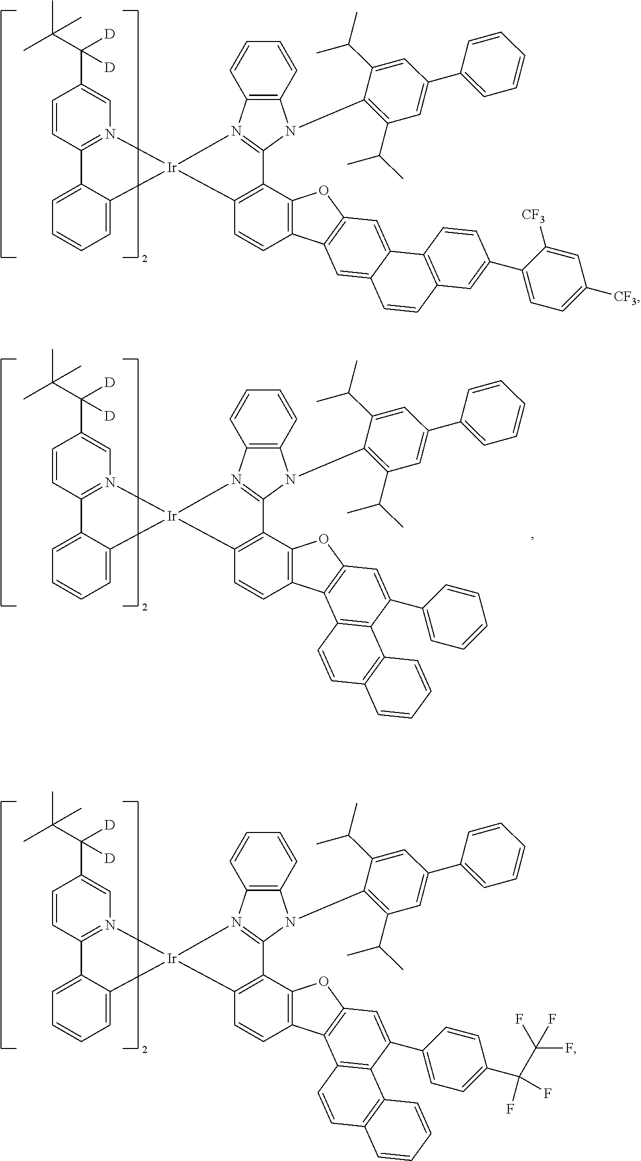

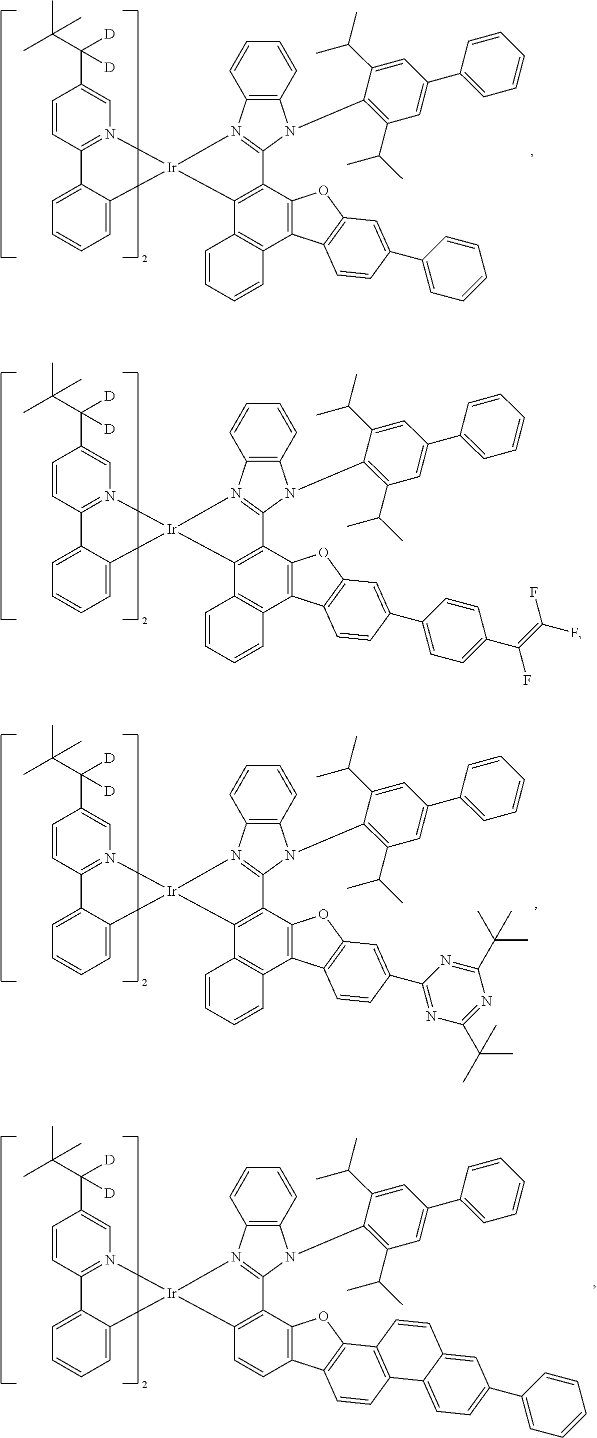

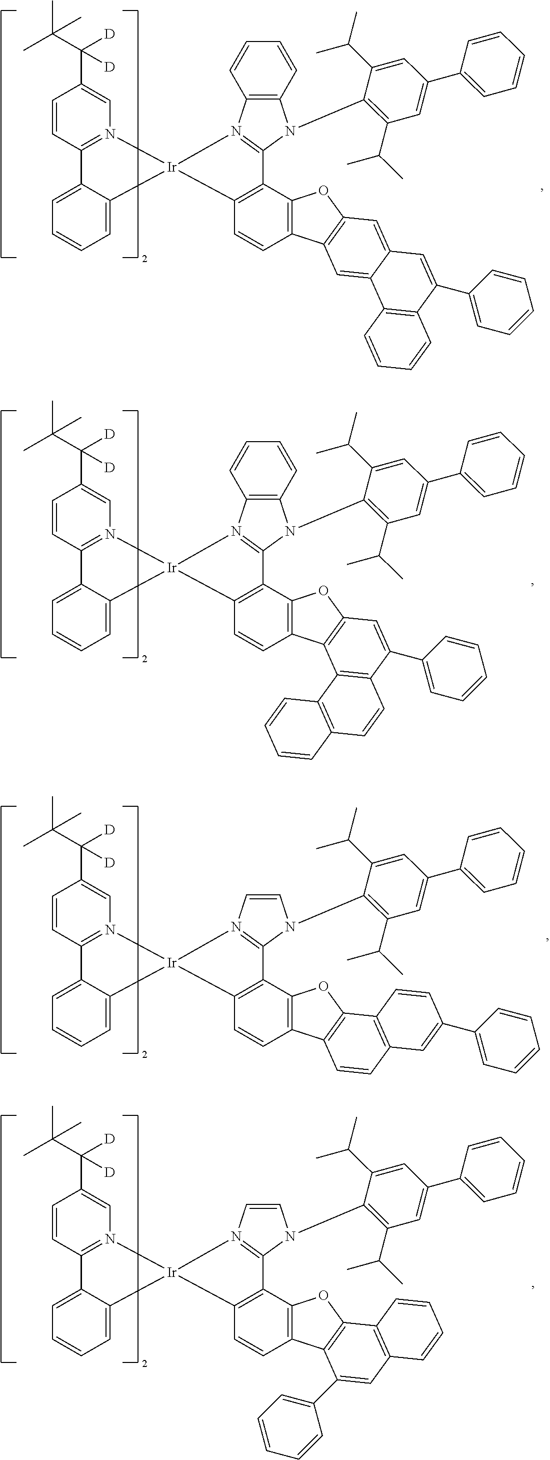

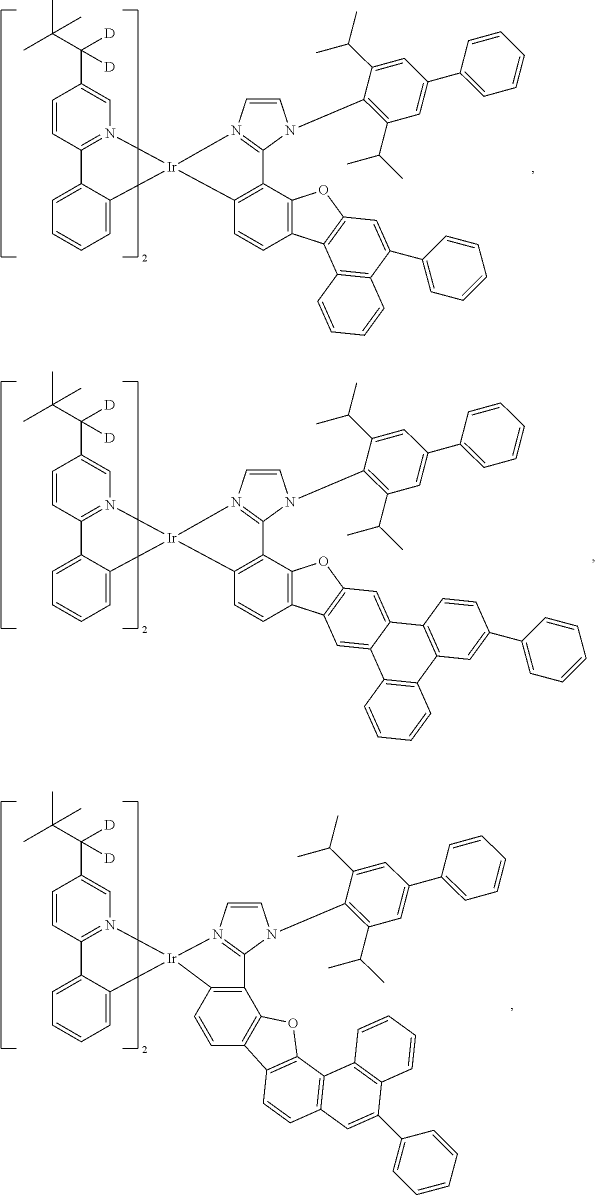

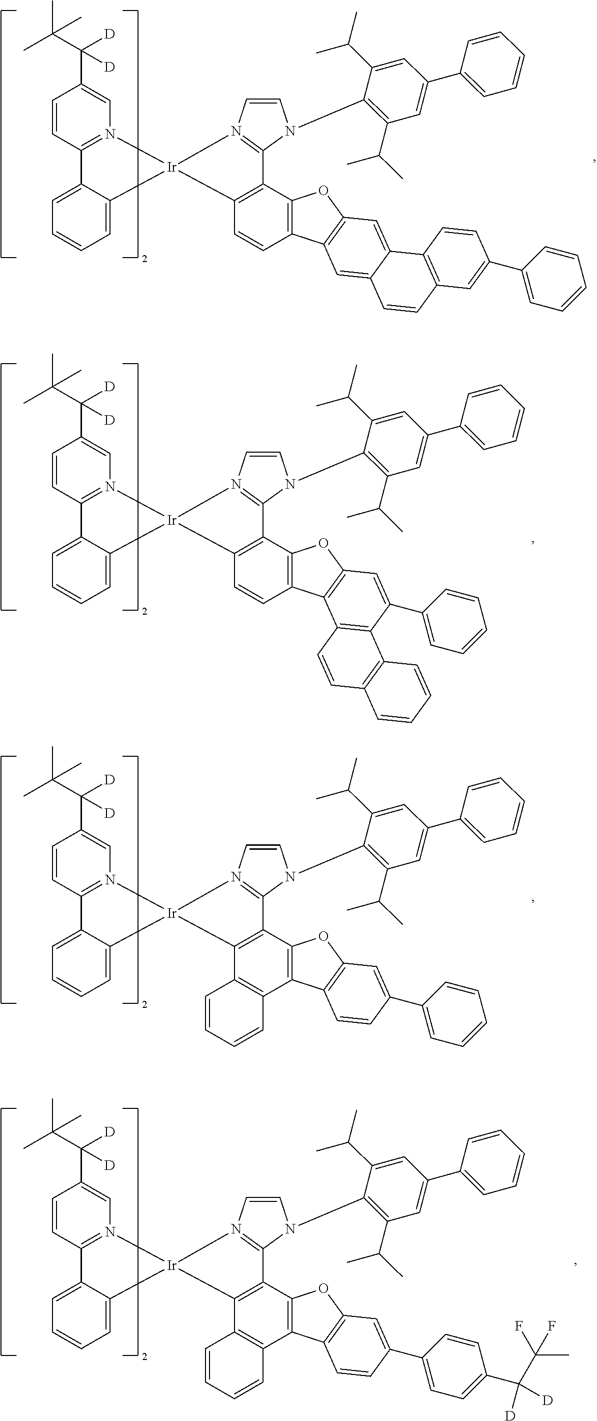

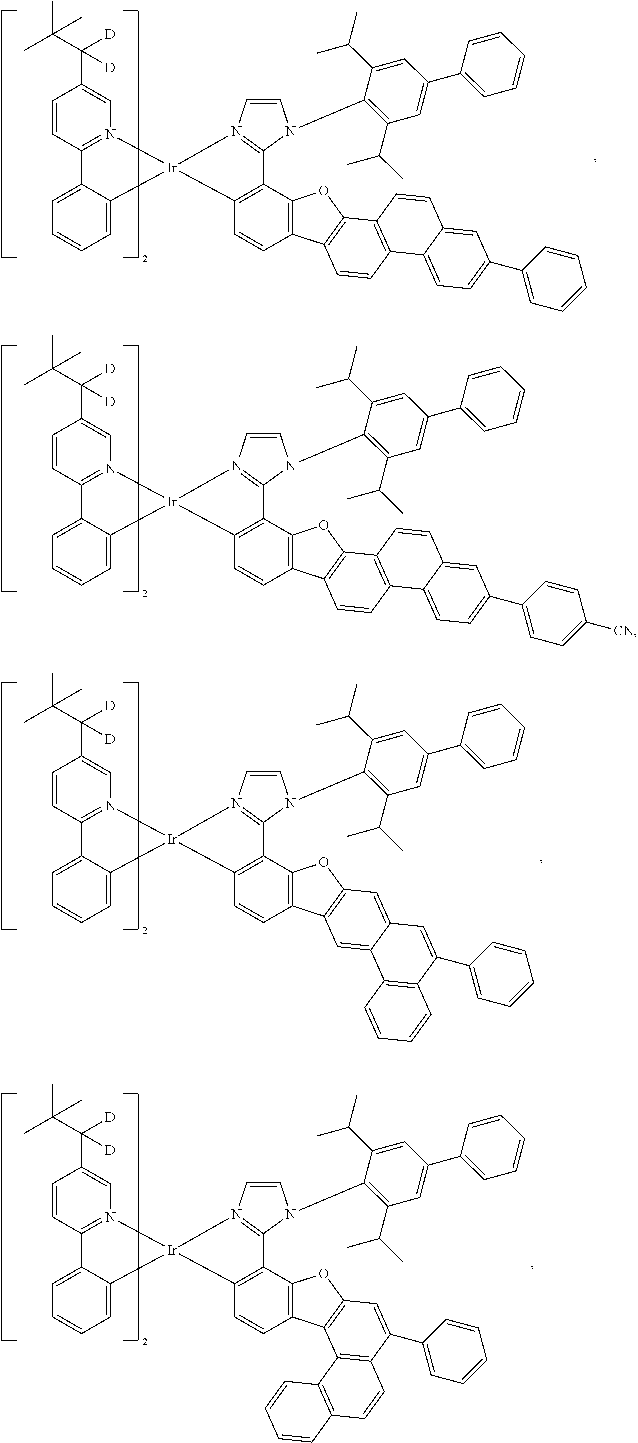

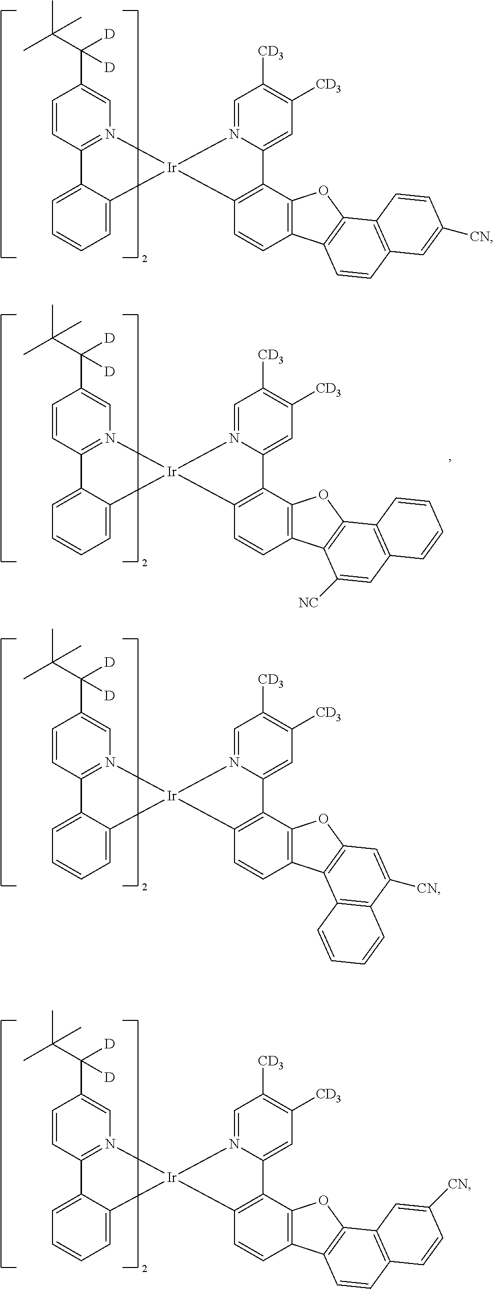

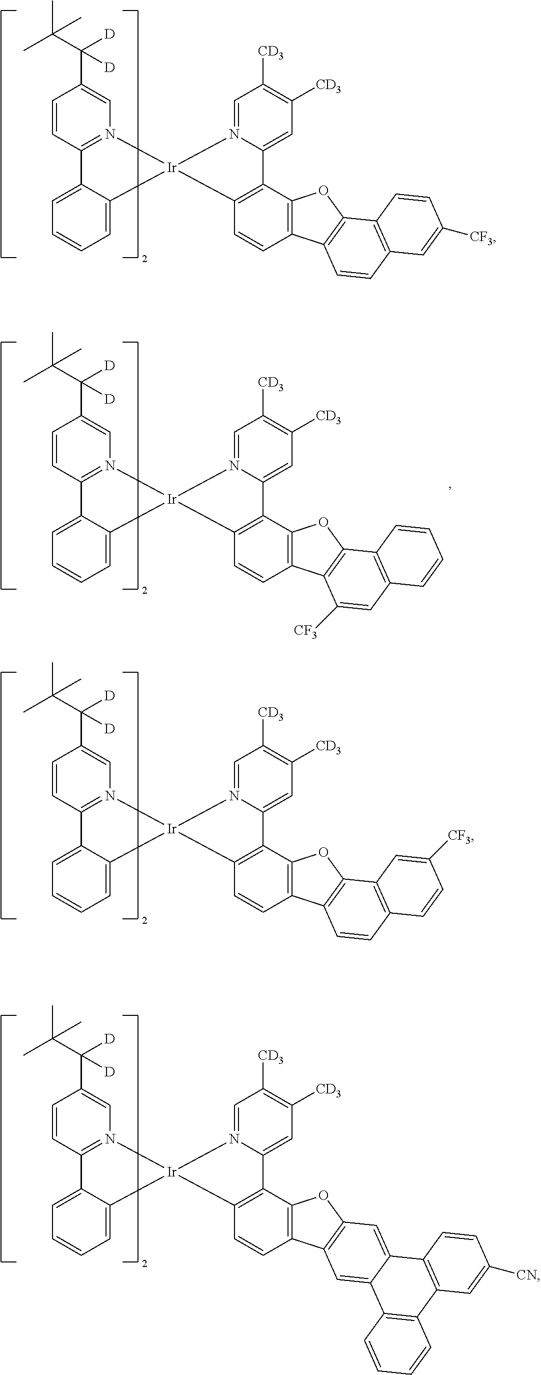

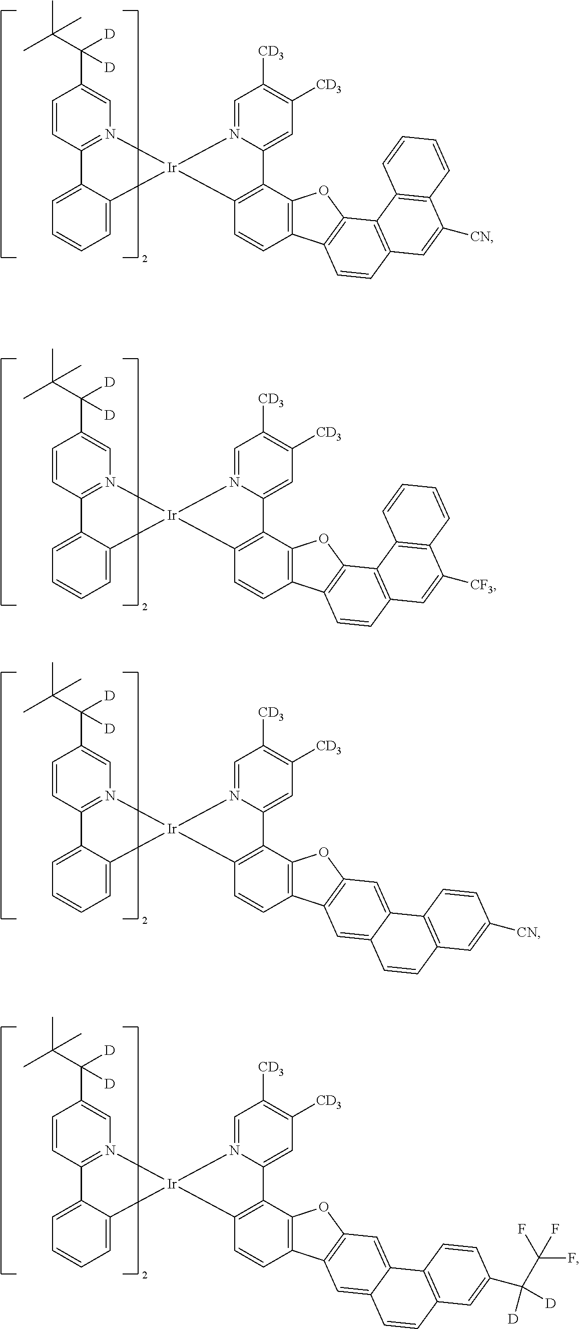

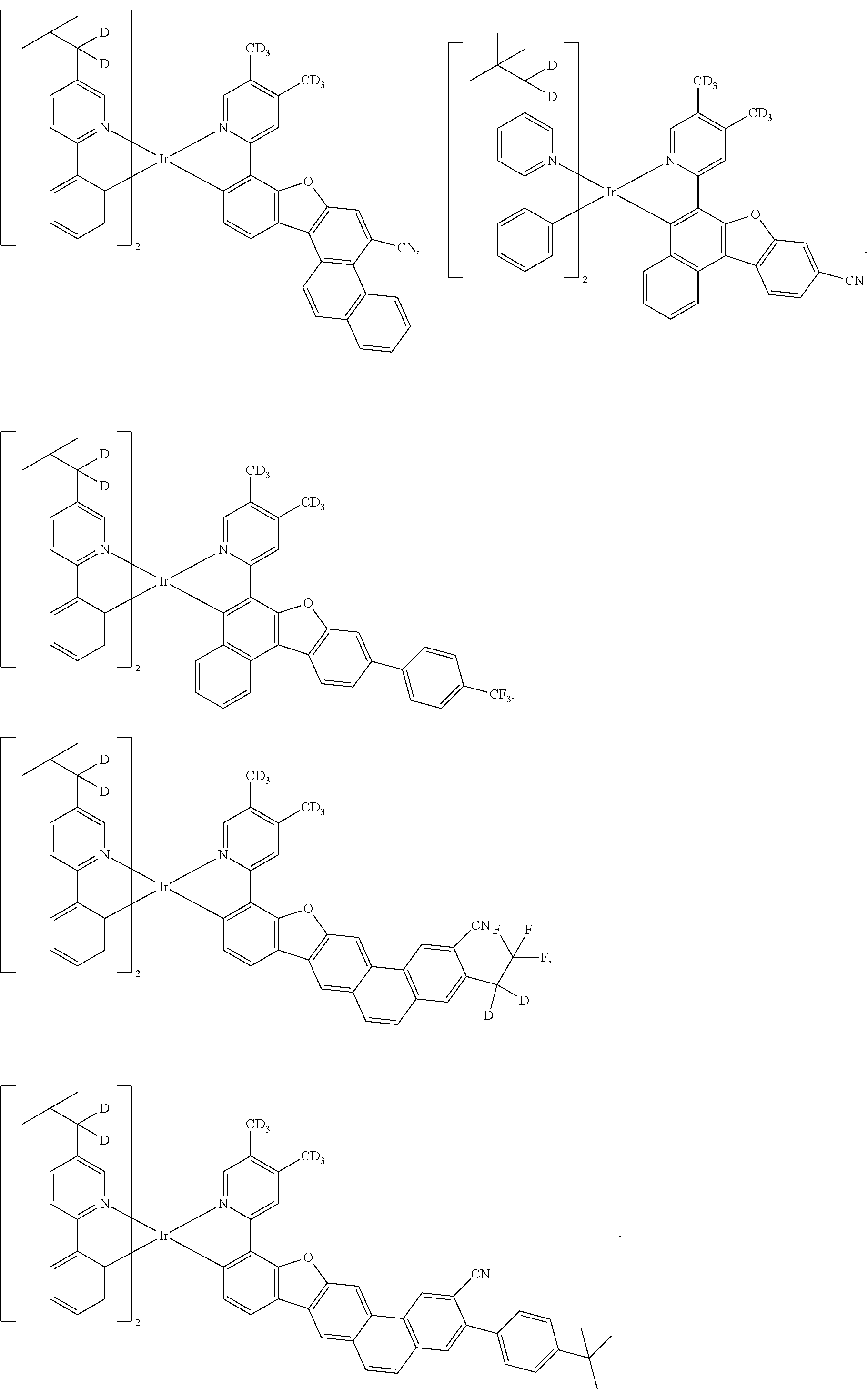

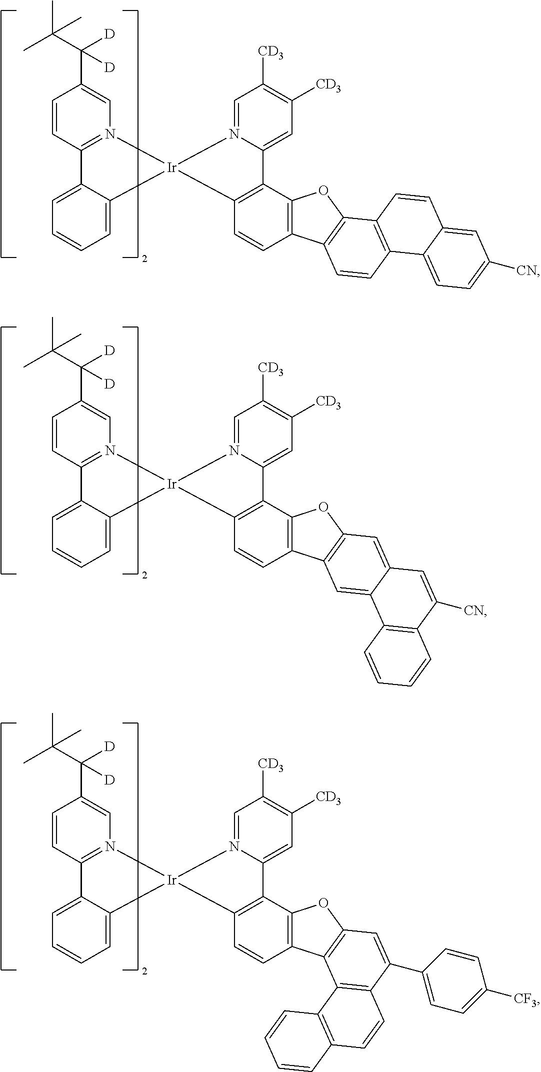

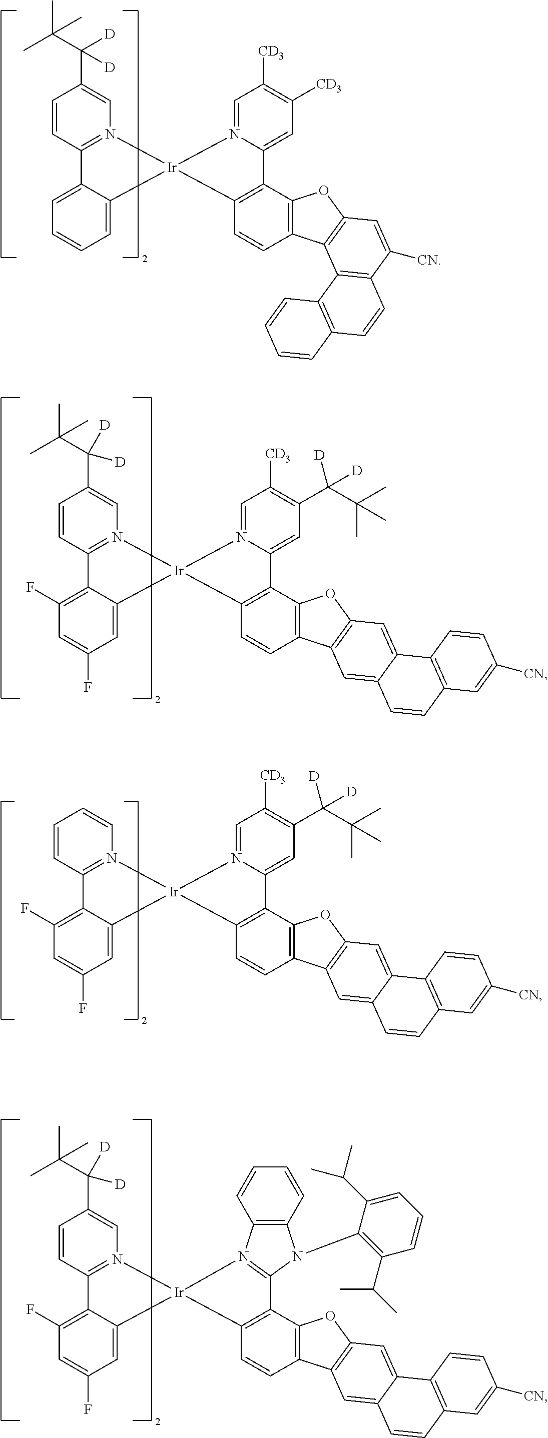

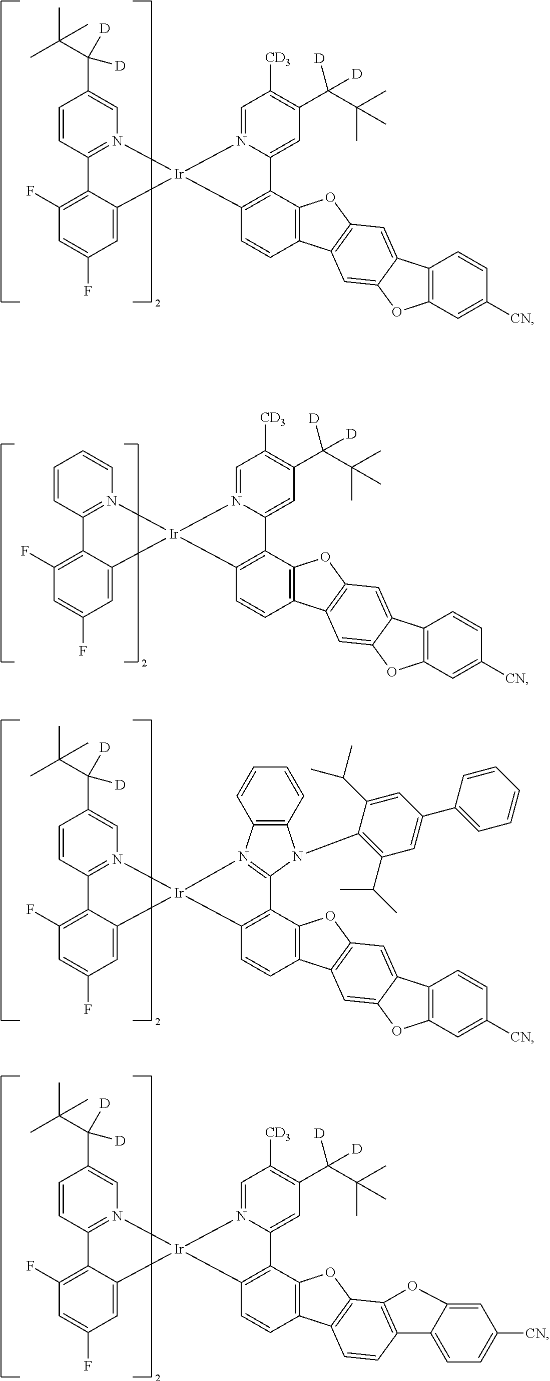

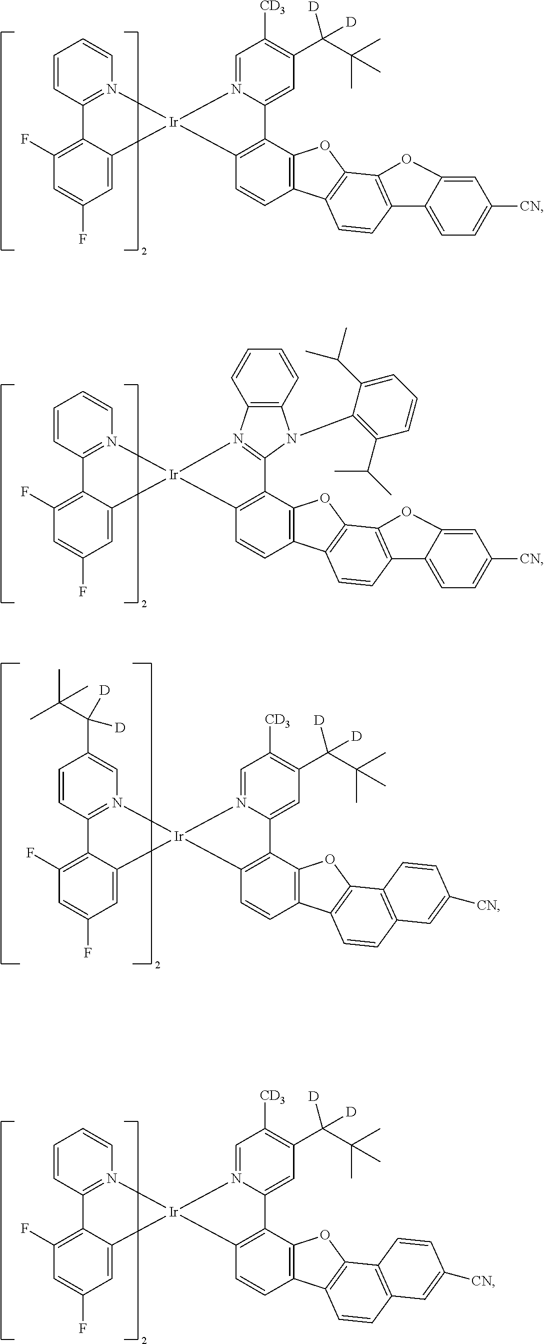

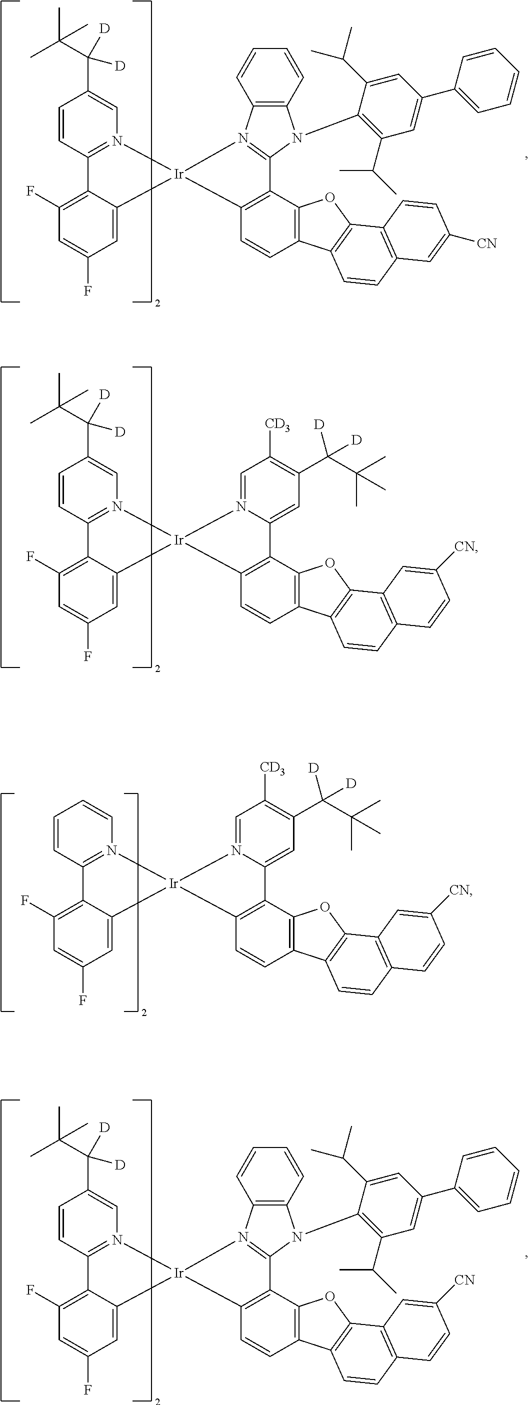

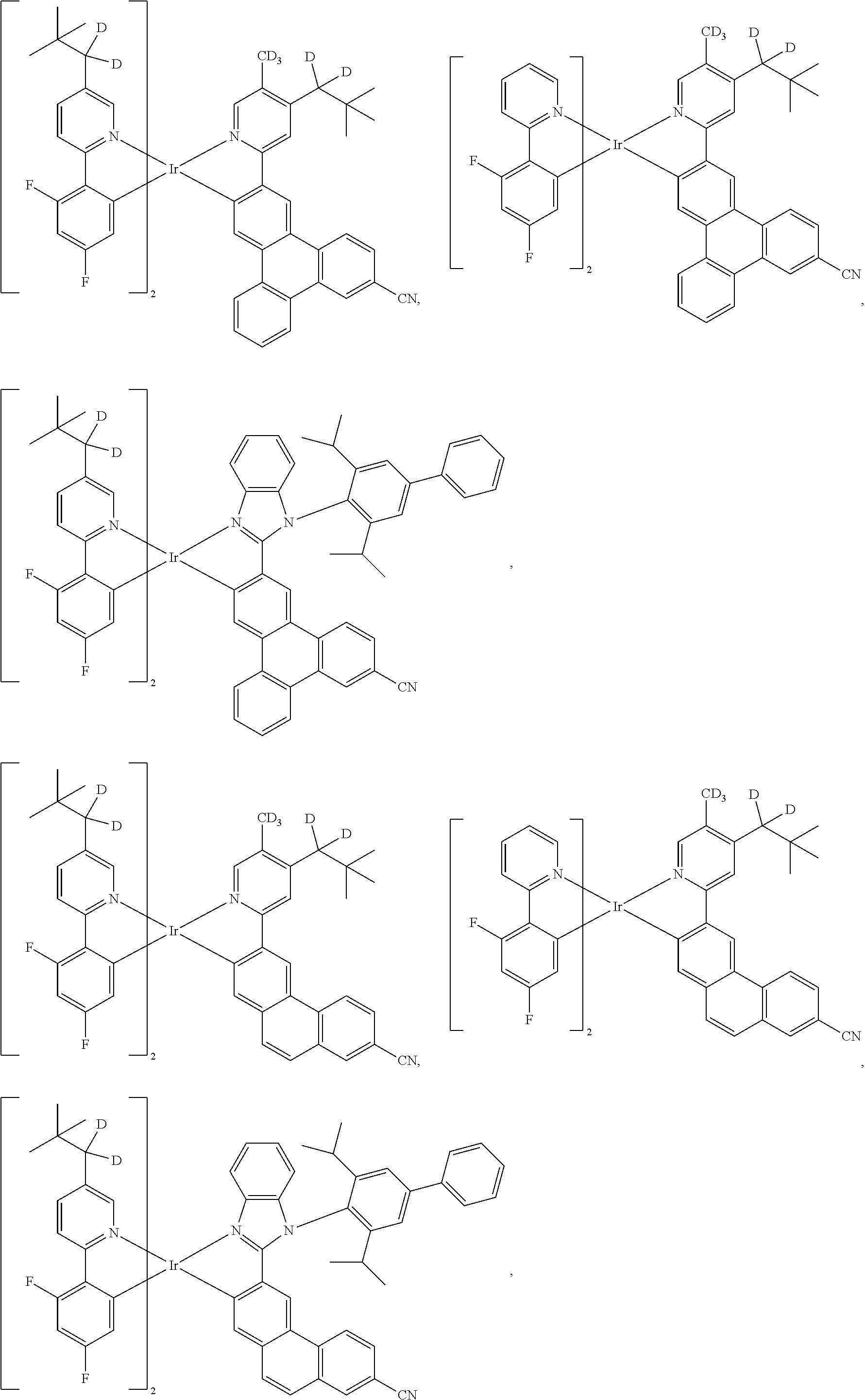

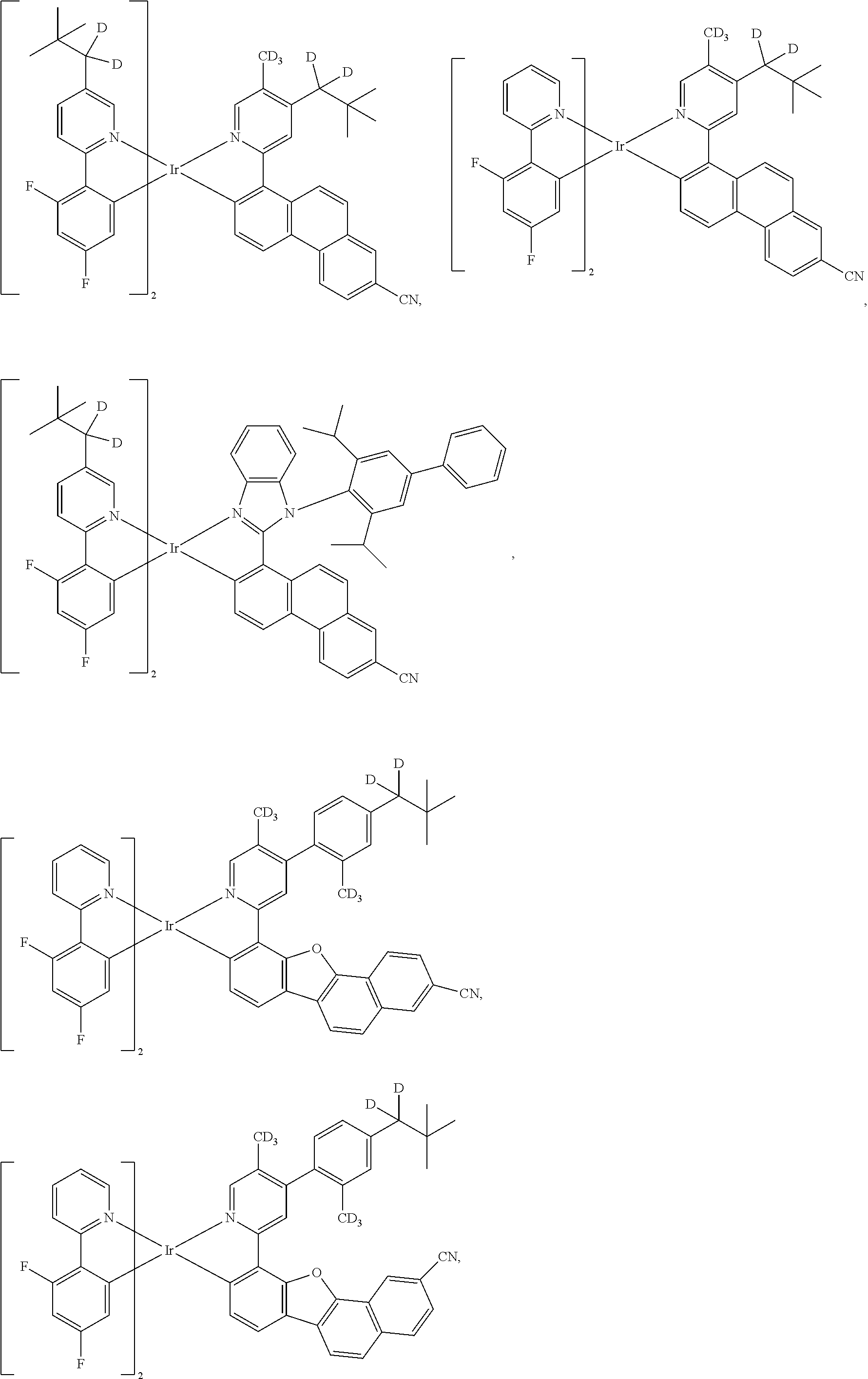

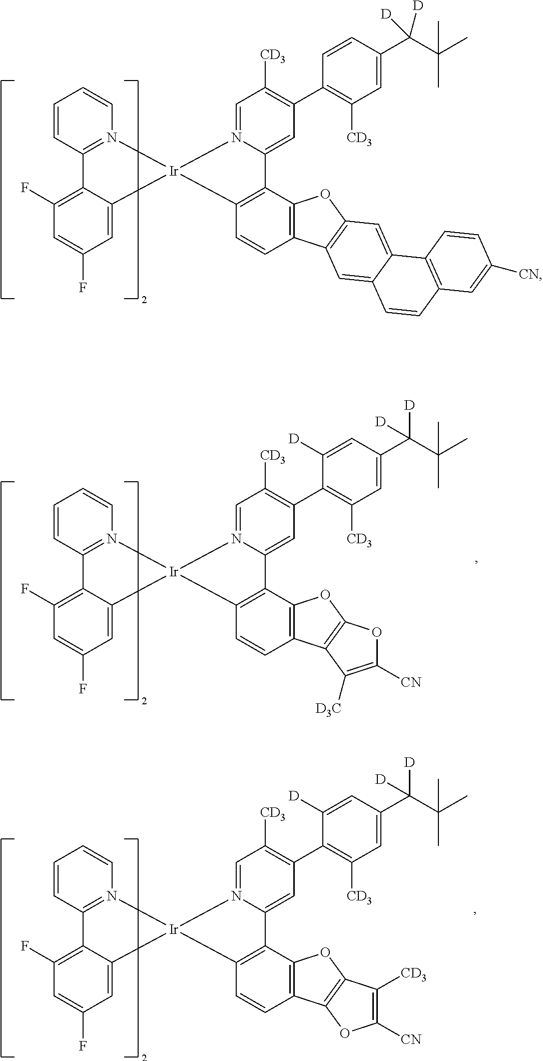

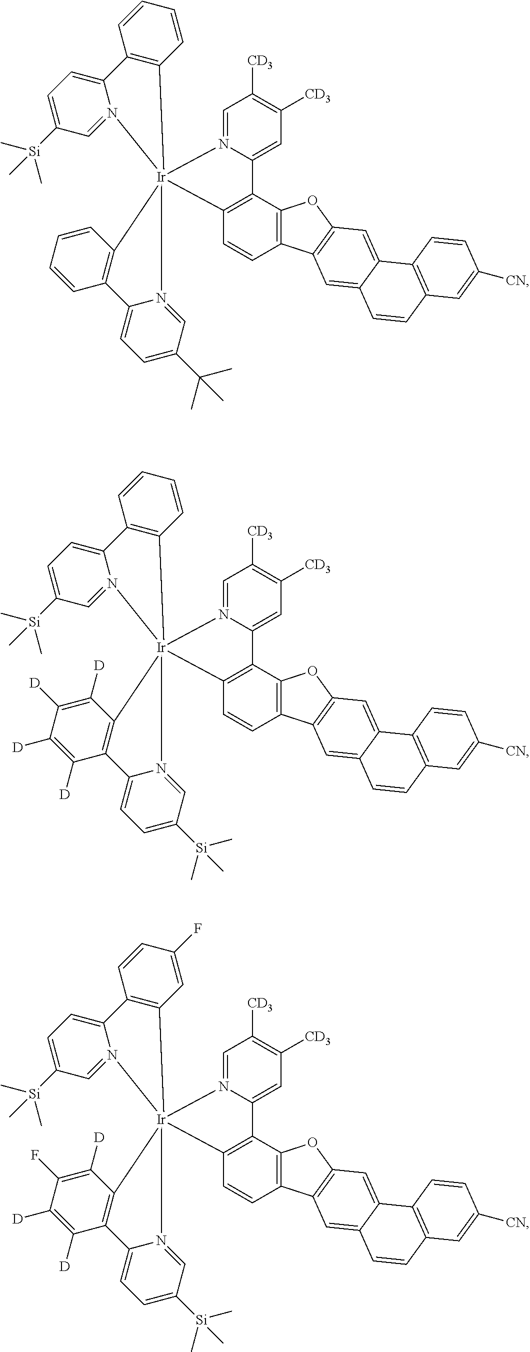

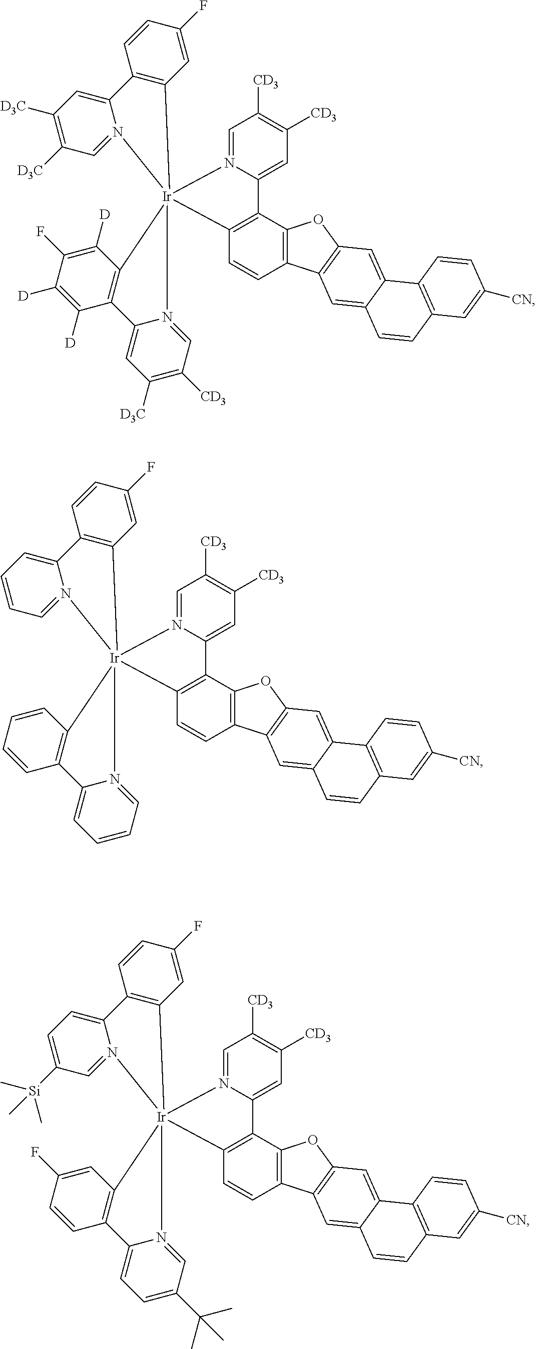

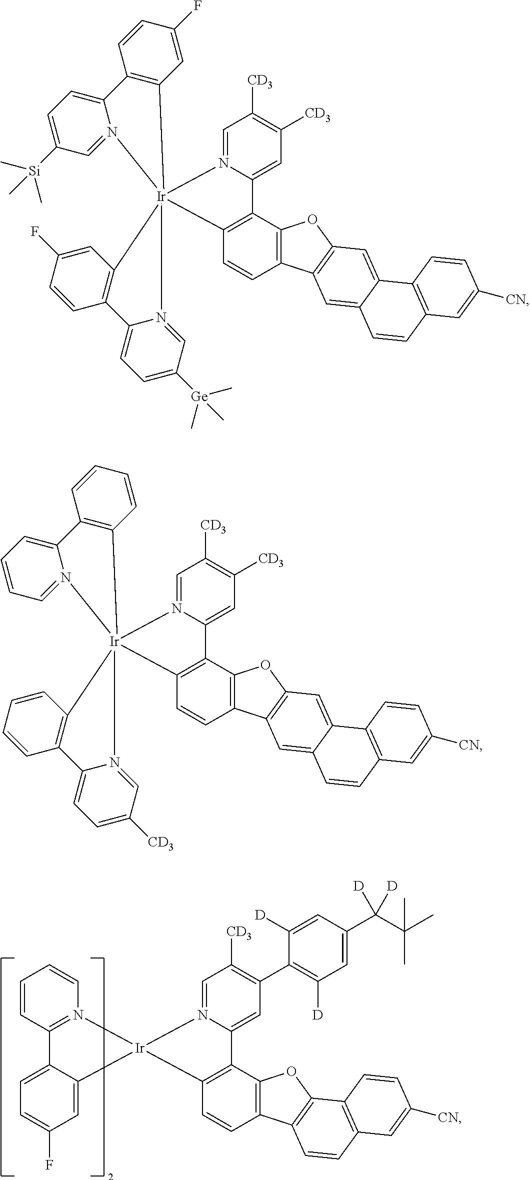

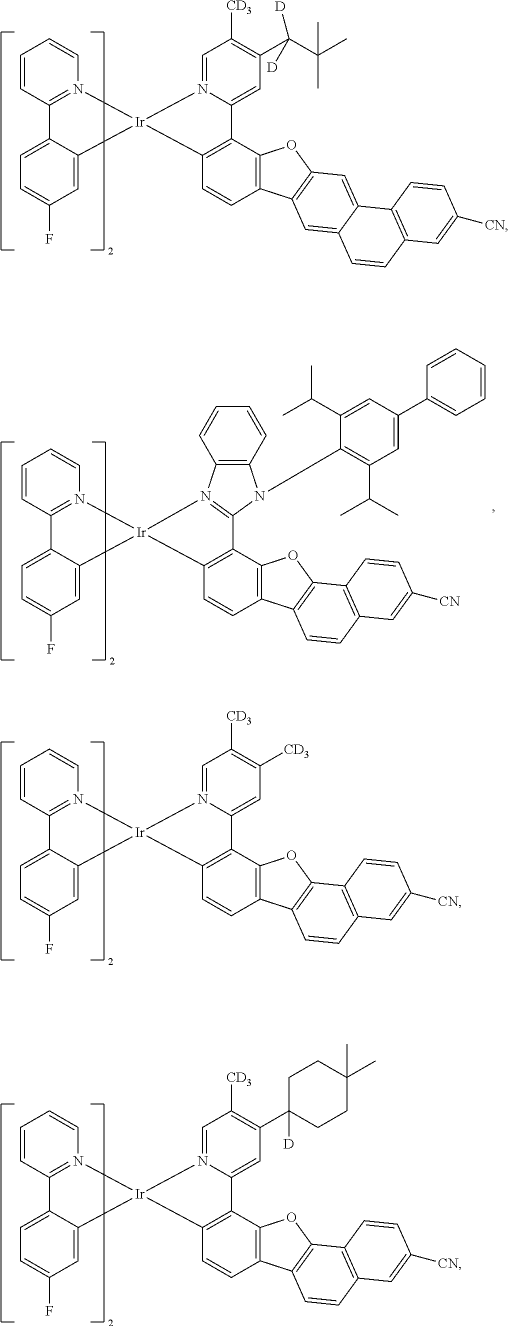

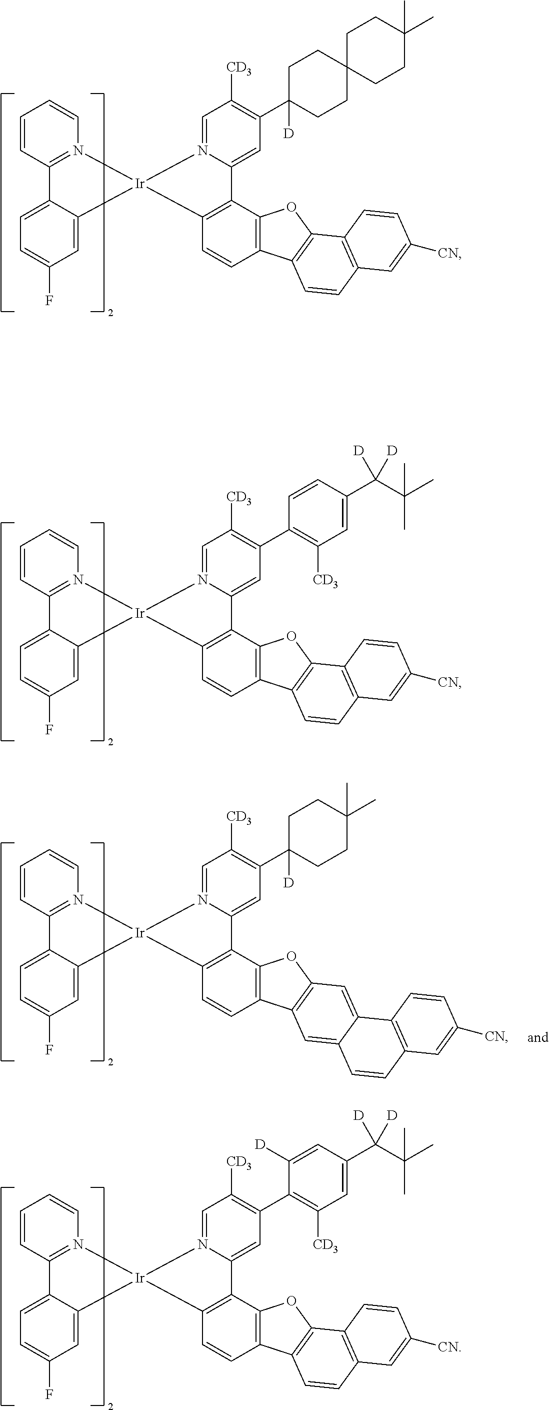

In some embodiments, the compound E1 capable of functioning as an emitter can be at least 30% deuterated, at least 40% deuterated, at least 50% deuterated, at least 60% deuterated, at least 70% deuterated, at least 80% deuterated, at least 90% deuterated, at least 95% deuterated, at least 99% deuterated, or 100% deuterated. As used herein, percent deuteration has its ordinary meaning and includes the percent of all possible hydrogen atoms in the compound (e.g., positions that are hydrogen or deuterium) that are occupied by deuterium atoms. In some embodiments, carbon atoms comprised the ring coordinated to the metal M are fully or partially deuterated. In some embodiments, carbon atoms comprised by a polycyclic ring system coordinated to the metal M are fully or partially deuterated. In some embodiments, a substituent attached to a monocyclic or fused polycyclic ring system coordinated to the metal M is fully or partially deuterated.

In some embodiments, the compound of formula I has an emission at room temperature with a full width at half maximum (FWHM) of equal to or less than 50, 45, 40, 35, 30, 25, 20, 15, 10, or 5 nm. Narrower FWHM means better color purity for the OLED display application.

In some embodiments of heteroleptic compound having the formula of M(L_{A})ₚ(L_{B})_{q}(L_{C})ᵣ as defined above, the ligand L_{A} has a first substituent R^{I}, where the first substituent R^{I} has a first atom a-I that is the farthest away from the metal M among all atoms in the ligand L_{A}. Additionally, the ligand L_{B}, if present, has a second substituent R^{II}, where the second substituent R^{II} has a first atom a-II that is the farthest away from the metal M among all atoms in the ligand L_{B}. Furthermore, the ligand L_{C}, if present, has a third substituent R^{III}, where the third substituent R^{III} has a first atom a-III that is the farthest away from the metal M among all atoms in the ligand L_{C}.

In such heteroleptic compounds, vectors V_{D1}, V_{D2}, and V_{D3} can be defined that are defined as follows. V_{D1} represents the direction from the metal M to the first atom a-I and the vector V_{D1} has a value D¹ that represents the straight line distance between the metal M and the first atom a-I in the first substituent R^{I}. V_{D2} represents the direction from the metal M to the first atom a-II and the vector V_{D2} has a value D² that represents the straight line distance between the metal M and the first atom a-II in the second substituent R¹. V_{D3} represents the direction from the metal M to the first atom a-III and the vector V_{D3} has a value D³ that represents the straight line distance between the metal M and the first atom a-III in the third substituent R^{III}.

In such heteroleptic compounds, a sphere having a radius r is defined whose center is the metal M and the radius r is the smallest radius that will allow the sphere to enclose all atoms in the compound that are not part of the substituents R^{I}, R^{II} and R^{III}; and where at least one of D¹, D², and D³ is greater than the radius r by at least 1.5 Å. In some embodiments, at least one of D¹, D², and D³ is greater than the radius r by at least 2.9, 3.0, 4.3, 4.4, 5.2, 5.9, 7.3, 8.8, 10.3, 13.1, 17.6, or 19.1 Å. In some embodiments, at least two of D¹, D², and D³ is greater than the radius r by at least 1.5, 2.9, 3.0, 4.3, 4.4, 5.2, 5.9, 7.3, 8.8, 10.3, 13.1, 17.6, or 19.1 Å.

In some embodiments of such heteroleptic compound, the compound has a transition dipole moment axis and angles are defined between the transition dipole moment axis and the vectors V_{D1}, V_{D2}, and V_{D3}, where at least one of the angles between the transition dipole moment axis and the vectors V_{D1}, V_{D2}, and V_{D3} is less than 40°. In some embodiments, at least one of the angles between the transition dipole moment axis and the vectors V_{D1}, V_{D2}, and V_{D3} is less than 30°, 20°, 15°, or 10°. In some embodiments, at least two of the angles between the transition dipole moment axis and the vectors V_{D1}, V_{D2}, and V_{D3} are less than 20°. In some embodiments, at least two of the angles between the transition dipole moment axis and the vectors V_{D1}, V_{D2}, and V_{D3} are less than 15° or 10°.

In some embodiments, all three angles between the transition dipole moment axis and the vectors V_{D1}, V_{D2}, and V_{D3} are less than 20°. In some embodiments, all three angles between the transition dipole moment axis and the vectors V_{D1}, V_{D2}, and V_{D3} are less than 150 or 10°.

In some embodiments of such heteroleptic compounds, the compound has a vertical dipole ratio (VDR) of 0.33 or less. In some embodiments of such heteroleptic compounds, the compound has a VDR of 0.30, 0.25, 0.20, or 0.15 or less.

One of ordinary skill in the art would readily understand the meaning of the terms transition dipole moment axis of a compound and vertical dipole ratio of a compound. Nevertheless, the meaning of these terms can be found in U.S. Pat. No. 10,672,997 whose disclosure is incorporated herein by reference in its entirety. In U.S. Pat. No. 10,672,997, horizontal dipole ratio (HDR) of a compound, rather than VDR, is discussed. However, one skilled in the art readily understands that VDR=1−HDR.

VDR is the ensemble average fraction of vertically oriented molecular dipoles of the light-emitting compound in a thin film sample of an emissive layer, where the orientation “vertical” is relative to the plane of the surface of the substrate (i.e., normal to the surface of the substrate plane) on which the thin film sample is formed. A similar concept is horizontal dipole ratio (HDR) which is the ensemble average fraction of horizontally oriented molecular dipoles of the light-emitting compound in a thin film sample of an emissive layer, where the orientation “horizontal” is relative to the plane of the surface of the substrate (i.e. parallel to the surface of the substrate plane) on which the thin film sample is formed. By definition, VDR+HDR=1. VDR can be measured by angle dependent, polarization dependent, photoluminescence measurements. By comparing the measured emission pattern of a photo-excited thin film test sample, as a function of polarization, to the computationally modeled pattern, one can determine VDR of the thin film test sample emission layer. For example, a modelled data of p-polarized emission is shown in FIG. 3. The modelled p-polarized angle photoluminescence (PL) is plotted for emitters with different VDRs. A peak in the modelled PL is observed in the p-polarized PL around the angle of 45 degrees with the peak PL being greater when the VDR of the emitter is higher.

In the example used to generate FIG. 3, a 30 nm thick film of material with a refractive index of 1.75 and the emission is monitored in a semi-infinite medium with a refractive index of 1.75. Each curve is normalized to a photoluminescence intensity of 1 at an angle of zero degrees, which is perpendicular to the surface of the film. As the VDR of the emitter is varied, the peak around 45 degrees increases greatly. When using a software to fit the VDR of experimental data, the modeled VDR would be varied until the difference between the modeled data and the experimental data is minimized.

Because the VDR represents the average dipole orientation of the light-emitting compound in the thin film sample, even if there are additional emission capable compounds in the emissive layer, if they are not contributing to the light emission, the VDR measurement does not reflect their VDR. Further, by inclusion of a host material that interacts with the light-emitting compound, the VDR of the light-emitting compound can be modified. Thus, a light-emitting compound in a thin film sample with host material A will exhibit one measured VDR value and that same light-emitting compound in a thin film sample with host material B will exhibit a different measured VDR value. Further, in some embodiments, exciplex or excimers are desirable which form emissive states between two neighboring molecules. These emissive states may have a VDR that is different than that if only one of the components of the exciplex or excimer were emitting or present in the sample.

In some embodiments, the compound can be an emissive dopant. In some embodiments, the compound can produce emissions via phosphorescence, fluorescence, thermally activated delayed fluorescence, triplet-triplet annihilation, or combinations of these processes. In some embodiments, the emissive dopant can be a racemic mixture, or can be enriched in one enantiomer. In some embodiments, the present compounds can have different stereoisomers, such as fac and mer. The current compound relates both to individual isomers and to mixtures of various isomers in any mixing ratio. In some embodiments, the compound can be homoleptic (each ligand is the same). In some embodiments, the compound can be heteroleptic (at least one ligand is different from others). When there are more than one ligand coordinated to a metal, the ligands can all be the same in some embodiments. In some other embodiments, at least one ligand is different from the other ligands. In some embodiments, every ligand can be different from every other ligand. This is also true in embodiments where a ligand being coordinated to a metal can be linked with other ligands being coordinated to that metal to form a tridentate, tetradentate, pentadentate, or hexadentate ligands. Thus, where the coordinating ligands are being linked together, all of the ligands can be the same in some embodiments, and at least one of the ligands being linked can be different from the other ligand(s) in some other embodiments.

In yet another aspect of the present disclosure, a formulation that comprises the novel compound disclosed herein is described. The formulation can include one or more components selected from the group consisting of a solvent, an emitter, a host, a hole injection material, hole transport material, electron blocking material, hole blocking material, and an electron transport material, disclosed herein.

The present disclosure encompasses any chemical structure comprising the novel compound of the present disclosure, or a monovalent or polyvalent variant thereof. In other words, the inventive compound, or a monovalent or polyvalent variant thereof, can be a part of a larger chemical structure. Such chemical structure can be selected from the group consisting of a monomer, a polymer, a macromolecule, and a supramolecule (also known as supermolecule). As used herein, a “monovalent variant of a compound” refers to a moiety that is identical to the compound except that one hydrogen has been removed and replaced with a bond to the rest of the chemical structure. As used herein, a “polyvalent variant of a compound” refers to a moiety that is identical to the compound except that more than one hydrogen has been removed and replaced with a bond or bonds to the rest of the chemical structure. In the instance of a supramolecule, the inventive compound can also be incorporated into the supramolecule complex without covalent bonds. As used in this context, the description that a structure A comprises a moiety B means that the structure A includes the structure of moiety B not including the H or D atoms that can be attached to the moiety B. This is because at least one H or D on a given moiety structure has to be replaced to become a substituent so that the moiety B can be part of the structure A, and one or more of the H or D on a given moiety B structure can be further substituted once it becomes a part of structure A.

### C. The OLEDs and the Devices of the Present Disclosure

In another aspect, the present disclosure also provides an OLED device comprising a first organic layer that contains a compound as disclosed in the above compounds section of the present disclosure.

In some embodiments, the OLED comprises: an anode; a cathode; and an organic layer disposed between the anode and the cathode, where the organic layer comprises a compound E1 or E1′ as described herein.

In some embodiments, the organic layer is selected from the group consisting of HIL, HTL, EBL, EML, HBL, ETL, and EIL. In some embodiments, the organic layer may be an emissive layer and the compound as described herein may be an emissive dopant or a non-emissive dopant.

In some embodiments, the organic layer may further comprise a host, wherein host comprises at least one chemical group selected from the group consisting of triphenylene, carbazole, indolocarbazole, dibenzothiophene, dibenzofuran, dibenzoselenophene, 5λ²-benzo[d]benzo[4,5]imidazo[3,2-a]imidazole, 5,9-dioxa-13b-boranaphtho[3,2,1-de]anthracene, azaborinine, oxaborinine, dihydroacridine, xanthene, dihydrobenzoazasiline, dibenzooxasiline, phenoxazine, phenoxathiine, phenothiazine, dihydrophenazine, fluorene, naphthalene, anthracene, phenanthrene, phenanthroline, benzoquinoline, quinoline, isoquinoline, quinazoline, pyrimidine, pyrazine, pyridine, triazine, boryl, silyl, aza-triphenylene, aza-carbazole, aza-indolocarbazole, aza-dibenzothiophene, aza-dibenzofuran, aza-dibenzoselenophene, aza-5λ²-benzo[d]benzo[4,5]imidazo[3,2-a]imidazole, and aza-(5,9-dioxa-13b-boranaphtho[3,2,1-de]anthracene).

In some embodiments, the host can be selected from the group consisting of the structures of the following HOST Group 1:

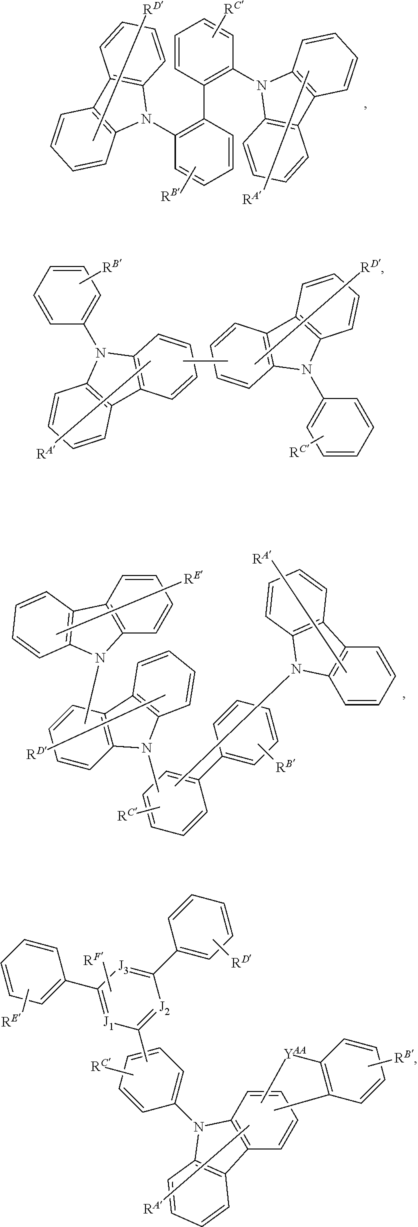

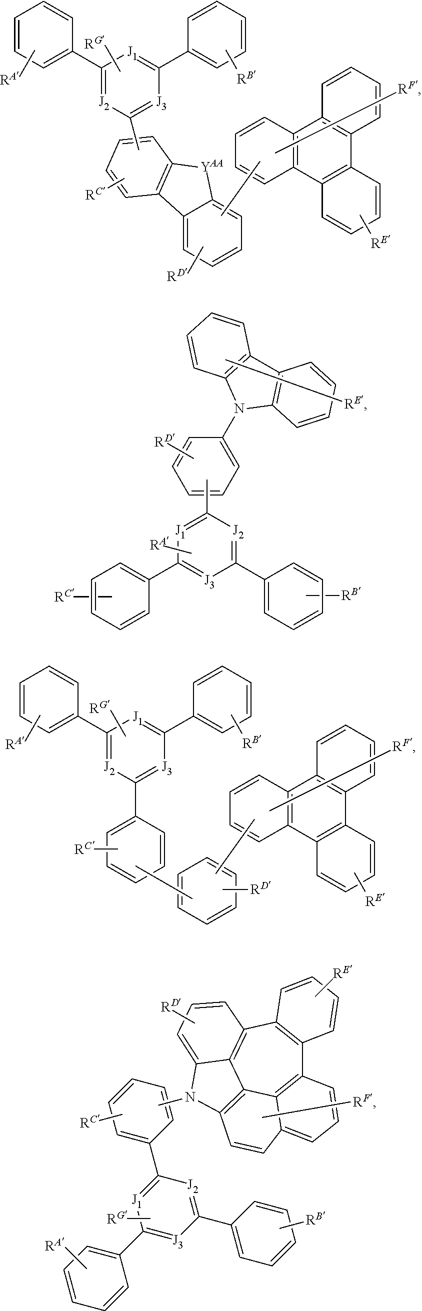

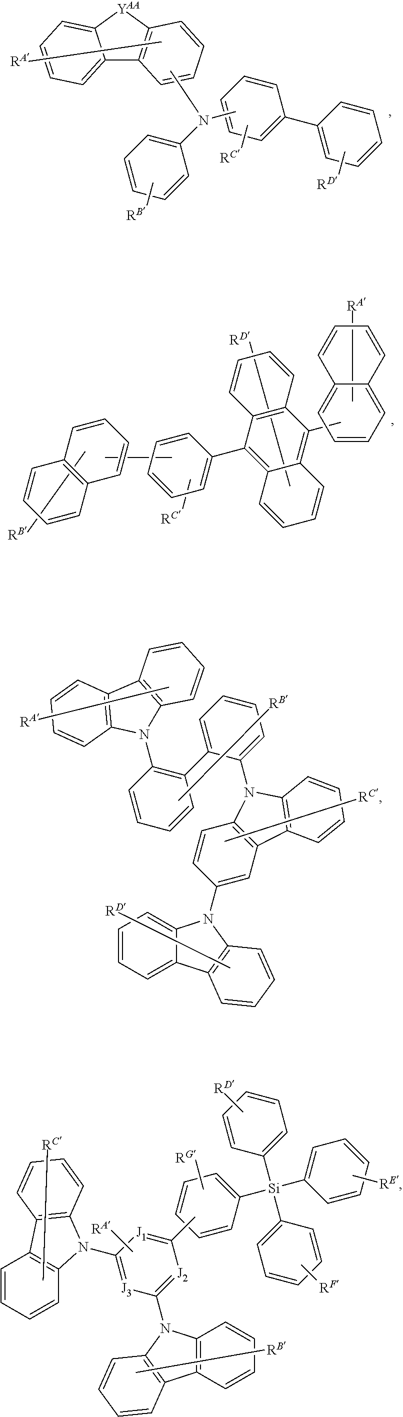

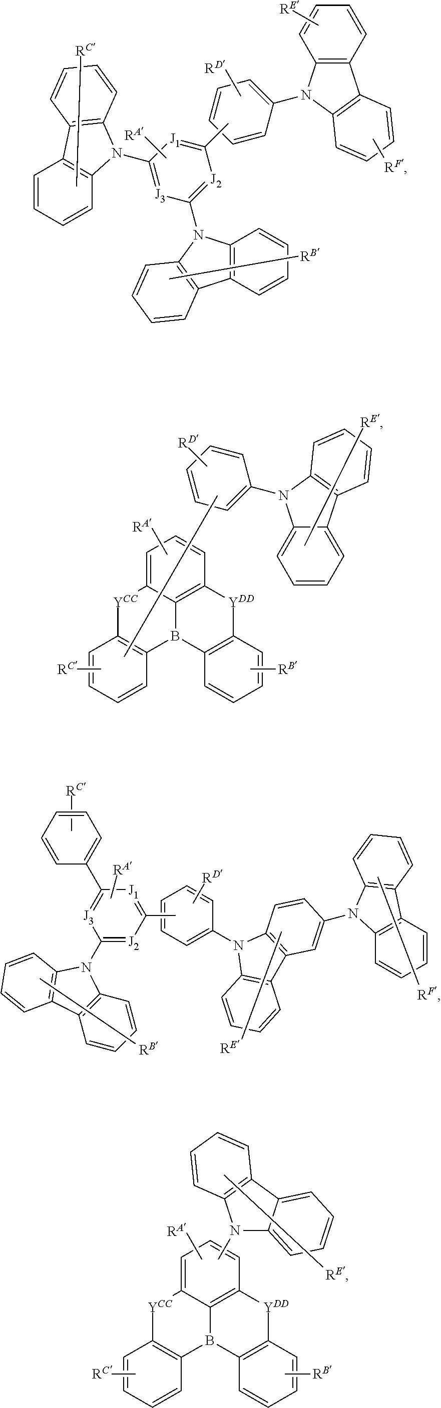

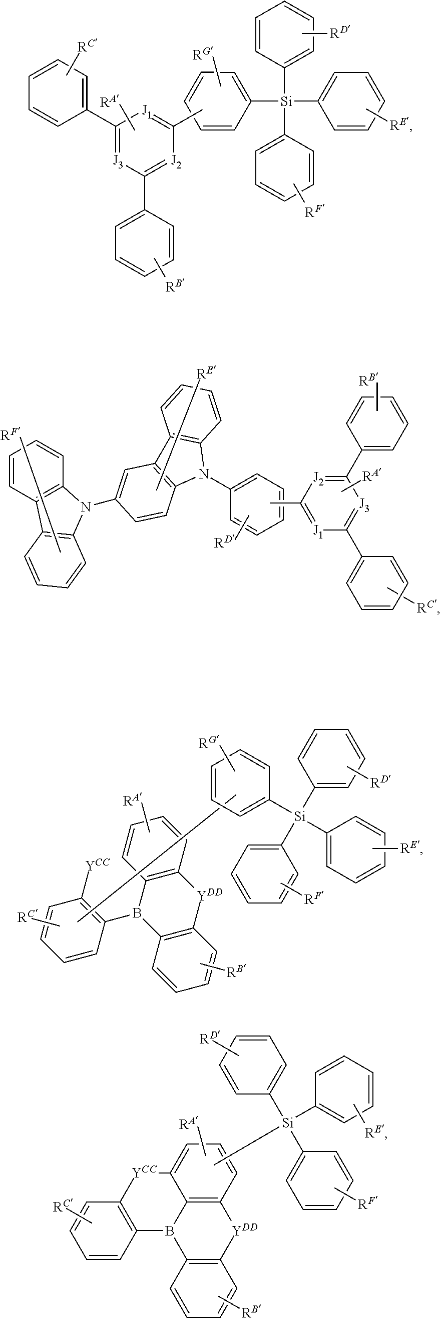

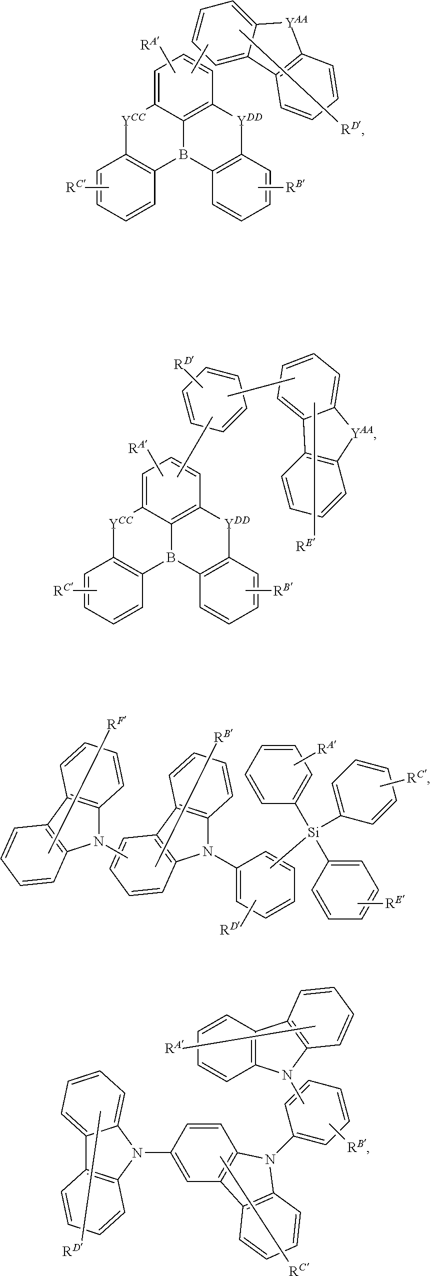

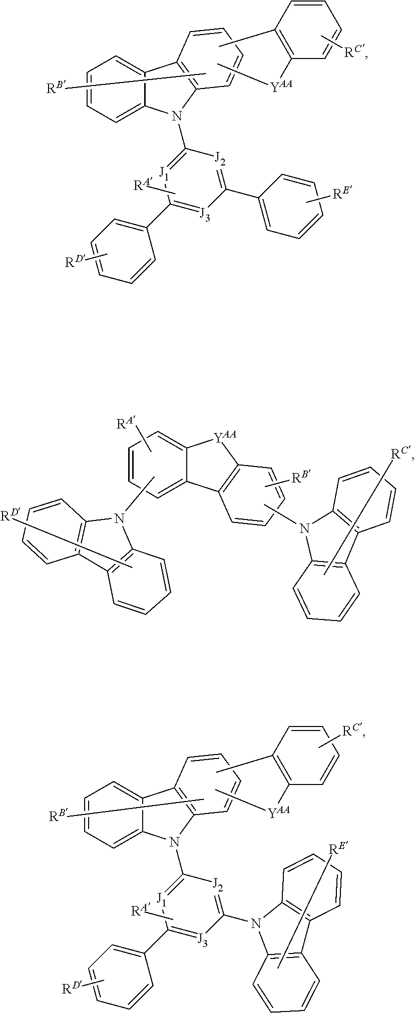

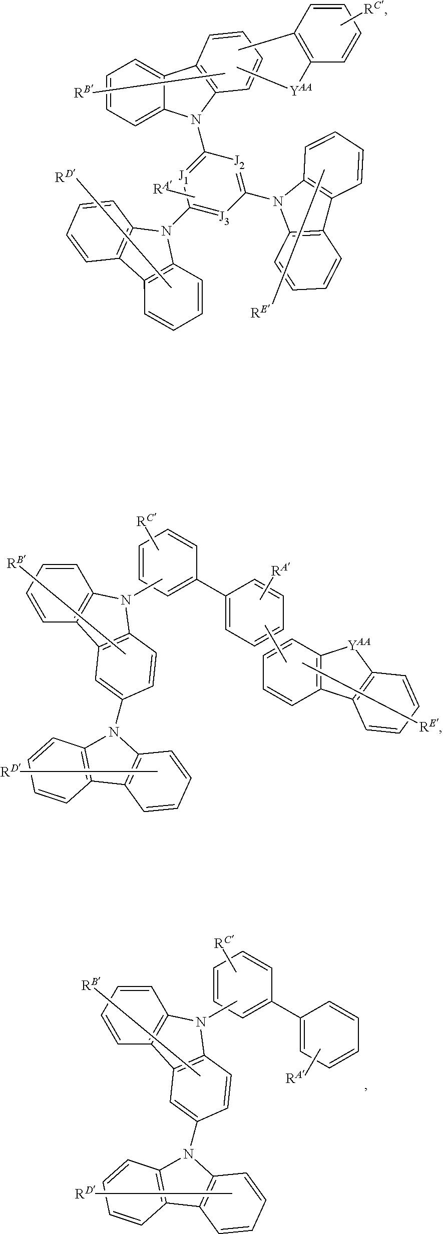

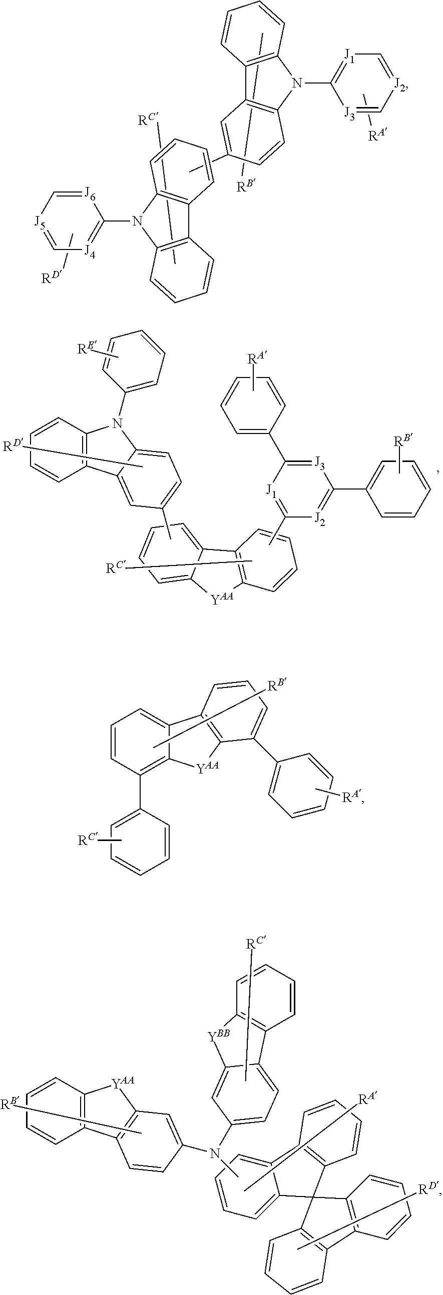

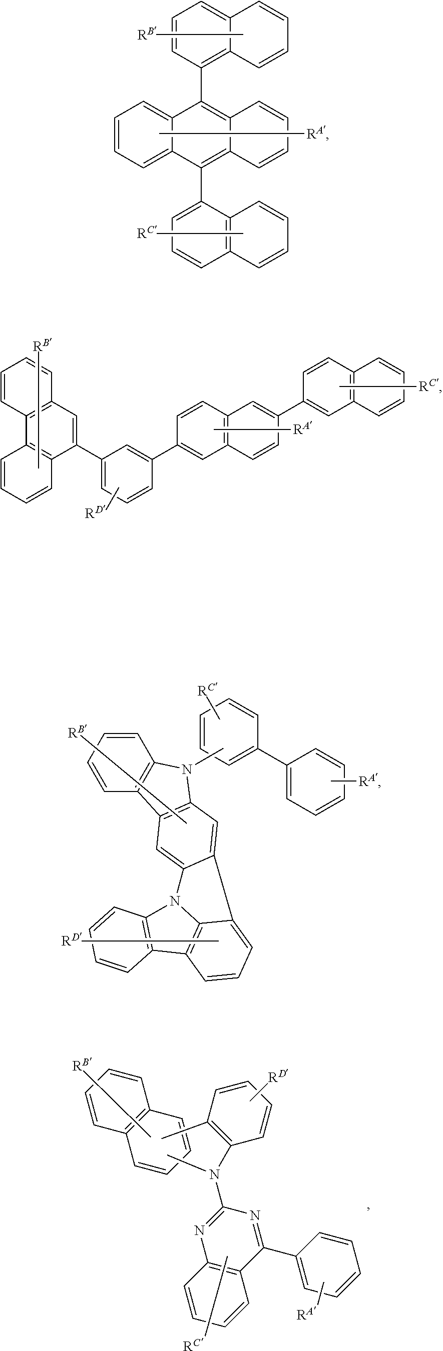

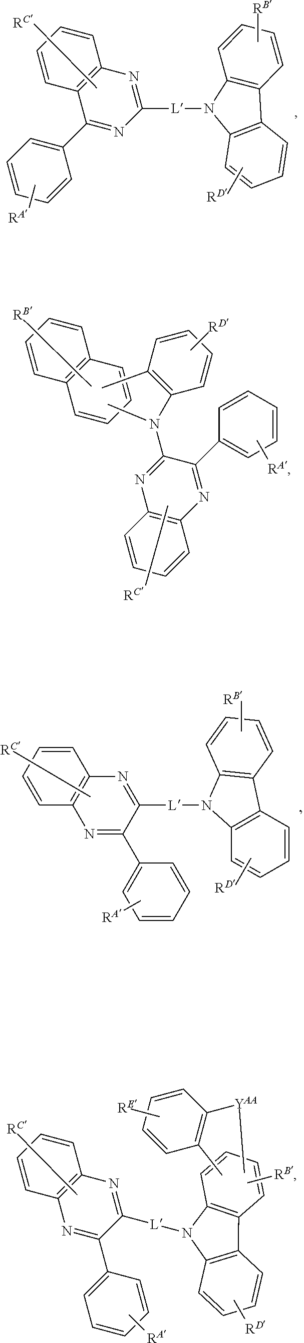

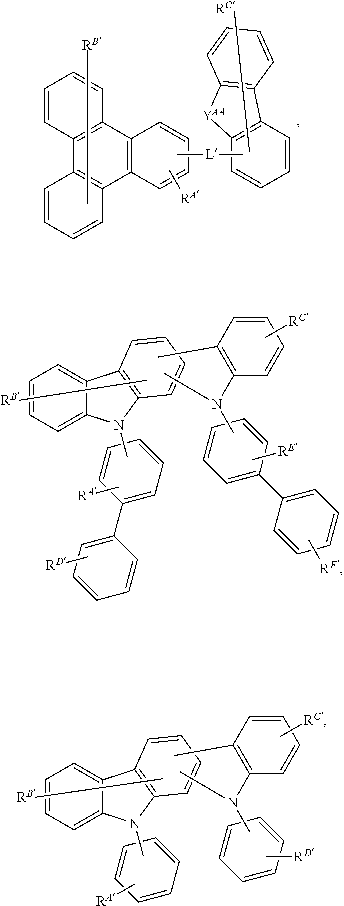

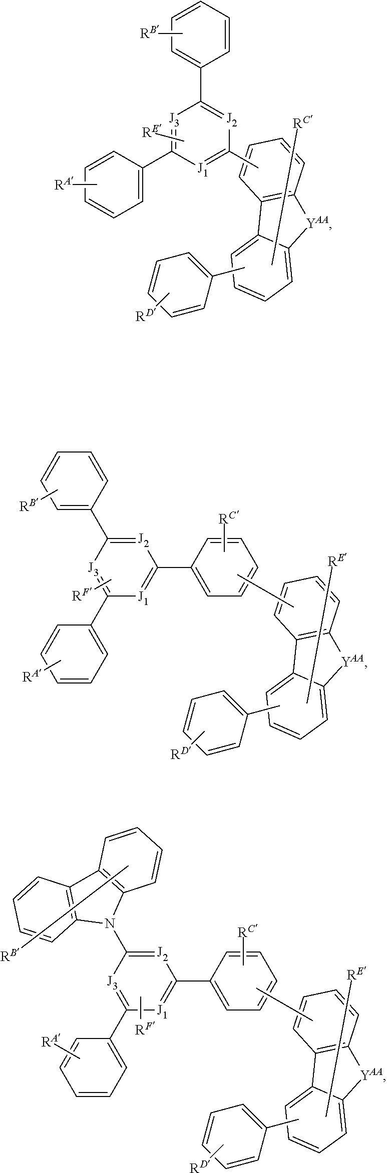

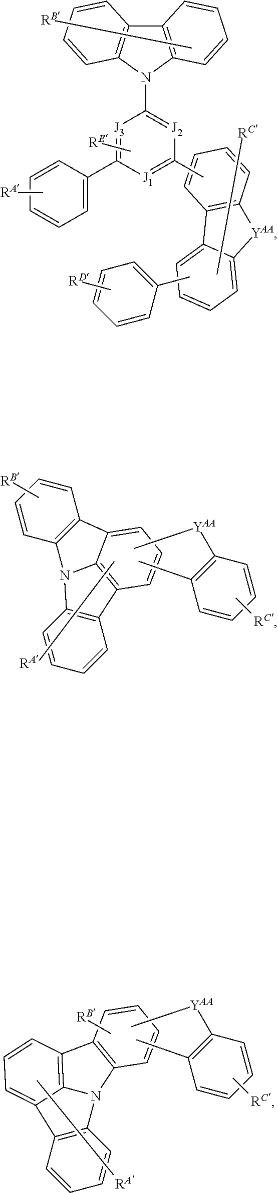

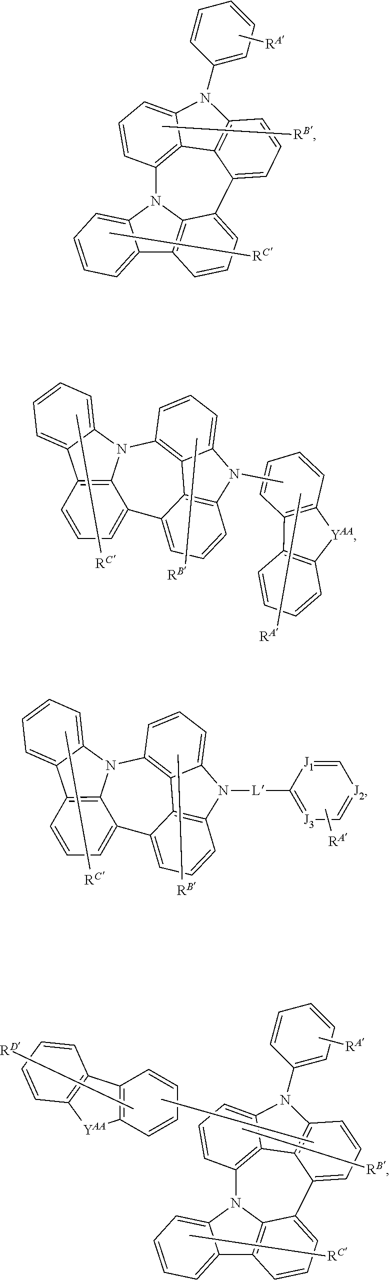

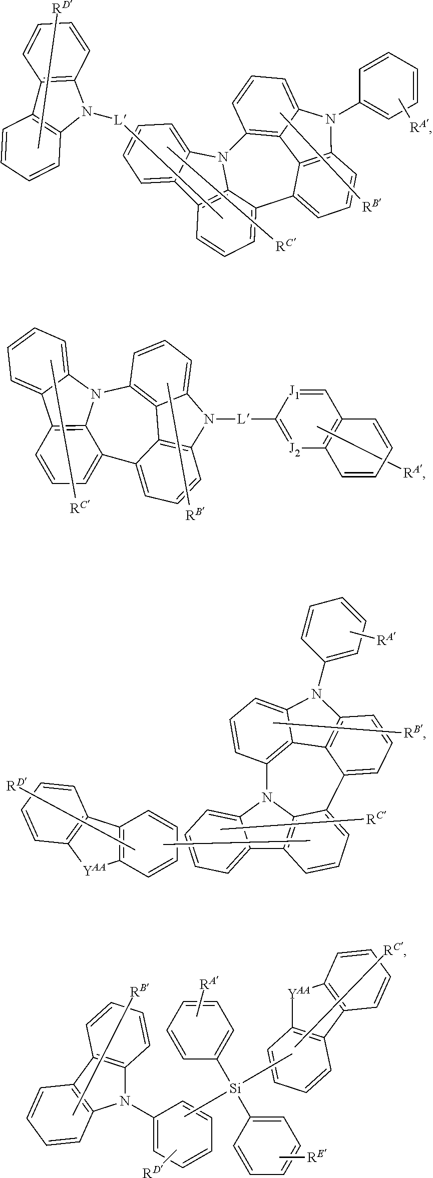

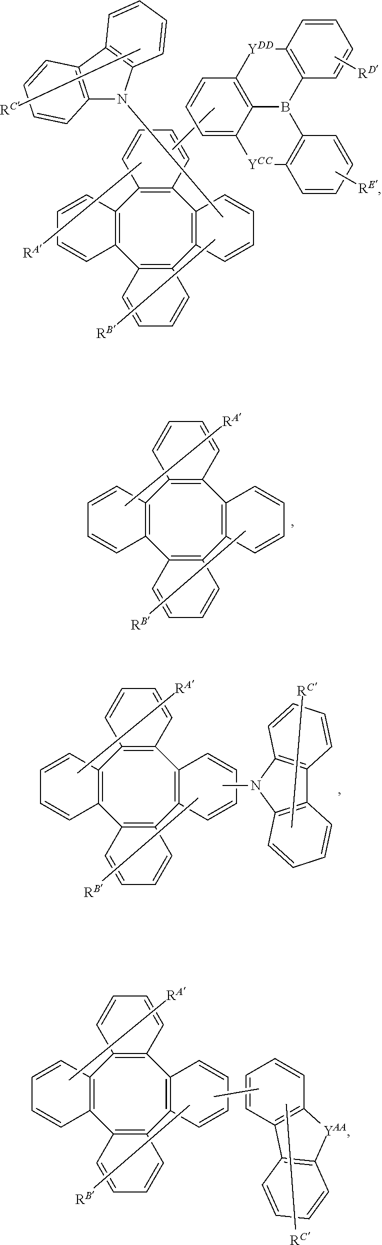

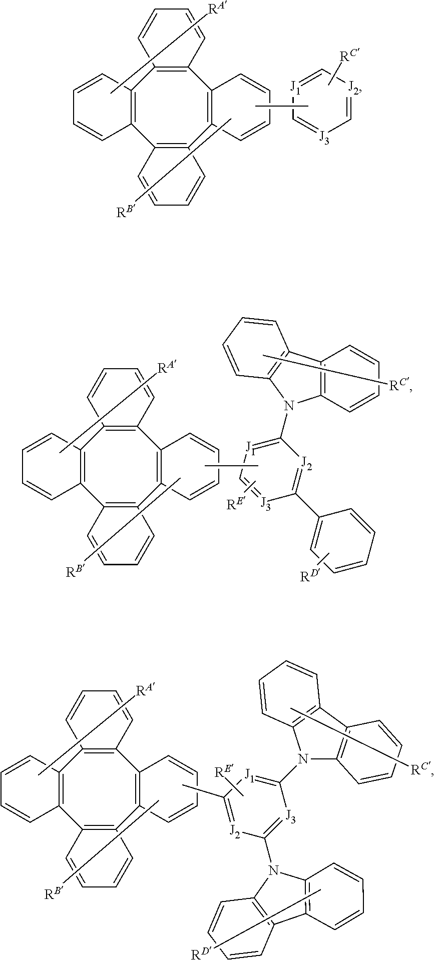

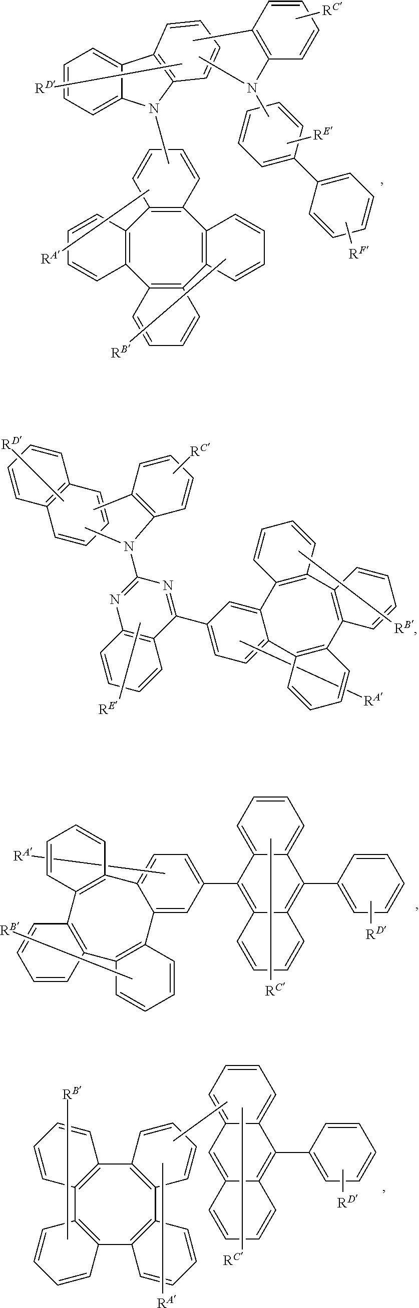

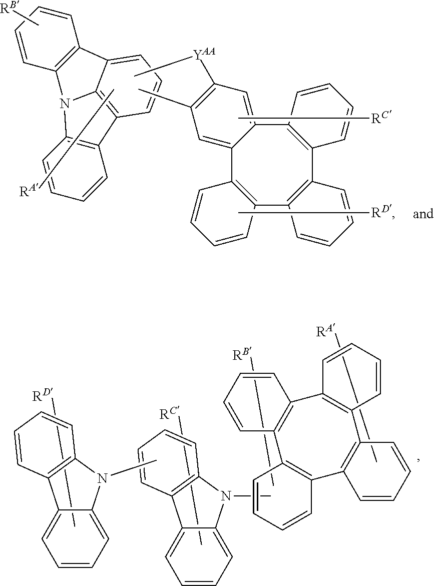

wherein:
each of J₁ to J₆ is independently C or N;
L′ is a direct bond or an organic linker;
each Y^{AA}, Y^{BB}, Y^{CC} and Y^{DD} is independently selected from the group consisting of absent a bond, direct bond, O, S, Se, CRR′, SiRR′, GeRR′, NR, BR, BRR′;
each of R^{A′}, R^{B′}, R^{C′}, R^{D′}, R^{E′}, R^{F′}, and R^{G′} independently represents mono, up to the maximum substitutions, or no substitutions;
each R, R′, R^{A′}, R^{B′}, R^{C′}, R^{D′}, R^{E′}, R^{F′}, and R^{G′} is independently a hydrogen or a substituent selected from the group consisting of the General Substituents as defined herein; any two substituents can be joined or fused to form a ring; and where possible, each unsubstituted aromatic carbon atom is optionally replaced with N to form an aza-substituted ring.

In some embodiments at least one of J₁ to J₃ is N. In some embodiments at least two of J₁ to J₃ are N. In some embodiments, all three of J₁ to J₃ are N. In some embodiments, each Y^{CC} and Y^{DD} is independently O, S, or SiRR′, or more preferably O or S. In some embodiments, at least one unsubstituted aromatic carbon atom is replaced with N to form an aza-ring.

In some embodiments, the host is selected from the group consisting of EG1-MG1-EG1 to EG53-MG27-EG53 with a formula of EGa-MGb-EGc, or EG1-EG1 to EG53-EG53 with a formula of EGa-EGc when MGb is absent, wherein a is an integer from 1 to 53, b is an integer from 1 to 27, c is an integer from 1 to 53. The structure of EG1 to EG53 is shown below:

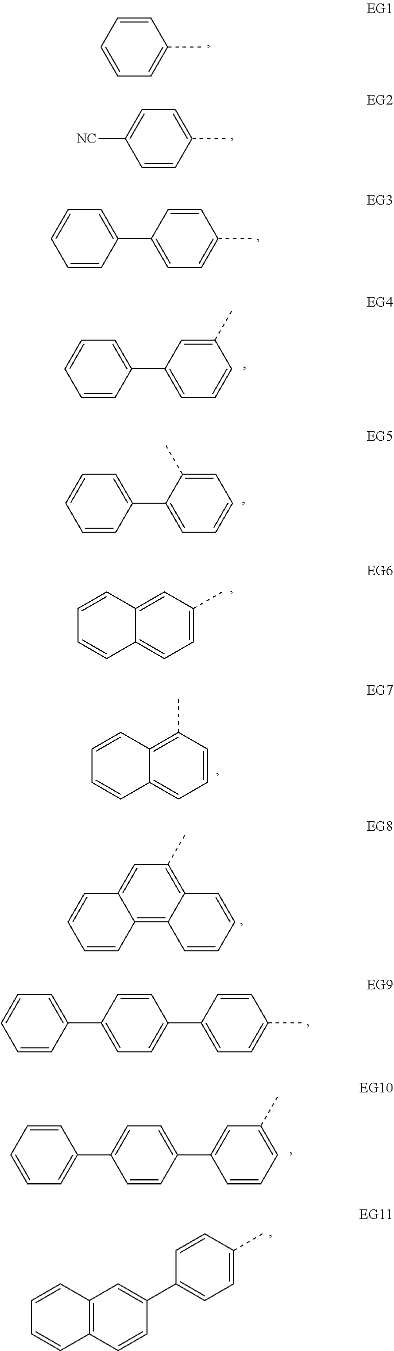

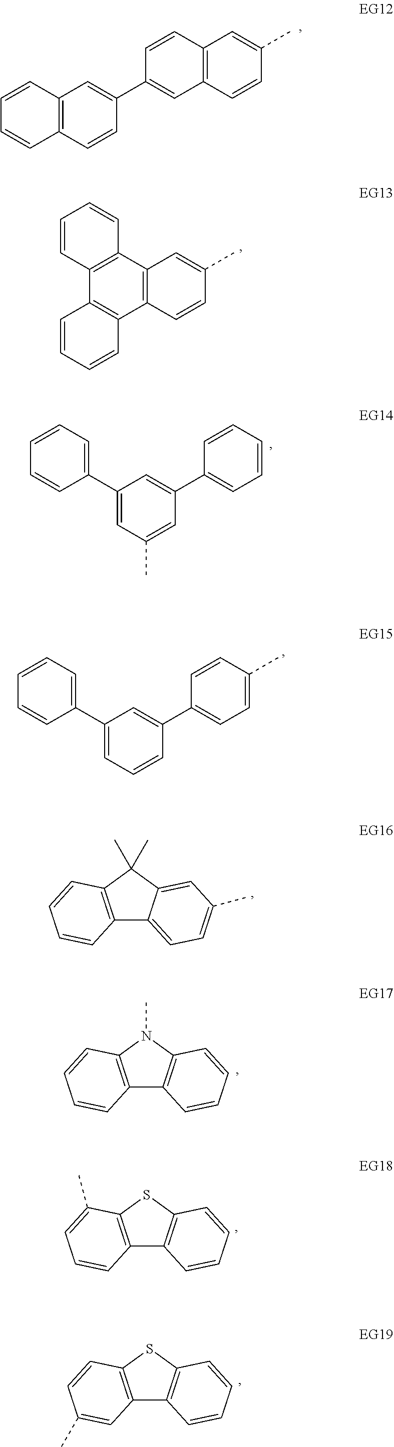

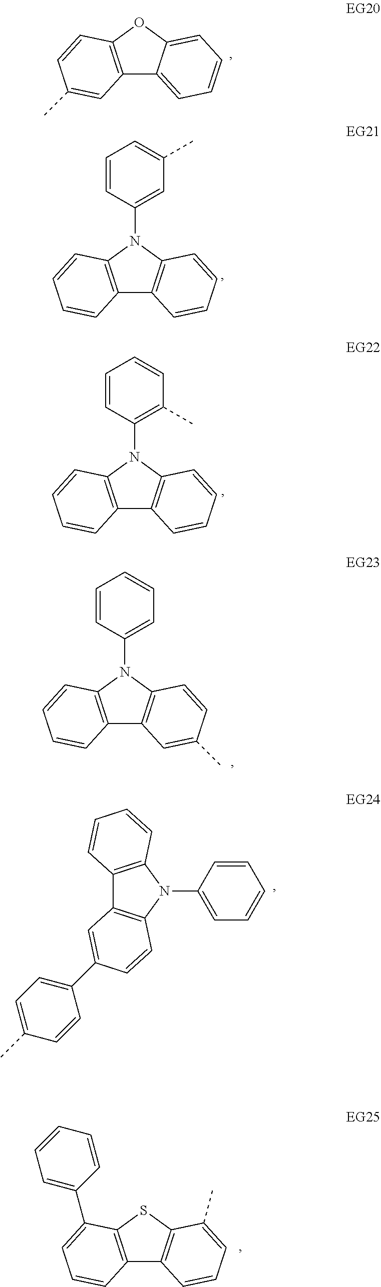

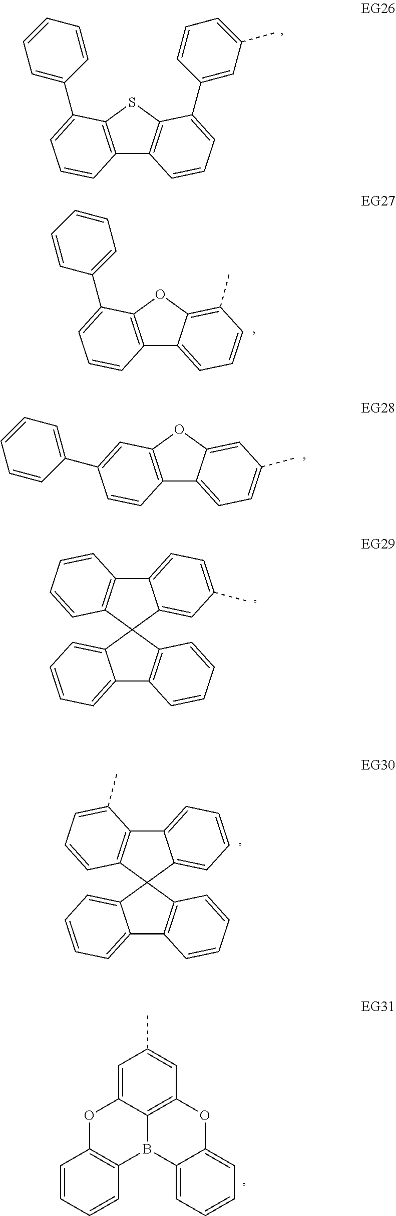

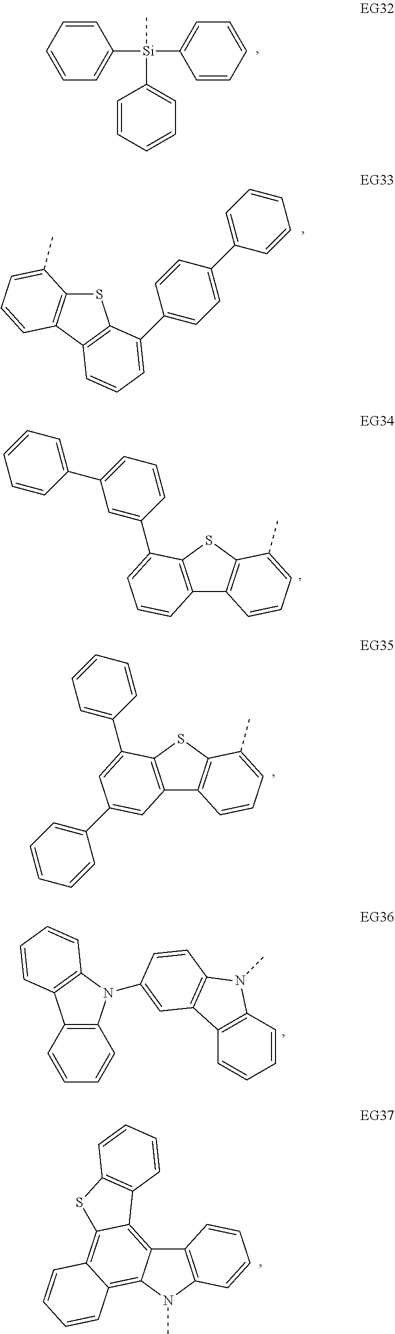

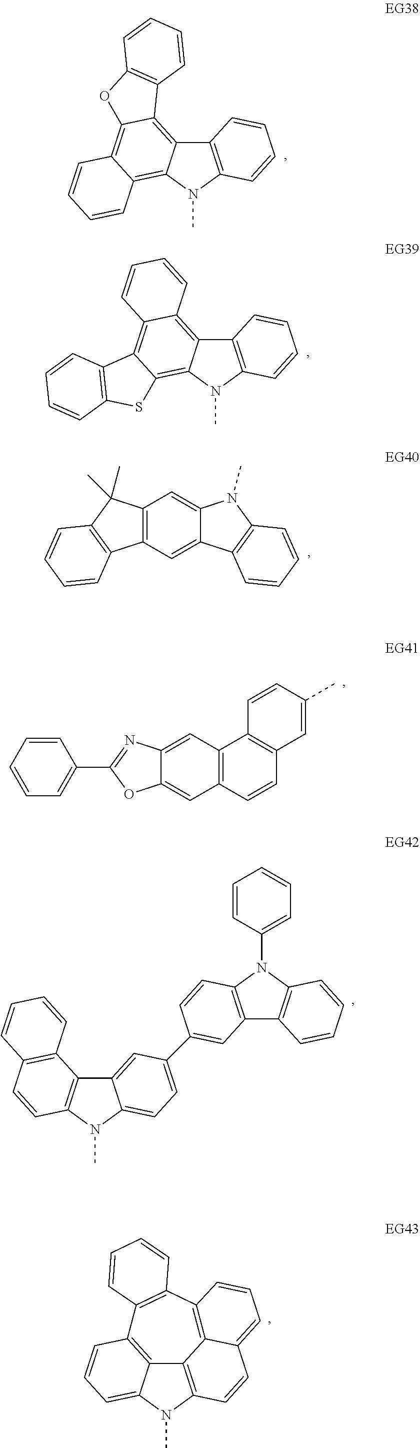

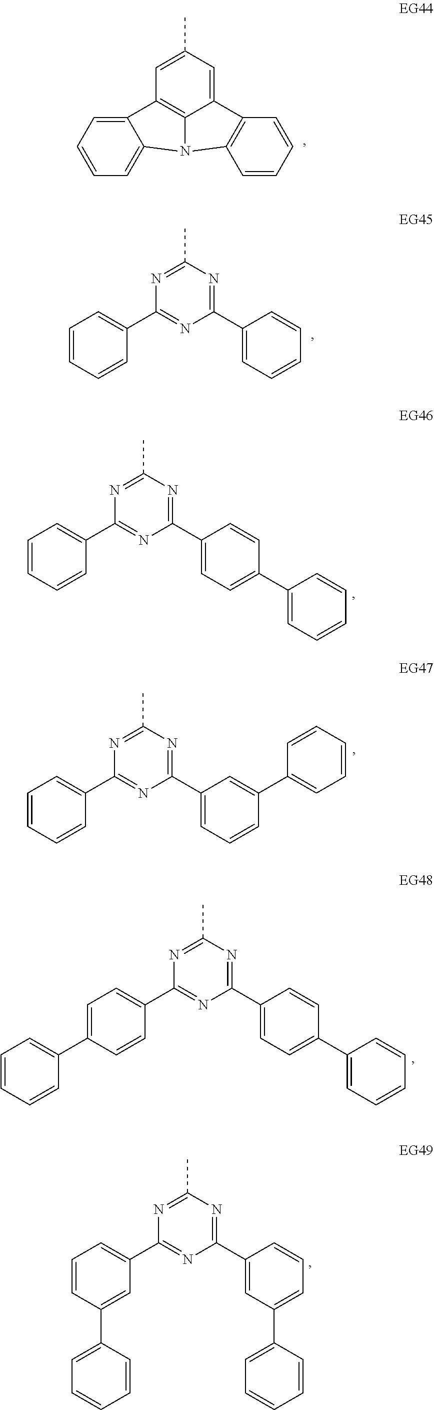

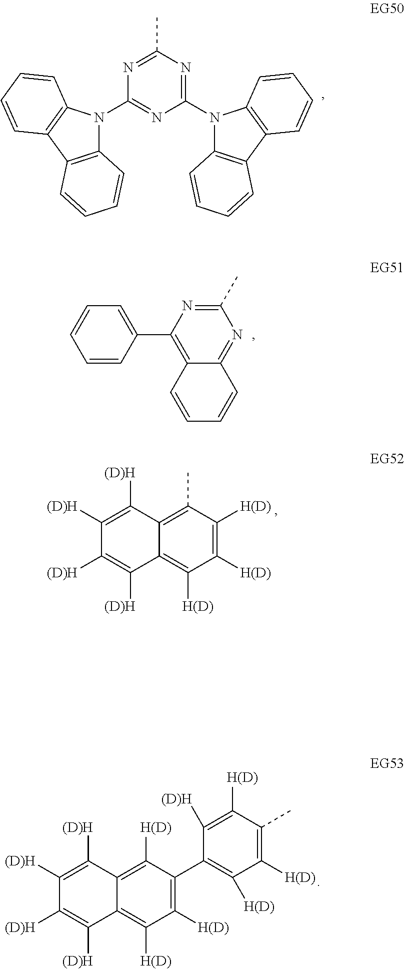

The structures of MG1 to MG27 are shown below:

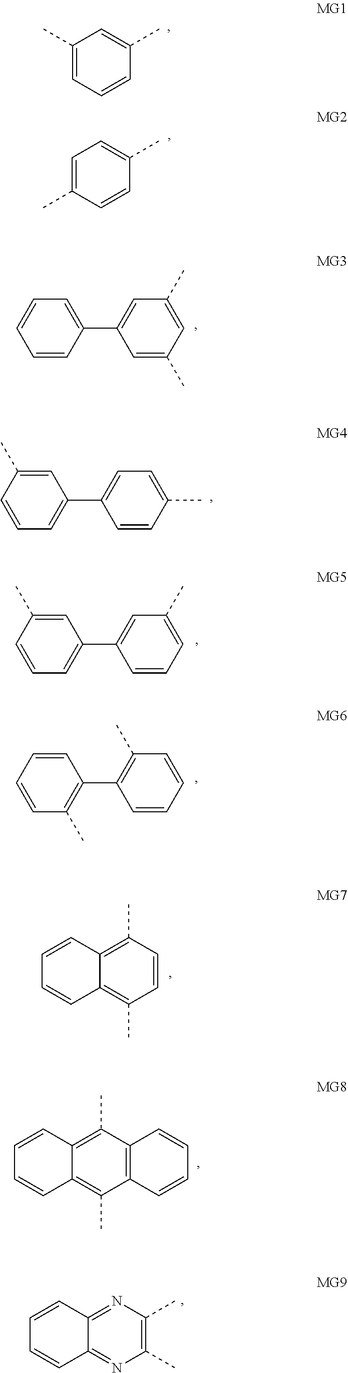

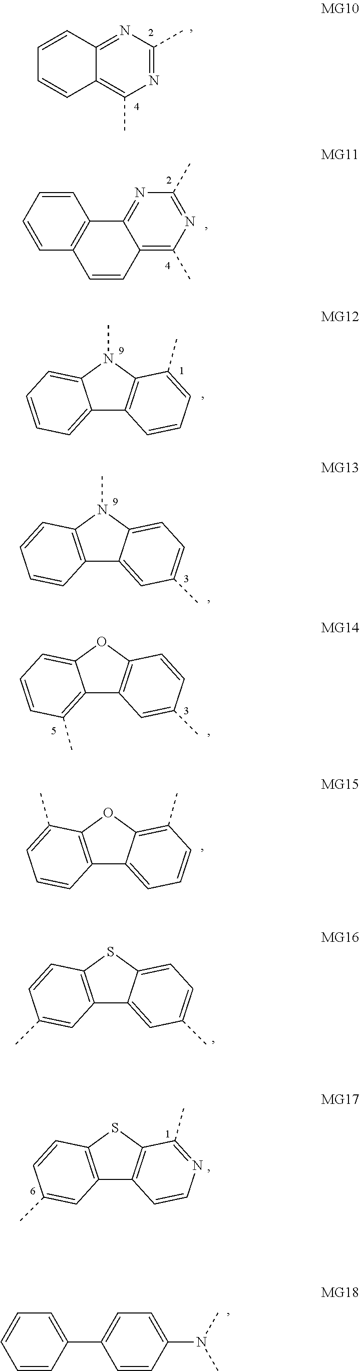

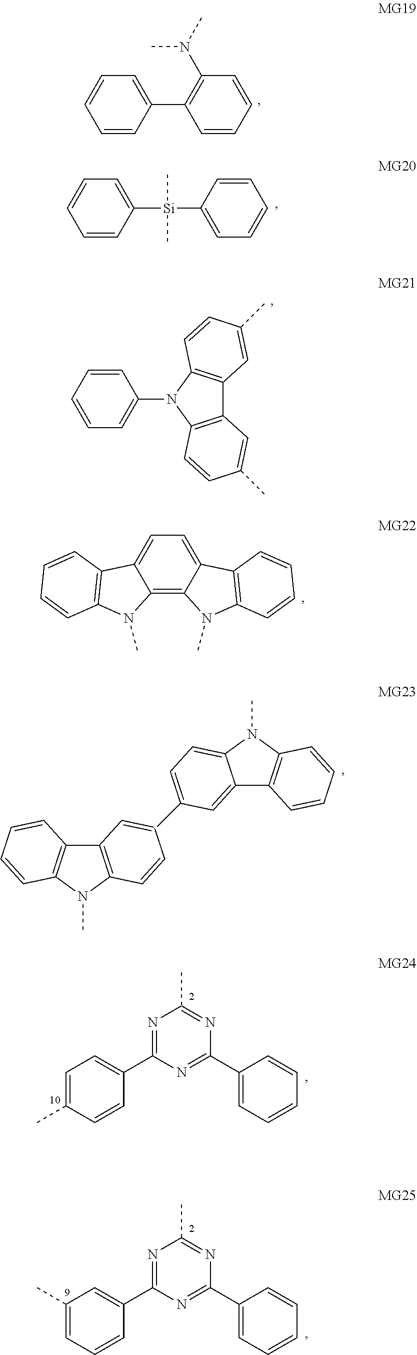

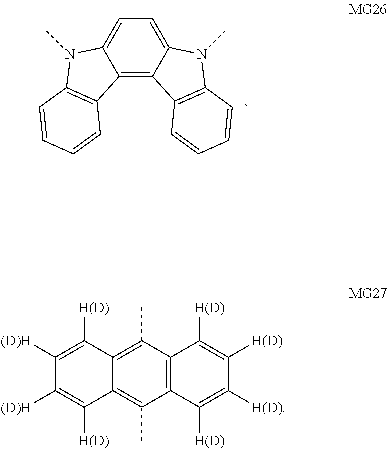

In the MGb structures shown above, the two bonding positions in the asymmetric structures MG10, MG11, MG12, MG13, MG14, MG17, MG24, and MG25 are labeled with numbers for identification purposes.

In some embodiments, the host can be any of the aza-substituted variants thereof, fully or partially deuterated variants thereof, and combinations thereof. In some embodiments, the host has formula EGa-MGb-Egc and is selected from the group consisting of h1 to h112 defined in the following HOST Group 2 list, where each of MGb, EGa, and EGc are defined as follows:

| h | MGb | EGα | EGc | h | MGb | EGα | EGc | h | MGb | EGα | EGc |
|---|---|---|---|---|---|---|---|---|---|---|---|
| h1 | MG1 | EG3 | EG36 | h39 | MG13 | 3-EG17 | 9-EG4 | h77 | MG23 | EG3 | EG4 |
| h2 | MG1 | EG8 | EG12 | h40 | MG13 | 3-EG17 | 9-EG13 | h78 | MG23 | EG3 | EG5 |
| h3 | MG1 | EG13 | EG14 | h41 | MG13 | 3-EG17 | 9-EG31 | h79 | MG23 | EG4 | EG4 |
| h4 | MG1 | EG13 | EG18 | h42 | MG13 | 3-EG17 | 9-EG45 | h80 | MG23 | EG4 | EG5 |
| h5 | MG1 | EG13 | EG25 | h43 | MG13 | 3-EG17 | 9-EG46 | h81 | MG24 | 2-EG1 | 10-EG33 |
| h6 | MG1 | EG13 | EG36 | h44 | MG13 | 3-EG17 | 9-EG48 | h82 | MG24 | 2-EG4 | 10-EG36 |
| h7 | MG1 | EG22 | EG36 | h45 | MG13 | 3-EG17 | 9-EG49 | h83 | MG24 | 2-EG21 | 10-EG36 |
| h8 | MG1 | EG25 | EG46 | h46 | MG13 | 3-EG32 | 9-EG31 | h84 | MG24 | 2-EG23 | 10-EG36 |
| h9 | MG1 | EG27 | EG46 | h47 | MG13 | 3-EG44 | 9-EG3 | h85 | MG25 | 2-EG1 | 9-EG33 |
| h10 | MG1 | EG27 | EG48 | h48 | MG14 | 3-EG13 | 5-EG45 | h86 | MG25 | 2-EG3 | 9-EG36 |
| h11 | MG1 | EG32 | EG50 | h49 | MG14 | 3-EG23 | 5-EG45 | h87 | MG25 | 2-EG4 | 9-EG36 |
| h12 | MG1 | EG35 | EG46 | h50 | MG15 | EG3 | EG48 | h88 | MG25 | 2-EG17 | 9-EG27 |
| h13 | MG1 | EG36 | EG45 | h51 | MG15 | EG17 | EG31 | h89 | MG25 | 2-EG17 | 9-EG36 |
| h14 | MG1 | EG36 | EG49 | h52 | MG15 | EG31 | EG36 | h90 | MG25 | 2-EG21 | 9-EG36 |
| h15 | MG1 | EG40 | EG45 | h53 | MG16 | EG17 | EG17 | h91 | MG25 | 2-EG23 | 9-EG27 |
| h16 | MG2 | EG3 | EG36 | h54 | MG17 | EG17 | EG17 | h92 | MG25 | 2-EG23 | 9-EG36 |
| h17 | MG2 | EG25 | EG31 | h55 | MG18 | EG16 | EG24 | h93 | MG26 | EG1 | EG9 |
| h18 | MG2 | EG31 | EG33 | h56 | MG18 | EG16 | EG30 | h94 | MG26 | EG1 | EG10 |
| h19 | MG2 | EG36 | EG45 | h57 | MG18 | EG20 | EG41 | h95 | MG26 | EG1 | EG21 |
| h20 | MG2 | EG36 | EG46 | h58 | MG19 | EG16 | EG29 | h96 | MG26 | EG1 | EG23 |
| h21 | MG3 | EG4 | EG36 | h59 | MG20 | EG1 | EG31 | h97 | MG26 | EG1 | EG26 |
| h22 | MG3 | EG34 | EG45 | h60 | MG20 | EG17 | EG18 | h98 | MG26 | EG3 | EG3 |
| h23 | MG4 | EG13 | EG17 | h61 | MG21 | EG23 | EG23 | h99 | MG26 | EG3 | EG9 |
| h24 | MG5 | EG13 | EG45 | h62 | MG22 | EG1 | EG45 | h100 | MG26 | EG3 | EG23 |
| h25 | MG5 | EG17 | EG36 | h63 | MG22 | EG1 | EG46 | h101 | MG26 | EG3 | EG26 |
| h26 | MG5 | EG18 | EG36 | h64 | MG22 | EG3 | EG46 | h102 | MG26 | EG4 | EG10 |
| h27 | MG6 | EG17 | EG17 | h65 | MG22 | EG4 | EG46 | h103 | MG26 | EG5 | EG10 |
| h28 | MG7 | EG43 | EG45 | h66 | MG22 | EG4 | EG47 | h104 | MG26 | EG6 | EG10 |
| h29 | MG8 | EG1 | EG28 | h67 | MG22 | EG9 | EG45 | h105 | MG26 | EG10 | EG10 |
| h30 | MG8 | EG6 | EG7 | h68 | MG23 | EG1 | EG3 | h106 | MG26 | EG10 | EG14 |
| h31 | MG8 | EG7 | EG7 | h69 | MG23 | EG1 | EG6 | h107 | MG26 | EG10 | EG15 |
| h32 | MG8 | EG7 | EG11 | h70 | MG23 | EG1 | EG14 | h108 | MG27 | EG52 | EG53 |
| h33 | MG9 | EG1 | EG43 | h71 | MG23 | EG1 | EG18 | h109 | — | EG13 | EG18 |
| h34 | MG10 | 4-EG1 | 2-EG37 | h72 | MG23 | EG1 | EG19 | h110 | — | EG17 | EG31 |
| h35 | MG10 | 4-EG1 | 2-EG38 | h73 | MG23 | EG1 | EG23 | h111 | — | EG17 | EG50 |
| h36 | MG10 | EG1 | EG42 | h74 | MG23 | EG1 | EG51 | h112 | — | EG40 | EG45 |
| h37 | MG11 | 4-EG1 | 2-EG39 | h75 | MG23 | EG2 | EG18 | | | | |
| h38 | MG12 | 1-EG17 | 9-EG31 | h76 | MG23 | EG3 | EG3 | | | | |

In the table above, the EGα and EGc structures that are bonded to one of the asymmetric structures MG10, MG11, MG12, MG13, MG14, MG17, MG24, and MG25, are noted with a numeric prefix identifying their bonding position in the MGb structure.

In some embodiments, the organic layer may further comprise a host, wherein the host comprises a metal complex.

In some embodiments, the emissive layer can comprise two hosts, a first host and a second host. In some embodiments, the first host is a hole transporting host, and the second host is an electron transporting host. In some embodiments, the first host is a hole transporting host, and the second host is a bipolar host. In some embodiments, the first host is an electron transporting host, and the second host is a bipolar host. In some embodiments, the first host and the second host can form an exciplex. In some embodiments, the emissive layer can comprise a third host. In some embodiments, the third host is selected from the group consisting of an insulating host (wide band gap host), a hole transporting host, and an electron transporting host. In some embodiments, the third host forms an exciplex with one of the first host and the second host, or with both the first host and the second host. In some embodiments, the emissive layer can comprise a fourth host. In some embodiments, the fourth host is selected from the group consisting of an insulating host (wide band gap host), a hole transporting host, and an electron transporting host. In some embodiments, the fourth host forms an exciplex with one of the first host, the second host, and the third host, with two of the first host, the second host, and the third host, or with each of the first host, the second host, and the third host. In some embodiments, the electron transporting host has a LUMO less than −2.4 eV, less than −2.5 eV, less than −2.6 eV, or less than −2.7 eV. In some embodiments, the hole transporting host has a HOMO higher than −5.6 eV, higher than −5.5 eV, higher than −5.4 eV, or higher than −5.35 eV. The HOMO and LUMO values can be determined using solution electrochemistry. Solution cyclic voltammetry and differential pulsed voltammetry can be performed using a CH Instruments model 6201B potentiostat using anhydrous dimethylformamide (DMF) solvent and tetrabutylammonium hexafluorophosphate as the supporting electrolyte. Glassy carbon, platinum wire, and silver wire were used as the working, counter and reference electrodes, respectively. Electrochemical potentials can be referenced to an internal ferrocene-ferroconium redox couple (Fc/Fc+) by measuring the peak potential differences from differential pulsed voltammetry. The corresponding highest occupied molecular orbital (HOMO) and lowest unoccupied molecular orbital (LUMO) energies can be determined by referencing the cationic and anionic redox potentials to ferrocene (4.8 eV vs. vacuum) according to literature ((a) Fink, R.; Heischkel, Y.; Thelakkat, M.; Schmidt, H.-W. Chem. Mater. 1998, 10, 3620-3625. (b) Pommerehne, J.; Vestweber, H.; Guss, W.; Mahrt, R. F.; Bassler, H.; Porsch, M.; Daub, J. Adv. Mater. 1995, 7, 551).

In some embodiments, the compound as described herein may be a sensitizer or a component of a sensitizer; wherein the device may further comprise an acceptor that receives the energy from the sensitizer. In some embodiments, the acceptor is an emitter in the device. In some embodiments, the acceptor may be a fluorescent material. In some embodiments, the compound described herein can be used as a phosphorescent sensitizer in an OLED where one or multiple layers in the OLED contain an acceptor in the form of one or more non-delayed fluorescent and/or delayed fluorescence material. In some embodiments, the compound described herein can be used as one component of an exciplex to be used as a sensitizer. As a phosphorescent sensitizer, the compound must be capable of energy transfer to the acceptor and the acceptor will emit the energy or further transfer energy to a final emitter. The acceptor concentrations can range from 0.001% to 99.9%. The acceptor could be in either the same layer as the phosphorescent sensitizer or in one or more different layers. In some embodiments, the acceptor is a thermally activated delayed fluorescence (TADF) material. In some embodiments, the acceptor is a non-delayed fluorescent material. In some embodiments, the emission can arise from any or all of the sensitizer, acceptor, and final emitter. In some embodiments, the acceptor has an emission at room temperature with a full width at half maximum (FWHM) of equal to or less than 50, 45, 40, 35, 30, 25, 20, 15, 10, or 5 nm. Narrower FWHM means better color purity for the OLED display application.

As used herein, phosphorescence generally refers to emission of a photon with a change in electron spin quantum number, i.e., the initial and final states of the emission have different electron spin quantum numbers, such as from T1 to S0 state. Most of the Ir and Pt complexes currently used in OLED are phosphorescent emitters. In some embodiments, if an exciplex formation involves a triplet emitter, such exciplex can also emit phosphorescent light. On the other hand, fluorescent emitters generally refer to emission of a photon without a change in electron spin quantum number, such as from S1 to S0 state, or from D1 to D0 state. Fluorescent emitters can be delayed fluorescent or non-delayed fluorescent emitters. Depending on the spin state, fluorescent emitter can be a singlet emitter or a doublet emitter, or other multiplet emitter. It is believed that the internal quantum efficiency (IQE) of fluorescent OLEDs can exceed the 25% spin statistics limit through delayed fluorescence. There are two types of delayed fluorescence, i.e. P-type and E-type delayed fluorescence. P-type delayed fluorescence is generated from triplet-triplet annihilation (TTA). On the other hand, E-type delayed fluorescence does not rely on the collision of two triplets, but rather on the thermal population between the triplet states and the singlet excited states. Thermal energy can activate the transition from the triplet state back to the singlet state. This type of delayed fluorescence is also known as TADF. E-type delayed fluorescence characteristics can be found in an exciplex system or in a single compound. Without being bound by theory, it is believed that TADF emissions require a compound or an exciplex having a small singlet-triplet energy gap (ΔE_{S-T}) less than or equal to 400, 350, 300, 250, 200, 150, 100, or 50 meV. There are two major types of TADF emitters, one is called donor-acceptor type TADF, the other one is called multiple resonance (MR) TADF. Often, single compound donor-acceptor TADF compounds are constructed by connecting an electron donor moiety such as amino- or carbazole-derivatives and an electron acceptor moiety such as N-containing six-membered aromatic rings or cyano-substituted aromatic rings. Donor-acceptor exciplexes can be formed between a hole transporting compound and an electron transporting compound. Examples of MR-TADF materials include highly conjugated fused ring systems. In some embodiments, MR-TADF materials comprises boron, carbon, and nitrogen atoms. Such materials may comprise other atoms, such as oxygen, as well. In some embodiments, the reverse intersystem crossing time from T1 to S1 of the delayed fluorescent emission at 293K is less than or equal to 10 microseconds. In some embodiments, such time can be greater than 10 microseconds and less than 100 microseconds.

In some embodiments, the OLED may comprise an additional compound selected from the group consisting of a non-delayed fluorescence material, a delayed fluorescence material, a phosphorescent material, and combination thereof.

In some embodiments, the inventive compound described herein is a phosphorescent material.

In some embodiments, the phosphorescent material is an emitter which emits light within the OLED. In some embodiments, the phosphorescent material does not emit light within the OLED. In some embodiments, the phosphorescent material energy transfers its excited state to another material within the OLED. In some embodiments, the phosphorescent material participates in charge transport within the OLED. In some embodiments, the phosphorescent material is a sensitizer or a component of a sensitizer, and the OLED further comprises an acceptor. In some embodiments, the phosphorescent material forms an exciplex with another material within the OLED, for example a host material, an emitter material.

In some embodiments, the non-delayed fluorescence material or the delayed fluorescence material is an emitter which emits light within the OLED. In some embodiments, the non-delayed fluorescence material or the delayed fluorescence material does not emit light within the OLED. In some embodiments, the non-delayed fluorescence material or the delayed fluorescence material energy transfers its excited state to another material within the OLED. In some embodiments, the non-delayed fluorescence material or the delayed fluorescence material participates in charge transport within the OLED. In some embodiments, the non-delayed fluorescence material or the delayed fluorescence material is an acceptor, and the OLED further comprises a sensitizer.

In some embodiments of the OLED, the delayed fluorescence material comprises at least one donor group and at least one acceptor group. In some embodiments, the delayed fluorescence material is a metal complex. In some embodiments, the delayed fluorescence material is a non-metal complex. In some embodiments, the delayed fluorescence material is a Pt, Pd, Zn, Cu, Ag, or Au complex (some of them are also called metal-assisted (MA) TADF). In some embodiments, the metal-assisted delayed fluorescence material comprises a metal-carbene bond. In some embodiments, the non-delayed fluorescence material or delayed fluorescence material comprises at least one chemical group selected from the group consisting of aryl-amine, aryloxy, arylthio, triphenylene, carbazole, indolocarbazole, dibenzothiophene, dibenzofuran, dibenzoselenophene, 5λ²-benzo[d]benzo[4,5]imidazo[3,2-a]imidazole, 5,9-dioxa-13b-boranaphtho[3,2,1-de]anthracene, 5λ²,9λ²-diaza-13b-boranaphtho[2,3,4-de]anthracene, 5-oxa-9λ²-aza-13b-boranaphtho[3,2,1-de]anthracene, azaborinine, oxaborinine, dihydroacridine, xanthene, dihydrobenzoazasiline, dibenzooxasiline, phenoxazine, phenoxathiine, phenothiazine, dihydrophenazine, fluorene, naphthalene, anthracene, phenanthrene, phenanthroline, benzoquinoline, quinoline, isoquinoline, quinazoline, pyrimidine, pyrazine, pyridine, triazine, boryl, amino, silyl, aza-variants thereof, and combinations thereof. In some embodiments, non-delayed the fluorescence material or delayed fluorescence material comprises a tri(aryl/heteroaryl)borane with one or more pairs of the substituents from the aryl/heteroaryl being joined to form a ring. In some embodiments, the fluorescence material comprises at least one chemical group selected from the group consisting of naphthalene, anthracene, phenalene, phenanthrene, fluorene, pyrene, chrysene, perylene, and azulene.

In yet another aspect, the OLED of the present disclosure may also comprise an emissive region containing a compound or a formulation of the compound as disclosed in the above compounds section of the present disclosure. In some embodiments, the emissive region can comprise a compound or a formulation of the compound E1 or E1′ as described herein. In some embodiments, the emissive region consists of one or more organic layers, wherein at least one of the one or more organic layers has a minimum thickness selected from the group consisting of 350, 400, 450, 500, 550, 600, 650 and 700 Å. In some embodiments, the at least one of the one or more organic layers are formed from an Emissive System that has a figure of merit (FOM) value equal to or larger than the number selected from the group consisting of 2.50, 2.55, 2.60, 2.65, 2.70, 2.75, 2.80, 2.85, 2.90, 2.95, 3.00, 5.00, 10.0, 15.0, and 20.0. The definition of FOM is available in U.S. patent Application Publication No. 2023/0292605, and its entire contents are incorporated herein by reference. In some embodiments, the at least one of the one or more organic layers comprises a compound or a formulation of the compound as disclosed in Sections A and D of the present disclosure.

In some embodiments, the OLED or the emissive region comprising the inventive compound disclosed herein can be incorporated into a full-color pixel arrangement of a device. The full-color pixel arrangement of such device comprises at least one pixel, wherein the at least one pixel comprises a first subpixel and a second subpixel. The first subpixel includes a first OLED comprising a first emissive region. The second subpixel includes a second OLED comprising a second emissive region. In some embodiments, the first and/or second OLED, the first and/or second emissive region can be the same or different and each can independently have the various device characteristics and the various embodiments of the inventive compounds included therein, and various combinations and subcombinations of the various device characteristics and the various embodiments of the inventive compounds included therein, as disclosed herein.

In some embodiments, the first emissive region is configured to emit a light having a peak wavelength λₘₐₓ₁; the second emissive region is configured to emit a light having a peak wavelength λₘₐₓ₂. In some embodiments, the difference between the peak wavelengths λₘₐₓ₁ and λₘₐₓ₂ is at least 4 nm but within the same color. For example, a light blue and a deep blue light as described above. In some embodiments, a first emissive region is configured to emit a light having a peak wavelength λₘₐₓ₁ in one region of the visible spectrum of 400-500 nm, 500-600 nm, 600-700 nm; and a second emissive region is configured to emit light having a peak wavelength λₘₐₓ₂ in one of the remaining regions of the visible spectrum of 400-500 nm, 500-600 nm, 600-700 nm. In some embodiments, the first emissive region comprises a first number of emissive layers that are deposited one over the other if more than one; and the second emissive region comprises a second number of emissive layers that is deposited one over the other if more than one; and the first number is different from the second number. In some embodiments, both the first emissive region and the second emissive region comprise a phosphorescent materials, which may be the same or different. In some embodiments, the first emissive region comprises a phosphorescent material, while the second emissive region comprises a fluorescent material. In some embodiments, both the first emissive region and the second emissive region comprise a fluorescent materials, which may be the same or different.

In some embodiments, the at least one pixel of the OLED or emissive regions includes a total of N subpixels; wherein the N subpixels comprises the first subpixel and the second subpixel; wherein each of the N subpixels comprises an emissive region; wherein the total number of the emissive regions within the at least one pixel is equal to or less than N−1. In some embodiments, the second emissive region is exactly the same as the first emissive region; and each subpixel of the at least one pixel comprises the same one emissive region as the first emissive region. In some embodiments, the full-color pixel arrangements can have a plurality of pixels comprising a first pixel region and a second pixel region; wherein at least one display characteristic in the first pixel region is different from the corresponding display characteristic of the second pixel region, and wherein the at least one display characteristic is selected from the group consisting of resolution, cavity mode, color, outcoupling, and color filter.

In some embodiments, the OLED is a stacked OLED comprising one or more charge generation layers (CGLs). In some embodiments, the OLED comprises a first electrode, a first emissive region disposed over the first electrode, a first CGL disposed over the first emissive region, a second emissive region disposed over the first CGL, and a second electrode disposed over the second emissive region. In some embodiments, the first and/or the second emissive regions can have the various device characteristics as described above for the pixelated device. In some embodiments, the stacked OLED is configured to emit white color. In some embodiments, one or more of the emissive regions in a pixelated or in a stacked OLED comprises a sensitizer and an acceptor with the various sensitizing device characteristics and the various embodiments of the inventive compounds disclosed herein. For example, the first emissive region is comprised in a sensitizing device, while the second emissive region is not comprised in a sensitizing device; in some instances, both the first and the second emissive regions are comprised in sensitizing devices.

In some embodiments, the OLED can emit light having at least 1%, 5%, 10, 30%, 50%, 70%, 80%, 90%, 95%, 99%, or 100% from the plasmonic mode. In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. In some embodiments, the enhancement layer is provided no more than a threshold distance away from the organic emissive layer, wherein the emitter material has a total non-radiative decay rate constant and a total radiative decay rate constant due to the presence of the enhancement layer. A threshold distance is where the total non-radiative decay rate constant is equal to the total radiative decay rate constant. Another threshold distance is the distance at which the total radiative decay rate constant divided by the sum of the total non-radiative decay rate constant and total radiative decay rate constant is equal to the photoluminescent yield of the emissive material without the enhancement layer present.

In some embodiments, the OLED further comprises an outcoupling layer. In some embodiments, the outcoupling layer is disposed over the enhancement layer on a side opposite the organic emissive layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. In some embodiments, one or more intervening layer can be disposed between the enhancement layer and the outcoupling layer. The examples for intervening layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and a reduced efficiency roll-off of the OLED device. Placement of the enhancement layer on the cathode side, anode side, or on both sides, or the enhancement layer itself being as the CGL, results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

In some embodiments, the enhancement layer can be comprised of plasmonic materials, optically active metamaterials, or hyperbolic metamaterials. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, or Ca, alloys or mixtures of these materials, and stacks of these materials. In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly.

In some embodiments, the outcoupling layer has wavelength-sized or sub-wavelength sized features that are arranged periodically, quasi-periodically, or randomly. In some embodiments, the outcoupling layer may be composed of a plurality of nanoparticles. In some embodiments, the outcoupling layer is composed of a plurality of nanoparticles disposed over a material. In these embodiments the outcoupling layer may be tunable by at least one of: varying a size of the plurality of nanoparticles, varying a shape of the plurality of nanoparticles, changing a material of the plurality of nanoparticles, adjusting a thickness of the material, changing the refractive index of the material, adding an additional layer disposed on the plurality of nanoparticles, varying a thickness of the enhancement layer, or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, and Ca, alloys or mixtures of these materials, and stacks of these materials. In some embodiments the outcoupling layer is formed by lithography.

In some embodiments of plasmonic device, the emitter, and/or host compounds used in the emissive layer has a vertical dipole ratio (VDR) of 0.33 or more. In some such embodiments, the emitter, and/or host compounds have a VDR of 0.40, 0.50, 0.60, 0.70, or more.

In yet another aspect, the present disclosure also provides a consumer product comprising an organic light-emitting device (OLED) having an anode; a cathode; and an organic layer disposed between the anode and the cathode, wherein the organic layer may comprise a compound or a formulation of the compound as disclosed in the above compounds section of the present disclosure.

In some embodiments, the consumer product comprises an OLED having an anode; a cathode; and an organic layer disposed between the anode and the cathode, wherein the organic layer may comprise a compound E1 or E1′ as described herein.

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, and an “exciton,” which is a localized electron-hole pair having an excited energy state, is formed. Light is emitted when the exciton relaxes via a photoemissive mechanism. In some cases, the exciton may be localized as an excimer or an exciplex. Non-radiative mechanisms, such as thermal relaxation, may also occur, but are generally considered undesirable.

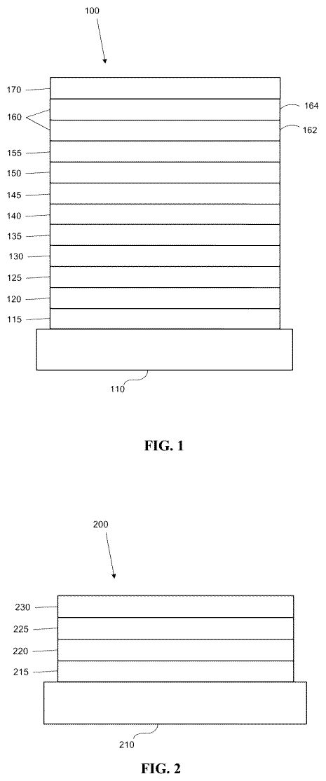

FIG. 1 shows an organic light emitting device 100. The figures are not necessarily drawn to scale. Device 100 may include a substrate 110, an anode 115, a hole injection layer (HIL) 120, a hole transport layer (HTL) 125, an electron blocking layer (EBL) 130, an emissive layer (EML) 135, a hole blocking layer (HBL) 140, an electron transport layer (ETL) 145, an electron injection layer (EIL) 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the present disclosure may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP, also referred to as organic vapor jet deposition (OVJD)), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation, sputtering, chemical vapor deposition, atomic layer deposition, and electron beam deposition. Preferred patterning methods include deposition through a mask, photolithography, and cold welding such as described in U.S. Pat. Nos. 6,294,398 and 6,468,819, which are incorporated by reference in their entireties, and patterning associated with some of the deposition methods such as ink-jet and organic vapor jet printing (OVJP). Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons are a preferred range. Materials with asymmetric structures may have better solution processability than those having symmetric structures, because asymmetric materials may have a lower tendency to recrystallize. Dendrimer substituents may be used to enhance the ability of small molecules to undergo solution processing.

Devices fabricated in accordance with embodiments of the present disclosure may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a plurality of alternative layers of polymeric material and non-polymeric material; organic material and inorganic material; or a mixture of a polymeric material and a non-polymeric material as one example described in U.S. Pat. No. 7,968,146, PCT Pat. Application Nos. PCT/US2007/023098 and PCT/US2009/042829, which are herein incorporated by reference in their entireties.

Devices fabricated in accordance with embodiments of the present disclosure can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the present disclosure can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, curved displays, computer monitors, medical monitors, televisions, billboards, lights for interior or exterior illumination and/or signaling, heads-up displays, fully or partially transparent displays, flexible displays, rollable displays, foldable displays, stretchable displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theater or stadium screen, a light therapy device, and a sign. Various control mechanisms may be used to control devices fabricated in accordance with the present disclosure, including passive matrix and active matrix. Many of the devices are intended for use in a temperature range comfortable to humans, such as 18 degrees C. to 30 degrees C., and more preferably at room temperature (20-25° C.), but could be used outside this temperature range, for example, from −40 degree c. to +80° C.

More details on OLEDs, and the definitions described above, can be found in U.S. Pat. No. 7,279,704, which is incorporated herein by reference in its entirety.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes. In some embodiments, the OLED further comprises one or more quantum dots. Such quantum dots can be in the emissive layer, or in other functional layers, such as a down conversion layer.

In some embodiments, the OLED comprises a RGB pixel arrangement or white plus color filter pixel arrangement. In some embodiments, the OLED is a mobile device, a handheld device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

### D. Other Materials Used in the OLED

The materials described herein are as various examples useful for a particular layer in an OLED. They may also be used in combination with a wide variety of other materials present in the device. For example, emissive dopants disclosed herein may be used by themselves in the EML, or in conjunction with a wide variety of other emitters, hosts, transport layers, blocking layers, injection layers, electrodes and other layers that may be present. The materials described or referred to below are non-limiting examples of materials that may be useful in combination with the compounds and the devices disclosed herein, and one of skill in the art can readily consult the literature to identify other materials that may be useful in combination.

### a) Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer. In some embodiments, conductivity dopants comprises at least one chemical moiety selected from the group consisting of cyano, fluorinated aryl or heteroaryl, fluorinated alkyl or cycloalkyl, alkylene, heteroaryl, amide, benzodithiophene, and highly conjugated heteroaryl groups extended by non-ring double bonds.

### b) HIL/HTL:

A hole injecting/transporting material to be used in the present disclosure is not particularly limited, and any compound may be used as long as the compound is typically used as a hole injecting/transporting material. Examples of the material include, but are not limited to: a phthalocyanine or porphyrin derivative; an aromatic amine derivative; an indolocarbazole derivative; a polymer containing fluorohydrocarbon; a polymer with conductivity dopants; a conducting polymer, such as PEDOT/PSS; a self-assembly monomer derived from compounds such as phosphonic acid and silane derivatives; a metal oxide derivative, such as MoOₓ; a p-type semiconducting organic compound, such as 1,4,5,8,9,12-Hexaazatriphenylenehexacarbonitrile; a metal complex, and a cross-linkable compounds.

Examples of aromatic amine derivatives used in HIL or HTL include, but not limit to the following general structures:

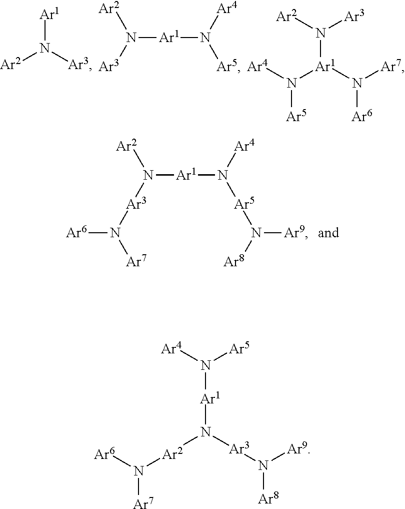

Each of Ar¹ to Ar⁹ is selected from the group consisting of aromatic hydrocarbon cyclic compounds such as benzene, biphenyl, triphenyl, triphenylene, naphthalene, anthracene, phenalene, phenanthrene, fluorene, pyrene, chrysene, perylene, and azulene; the group consisting of aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and the group consisting of 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Each of Ar¹ to Ar⁹ may be unsubstituted or may be substituted by a general substituent as described above, any two substituents can be joined or fused into a ring.

In some embodiments, each Ar¹ to Ar⁹ independently comprises a moiety selected from the group consisting of:

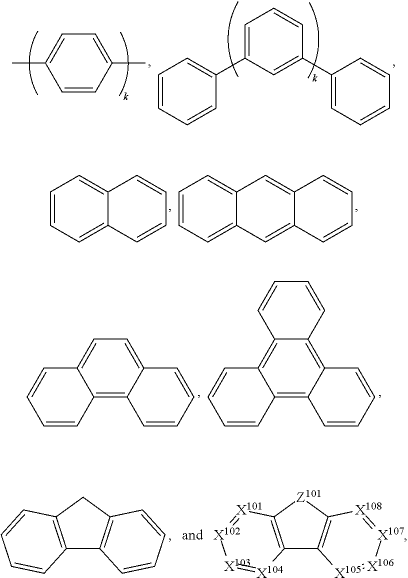

wherein k is an integer from 1 to 20; X¹⁰¹ to X¹⁰⁸ is C or N; Z¹⁰¹ is C, N, O, or S.

Examples of metal complexes used in HIL or HTL include, but are not limited to the following general formula:

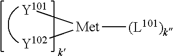

wherein Met is a metal, which can have an atomic weight greater than 40; (Y¹⁰¹-Y¹⁰²) is a bidentate ligand, the coordinating atoms of Y¹¹⁰ and Y¹⁰² are independently selected from C, N, O, P, and S; L¹⁰¹ is an another ligand; k′ is an integer value from 1 to the maximum number of ligands that may be attached to the metal; and k′+k″ is the maximum number of ligands that may be attached to the metal.

In some embodiments, (Y¹⁰¹-Y¹⁰²) is a 2-phenylpyridine or 2-phenylimidazole derivative. In some embodiments, (Y¹⁰¹-Y¹⁰²) is a carbene ligand. In some embodiments, Met is selected from Ir, Pt, Pd, Os, Cu, and Zn. In some embodiments, the metal complex has a smallest oxidation potential in solution vs. Fc⁺/Fc couple less than about 0.6 V.

In some embodiments, the HIL/HTL material is selected from the group consisting of phthalocyanine and porphryin compounds, starburst triarylamines, CFₓ fluorohydrocarbon polymer, conducting polymers (e.g., PEDOT:PSS, polyaniline, polypthiophene), phosphonic acid and sliane SAMs, triarylamine or polythiophene polymers with conductivity dopants, Organic compounds with conductive inorganic compounds (such as molybdenum and tungsten oxides), n-type semiconducting organic complexes, metal organometallic complexes, cross-linkable compounds, polythiophene based polymers and copolymers, triarylamines, triaylamine with spirofluorene core, arylamine carbazole compounds, triarylamine with (di)benzothiophene/(di)benzofuran, indolocarbazoles, isoindole compounds, and metal carbene complexes.

### c) EBL:

An electron blocking layer (EBL) may be used to reduce the number of electrons and/or excitons that leave the emissive layer. The presence of such a blocking layer in a device may result in substantially higher efficiencies, and/or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than one or more emitters closest to the EBL interface. In some embodiments, the compound used in EBL contains at least one carbazole group and/or at least one arylamine group. In some embodiments the HOMO level of the compound used in the EBL is shallower than the HOMO level of one or more of the hosts in the EML. In some embodiments, the compound used in EBL contains the same molecule or the same functional groups used as one of the hosts described herein.

### d) Hosts:

The light emitting layer of the organic EL device of the present disclosure preferably contains at least a light emitting material as the dopant, and a host material. Examples of the host material are not particularly limited, and any metal complexes or organic compounds may be used as long as the host won't fully quench the emission of the dopant.

Examples of metal complexes used as host are preferred to have the following general formula:

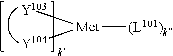

wherein Met is a metal; (Y¹⁰³-Y¹⁰⁴) is a bidentate ligand, the coordinating atoms of Y¹⁰³ and Y¹⁰⁴ are independently selected from C, N, O, P, and S; L¹⁰¹ is an another ligand; k′ is an integer value from 1 to the maximum number of ligands that may be attached to the metal; and k′+k″ is the maximum number of ligands that may be attached to the metal.

In some embodiments, the metal complexes are:

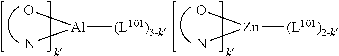

wherein (O—N) is a bidentate ligand, having metal coordinated to atoms O and N.

In some embodiments, Met is selected from Ir and Pt. In a further embodiments, (Y¹⁰³-Y¹⁰⁴) is a carbene ligand.

In some embodiments, the host compound contains at least one of the following groups selected from the group consisting of aromatic hydrocarbon cyclic compounds such as benzene, biphenyl, triphenyl, triphenylene, tetraphenylene, naphthalene, anthracene, phenalene, phenanthrene, fluorene, pyrene, chrysene, perylene, and azulene; the group consisting of aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, aza-dibenzothiophene, aza-dibenzofuran, aza-dibenzoselenophene, aza-carbazole, aza-indolocarbazole, aza-triphenylene, aza-tetraphenylene, 5λ²-benzo[d]benzo[4,5]imidazo[3,2-a]imidazole, 5,9-dioxa-13b-boranaphtho[3,2,1-de]anthracene; and the group consisting of 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Each option within each group may be unsubstituted or may be substituted by the general substituents as described herein or may be further fused.

In some embodiments, the host compound comprises at least one of the moieties selected from the group consisting of:

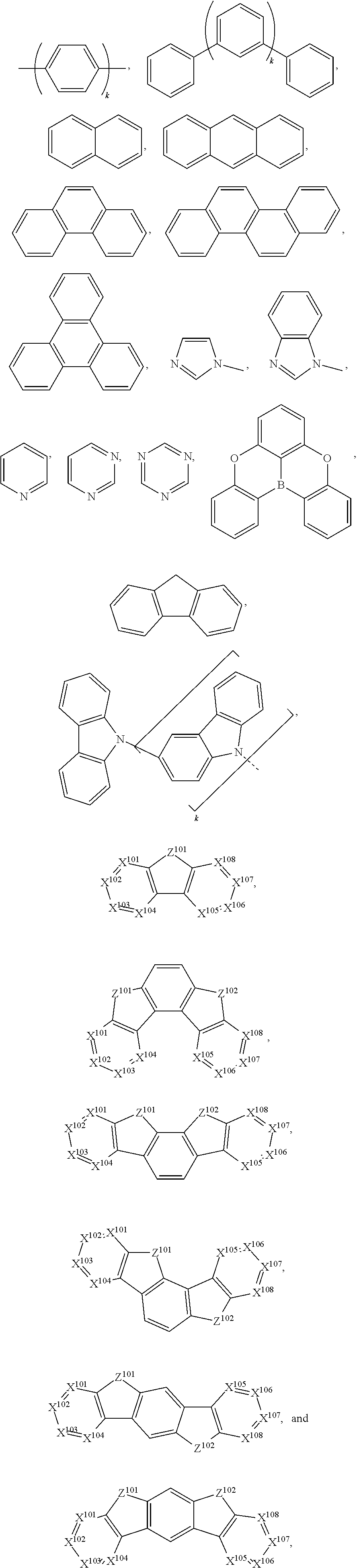

wherein k is an integer from 0 to 20 or 1 to 20. X¹⁰¹ to X¹⁰⁸ are independently selected from C or N, Z¹⁰¹ and Z¹⁰² are independently selected from C, N, O, or S.

In some embodiments, the host material is selected from the group consisting of arylcarbazoles, metal 8-hydroxyquinolates, (e.g., alq3, balq), metal phenoxybenzothiazole compounds, conjugated oligomers and polymers (e.g., polyfluorene), aromatic fused rings, zinc complexes, chrysene based compounds, aryltriphenylene compounds, poly-fused heteroaryl compounds, donor acceptor type molecules, dibenzofuran/dibenzothiophene compounds, polymers (e.g., pvk), spirofluorene compounds, spirofluorene-carbazole compounds, indolocabazoles, 5-member ring electron deficient heterocycles (e.g., triazole, oxadiazole), tetraphenylene complexes, metal phenoxypyridine compounds, metal coordination complexes (e.g., Zn, Al with N\hat{ }N ligands), dibenzothiophene/dibenzofuran-carbazole compounds, silicon/germanium aryl compounds, aryl benzoyl esters, carbazole linked by non-conjugated groups, aza-carbazole/dibenzofuran/dibenzothiophene compounds, and high triplet metal organometallic complexes (e.g., metal-carbene complexes).

### e) Emitter Materials in EML:

One or more emitter materials may be used in conjunction with the compound or device of the present disclosure. The emitter material can be emissive or non-emissive in the current device as described herein. Examples of the emitter materials are not particularly limited, and any compounds may be used as long as the compounds are capable of producing emissions in a regular OLED device. Examples of suitable emitter materials include, but are not limited to, compounds which are capable of producing emissions via phosphorescence, non-delayed fluorescence, delayed fluorescence, especially the thermally activated delayed fluorescence, i.e., TADF (also referred to as E-type delayed fluorescence), triplet-triplet annihilation, or combinations of these processes.

In some embodiments, the emitter material has the formula of M(L¹)ₓ(L²)_{y}(L³)_{z};
wherein L¹, L², and L³ can be the same or different;
wherein x is 1, 2, or 3;
wherein y is 0, 1, or 2;
wherein z is 0, 1, or 2;
wherein x+y+z is the oxidation state of the metal M;
wherein L¹ is selected from the group consisting of the structures of LIGAND LIST 1 as described herein;
   wherein each L² and L³ are independently selected from the group consisting of

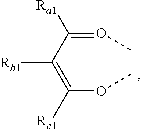

and the structures of LIGAND LIST 1; wherein:
M is selected from the group consisting of Ir, Rh, Re, Ru, Os, Pt, Pd, Zn, Au, Ag, and Cu;
T is selected from the group consisting of B, Al, Ga, and In;
K^{1′} is a direct bond or is selected from the group consisting of NRₑ, PRₑ, O, S, and Se;
each Y¹ to Y⁵ are independently selected from the group consisting of carbon and nitrogen;
Y′ is selected from the group consisting of BRₑ, NRₑ, PRₑ, O, S, Se, C═O, S═O, SO₂, CRₑR_{f}, SiRₑR_{f}, and GeRₑR_{f};
each Rₐ, R_{b}, R_{c}, and R_{d} can independently represent from mono to the maximum possible number of substitutions, or no substitution;
each Rₐ₁, R_{b1}, R_{c1}, R_{d1}, Rₐ, R_{b}, R_{c}, R_{d}, Rₑ, and R_{f} is independently a hydrogen or a substituent selected from the group consisting of the general substituents as defined herein; and
   wherein any two substituents can be fused or joined to form a ring or form a multidentate ligand.

In some embodiments, the emitter material is selected from the group consisting of the following Dopant Group 1:

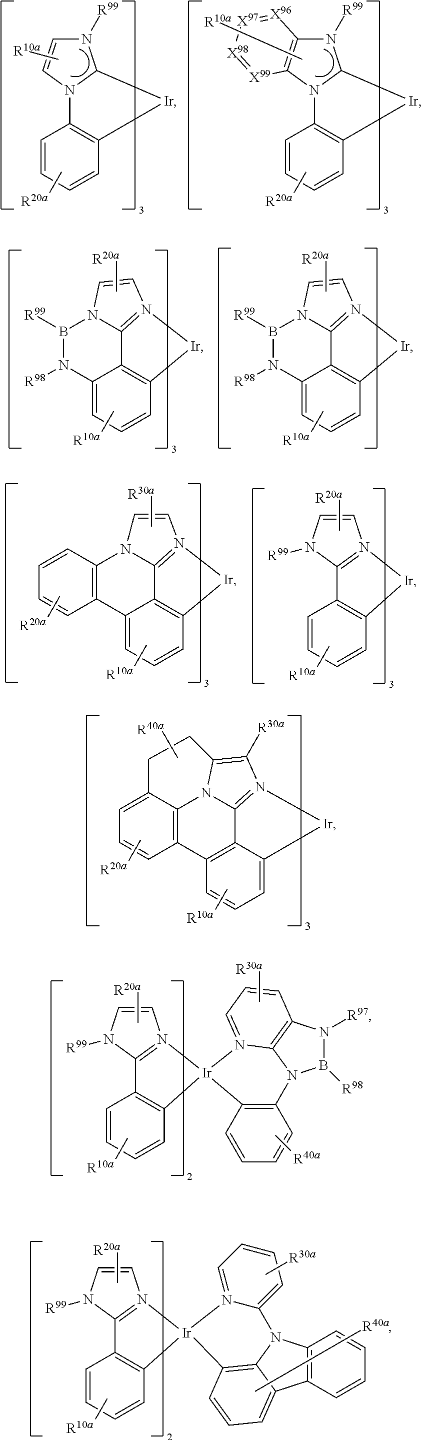

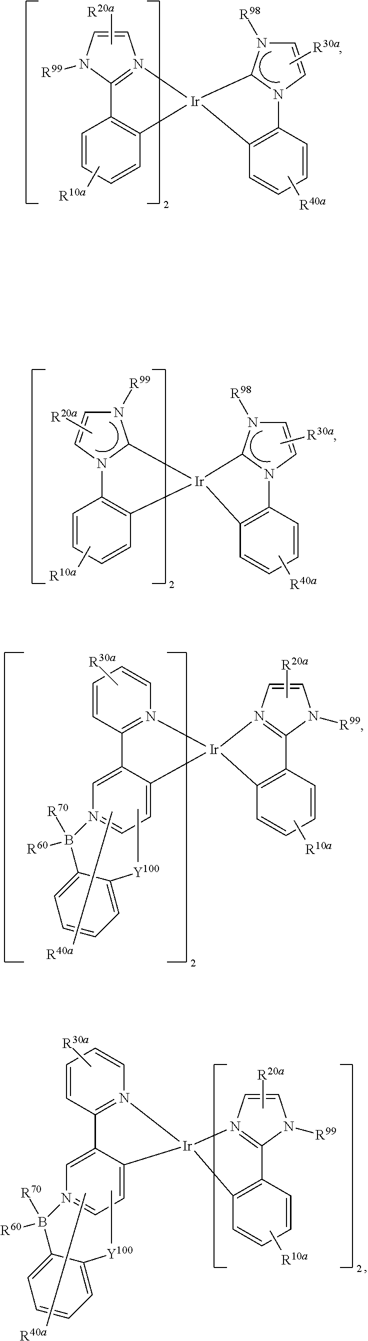

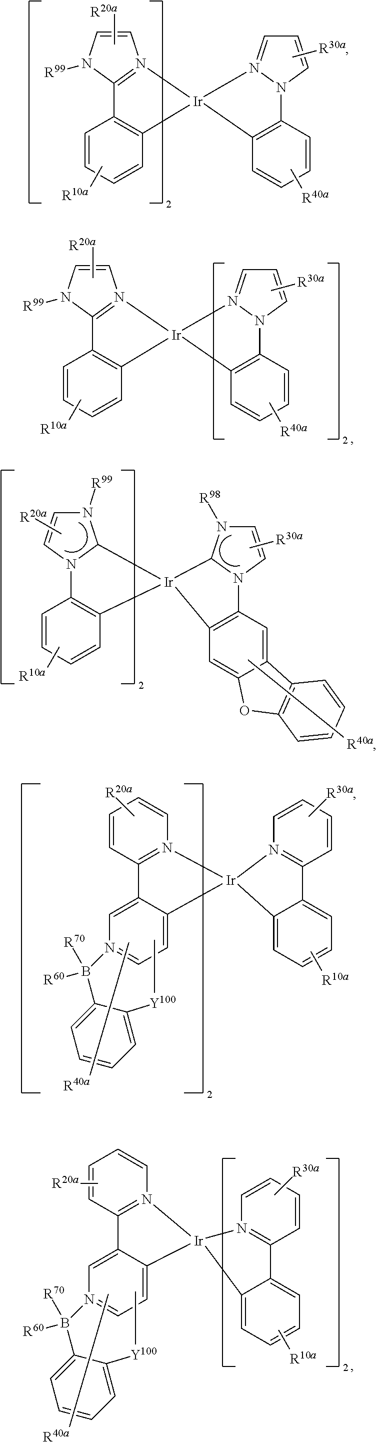

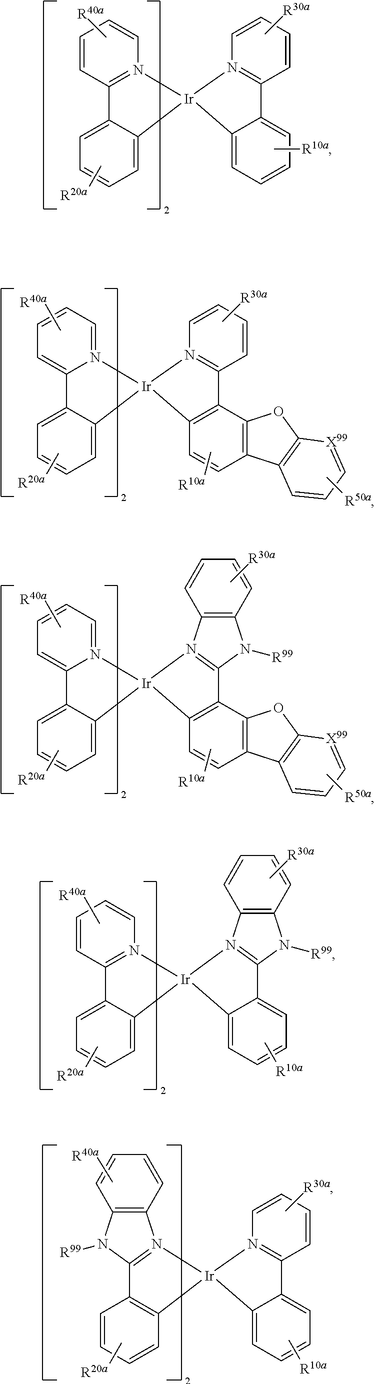

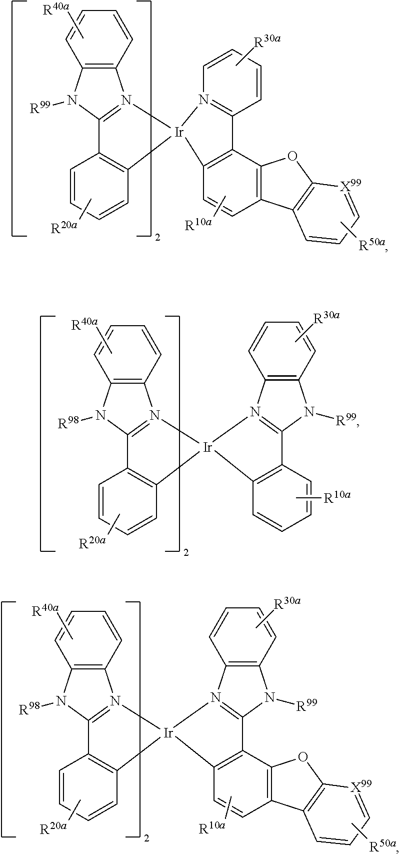

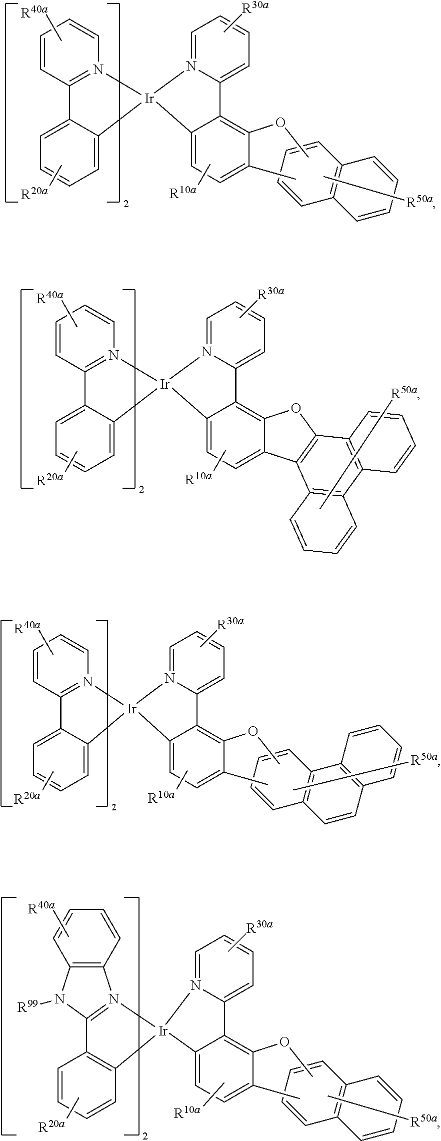

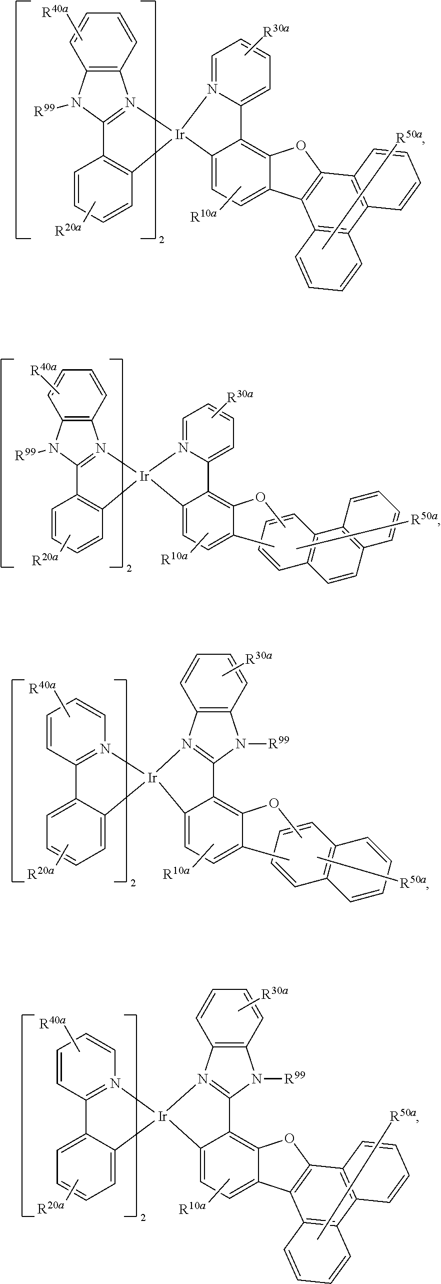

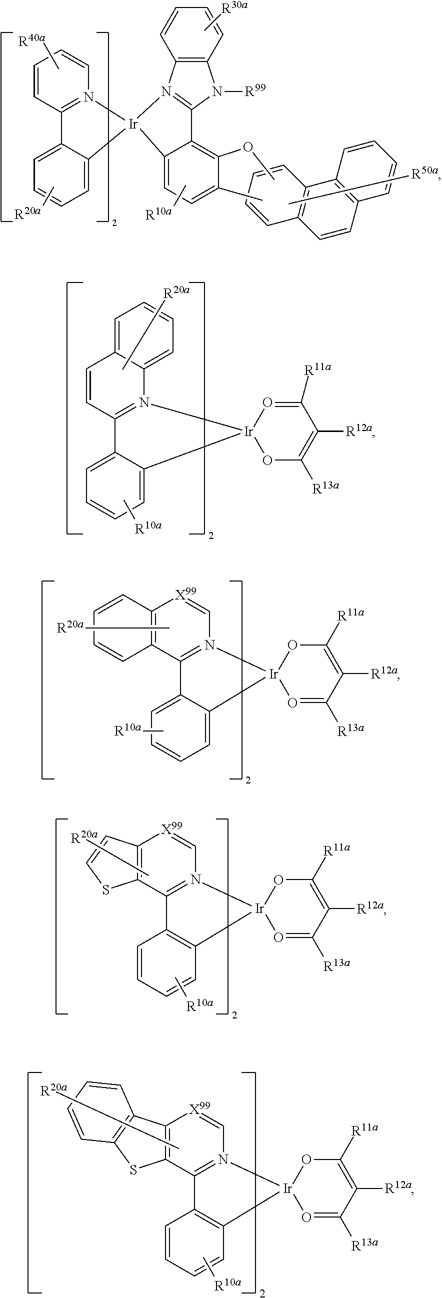

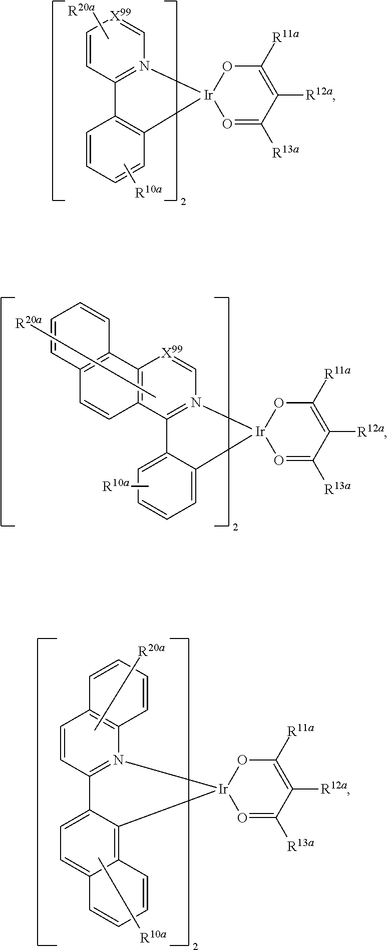

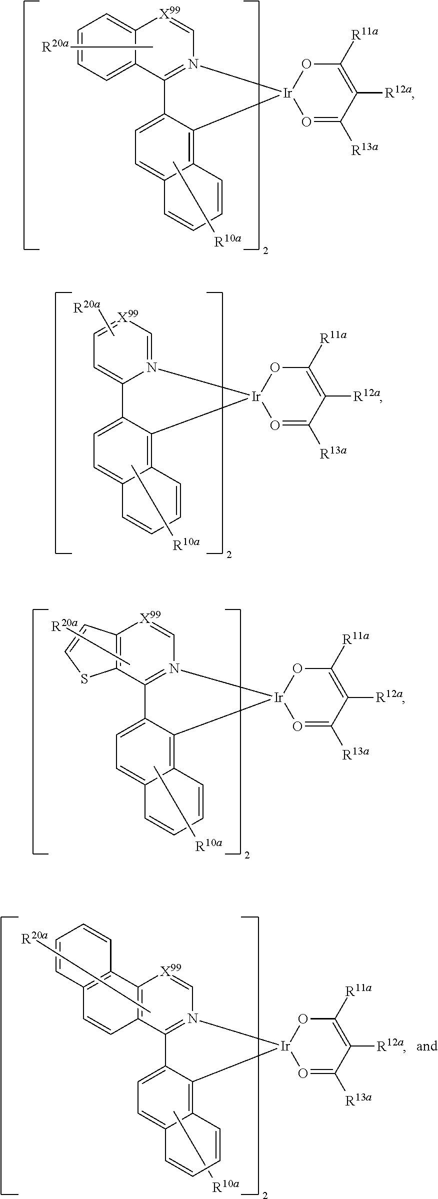

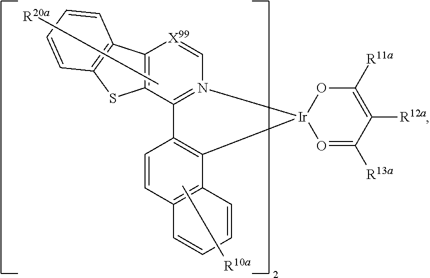

wherein
each of X⁹⁶ to X⁹⁹ is independently C or N;
each Y¹⁰⁰ is independently selected from the group consisting of a NR″, O, S, and Se;
each of R^{10a}, R^{20a}, R^{30a}, R^{40a}, and R^{50a} independently represents mono substitution, up to the maximum substitutions, or no substitution;
each of R, R′, R″, R^{10a}, R^{11a}, R^{12a}, R^{13a}, R^{20a}, R^{30a}, R^{40a}, R^{50a}, R⁶⁰, R⁷⁰, R⁹⁷, R⁹⁸, and R⁹⁹ is independently a hydrogen or a substituent selected from the group consisting of the general substituents as defined herein; any two substituents can be joined or fused to form a ring.

In some embodiments, the emitter material is selected from the group consisting of the following Dopant Group 2:

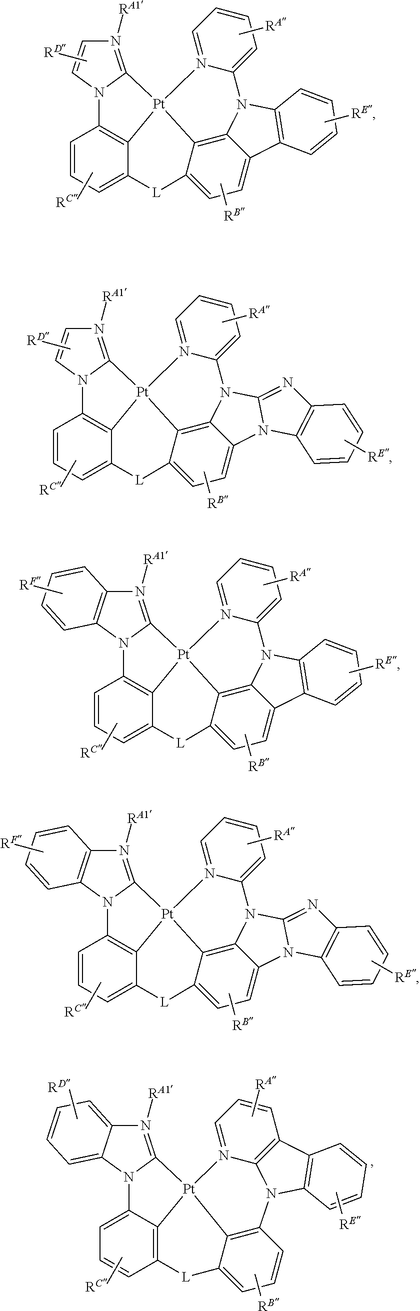

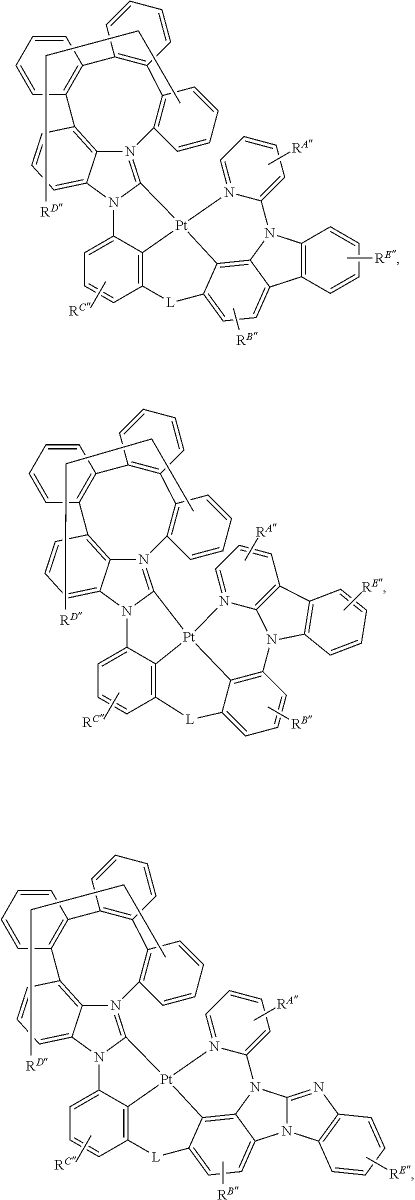

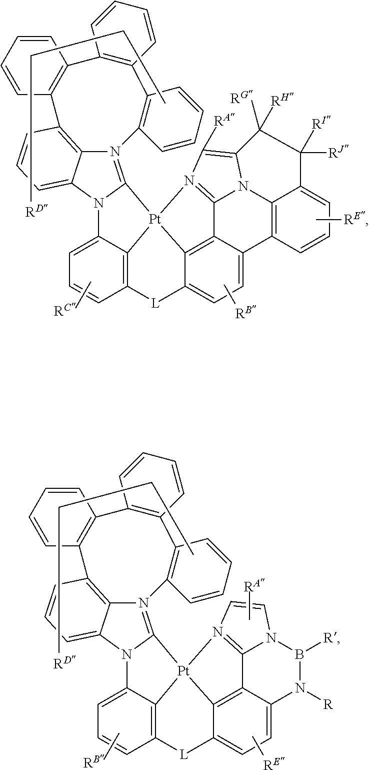

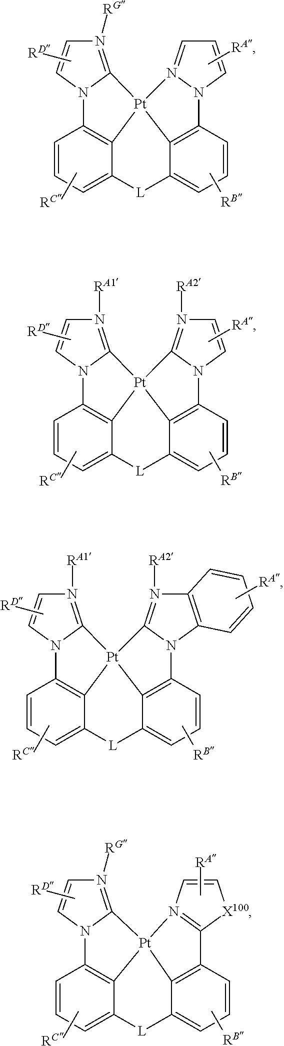

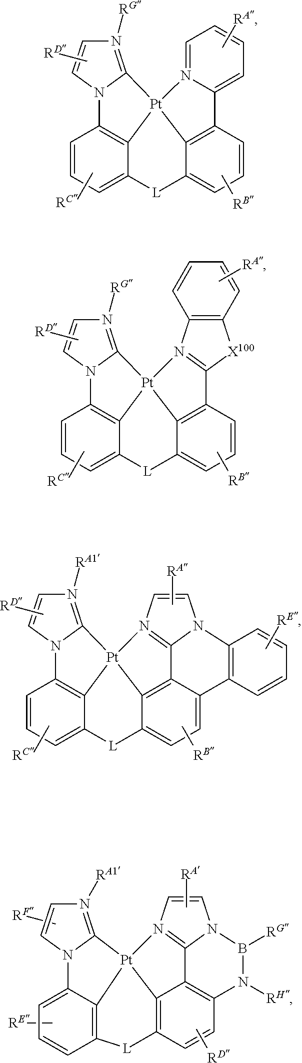

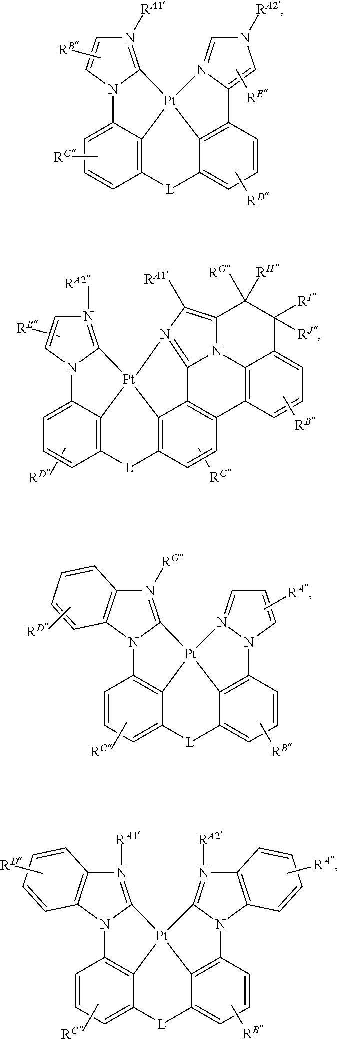

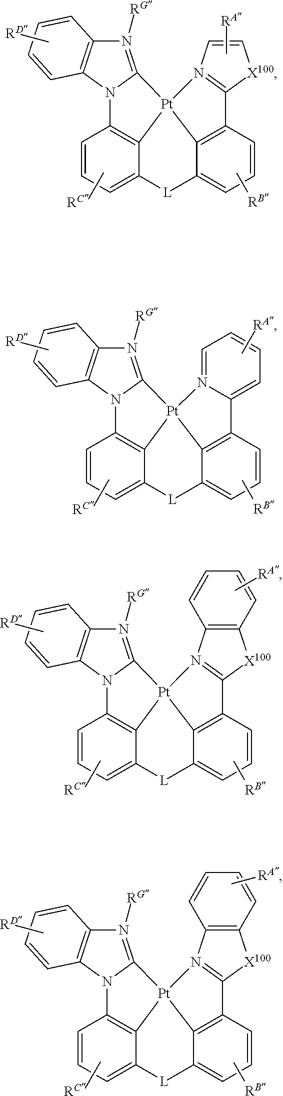

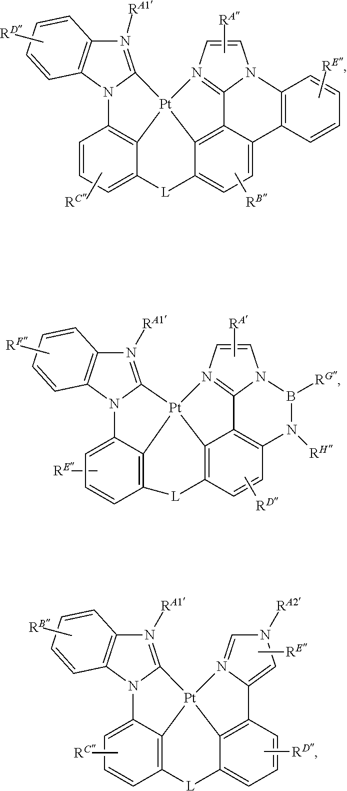

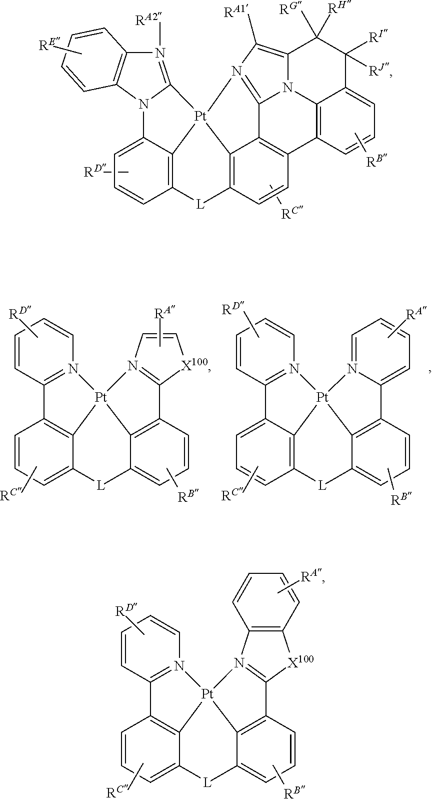

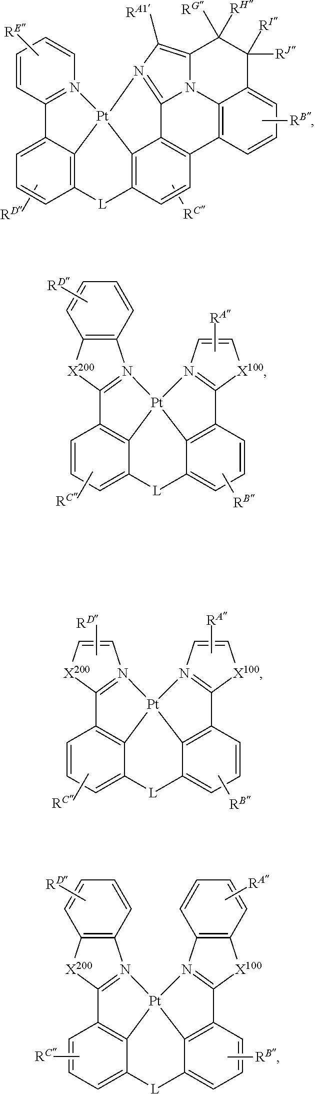

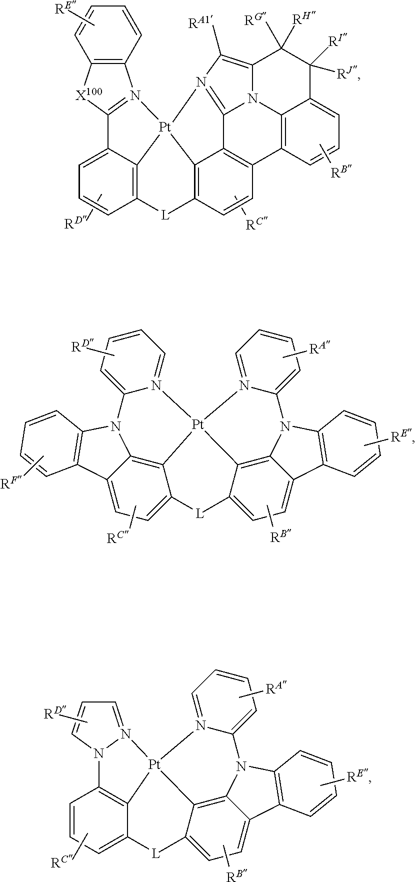

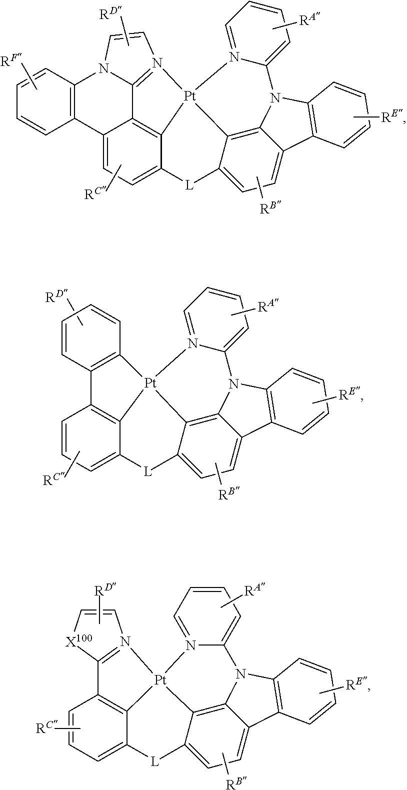

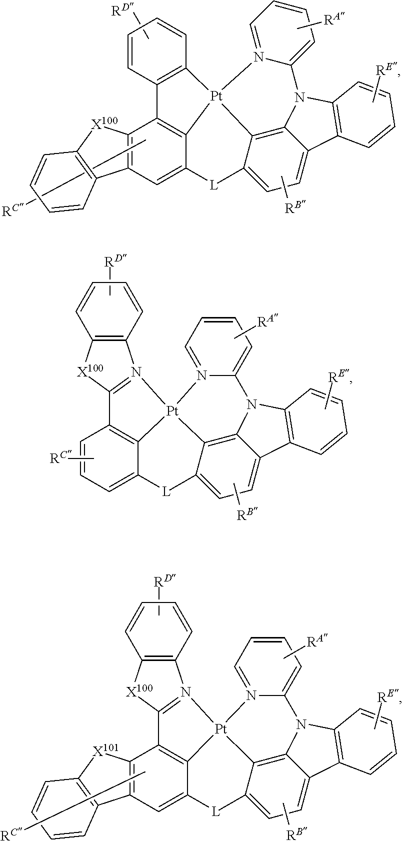

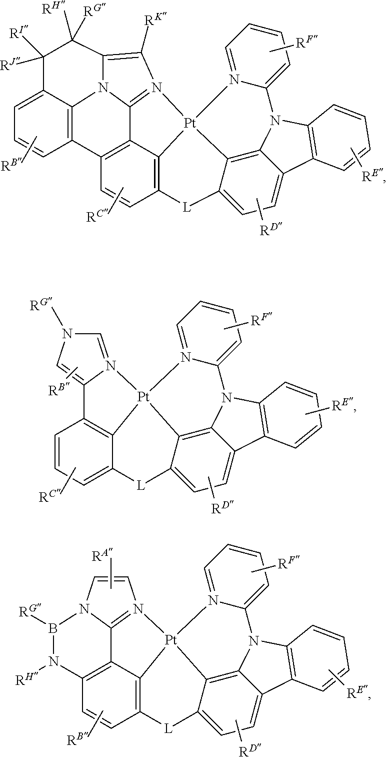

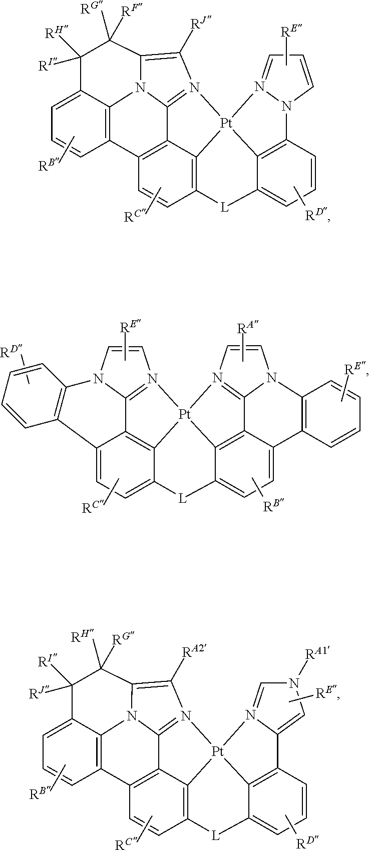

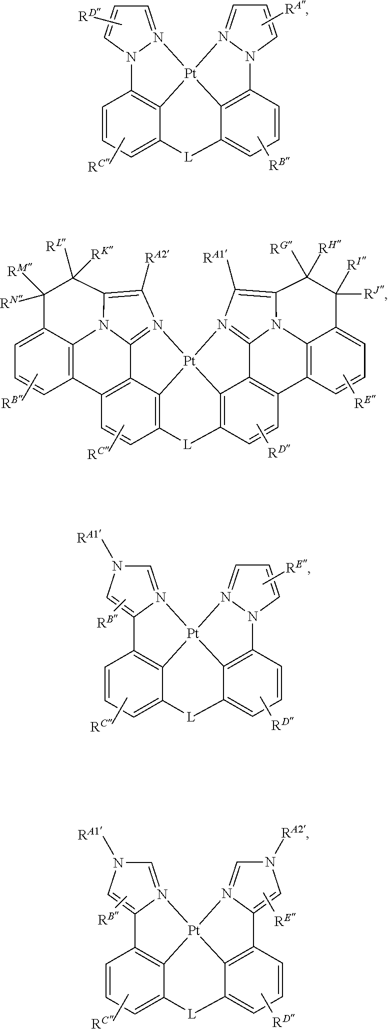

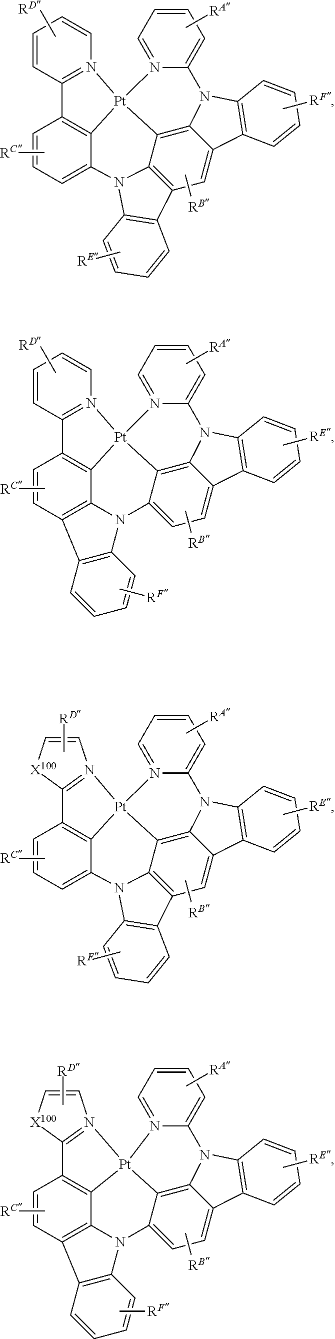

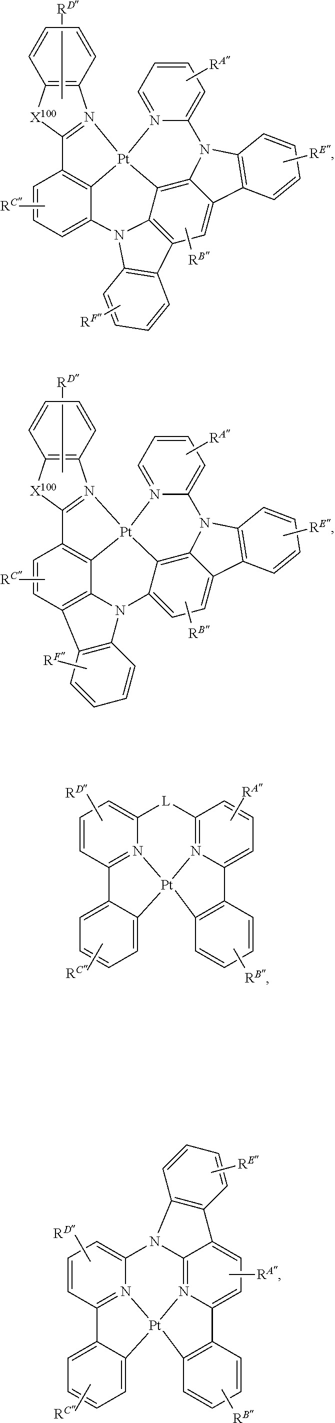

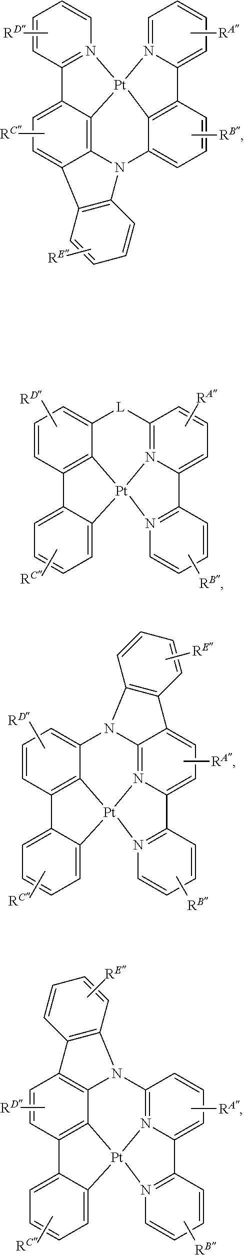

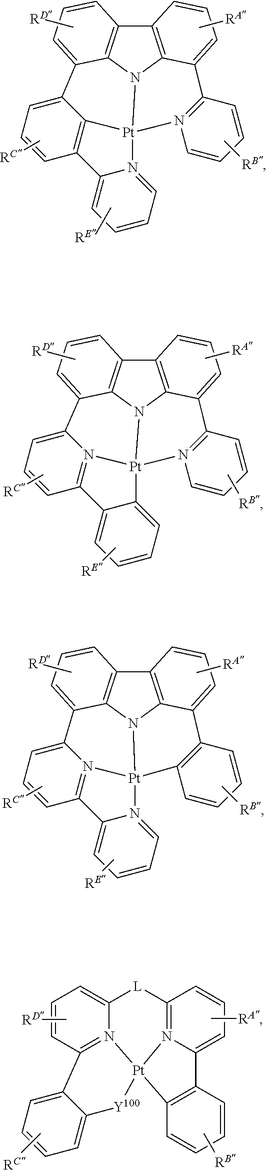

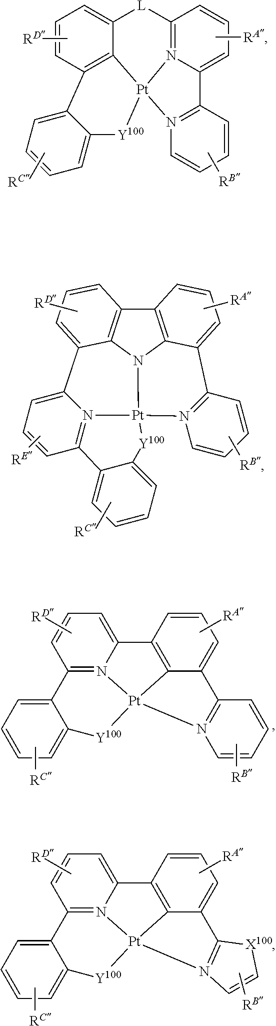

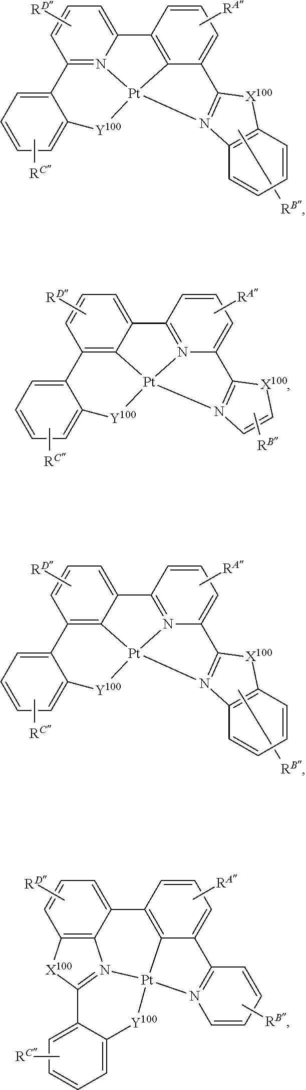

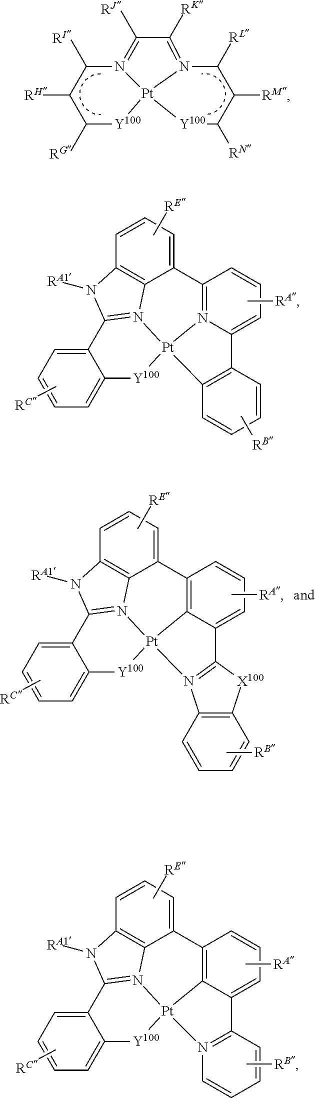

wherein:
each Y¹⁰⁰ is independently selected from the group consisting of a NR″, O, S, and Se;
L is independently selected from the group consisting of a direct bond, BR″, BR″R″′, NR″, PR″, O, S, Se, C═O, C═S, C═Se, C═NR″, C═CR″R″′, S═O, SO₂, CR″, CR″R″′, SiR″R″′, GeR″R″′, alkyl, cycloalkyl, aryl, heteroaryl, and combinations thereof;
X¹⁰⁰ and X²⁰⁰ for each occurrence is selected from the group consisting of O, S, Se, NR″, and CR″R″′;
each R^{A″}, R^{B″}, R^{C″}, R^{D″}, R^{E″}, and R^{F″} independently represents mono-, up to the maximum substitutions, or no substitutions; each of R, R′, R″, R″′, R^{A1′}, R^{A2′}, R^{A″}, R^{B″}, R^{C″}, R^{D″}, R^{E″}, R^{F″}, R^{G″}, R^{H″}, R^{I″}, R^{J″}, R^{K″}, R^{L″}, R^{M″}, and R^{N″} is independently a hydrogen or a substituent selected from the group consisting of the general substituents as defined herein; any two substituents can be joined or fused to form a ring;

In some embodiments of the above Dopant Groups 1 and 2, each unsubstituted aromatic carbon atom can be replaced with N to form an aza-ring. In some embodiments, the maximum number of N atom in one ring is 1 or 2. In some embodiments of the above Dopant Groups 2, Pt atom in each formula can be replaced by Pd atom.

In some embodiments of the OLED, the delayed fluorescence material comprises at least one donor group and at least one acceptor group. In some embodiments, the delayed fluorescence material is a metal complex. In some embodiments, the delayed fluorescence material is a non-metal complex. In some embodiments, the delayed fluorescence material is a Zn, Cu, Ag, or Au complex.

In some embodiments of the OLED, the delayed fluorescence material has the formula of M(L⁵)(L⁶), wherein M is Cu, Ag, or Au, L⁵ and L⁶ are different, and L⁵ and L⁶ are independently selected from the group consisting of:

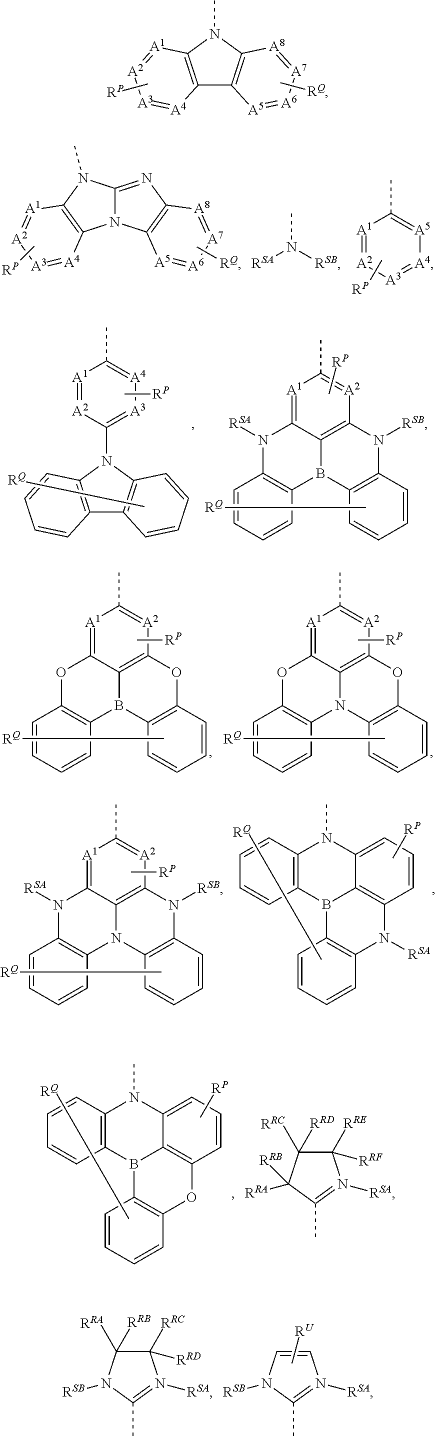

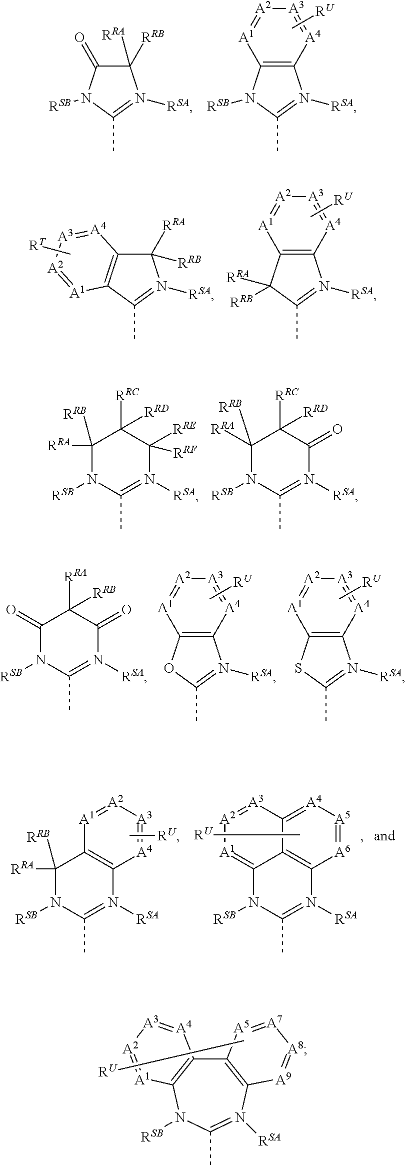

wherein A¹-A⁹ are each independently selected from C or N;
each R^{P}, R^{Q}, and R^{U} independently represents mono-, up to the maximum substitutions, or no substitutions; wherein each R^{P}, R^{P}, R^{U}, R^{5A}, R^{5B}, R^{RA}, R^{RB}, R^{RC}, R^{RD}, R^{RE}, and R^{RF} is independently a hydrogen or a substituent selected from the group consisting of the general substituents as defined herein; any two substituents can be joined or fused to form a ring.

In some embodiments of the OLED, the delayed fluorescence material comprises at least one of the donor moieties selected from the group consisting of:

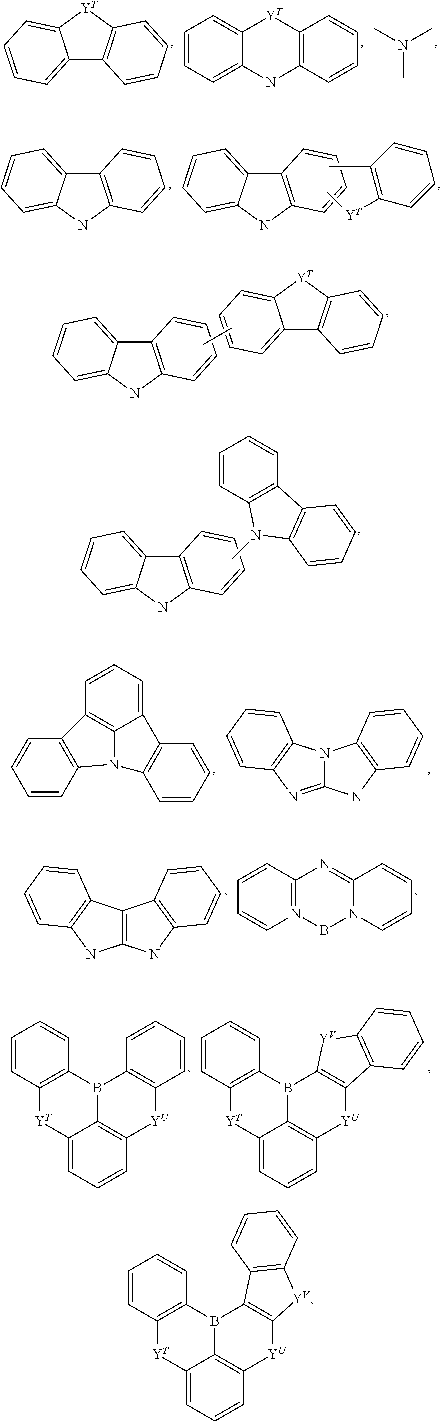

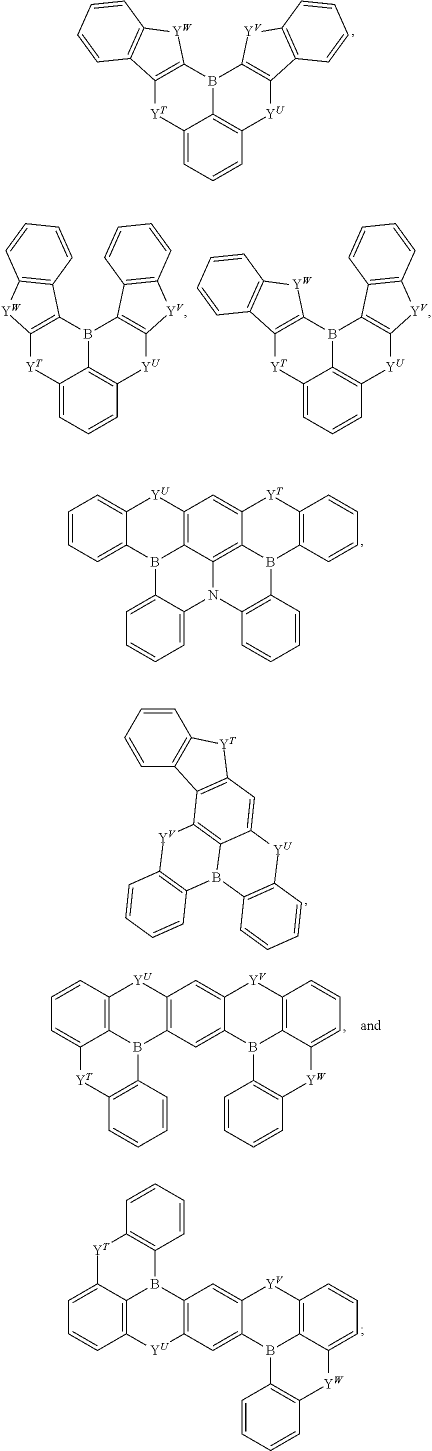

wherein Y^{T}, Y^{U}, Y^{V}, and Y^{W} are each independently selected from the group consisting of B, C, Si, Ge, N, P, O, S, Se, C═O, S═O, and SO₂.

In some of the above embodiments, any carbon ring atoms up to maximum of a total number of three, together with their substituents, in each phenyl ring of any of above structures can be replaced with N.

In some embodiments, the delayed fluorescence material comprises at least one of the acceptor moieties selected from the group consisting of nitrile, isonitrile, borane, fluoride, pyridine, pyrimidine, pyrazine, triazine, aza-carbazole, aza-dibenzothiophene, aza-dibenzofuran, aza-dibenzoselenophene, aza-triphenylene, imidazole, pyrazole, oxazole, thiazole, isoxazole, isothiazole, triazole, thiadiazole, and oxadiazole. In some embodiments, the acceptor moieties and the donor moieties as described herein can be connected directly, through a conjugated linker, or a non-conjugated linker, such as a sp³ carbon or silicon atom.

In some embodiments, the fluorescent material comprises at least one of the chemical moieties selected from the group consisting of:

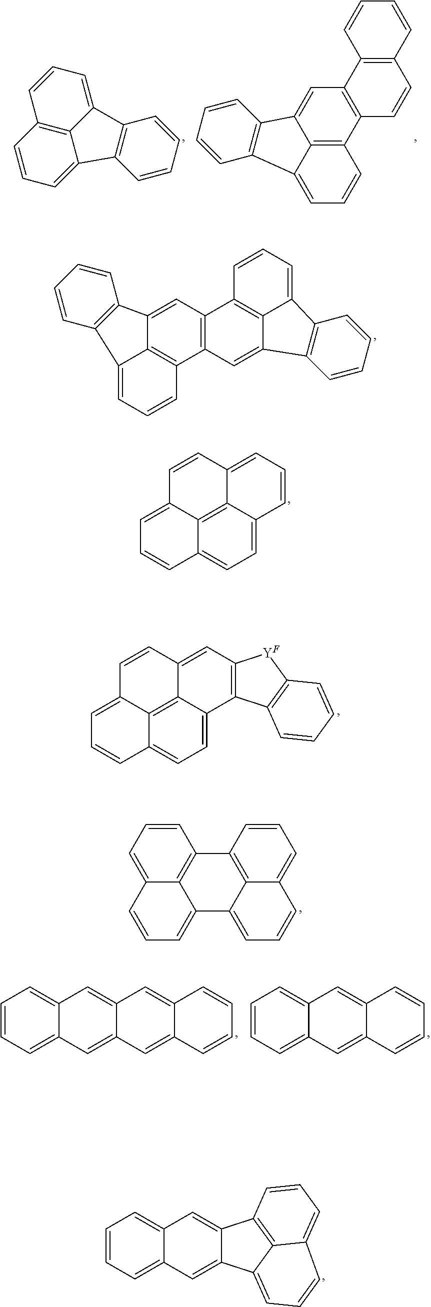

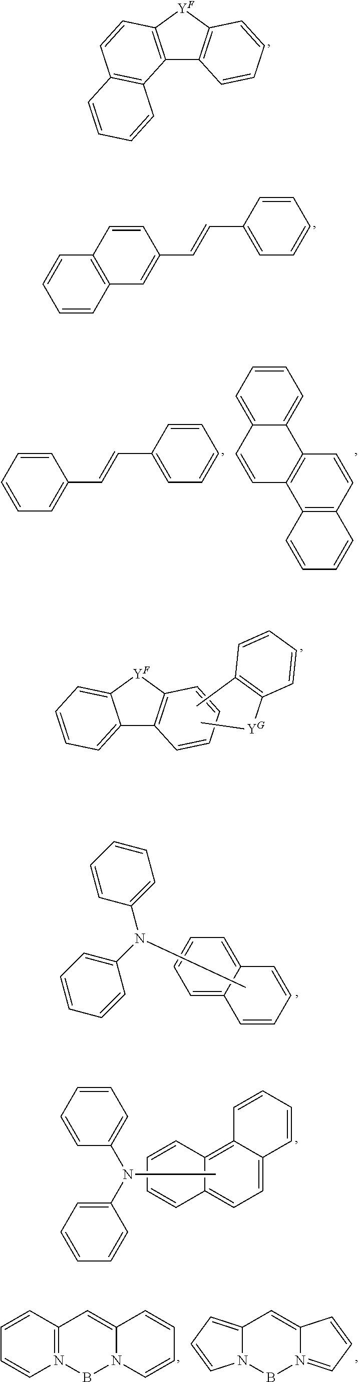

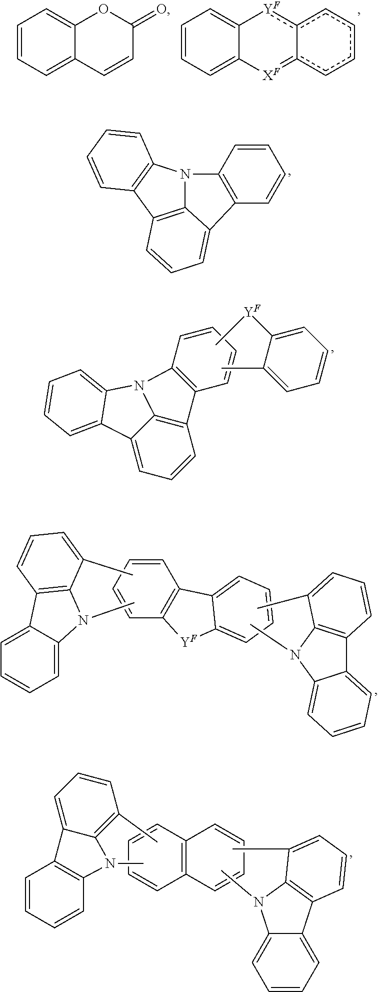

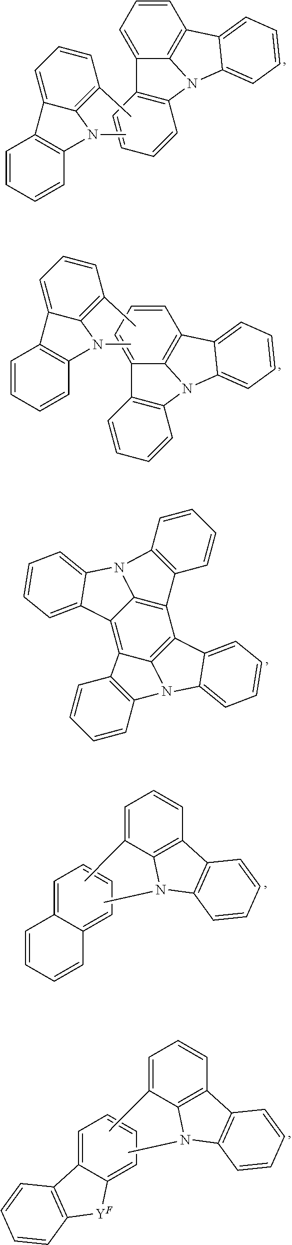

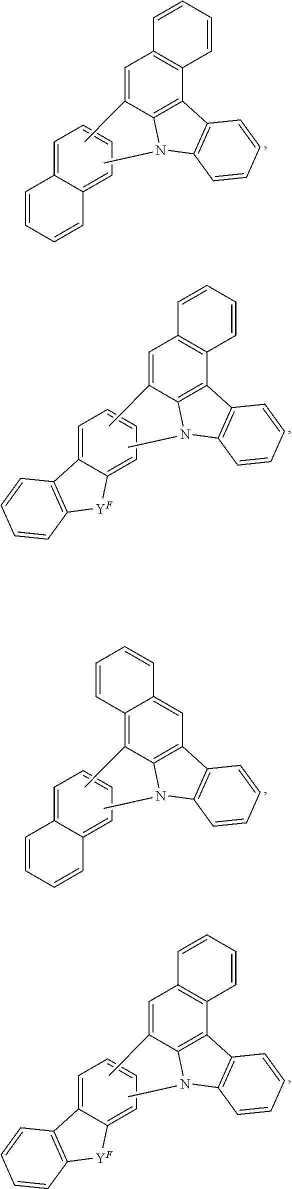

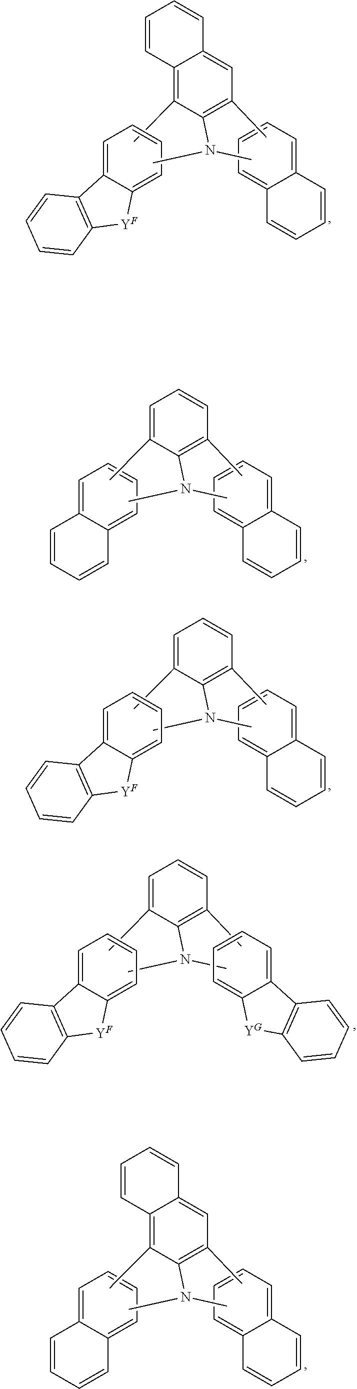

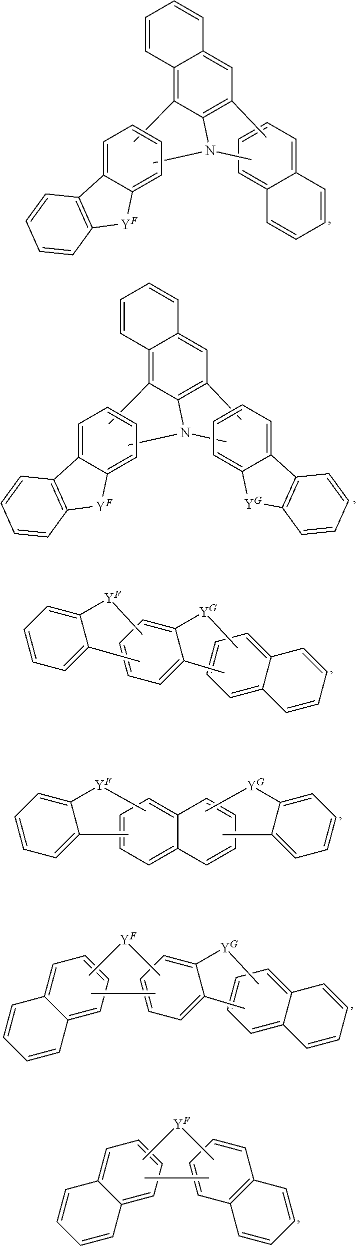

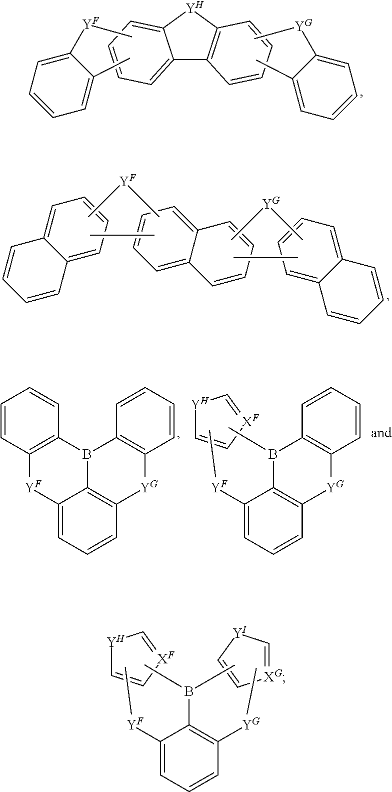

wherein Y^{F} Y^{G}, Y^{H}, and Y^{I} are each independently selected from the group consisting of B, C, Si, Ge, N, P, O, S, Se, C═O, S═O, and SO₂;
wherein X^{F} and X^{G} are each independently selected from the group consisting of C and N.

In some of the above embodiments, any carbon ring atoms up to maximum of a total number of three, together with their substituents, in each phenyl ring of any of above structures can be replaced with N.

### f) HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further away from the vacuum level) and/or higher triplet energy than one or more of the emitters closest to the HBL interface.

In some embodiments, a compound used in the HBL contains the same molecule or the same functional groups used as host described above.

In some embodiments, a compound used in the HBL comprises at least one of the following moieties selected from the group consisting of:

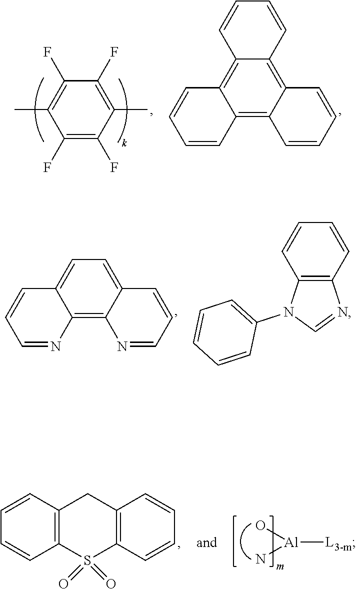

wherein k is an integer from 1 to 20; L¹⁰¹ is another ligand, k′ is an integer from 1 to 3.

### g) ETL:

Electron transport layer (ETL) may include a material capable of transporting electrons. Electron transport layer may be intrinsic (undoped), or doped. Doping may be used to enhance conductivity. Examples of the ETL material are not particularly limited, and any metal complexes or organic compounds may be used as long as they are typically used to transport electrons.

In some embodiments, compound used in ETL comprises at least one of the following moieties in the molecule:

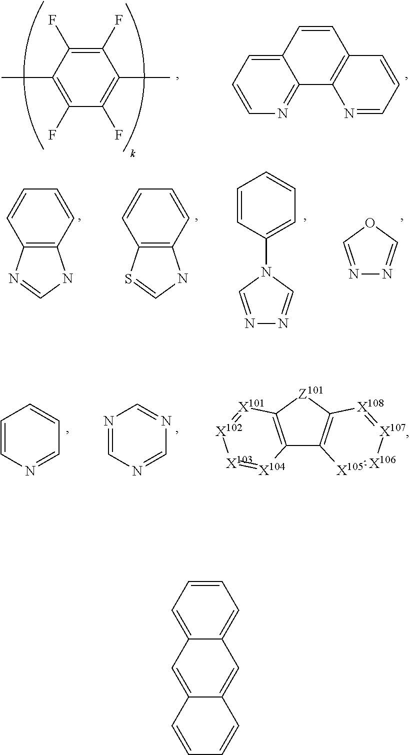

and fullerenes; wherein k is an integer from 1 to 20, X¹⁰¹ to X¹⁰⁸ is selected from C or N; Z¹⁰¹ is selected from the group consisting of C, N, O, and S.

In some embodiments, the metal complexes used in ETL contains, but not limit to the following general formula:

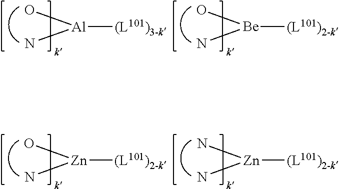

wherein (O—N) or (N—N) is a bidentate ligand, having metal coordinated to atoms O, N or N, N; L¹⁰¹ is another ligand; k′ is an integer value from 1 to the maximum number of ligands that may be attached to the metal.

In some embodiments, the ETL material is selected from the group consisting of anthracene-benzoimidazole compounds, aza triphenylene derivatives, anthracene-benzothiazole compounds, metal 8-hydroxyquinolates, metal hydroxybenoquinolates, bathocuprine compounds, 5-member ring electron deficient heterocycles (e.g., triazole, oxadiazole, imidazole, benzoimidazole), silole compounds, arylborane compounds, fluorinated aromatic compounds, fullerene (e.g., C60), triazine complexes, and Zn (N\hat{ }N) complexes.

### h) Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

In any compounds disclosed herein, the hydrogen atoms can be partially or fully deuterated. The minimum amount of hydrogen of the compound being deuterated is selected from the group consisting of 30%, 40%, 50%, 60%, 70%, 80%, 90%, 95%, 99%, and 100%. As used herein, percent deuteration has its ordinary meaning and includes the percent of all possible hydrogen and deuterium atoms that are replaced by deuterium atoms. In some embodiments, the deuterium atoms are attached to an aromatic ring. In some embodiments, the deuterium atoms are attached to a saturated carbon atom, such as an alkyl or cycloalkyl carbon atom. In some other embodiments, the deuterium atoms are attached to a heteroatom, such as S1, or Ge atom.

It is understood that the various embodiments described herein are by way of example only and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

### E. Experimental Data

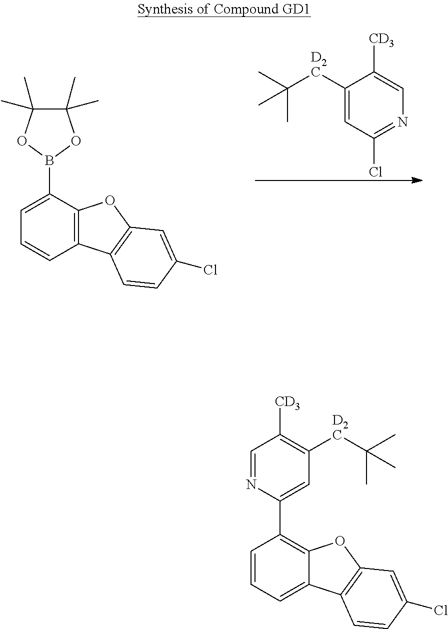

### Synthesis of 2-(7-chlorodibenzo[b,d]furan-4-yl)-4-(2,2-dimethylpropyl-1,1-d2)-5-(methyl-d3)pyridine

To a solution of 2-(7-chlorodibenzo[b,d]furan-4-yl)-4,4,5,5-tetramethyl-1,3,2-dioxaborolane (7.131 g, 1.1 Eq, 21.70 mmol), palladiumtetrakis (912.0 mg, 0.04 Eq, 789.2 μmol), and K2CO3 (5.453 g, 2.00 Eq, 39.46 mmol) in 1,4-Dioxane (73.99 mL) and Water (24.66 mL) was added 2-chloro-4-(2,2-dimethylpropyl-1,1-d2)-5-(methyl-d3)pyridine (4.000 g, 1 Eq, 19.73 mmol). The mixture was degassed by N₂ for 10 minutes, and the reaction was stirred at 95° C. for 16 hour. After cooling to room temperature, the crude material was purified on a silica gel chromatography system, eluting with 10-20% ethyl acetate in heptanes. Fractions containing product were concentrated under reduced pressure. The solid was dried 3 hours in a vacuum oven at 50° C. to give 2-(7-chlorodibenzo[b,d]furan-4-yl)-4-(2,2-dimethylpropyl-1,1-d2)-5-(methyl-d3)pyridine (5.36 g, 74% yield) as a white solid.

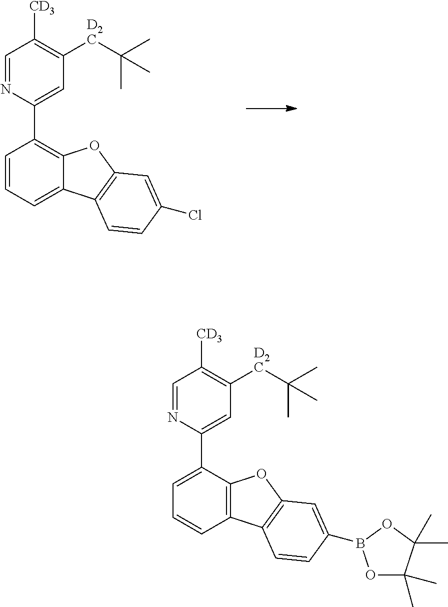

### Synthesis of 4-(2,2-dimethylpropyl-1,1-d2)-5-(methyl-d3)-2-(7-(4,4,5,5-tetramethyl-1,3,2-dioxaborolan-2-yl)dibenzo[b,d]furan-4-yl)pyridine

A solution of 2-(7-chlorodibenzo[b,d]furan-4-yl)-4-(2,2-dimethylpropyl-1,1-d2)-5-(methyl-d3)pyridine (5.160 g, 1 Eq, 13.99 mmol), bis(pinacolato)diborane (5.328 g, 1.5 Eq, 20.98 mmol), XPhos Pd G2 (330.2 mg, 0.03 Eq, 419.6 μmol), and potassium acetate (4.118 g, 2.62 ml, 3 Eq, 41.96 mmol) in 1,4-dioxane (70 ml) was purged with nitrogen for 5 min. The reaction was heated in an oil bath set at 100° C. under nitrogen for 18 hours. After cooling to room temperature, the crude material was purified on a silica gel chromatography system, eluting with 15-25% ethyl acetate in heptanes. Fractions containing product were concentrated under reduced pressure. The solid was dried 3 hours in a vacuum oven at 50° C. to give 4-(2,2-dimethylpropyl-1,1-d2)-5-(methyl-d3)-2-(7-(4,4,5,5-tetramethyl-1,3,2-dioxaborolan-2-yl)dibenzo[b,d]furan-4-yl)pyridine (6.08 g, 94% yield) as a white solid.

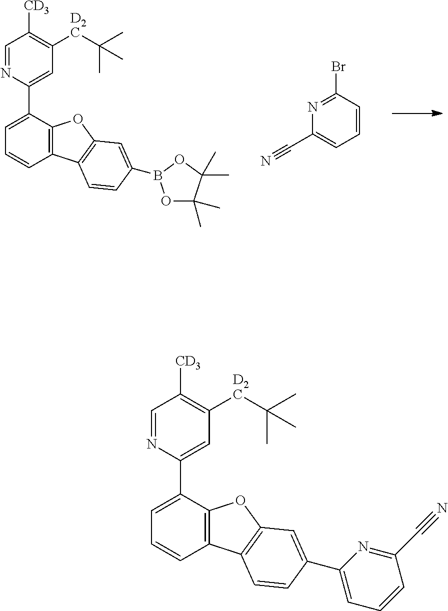

### Synthesis of 6-(6-(4-(2,2-dimethylpropyl-1,1-d2)-5-(methyl-d3)pyridin-2-yl)dibenzo[b,d]furan-3-yl)picolinonitrile

A solution of 4-(2,2-dimethylpropyl-1,1-d2)-5-(methyl-d3)-2-(7-(4,4,5,5-tetramethyl-1,3,2-dioxaborolan-2-yl)dibenzo[b,d]furan-4-yl)pyridine (3.000 g, 1 Eq, 6.516 mmol), 6-bromopicolinonitrile (1.491 g, 1.25 Eq, 8.144 mmol), and tetrakis(triphenylphosphine)palladium(0) (752.9 mg, 0.1 Eq, 651.6 μmol) in 1,4-dioxane (40 mL) in a 250 ml flask was purged with N₂ for 15 min. Potassium carbonate (2.701 g, 1.14 mL, 3 Eq, 19.55 mmol) and water (10 mL) were added. The reaction was heated in an oil bath set at 100° C. under nitrogen for 18 hours. After cooling to room temperature, the crude material was purified on a silica gel chromatography system, eluting with 5-7.5% ethyl acetate in DCM. Fractions containing product were concentrated under reduced pressure. The solid was dried 3 hours in a vacuum oven at 50° C. to give 6-(6-(4-(2,2-dimethylpropyl-1,1-d2)-5-(methyl-d3)pyridin-2-yl)dibenzo[b,d]furan-3-yl)picolinonitrile (2.1 g, 74% yield) as a white solid.

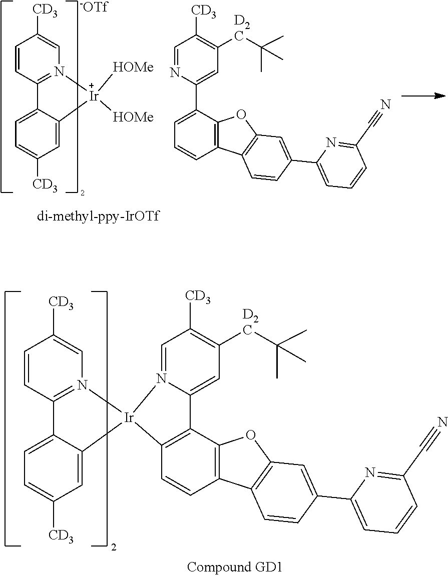

To a solution of di-methyl-ppy-IrOTf (200 mg, 1 Eq, 256 μmol) and 6-(6-(4-(2,2-dimethylpropyl-1,1-d2)-5-(methyl-d3)pyridin-2-yl)dibenzo[b,d]furan-3-yl)picolinonitrile (112 mg, 1 Eq, 256 μmol) in 2-ethoxyethanol (5 ml) was added 2,6-dimethylpyridine (54.8 mg, 59.3 μL, 2 Eq, 512 μmol). The reaction was stirred at 125° C. for a week. After cooling to room temperature, the crude material was purified on a silica gel chromatography system, eluting with 75% toluene in heptanes. Fractions containing product were concentrated under reduced pressure. The solid was dried 3 hours in a vacuum oven at 50° C. to give Compound GD1 (60 mg, 23% yield) as a yellow solid.

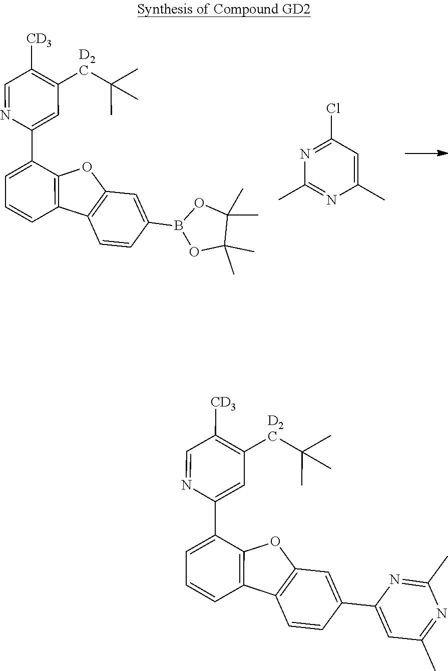

### Synthesis of 4-(6-(4-(2,2-dimethylpropyl-1,1-d2)-5-(methyl-d3)pyridin-2-yl)dibenzo[b,d]furan-3-yl)-2,6-dimethylpyrimidine

A solution of 4-(2,2-dimethylpropyl-1,1-d2)-5-(methyl-d3)-2-(7-(4,4,5,5-tetramethyl-1,3,2-dioxaborolan-2-yl)dibenzo[b,d]furan-4-yl)pyridine (1.900 g, 1 Eq, 4.126 mmol), 4-chloro-2,6-dimethylpyrimidine (794.3 mg, 1.35 Eq, 5.571 mmol), and tetrakis(triphenylphosphine)palladium(0) (250.0 mg, 0.05243 Eq, 216.3 μmol) in 1,4-dioxane (100 ml) in a 250 ml flask was purged with N₂ for 15 min. Potassium carbonate (1.711 g, 3 Eq, 12.38 mmol) and water (10 mL) were added. The reaction was heated in an oil bath set at 90° C. under nitrogen for 24 hours. After cooling to room temperature, the crude material was purified on a silica gel chromatography system, eluting with 2.5-30% THF, 20% DCM in heptanes. Fractions containing product were concentrated under reduced pressure. The solid was dried 3 hours in a vacuum oven at 50° C. to give 4-(6-(4-(2,2-dimethylpropyl-1,1-d2)-5-(methyl-d3)pyridin-2-yl)dibenzo[b,d]furan-3-yl)-2,6-dimethylpyrimidine (1.1 g, 61% yield) as a white solid.

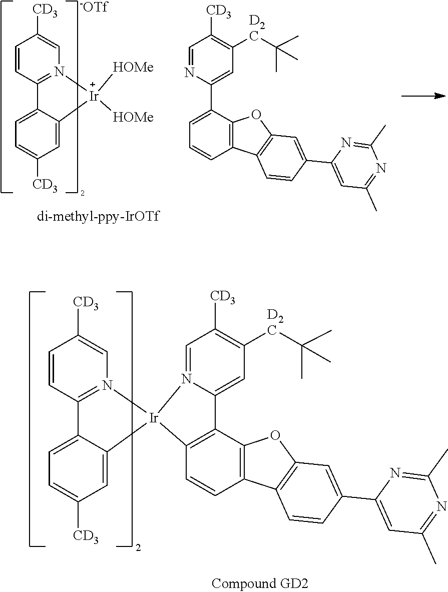

To a solution of di-methyl-ppy-IrOTf (1.861 g, 1.05 Eq, 2.383 mmol), 4-(6-(4-(2,2-dimethylpropyl-1,1-d2)-5-(methyl-d3)pyridin-2-yl)dibenzo[b,d]furan-3-yl)-2,6-dimethylpyrimidine (1.000 g, 1 Eq, 2.270 mmol) in 2-ethoxyethanol (70 ml) was added 2,6-dimethylpyridine (500.0 mg, 2.056 Eq, 4.666 mmol). The reaction was stirred at 115° C. for 2 days. After cooling to room temperature, the crude material was purified on a silica gel chromatography system, eluting with 1-20% ethyl acetate in toluene. Fractions containing product were concentrated under reduced pressure. The solid was dried 3 hours in a vacuum oven at 50° C. to give Compound GD2 (0.68 g, 30% yield) as a yellow solid.

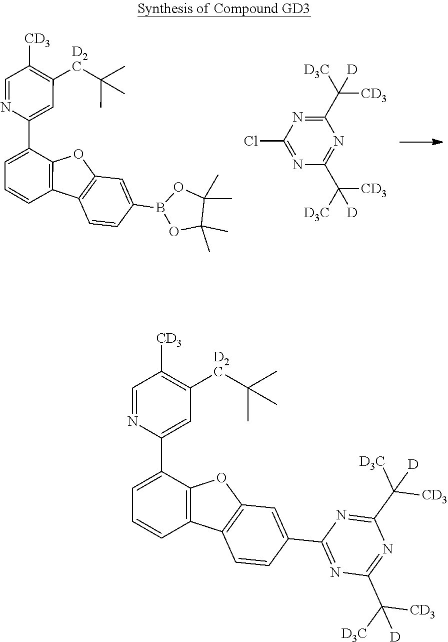

### Synthesis of 2-(6-(4-(2,2-dimethylpropyl-1,1-d2)-5-(methyl-d3)pyridin-2-yl)dibenzo[b,d]furan-3-yl)-4,6-bis(propan-2-yl-d7)-1,3,5-triazine

A solution of 4-(2,2-dimethylpropyl-1,1-d2)-5-(methyl-d3)-2-(7-(4,4,5,5-tetramethyl-1,3,2-dioxaborolan-2-yl)dibenzo[b,d]furan-4-yl)pyridine (1.750 g, 1 Eq, 3.801 mmol), 2-chloro-4,6-bis(propan-2-yl-d7)-1,3,5-triazine (1.000 g, 1.231 Eq, 4.678 mmol), and tetrakis(triphenylphosphine)palladium(0) (175.7 mg, 0.04 Eq, 152.0 μmol) in 1,4-dioxane (140 ml) in a 250 ml flask was purged with N₂ for 15 min. Potassium carbonate (1.576 g, 3 Eq, 11.40 mmol) and water (20 ml) were added. The reaction was heated in an oil bath set at 100° C. under nitrogen for 24 hours. After cooling to room temperature, the crude material was purified on a silica gel chromatography system, eluting with 2-20% ethyl acetate, 20% DCM in heptanes. Fractions containing product were concentrated under reduced pressure. The solid was dried 3 hours in a vacuum oven at 50° C. to give 2-(6-(4-(2,2-dimethylpropyl-1,1-d2)-5-(methyl-d3)pyridin-2-yl)dibenzo[b,d]furan-3-yl)-4,6-bis(propan-2-yl-d7)-1,3,5-triazine (1.5 g, 75% yield) as a white solid.

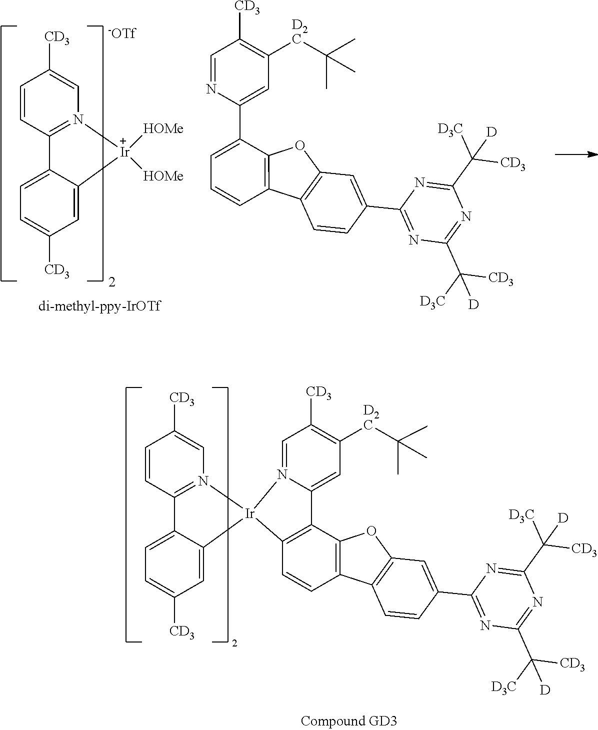

To a solution of di-methyl-ppy-IrOTf (2.655 g, 1.2 Eq, 3.400 mmol), 2-(6-(4-(2,2-dimethylpropyl-1,1-d2)-5-(methyl-d3)pyridin-2-yl)dibenzo[b,d]furan-3-yl)-4,6-bis(propan-2-yl-d7)-1,3,5-triazine (1.450 g, 1 Eq, 2.833 mmol) in 2-ethoxyethanol (80 mL) was added 2,6-dimethylpyridine (1.214 g, 4 Eq, 11.33 mmol). The reaction was stirred at 90° C. for 2 days. After cooling to room temperature, the crude material was purified on a silica gel chromatography system, eluting with 2-4% acetone, 30% toluene in heptanes. Fractions containing product were concentrated under reduced pressure. The solid was dried 3 hours in a vacuum oven at 50° C. to give Compound GD3 (0.57 g, 19% yield) as a yellow solid.

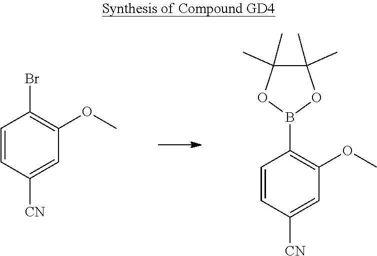

In a 1000 mL round bottom flask, 1,4-dioxane (400.0 ml) was bubbled vigorously with nitrogen for 10 minutes. 2-Bromo-5-cyanoanisole (40.00 g, 98% Wt, 1 Eq, 184.9 mmol), Bis(pinacolato)diborane (52.59 g, 99% Wt, 1.109 Eq, 205.0 mmol), PdCl₂(dppf) (6.860 g, 95% Wt, 0.04818 Eq, 8.907 mmol) and potassium acetate (92.26 g, 99.7% Wt, 5.070 Eq, 937.3 mmol) were added to degassed dioxane and again degassed with nitrogen for 10 minutes. The reaction mass was heated at 80° C. for 16 h. Dioxane was removed completely under reduced pressure and the residue was diluted with EtOAc (100 ml) and water (100 mL). The phases were separated, the aqueous layer was additionally extracted twice with EtOAc (50 mL). The combined organic extract was washed with saturated brine (20-30 mL), and dried with sodium sulphate. The drying agent was filtered off, and the filtrates were concentrated under vacuum at 45° C. to yield brown colored solid. The crude product was dissolved in dichloromethane, loaded onto a silica gel column and eluted with 100% heptanes to 23% EtOAc/heptanes. 3-methoxy-4-(4,4,5,5-tetramethyl-1,3,2-dioxaborolan-2-yl)benzonitrile was obtained as an off-white solid, 47.88 g (68%).

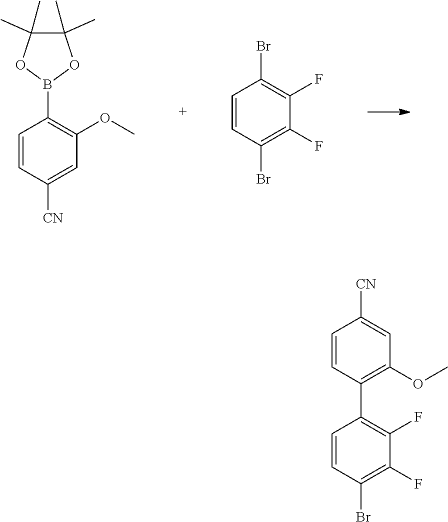

A representative procedure: In a 500 mL round bottom flask, a mixture of 1,4-dioxane (145.0 ml) and water (36.20 ml) was bubbled vigorously with nitrogen for 10 minutes. Then 3-methoxy-4-(4,4,5,5-tetramethyl-1,3,2-dioxaborolan-2-yl)benzonitrile (47.88 g, 1 Eq, 125.7 mmol), 1,4-dibromo-2,3-difluorobenzene (45.39 g, 1.302 Eq, 163.6 mmol), sodium carbonate (29.50 g, 2.204 Eq, 276.9 mmol), and 1,1′-bis(diphenylphosphino)ferrocene-palladium(II) dichloride (3.381 g, 0.03493 Eq, 4.389 mmol) were added together in one portion. The headspace of the flask was purged with nitrogen for a few minutes, and the reaction mixture stirred vigorously at 80° C. overnight. Dioxane was removed under reduced pressure. The residue was diluted with water (100 mL) and dichloromethane (100 mL). The phases were separated, the aqueous layer was additionally extracted twice with dichloromethane (50 mL), and the combined organic layer was dried with sodium sulphate. The drying agent was filtered off, and the filtrates were concentrated under vacuum at 45° C. to yield brown colored solid. The crude product was dissolved in dichloromethane, loaded onto a silica gel column and eluted with EtOAc and heptanes to yield 4′-bromo-2′,3′-difluoro-2-methoxy-[1,1′-biphenyl]-4-carbonitrile as a white fluffy solid, 23 g (54%).

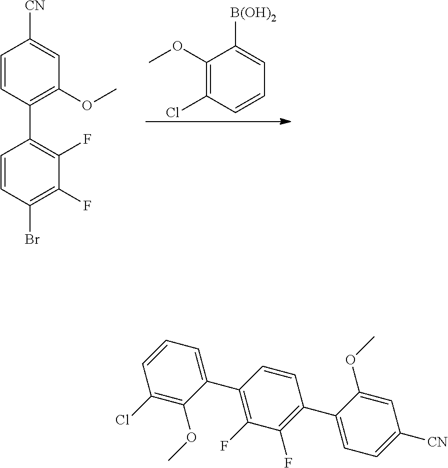

In a 500 mL round bottom flask, a mixture of 1,4-dioxane (77.00 mL) and water (39.00 mL) was bubbled vigorously with nitrogen for 10 minutes. Then (3-chloro-2-methoxyphenyl)boronic acid (19.44 g, 1.5 Eq, 102.2 mmol), 4′-bromo-2′,3′-difluoro-2-methoxy-[1,1′-biphenyl]-4-carbonitrile (23.00 g, 1 Eq, 68.12 mmol), sodium carbonate (22.06 g, 3.04 Eq, 207.1 mmol), and 1,1′-bis(diphenylphosphino)ferrocene-palladium(II) dichloride (2.623 g, 0.05 Eq, 3.406 mmol) were added together in one portion. The headspace of the flask was purged with nitrogen for a few minutes, and the reaction mixture stirred vigorously at 80° C. overnight. Dioxane was removed under reduced pressure. The residue was diluted with water (100 mL) and dichloromethane (100 mL). The phases were separated, the aqueous layer was additionally extracted twice with dichloromethane (50 mL), and the combined organic layer was dried with sodium sulphate. The drying agent was filtered off, and the filtrates were concentrated under vacuum at 45° C. to give a brown colored solid. The crude material was purified by column chromatography eluting with EtOAc and heptanes to yield the product 3″-chloro-2′,3′-difluoro-2,2″-dimethoxy-[1,1′:4′,1″-terphenyl]-4-carbonitrile as an off-white solid, 24 g (89%).

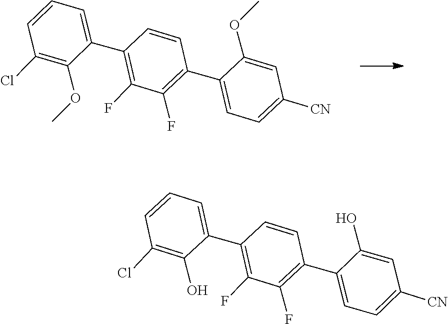 [SMILES: COc1cc(C#N)ccc1-c1ccc(-c2cccc(Cl)c2OC)c(F)c1F ; N#Cc1ccc(-c2ccc(-c3cccc(Cl)c3O)c(F)c2F)c(O)c1]

In a 2 L three-neck round bottom flask equipped with a septum, a solution of 3″-chloro-2′,3′-difluoro-2,2″-dimethoxy-[1,1′:4′,1″-terphenyl]-4-carbonitrile (10.00 g, 1.0 Eq, 25.14 mmol) in anhydrous dichloromethane (50 mL) was prepared under nitrogen and cooled to −75° C. in a dry ice-acetone bath. Neat boron tribromide (66.20 g, 25.5 mL, 10.5 Eq, 264.0 mmol) was added dropwise to yield a clear yellow colored solution. A nitrogen balloon was attached, and the mixture was stirred allowing to warm up slowly to room temperature for overall 24 h. The mixture was cooled in a dry ice/acetone bath and then carefully quenched with MeOH (36 mL). Then the cooling bath was removed, and saturated aq. NaHCO₃ (˜1000 mL) was added dropwise, cooling in a water. After a brief stirring, EtOAc (300 mL) was added, and two clear phases were separated. The aqueous layer was extracted twice with EtOAc (100 mL), and the combined organic extract was dried with Na₂SO₄. The drying agent was filtered off, and the filtrates were concentrated under vacuum at 45° C. to give a crude dark brown solid. The crude solid product was combined with another lot of material prepared the same way and purified by column chromatography to yield 3″-chloro-2′,3′-difluoro-2,2″-dihydroxy-[1,1′:4′,1″-terphenyl]-4-carbonitrile 19.37 g (quantitative yield).

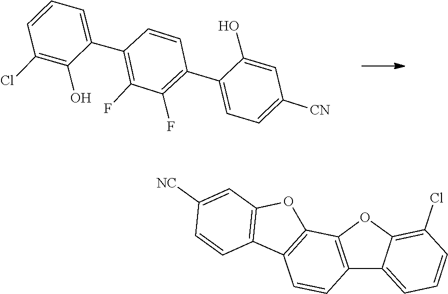 [SMILES: N#Cc1ccc(-c2ccc(-c3cccc(Cl)c3O)c(F)c2F)c(O)c1 ; N#Cc1ccc2c(c1)oc1c2ccc2c3cccc(Cl)c3oc21]

In a 500 mL round bottom flask 3″-chloro-2′,3′-difluoro-2,2″-dihydroxy-[1,1′:4′,1″-terphenyl]-4-carbonitrile (13.65 g, 1 Eq, 36.63 mmol) and potassium carbonate (15.87 g, 3.12 Eq, 114.3 mmol) were added to NMP (55 mL) to give a yellow-colored solution. The resulting mixture was stirred for 6 h at 130° C. The reaction mixture was diluted with 20 mL of ethyl acetate and the resulting precipitate was filtered. The precipitate was washed each with 20 mL of water, ethanol and heptanes to produce 18-chloro-3,20-dioxapentacyclo[11.7.0.02,10.04,9.014,19]icosa-1,4(9),5,7,10,12,14,16,18-nonaene-6-carbonitrile as an off-white solid, 11 g (94%).

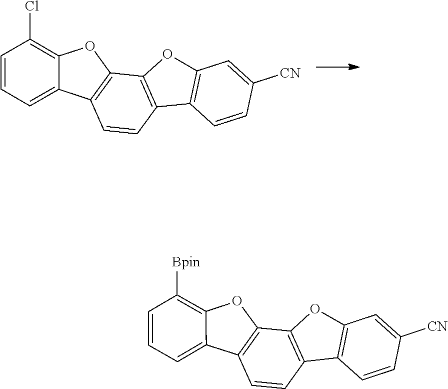

A mixture of 18-chloro-3,20-dioxapentacyclo[11.7.0.02,10.04,9.014,19]icosa-1,4(9),5,7,10,12,14,16,18-nonaene-6-carbonitrile (2.00 g, 6.29 mmol), Bis(pinacolato)diboron (2.40 g, 9.44 mmol), Potassium acetate (1.24 g, 12.6 mmol), 2-(Dicyclohexylphosphino)-2′,4′,6′-tri-isopropyl-1,1′-biphenyl (XPhos) (0.60 g, 1.26 mmol) and 1,4-dioxane (60 mL) was sparged with nitrogen for 10 minutes. XPhos Pd G3 (0.53 g, 0.629 mmol) was added and the mixture sparged with nitrogen for a further five minutes. The reaction mixture was then heated at 100° C. for 2 hours. The reaction mixture was diluted with EtOAc (200 mL) then passed through a phase separator. The organics were washed with water (100 ml) and brine (100 mL), dried (MgSO₄), filtered and evaporated to dryness. The solid obtained was washed with a mixture of pentane/Et₂O (10:1, 30 ml) then dried under vacuum at 40° C. to give 18-(4,4,5,5-tetramethyl-1,3,2-dioxaborolan-2-yl)-3,20-dioxapentacyclo[11.7.0.02,10.04,9.014,19]icosa-1,4,6,8,10,12,14,16,18-nonaene-6-carbonitrile (2.10 g, 4.11 mmol, 65.22%) as a grey solid.

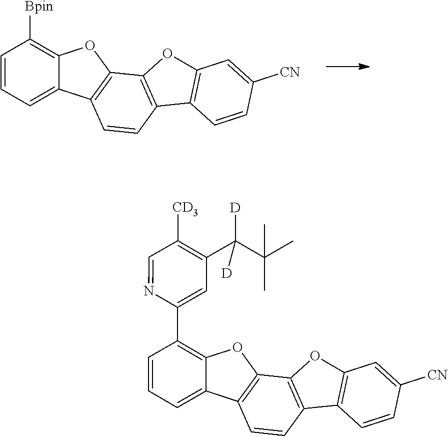

A mixture of 18-(4,4,5,5-tetramethyl-1,3,2-dioxaborolan-2-yl)-3,20-dioxapentacyclo[11.7.0.02,10.04,9.014,19]icosa-1,4,6,8,10,12,14,16,18-nonaene-6-carbonitrile (2.10 g, 5.13 mmol), 6-chloro-2-(1,1-dideuterio-2,2-dimethyl-propyl)-3-(trideuteriomethyl)pyridine (1.04 g, 5.13 mmol), cesium carbonate (4.18 g, 12.8 mmol), 1,4-dioxane (50 mL) and water (10 mL) was sparged with nitrogen for 10 minutes. XPhos Pd G3 (0.22 g, 0.257 mmol) was added and the mixture sparged for a further 5 minutes before heating at 90° C. for 2 hours. The cooled reaction mixture was filtered and the collected grey solid re-dissolved in DCM (100 mL), washed with water/brine (100 mL), passed through a phase separator, and evaporated to give an off-white solid. This was purified by column chromatography in DCM and hexanes then recrystallized from isopropyl alcohol to give 18-[4-(1,1-dideuterio-2,2-dimethyl-propyl)-5-(trideuteriomethyl)-2-pyridyl]-3,20-dioxapentacyclo[11.7.0.02,10.04,9.014,19]icosa-1,4,6,8,10,12,14,16,18-nonaene-6-carbonitrile (1.39 g, 3.09 mmol, 60.23%) as a white solid.

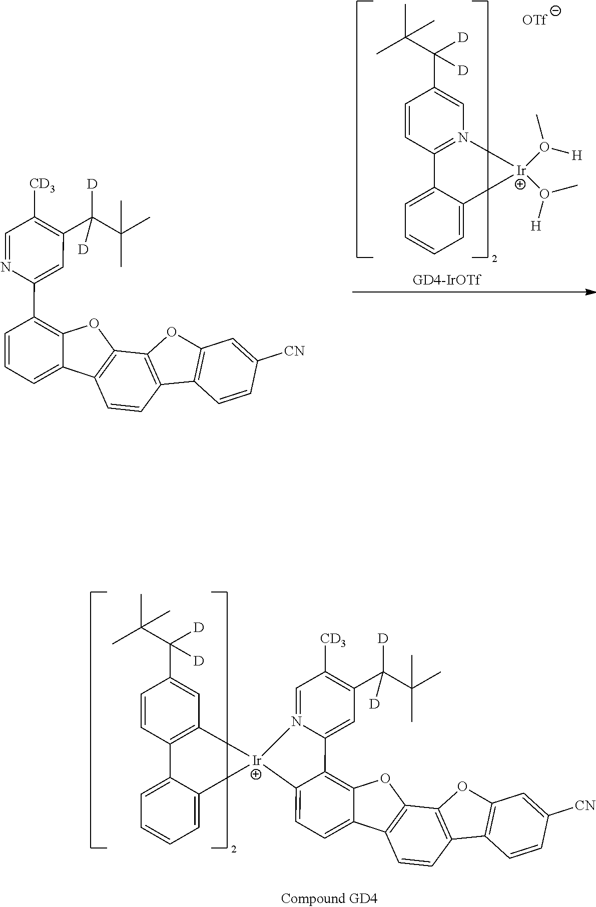

One 100 ml RBF was charged with GD4-IrOTf (3.817 g, 1 Eq, 4.449 mmol), 18-[4-(1,1-dideuterio-2,2-dimethyl-propyl)-5-(trideuteriomethyl)-2-pyridyl]-3,20-dioxapentacyclo[11.7.0.02,10.04,9.014,19]icosa-1,4,6,8,10,12,14,16,18-nonaene-6-carbonitrile (2.000 g, 1 Eq, 4.449 mmol), 2,6-dimethylpyridine (953.5 mg, 2 Eq, 8.898 mmol) and 2-ethoxyethanol (50.00 mL) heat to 100° C. for 200 hrs. The crude product was purified by column chromatography to give Compound GD4, 2.18 g (47.1%).

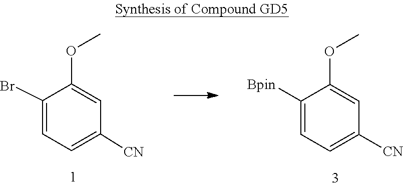

A 1 L round-bottom flask containing 1,4-dioxane (450 mL) was degassed with nitrogen for 15 minutes. 1 (62.5 g, 295 mmol), bis(pinacolato)diborane (82.3 g, 324 mmol), potassium acetate (145 g, 1.47 mol) and PdCl₂(dppf)-CH₂Cl₂ adduct (12.0 g, 14.7 mmol) were then added, the headspace was repurged, and the mixture was heated in an 80° C. oil bath overnight. The reaction was cooled and diluted with EtOAc (600 mL) and water (600 mL). The mixture was stirred and filtered through a Celite bed, and the bed was washed with EtOAc (100 mL). The layers were separated, and the organic layer was washed with water (5×300 mL), dried (MgSO₄), filtered and stripped to give the crude product. The crude was dissolved in a minimum of DCM and filtered through a silica gel bed (2.5 L) in a sintered glass funnel, eluting with 35% EtOAc in heptanes to give 3 as a yellow solid (42 g, 61% yield) which was used in the next step as is.

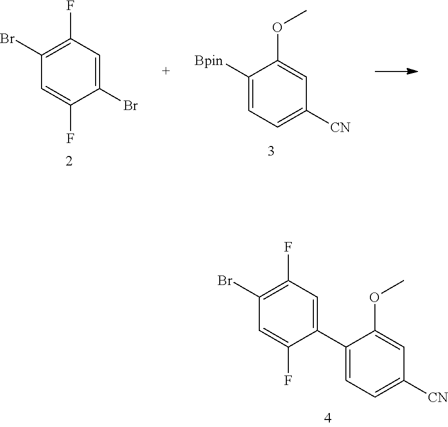

A 1 L round-bottom flask containing 1,4-dioxane (200 mL) and water (65 mL) was degassed with nitrogen for 15 minutes. 2 (84.4 g, 311 mmol), 3 (61.9 g, 239 mmol), sodium carbonate (55.7 g, 526 mmol) and PdCl₂(dppf)-CH₂Cl₂ adduct (9.76 g, 11.9 mmol) were then added, the headspace was repurged, and the mixture was heated in an 80° C. oil bath overnight. The reaction was cooled and diluted with EtOAc (500 mL) and water (500 mL). The mixture was filtered through a Celite bed, and the bed was washed with EtOAc (300 mL). The layers were separated, and the organic layer was washed with water (3×200 mL), dried (MgSO₄), filtered and stripped to give the crude product. The crude was absorbed onto silica (using DCM) and applied to a bed of 3.5 L of silica gel in a sintered glass funnel, eluting with 15% EtOAc in heptanes to give 4 as a yellow solid (26.5 g, 34% yield).

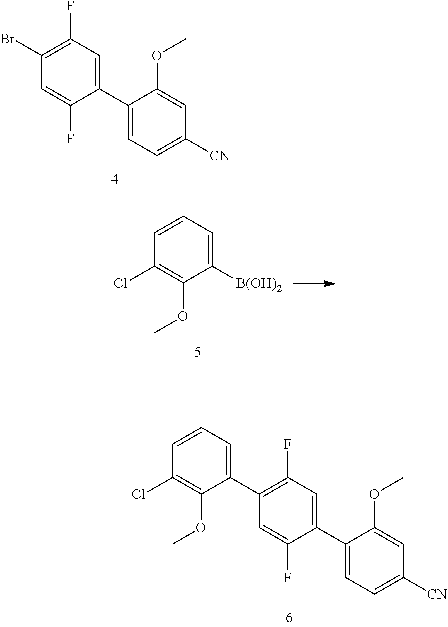 [SMILES: COc1cc(C#N)ccc1-c1cc(F)c(Br)cc1F ; COc1c(Cl)cccc1B(O)O ; COc1cc(C#N)ccc1-c1cc(F)c(-c2cccc(Cl)c2OC)cc1F]

A 2 L round-bottom flask containing 1,4-dioxane (540 mL) and water (270 mL) was degassed with nitrogen for 15 minutes. 5 (29.9 g, 160 mmol), 4 (40.0 g, 123 mmol), sodium carbonate (39.2 g, 370 mmol) and PdCl₂(dppf)-CH₂Cl₂ adduct (5.04 g, 6.17 mmol) were then added, the headspace was repurged, and the mixture was heated in an 80° C. oil bath overnight with mechanical stirring. The reaction was cooled, and DCM (2 L) and water (500 mL) were added. The layers were separated, and the organic layer was washed with water (4×300 mL). The organic layer was dried (MgSO₄), filtered and concentrated to give the crude product. The crude was absorbed onto silica and applied to a bed of 3.5 L of silica gel in a sintered glass funnel, eluting with 40 to 80% DCM in heptanes to give a solid. This material was recrystallized from a minimum of boiling ethyl acetate (˜10 mL/gram) and heptanes (an equal amount), allowing it to cool overnight. The solid was filtered and dried to give 6 as a white solid (40.5 g, 85% yield).

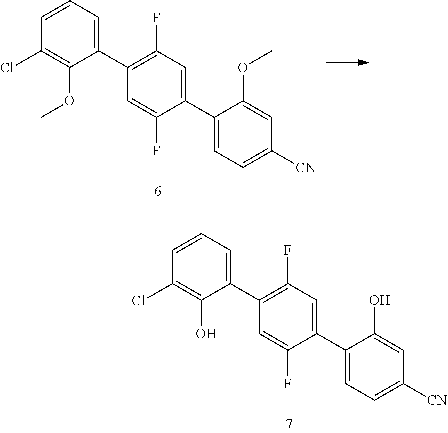 [SMILES: COc1cc(C#N)ccc1-c1cc(F)c(-c2cccc(Cl)c2OC)cc1F ; N#Cc1ccc(-c2cc(F)c(-c3cccc(Cl)c3O)cc2F)c(O)c1]

To a cooled (ice bath) mixture of 3″-chloro-2′,5′-difluoro-2,2″-dimethoxy-[1,1′:4′,1″-terphenyl]-4-carbonitrile 6 (48.0 g, 124 mmol) and DCM (280 mL) in a 1 L flask was slowly added BBr₃ (118 mL, 1.24 mol) to give a clear yellow solution, which was stirred in the ice bath for 1 hour, then allowed to warm to room temperature overnight. The reaction was quenched by adding dropwise to a bucket containing ice, adding more ice as needed. The mixture was then brought to pH˜3 using concentrated NaOH, then to pH˜7 using saturated NaHCO₃. EtOAc (3 L) was then added, and the layers were separated. The aqueous layer was extracted with ethyl acetate (500 mL). The combined organic layers were washed with water (3×500 mL), dried (MgSO₄), filtered and evaporated to give the crude product. The crude was purified by preabsorbing onto silica gel (using MeOH) and eluted through a silica gel bed (2 L) using 0 to 15% EtOAc in DCM as eluent to give 7 as a light yellow solid (35.5 g, 78% yield).

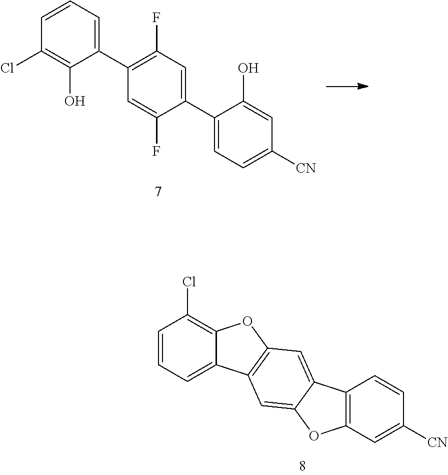 [SMILES: N#Cc1ccc(-c2cc(F)c(-c3cccc(Cl)c3O)cc2F)c(O)c1 ; N#Cc1ccc2c(c1)oc1cc3c(cc12)oc1c(Cl)cccc13]

To a 1 L round-bottom flask containing 7 (35.5 g, 99.23 mmol) was added NMP (525 mL) and potassium carbonate (41.1 g, 298 mmol) and the mixture was heated in a 170° C. oil bath overnight. The reaction was cooled and EtOAc (500 mL) was added. A precipitate formed, and the mixture was stirred for 1 hour. The solids were filtered and washed with EtOAc (100 mL), then with water (2×500 mL). The solids were transferred to a round-bottomed flask and stirred with water (500 mL) overnight. The solids were filtered and washed again with water until washes are neutral (˜750 mL). The solids were washed with EtOH (500 mL) and heptanes (300 mL) and dried to give desired product as a grey solid, (22.0 g, 69%) which was used as is in the following step.

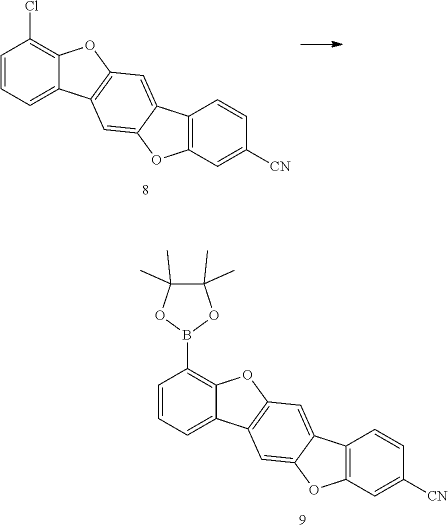 [SMILES: N#Cc1ccc2c(c1)oc1cc3c(cc12)oc1c(Cl)cccc13 ; CC1(C)OB(c2cccc3c2oc2cc4c(cc23)oc2cc(C#N)ccc24)OC1(C)C]

A 250 mL round-bottom flask containing 1,4-dioxane (52 mL) was degassed for 20 minutes. To the flask was added 8 (3.00 g, 9.44 mmol), bis(pinacolato)diborane (2.88 g, 11.3 mmol), potassium acetate (2.78 g, 28.3 mmol), tris(dibenzylideneacetone)dipalladium (432 mg, 472 μmol) and XPhos (900. mg, 1.89 mmol), and the headspace was repurged with nitrogen and the reaction was heated in a 100° C. oil bath overnight. The reaction was filtered hot through a Celite bed, and the bed was washed with hot 1,2-dichloroethane (100 mL) and DCM (100 mL). The filtrate was washed with water (2×50 mL), and the organic layer was dried (MgSO₄), filtered and evaporated to give an orange oil. The oil was taken up in ethyl acetate (10 mL) and heptanes (10 mL) was added. A precipitate formed, which was filtered and washed with heptanes to give 9 as a light orange solid, (3.48 g, 90%). This material was used as is in the next step.

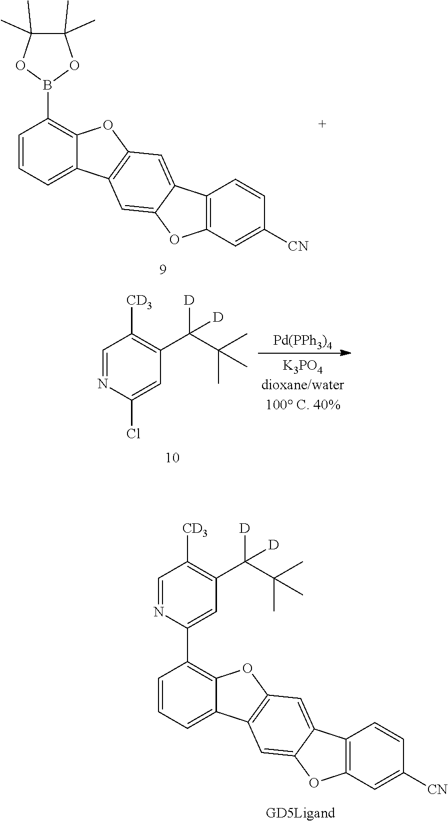 [SMILES: CC1(C)OB(c2cccc3c2oc2cc4c(cc23)oc2cc(C#N)ccc24)OC1(C)C ; [2H]C([2H])([2H])c1cnc(Cl)cc1C([2H])([2H])C(C)(C)C ; [2H]C([2H])([2H])c1cnc(-c2cccc3c2oc2cc4c(cc23)oc2cc(C#N)ccc24)cc1C([2H])([2H])C(C)(C)C ; "Pd(PPh3)4"]

A 500 mL round-bottom flask containing water (18.1 mL) and 1,4-dioxane (100 mL) was degassed for 20 minutes. The degassed solvent was added to a 500 mL round-bottom flask containing 9 (3.48 g, 8.50 mmol), and then 2-chloro-5-(2,2-dimethylpropyl-1,1-d₂)-4-(methyl-d₃)pyridine 10 (1.38 g, 6.80 mmol), potassium phosphate (5.42 g, 25.5 mmol) and tetrakis(triphenylphosphine)palladium(0) (491 mg, 425 μmol) were added. The headspace was repurged and heated in a 100° C. oil bath overnight. The mixture was cooled and diluted with EtOAc (450 mL) and water (150 mL), and the resulting mixture was stirred for 2 hours, during which time all solids dissolved. The layers were separated, and the organic layer was washed with water (2×100 mL). The organic layer was dried (MgSO₄), filtered and evaporated to give crude product. The crude was chromatographed by preabsorbing onto silica gel (using DCM) and eluting with 0 to 5% THF in DCM to give ligand as a light yellow solid. This material was recrystallized by dissolving in 35 mL/gram of boiling dichloroethane, then adding 35 mL/gram EtOAc and allowing to cool to room temperature overnight. The precipitate was filtered and dried to give GD5 Ligand as a white solid (1.53 g, 40% yield).

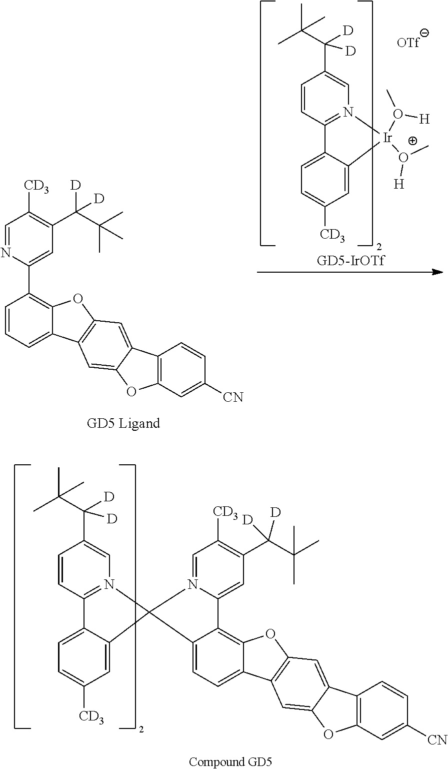

One 250 ml RBF was charged with GD %-IrOTf (2.601 g, 1.0 Eq, 2.915 mmol), GD5 Ligand (1.150 g, 1 Eq, 2.915 mmol), 2,6-dimethylpyridine (624.8 mg, 2 Eq, 5.831 mmol), 2-ethoxyethanol (50.00 mL). The reaction was heated to 100° C. for 4 days. Reaction mixture was evaporated to dryness and subject to column chromatography eluting with toluene and heptanes to yield Compound GD5 (1.32 g, 42%).

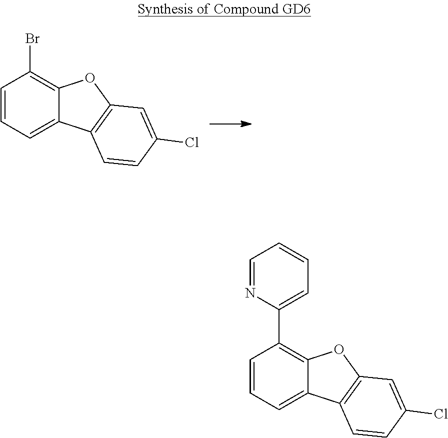 [SMILES: Clc1ccc2c(c1)oc1c(Br)cccc12 ; Clc1ccc2c(c1)oc1c(-c3ccccn3)cccc12]

To an oven-dried 300 mL 3-neck round-bottomed flask (RBF) fitted with a reflux condenser and charged with a stir bar, 1,4-Dioxane (88.80 mL) was added via syringe. The solvent was degassed via N₂ bubbling through a needle with an outlet in the rubber septum for 5 minutes. 6-bromo-3-chlorodibenzo[b,d]furan (5.000 g, 1 Eq, 17.76 mmol) was then added to the to the reaction vessel and allowed to dissolve over 5 minutes. Tetrakis(triphenylphosphine) Palladium(0) (1.026 g, 0.05 Eq, 888.0 μmol) was then added and the solution was degassed for an additional 15 minutes under N2 bubbling. Finally, pyridin-2-ylzinc(II) bromide (4.562 g, 40.85 mL, 0.500 molar, 1.15 Eq, 20.42 mmol) was added slowly to the reaction via syringe, then the reaction was heated to 60° C. under N2. After heating the reaction was cooled too room temperature then diluted with 100 mL of DCM and extracted 3 times with saturated NH₄Cl aq., dried over Na₂SO₄ then concentrated under reduce pressure. The crude product was purified on silica gel eluting with a DCM, heptane, ethyl acetate mixture. The pure product was concentrated under reduced pressure and dried under vacuum to yield a white powder (2.10 g, 17.6 mmol, 42%).

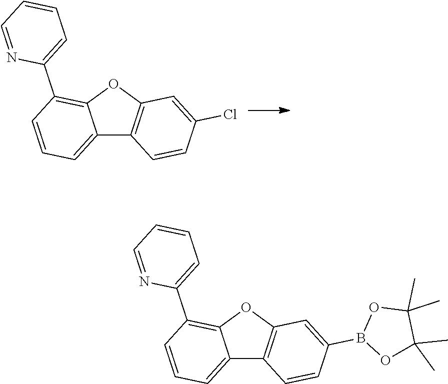 [SMILES: Clc1ccc2c(c1)oc1c(-c3ccccn3)cccc12 ; CC1(C)OB(c2ccc3c(c2)oc2c(-c4ccccn4)cccc23)OC1(C)C]

To a oven-dried RBF fitted with a condenser and charged with a stir bar, 2-(7-chlorodibenzo[b,d]furan-4-yl)pyridine (1.000 g, 1 Eq, 3.575 mmol), 4,4,4′,4′,5,5,5′,5′-octamethyl-2,2′-bi(1,3,2-dioxaborolane) (1.362 g, 1.5 Eq, 5.363 mmol), dicyclohexyl(2′,4′,6′-triisopropyl-[1,1′-biphenyl]-2-yl)phosphane (102.3 mg, 0.06 Eq, 214.5 μmol), and potassium acetate (877.1 mg, 2.5 Eq, 8.938 mmol) were added and dissolved in 1,4-Dioxane (17.88 mL). The solution was purged with nitrogen for 15 minutes then, Pd₂(dba)₃ (98.21 mg, 0.03 Eq, 107.3 μmol) was added and the reaction was heated to 85° C. for 20 hours. The reaction was allowed to cool to room temperature, diluted in ethyl acetate then filtered through a pad of Celite. The solution was concentrated under reduced pressure then the crude product was purified on silica gel eluting with ethyl acetate and heptanes. The pure product was concentrated under reduced pressure yielding a tan solid (0.52 g, 3.57 mmol, 39%).

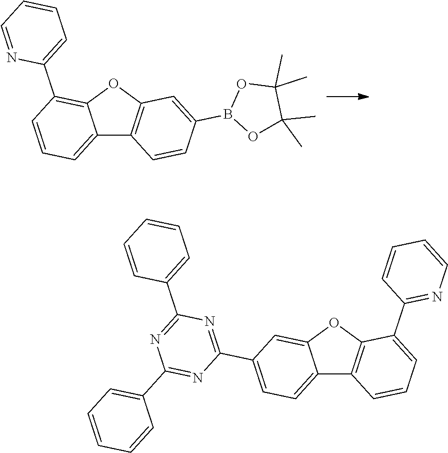 [SMILES: CC1(C)OB(c2ccc3c(c2)oc2c(-c4ccccn4)cccc23)OC1(C)C ; c1ccc(-c2nc(-c3ccccc3)nc(-c3ccc4c(c3)oc3c(-c5ccccn5)cccc34)n2)cc1]

To a 250 mL 2-neck RBF, 2-(7-(4,4,5,5-tetramethyl-1,3,2-dioxaborolan-2-yl)dibenzo[b,d]furan-4-yl)pyridine (1.690 g, 1 Eq, 4.552 mmol)₂-chloro-4,6-diphenyl-1,3,5-triazine (1.341 g, 1.1 Eq, 5.008 mmol) Potassium carbonate (1.573 g, 2.5 Eq, 11.38 mmol) were added and dissolve in 1,4-Dioxane (68.28 mL) and Water (22.76 mL). The reaction flask was fitted with a reflux condenser then purged with N₂ for 15 minutes. After N₂ purging, Pd(PPh₃)₄ (263.0 mg, 0.05 Eq, 227.6 μmol) was added and the reaction was heated to 85° C. for 20 hours under N₂ atmosphere. The crude product was filtered from the reaction mixture then purified on silica eluting with ethyl acetate and toluene. The product was concentrated under reduced pressure, precipitated in methanol then isolated via vacuum filtration. The purified product was dried under vacuum and isolated as a white solid (1.12 g, 4.552 mmol, 51%).

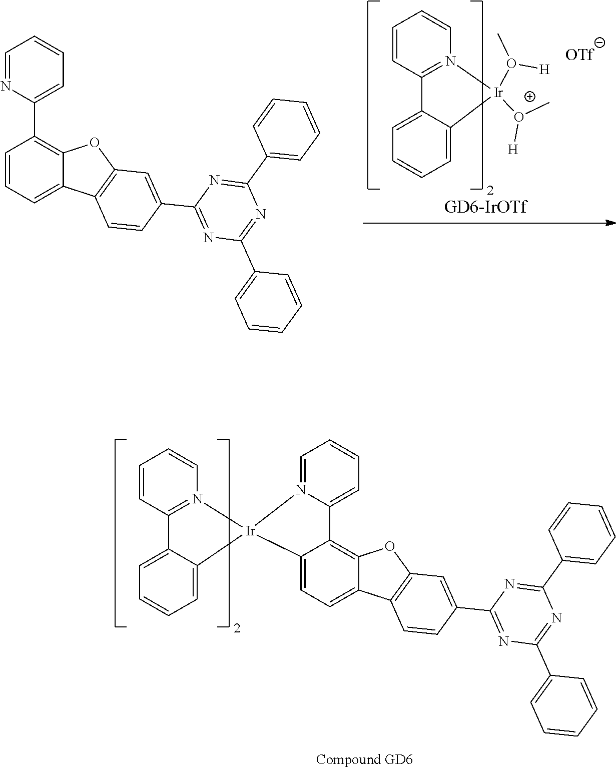

GD6-IrOTf (1.500 g, 1 Eq, 2.098 mmol) and 2,4-diphenyl-6-(6-(pyridin-2-yl)dibenzo[b,d]furan-3-yl)-1,3,5-triazine (1.000 g, 1 Eq, 2.098 mmol) were added to a two-neck RBF fitted with a condenser and charged with a stir bar. 2-ethoxyethanol (44.84 ml) and 2,6-dimethylpyridine (449.7 mg, 486.1 μL, 2 Eq, 4.197 mmol) were added and the reaction was heated to 100° C. for 72 hours. The crude product was concentrated under reduce pressure then re-dissolved in DCM and purified by column chromatography eluting with heptane and DCM giving Compound GD6 as a yellow solid (0.256 g, 12.5%).

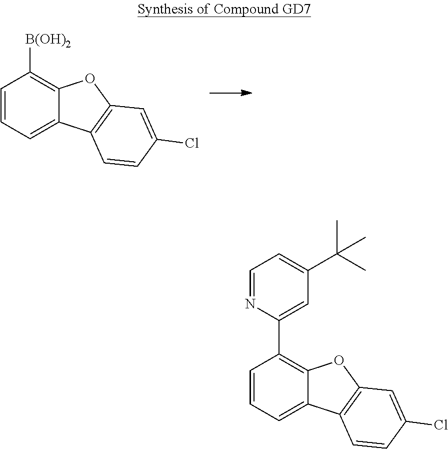 [SMILES: OB(O)c1cccc2c1oc1cc(Cl)ccc12 ; CC(C)(C)c1ccnc(-c2cccc3c2oc2cc(Cl)ccc23)c1]

2-Bromo-5-(tert-butyl)pyridine (6.00 g, 1 Eq, 28.0 mmol), potassium carbonate (9.68 g, 2.5 Eq, 70.1 mmol) and (7-chlorodibenzo[b,d]furan-4-yl)boronic acid (7.60 g, 1.1 Eq, 30.8 mmol) were dissolved in acetonitrile (60 mL) and water (20 ml) and degassed with nitrogen for 20 min. Pd(PPh₃)₄ (1.62 g, 0.05 Eq, 1.40 mmol) was added and the reaction mixture heated to 85° C. for 16 h. The reaction mixture was cooled to room temperature and diluted with EtOAc (300 ml) and washed with brine (300 mL). The aq was washed with more EtOAc (100 mL), the combined organics were washed with brine (50 mL) and the organics dried over Na₂SO₄ and the solvent was evaporated. The residue was purified by chromatography on silica gel eluting with DCM and hexanes to afford 4-(tert-butyl)-2-(7-chlorodibenzo[b,d]furan-4-yl)pyridine (5.96 g, 18 mmol, 63%) as a white solid.

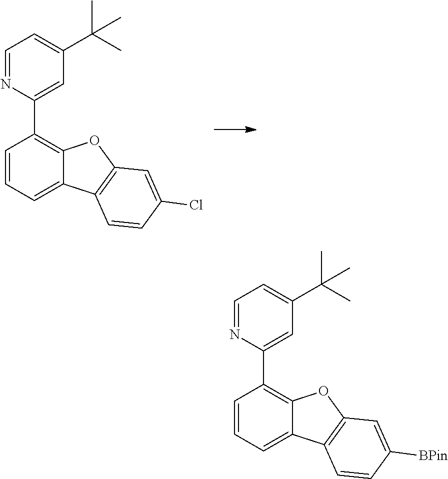

4-(tert-Butyl)-2-(7-chlorodibenzo[b,d]furan-4-yl)pyridine (6.30 g, 1 Eq, 18.76 mmol) was dissolved in dry dioxane (150 ml) under nitrogen, bispin (7.15 g, 1.5 Eq, 28.14 mmol) and potassium acetate (4.60 g, 2.5 Eq, 46.90 mmol) were added and the reaction mixture degassed with nitrogen for 20 min. XPhos (268 mg, 0.03 Eq, 562.8 μmol) and XPhosPd(crotyl)Cl (379 mg, 0.03 Eq, 562.8 μmol) were added and the reaction mixture heated to 70° C. overnight. The reaction mixture was cooled to room temperature, diluted with EtOAc (150 mL), filtered through a bed of celite and the bed washed with EtOAc (250 mL). The combined filtrates were concentrated in vacuo to give a black residue. The material was slurried in MeOH (100 ml) for 20 mins and collected by filtration to give 4-(tert-butyl)-2-(7-(4,4,5,5-tetramethyl-1,3,2-dioxaborolan-2-yl)dibenzo[b,d]furan-4-yl)pyridine (6.96 g, 16 mmol, 85%) as a grey solid.

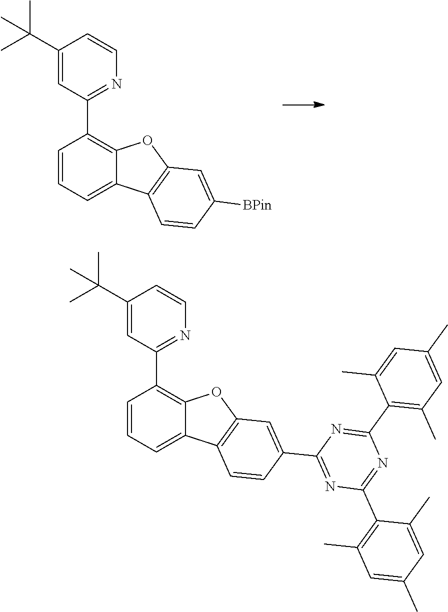

2-Chloro-4,6-dimesityl-1,3,5-triazine (3.63 g, 1 Eq, 10.316 mmol), potassium carbonate (3.56 g, 2.5 Eq, 25.790 mmol) and 4-(tert-butyl)-2-(7-(4,4,5,5-tetramethyl-1,3,2-dioxaborolan-2-yl)dibenzo[b,d]furan-4-yl)pyridine (4.45 g, 1.01 Eq, 10.419 mmol) were dissolved in acetonitrile (120 mL) and water (40 mL) and degassed with nitrogen for 20 min. Pd(PPh₃)₄ (596 mg, 0.05 Eq, 515.80 μmol) was added and the reaction mixture heated to 85° C. for 16 h. The reaction mixture was cooled to room temperature and diluted with DCM (200 mL) and water (100 mL). The aqueous layer was washed with more DCM (2×100 mL), the combined organics were dried over Na₂SO₄ and the solvent was evaporated. The residue was purified by chromatography on to give 2-(6-(4-(tert-butyl)pyridin-2-yl)dibenzo[b,d]furan-3-yl)-4,6-dimesityl-1,3,5-triazine (4.2 g, 6.75 mmol, 36% yield) as an off-white solid.

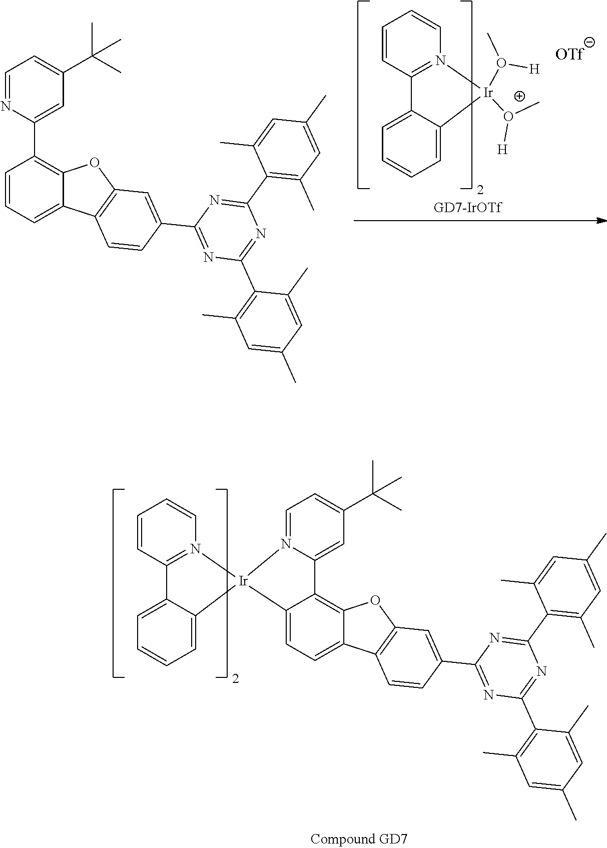

GD7-IrOTf (0.200 g, 1 Eq, 280 μmol) and 2-(6-(4-(tert-butyl)pyridin-2-yl)dibenzo[b,d]furan-3-yl)-4,6-dimesityl-1,3,5-triazine (173 mg, 1 Eq, 280 μmol) were added to a 100 mL RBF charged with a stir bar then dissolved in 2-ethoxyethanol (10.00 mL) and treated with 2,6-dimethylpyridine (60.1 mg, 64.9 μL, 2 Eq, 560 μmol). The reaction was heated to 100° C. for 20 hours. After heating the solvent was removed under reduced pressure. The crude product was purified by column chromatography eluting with THF and heptanes to give Compound GD7 as a yellow solid (85 mg, 27%).

DFT calculations were performed to determine the energy of the lowest triplet (T₁) excited state. The data was gathered using the program Gaussian16. Geometries were optimized using ωB97X functional and LANL2DZ basis set using a gap-tuned ω value. Excited state energies were computed by TDDFT at the optimized ground state geometries. THF solvent was simulated using a self-consistent reaction field to further improve agreement with the experiment. The LUMO population at each atom center was calculated using a Lowdin population analysis of the LUMO orbital, where the Fused Ring LUMO shown in Table 1 is the percentage the sum of the populations on a first moiety divided by the total. The percentage of metal-to-ligand charge transfer (³MLCT) and ligand-centered (LC) character involved in T₁ of the compounds were determined via transition density matrix analysis of the excited states. The transition density matrix was extracted from the T₁ state of TDDFT calculations at the ωB97X/LANL2DZ level using a gap-tuned ω value for structures optimized to the ground state at the same level. The ligand-centered character localized on the first group (Fused Ring LC) is given by the percentage of LC on the first group relative to the entire excited state population of the molecule. TDMs were additionally calculated for the emissive ligand using the above-identified transition density matrix. Using the MLCT and ligand-to-metal charge transfer (LMCT) components a TDM can be approximated as the sum of vectors connecting all atoms of the emissive ligand to the metal weighted by their MLCT and LMCT components. The TDM angle was then determined as the angle between the TDM vector and the bond connecting the metal to the ring system of the first group.

The calculations obtained with the above-identified DFT functional set and basis set are theoretical. Computational composite protocols, such as the Gaussian16 with B3LYP and CEP-31G protocol used herein, rely on the assumption that electronic effects are additive and, therefore, larger basis sets can be used to extrapolate to the complete basis set (CBS) limit. However, when the goal of a study is to understand variations in HOMO, LUMO, S₁, T₁, bond dissociation energies, etc. over a series of structurally-related compounds, the additive effects are expected to be similar. Accordingly, while absolute errors from using the B3LYP may be significant compared to other computational methods, the relative differences between the HOMO, LUMO, S1, T1, and bond dissociation energy values calculated with B3LYP protocol are expected to reproduce experiment quite well. See, e.g., Hong et al., Chem. Mater. 2016, 28, 5791-98, 5792-93 and Supplemental Information (discussing the reliability of DFT calculations in the context of OLED materials). Moreover, with respect to iridium or platinum complexes that are useful in the OLED art, the data obtained from DFT calculations correlate very well to actual experimental data. See Tavasli et al., J. Mater. Chem. 2012, 22, 6419-29, 6422 (Table 3) (showing DFT calculations closely correlating with actual data for a variety of emissive complexes); Morello, G. R., J. Mol. Model. 2017, 23:174 (studying of a variety of DFT functional sets and basis sets and concluding the combination of B3LYP and CEP-31G is particularly accurate for emissive complexes). The determination of excited state transition character is performed as a post-processing step on the above-mentioned DFT and TDDFT calculations. This analysis allows for decomposition of the excited state into the hole, i.e., where the excitation originates, and the electron, i.e., the final location of the excited state. Additionally, as this analysis is performed on a calculated property it is objective and repeatable; see Mai et al., Coord. Chem. Rev. 2018, 361, 74-97 (discussing the theoretical basis of the excited state decomposition in transition metal complexes).

The phosphorescent emission spectra for Compound GD1 to Compound GD7 as well as Comparison 1 to Comparison 3 were measured and are shown in Table 1. The peak emission maximum (λₘₐₓ) and full width at half-maximum (FWHM) were both measured from of the emission of degassed solution samples in 2-MeTHF at room temperature. The emission was measured on a Horiba Fluorolog-3 spectrofluorometer equipped with a Synapse Plus CCD detector. All samples were excited at 340 nm.

The VDR was measured as follows: Films for angle dependent photoluminescence were fabricated by vacuum thermal evaporation of 400 Å of H (70% H1 and 30% H2) doped with 5% of the emitter on UV-ozone pretreated glass substrates. The polarized angle dependent photoluminescence was then measured using a Fluxim Phelos system with a 340 nm or 405 nm excitation source and fit with Setfos software yielding the VDR. The Phelos spectral intensity versus angle was obtained by integrating the wavelength regime over a range which excluded the excitation source scatter. The fit routine within Setfos is as follows. The optical stack is set up identical to the experiment with a 0.7 mm glass substrate into which the emission is measured, a 40 nm EML film with the emitter, and air as the last later. The emitter distribution is set as exponential with a position at the top air-EML interface and a width of 50 nm. The integrated p-polarized and s-polarized spectral intensities vs. angle are used as the input targets for the Setfos fit/optimization routine. The fit parameters of the optimization are the: emitter orientation (VDR), emission intensity, and EML refractive index. The resulting VDR from this fit is the reported value where VDR=vertical dipole ratio (0.33 is random, anything less than 0.33 is net horizontally aligned).

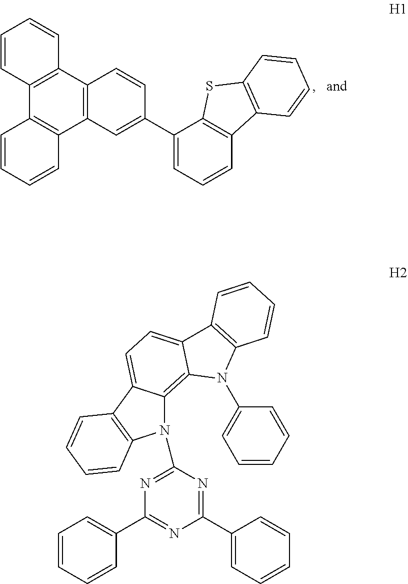 [SMILES: c1ccc2c(c1)sc1c(-c3ccc4c5ccccc5c5ccccc5c4c3)cccc12 ; c1ccc(-c2nc(-c3ccccc3)nc(-n3c4ccccc4c4ccc5c6ccccc6n(-c6ccccc6)c5c43)n2)cc1]

TABLE 1
Calculated and experimental emission properties

| | | Fused | Fused | | | |
|---|---|---|---|---|---|---|
| | TDM | Ring | Ring | | Amax | FWHM |
| Molecule | Angle | LC | LUMO | VDR | (nm) | (nm) |
| Comparison 1 | 46.88° | 22.13% | 25.67% | 0.31 | 528 nm | 72 |
| GD1 | 23.61° | 46.27% | 99.89% | 0.18 | 529 nm | 40 |
| GD2 | 21.88° | 46.97% | 96.71% | 0.20 | 526 nm | 32 |
| GD3 | 15.64° | 53.33% | 98.15% | 0.19 | 533 nm | 42 |
| GD6 | 17.48° | 54.29% | 98.70% | 0.18 | 538 nm | 53 |
| Comparison 2 | 32.12° | 38.33% | 72.88% | 0.24 | 524 nm | 50 |
| GD5 | 15.61° | 53.84% | 98.30% | 0.22 | 539 nm | 35 |
| Comparison 3 | 37.98° | 30.09% | 59.26% | 0.22 | 524 nm | 58 |
| GD4 | 24.41° | 48.57% | 97.94% | 0.20 | 520 nm | 28 |

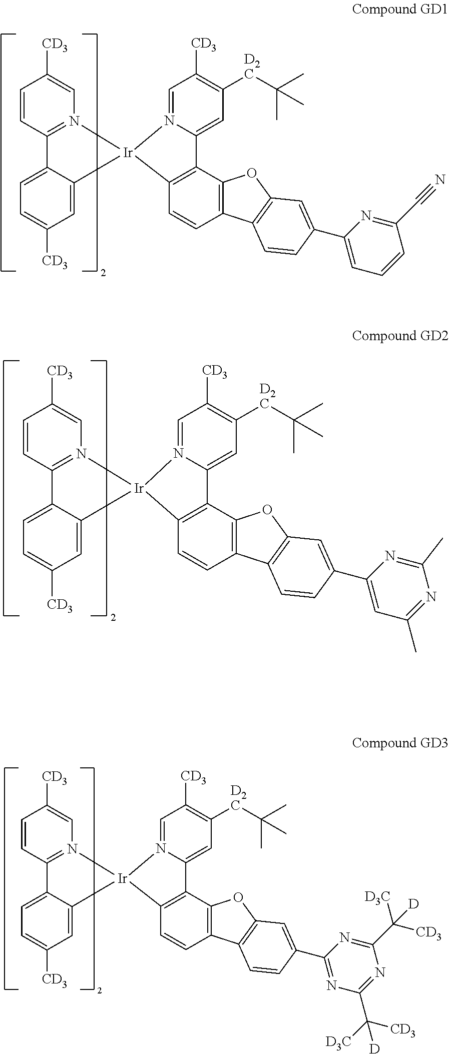

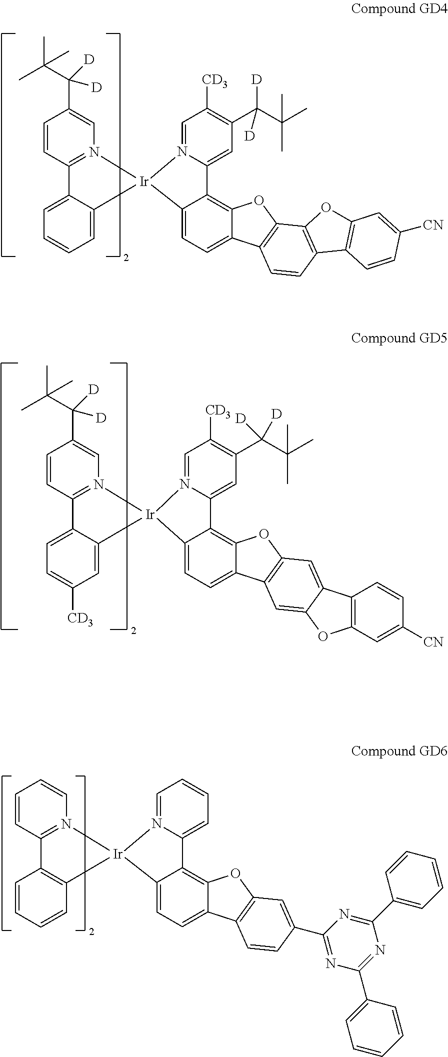

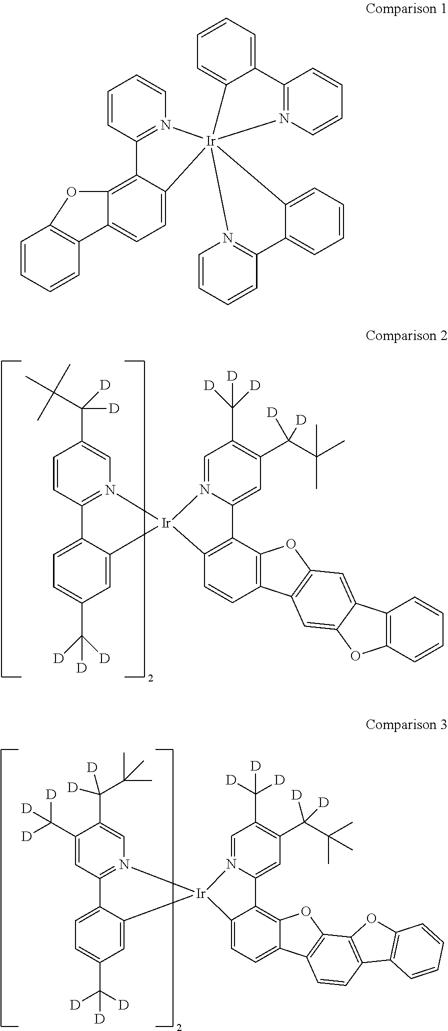

The above data shows that Compounds GD1, GD2, GD3, and GD6 each have lower VDRs and smaller FWHM than Comparison 1. Furthermore, GD5 has a lower VDR and smaller FWHM than Comparison 2, and GD4 has a lower VDR and smaller FWHM than Comparison 3. The 0.02 to 0.13 reduction in VDR and the 15 to 40 nm is beyond any value that could be attributed to experimental error and the observed improvement is significant. Based on the fact that the emitters have similar structures with the only difference being the addition of electron deficient groups at the end of the polycyclic fused ring systems, the significant performance improvement observed in the above data is unexpected. Without being bound by any theory, the improvement in FWHM may be attributed to a change in excited state localization with the compounds GD1 to GD7 each having greater than 45% Fused Ring LC. Furthermore, the improvement in VDR may be attributed to the improved TDM alignment along the direction of the fused ring system as indicated by the less than 25° TDM angle for each of the inventive compounds. The achievement of both narrow lineshape and lower VDR from the same molecule can allow OLED devices to achieve very high efficiencies with high spectral purity. Without being bound by any theory, this can be achieved by the improved localization of the LUMO to greater align the direction of any charge transfer transitions with the localization of the LC state.

What is claimed is:

1. A compound E1 capable of functioning as an emitter an organic light emitting device (OLED) at room temperature,
wherein the compound E1 is a metal coordination complex;
wherein the metal coordination complex comprises a first ligand, L_{A}, that comprises a first group; and
wherein the complex comprises a covalent bond between the metal and the first group; wherein the transition dipole moment (TDM) of the emissive state of the complex has a vector, wherein an angle formed between the TDM vector and the covalent bond between the metal and the first group is less than or equal to 40°, and wherein an excited state of the metal coordination complex has a ligand-centered (LC) character localized on the first group of greater than or equal to 45%.

2. The compound E1 of claim 1, wherein the angle formed between the TDM vector and the covalent bond between the metal and the first group is less than or equal to 15°; and/or
wherein an excited state of the compound has an LC character localized on the first group of greater than or equal to 58%; and/or
wherein the compound has a rod-like parameter, R^{R}, of at least 50%; and/or wherein the compound has a HOMO energy lower than −5.15 eV; and/or wherein the compound has a Q parameter less than 1×10⁻⁹ C.

3. The compound E1 of claim 1, wherein the compound is an iridium coordination complex or a platinum coordination complex; and/or
wherein the compound comprises a substituted or unsubstituted acetylacetonate ligand; and/or
wherein the compound comprises an emissive ligand; and/or wherein at least 70% of a LUMO of the compound is localized on the first group.

4. The compound E1 of claim 3, wherein the emissive ligand comprises a moiety selected from the group consisting of benzene, pyridine, pyrimidine, pyridazine, pyrazine, triazine, imidazole, imidazole derived carbene, pyrazole, pyrrole, oxazole, furan, thiophene, thiazole, triazole, naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, benzimidazole derived carbene, aza-benzimidazole derived carbene, carbazole, aza-carbazole, dibenzofuran, aza-dibenzofuran, dibenzothiophene, aza-dibenzothiophene, quinoxaline, phthalazine, phenanthrene, aza-phenanathrene, anthracene, aza-antracene, phenanthridine, fluorene, and aza-fluorene.

5. The compound E1 of claim 1, wherein L_{A} has the structure of Formula I, 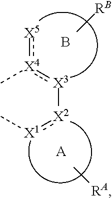
wherein:
each of moiety A and moiety B is independently a monocyclic ring or a polycyclic fused ring system, where the monocyclic ring or each ring of the polycyclic fused ring system is independently a 5-membered or 6-membered carbocyclic or heterocyclic ring;
ring B is the ring comprising X³, X⁴, and X⁵ and is a 5-membered or 6-membered carbocyclic or heterocyclic ring;
each of X¹ to X⁵ is independently C or N; [symbol]
is either a single bond or a double bond;
X¹ forms a covalent bond with the metal;
R^{A} and R^{B} each independently represents mono to the maximum allowable substitution, or no substitution;
each R^{A} and R^{B} is independently a hydrogen or a substituent selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof; and
any two substituents can be joined or fused to form a ring.

6. The compound E1 of claim 5, wherein each of moiety A and moiety B is independently selected from the group consisting of benzene, pyridine, pyrimidine, pyridazine, pyrazine, triazine, imidazole, imidazole derived carbene, pyrazole, pyrrole, oxazole, furan, thiophene, thiazole, triazole, naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, benzimidazole derived carbene, aza-benzimidazole derived carbene, carbazole, aza-carbazole, dibenzofuran, aza-dibenzofuran, dibenzothiophene, aza-dibenzothiophene, quinoxaline, phthalazine, phenanthrene, aza-phenanathrene, anthracene, aza-antracene, phenanthridine, fluorene, and aza-fluorene.

7. The compound E1 of claim 6, wherein moiety A comprises at least 3 fused rings; and/or
wherein moiety B is selected from the group consisting of benzene, pyridine, pyrimidine, pyridazine, pyrazine, triazine, imidazole, pyrazole, pyrrole, oxazole, furan, thiophene, thiazole, triazole, naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, and aza-benzimidazole; and/or
wherein at least one R^{A} is an electron-withdrawing group selected from the group consisting of F, CF₃, CN, COCH₃, CHO, COCF₃, COOMe, COOCF₃, NO₂, SF₃, SiF₃, PF₄, SF₅, OCF₃, SCF₃, SeCF₃, SOCF₃, SeOCF₃, SO₂F, SO₂CF₃, SeO₂CF₃, OSeO₂CF₃, OCN, SCN, SeCN, NC, +N(R¹²)₃, (R¹²)₂CCN, (R^{k2})₂CCF₃, CNC(CF₃)₂, BR^{k3}R^{k2}, substituted or unsubstituted dibenzoborole, 1-substituted carbazole, 1,9-substituted carbazole, substituted or unsubstituted carbazole, substituted or unsubstituted pyridine, substituted or unsubstituted pyrimidine, substituted or unsubstituted pyrazine, substituted or unsubstituted pyridoxine, substituted or unsubstituted triazine, substituted or unsubstituted oxazole, substituted or unsubstituted benzoxazole, substituted or unsubstituted thiazole, substituted or unsubstituted benzothiazole, substituted or unsubstituted imidazole, substituted or unsubstituted benzimidazole, ketone, carboxylic acid, ester, nitrile, isonitrile, sulfinyl, sulfonyl, partially and fully fluorinated alkyl, partially and fully fluorinated aryl, partially and fully fluorinated heteroaryl, cyano-containing alkyl, cyano-containing aryl, cyano-containing heteroaryl, isocyanate, 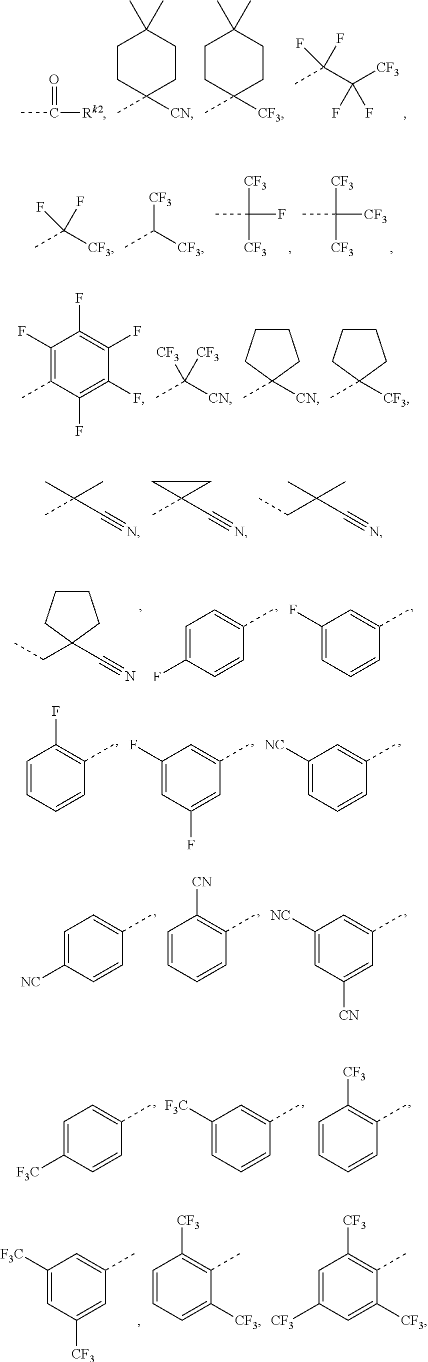 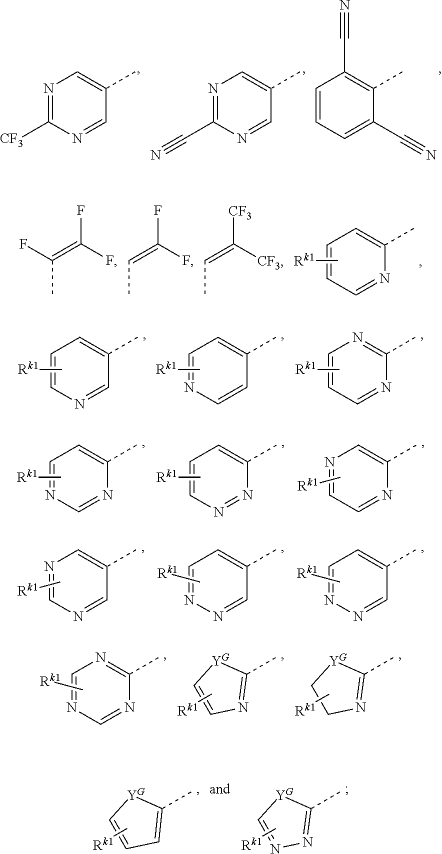
wherein each R^{k1} represents mono to the maximum allowable substitution, or no substitutions;
wherein Y^{G} is selected from the group consisting of BRₑ, NRₑ, PRₑ, O, S, Se, C═O, S═O, SO₂, CRₑR_{f}, SiRₑR_{f}, and GeRₑR_{f}; and
wherein each of R^{k1}, R^{k2}, R^{k3}, Rₑ, and R_{f} is independently a hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof, excluding fluoroalkyl.

8. The compound E1 of claim 5, wherein the compound comprises a first ligand L_{A} selected from the group consisting of 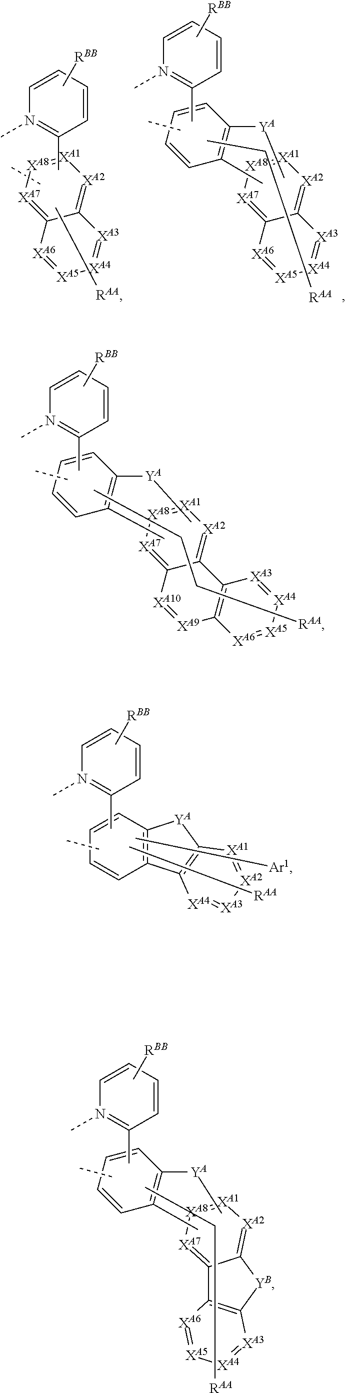 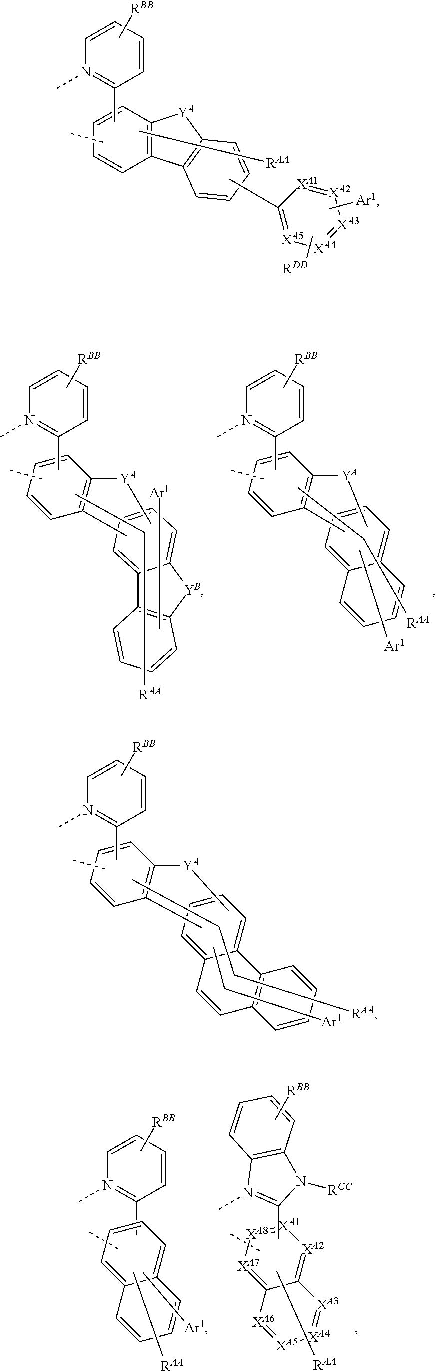 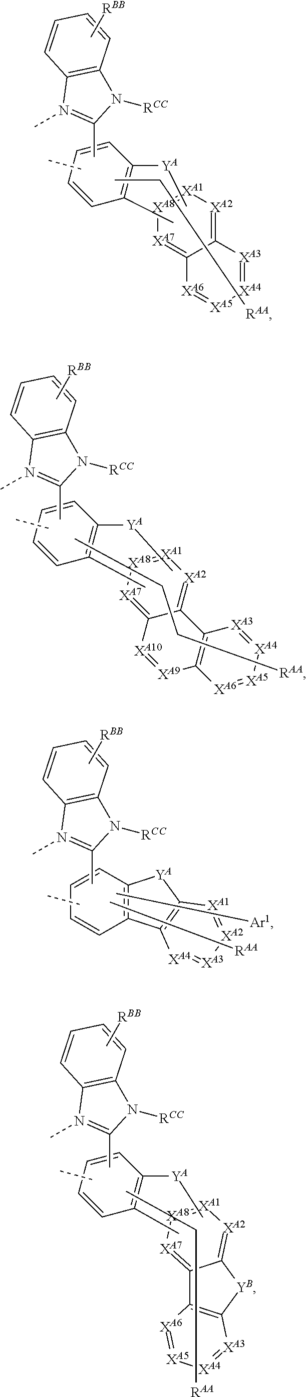 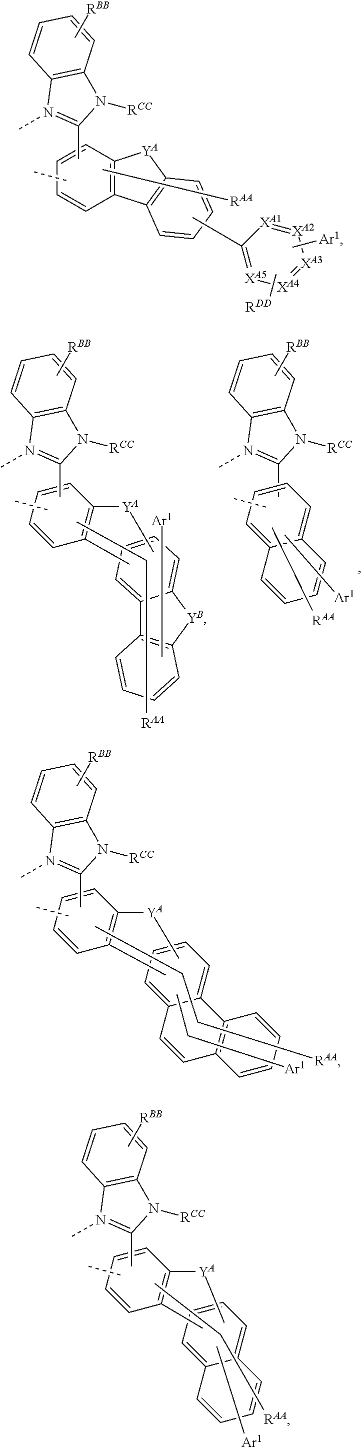 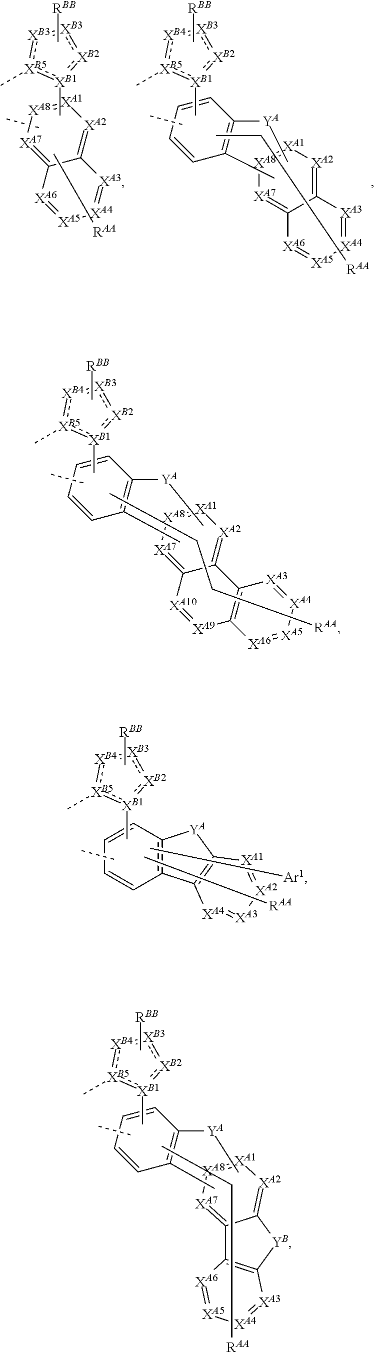 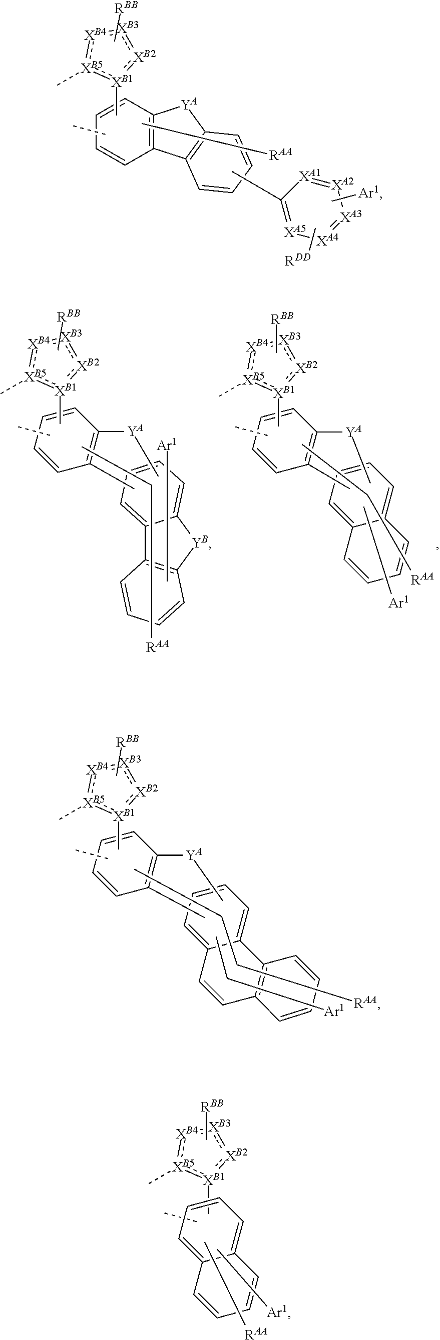 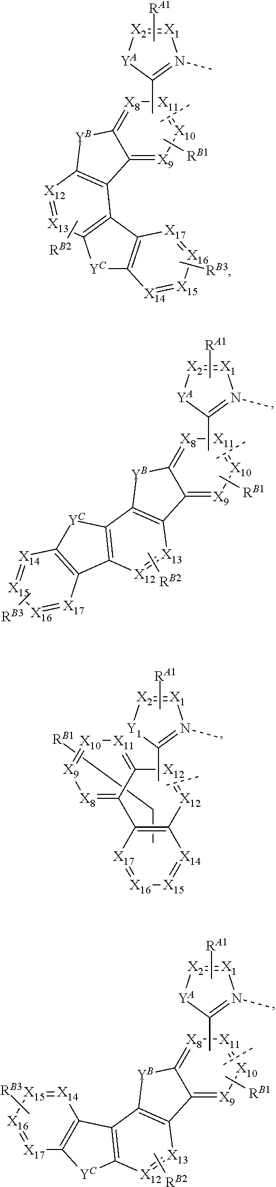 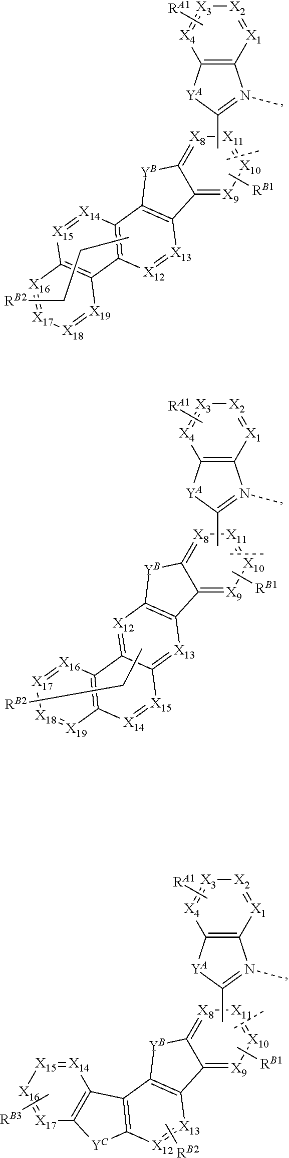 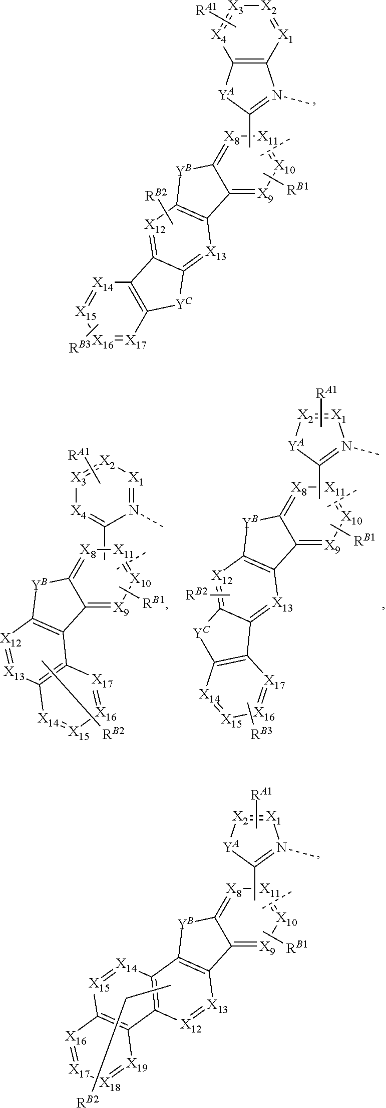 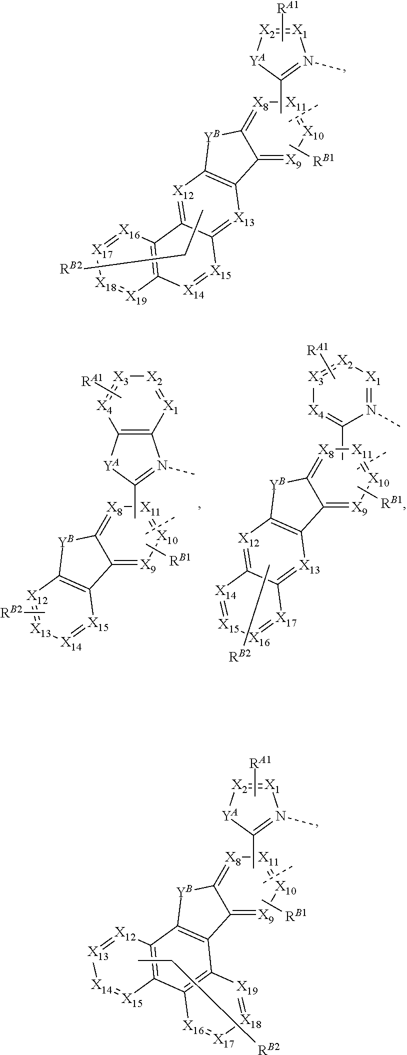 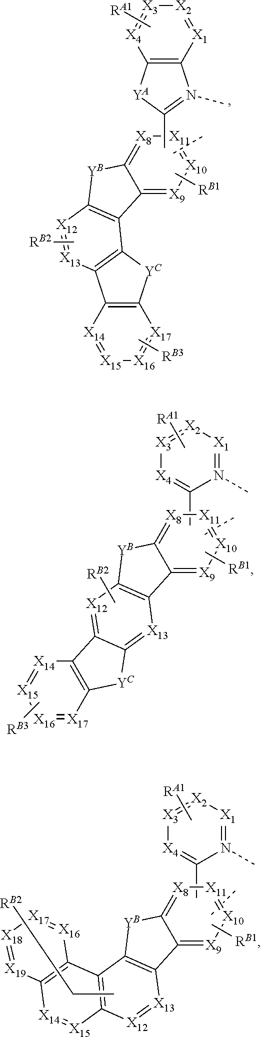 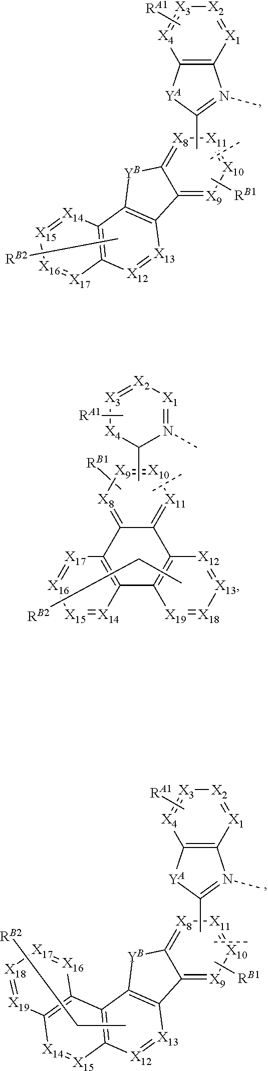 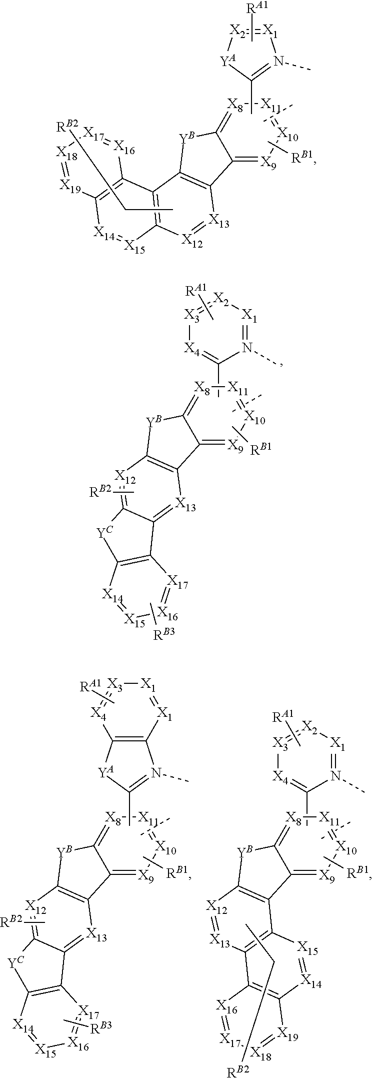 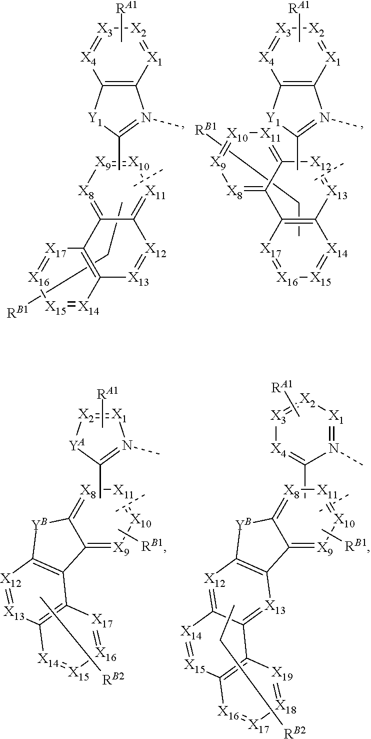 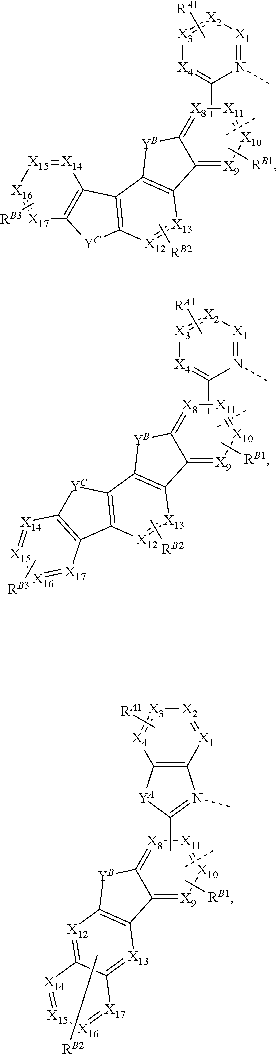 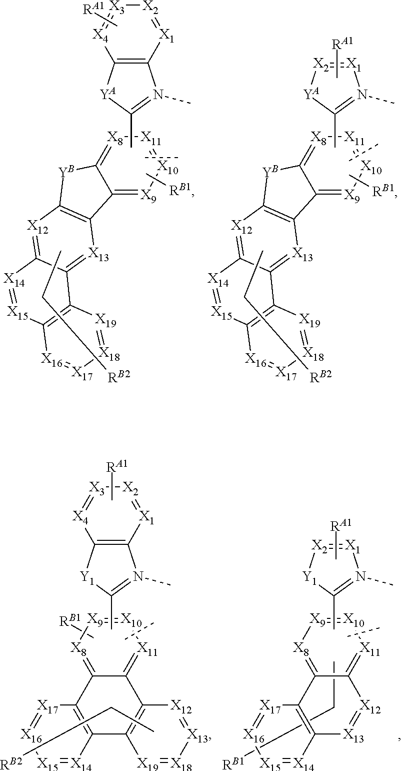 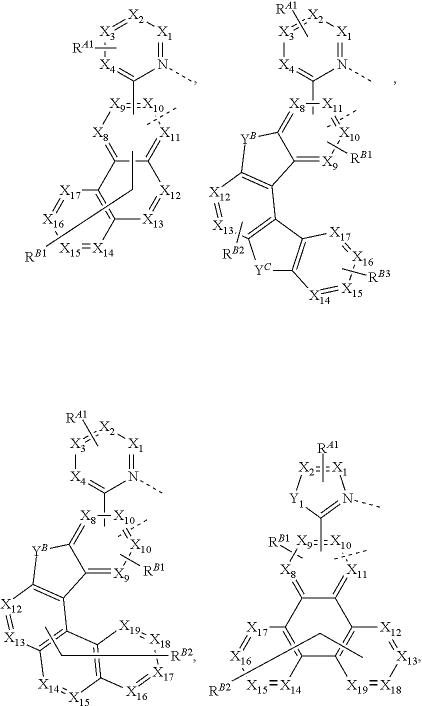 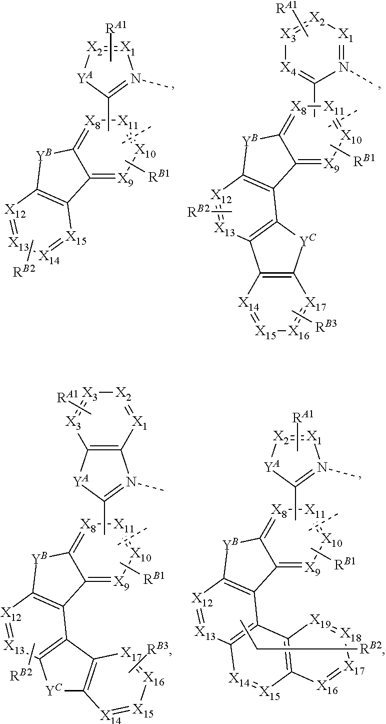 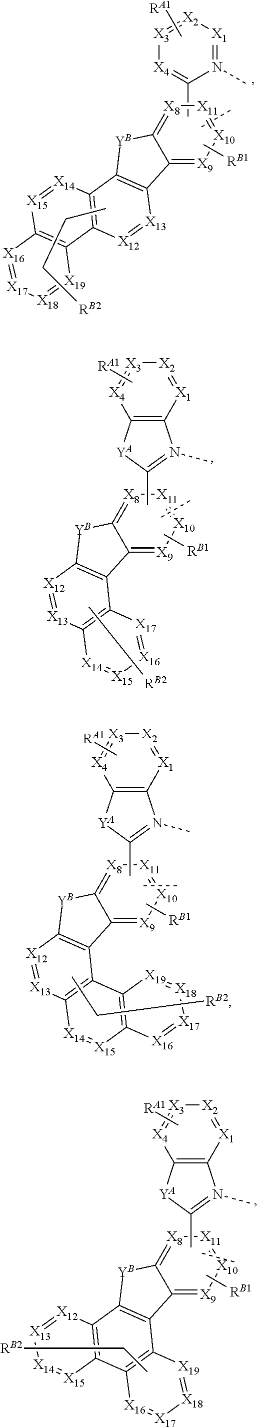 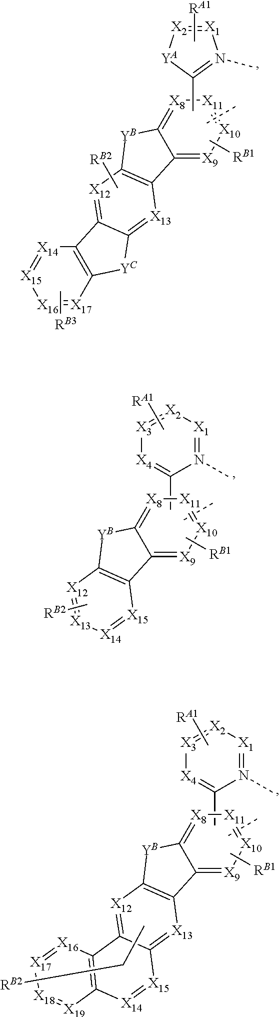 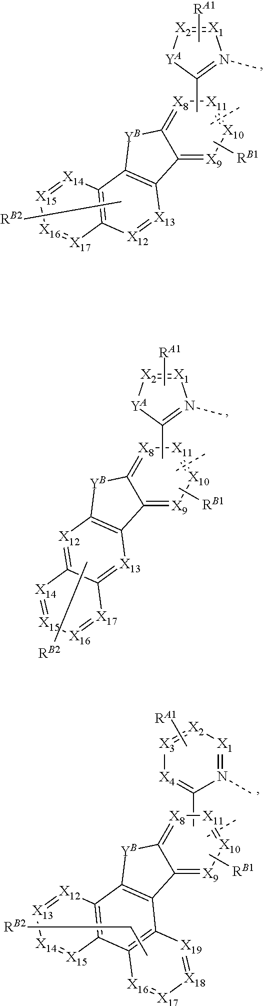 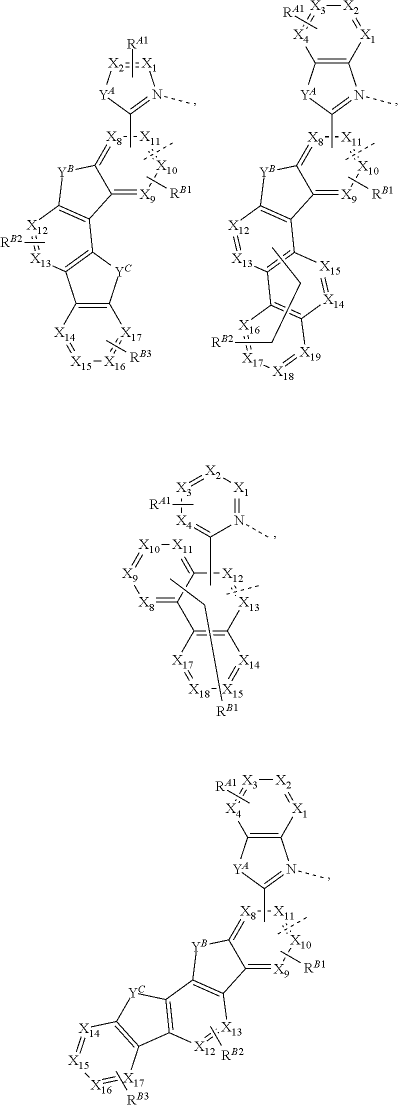 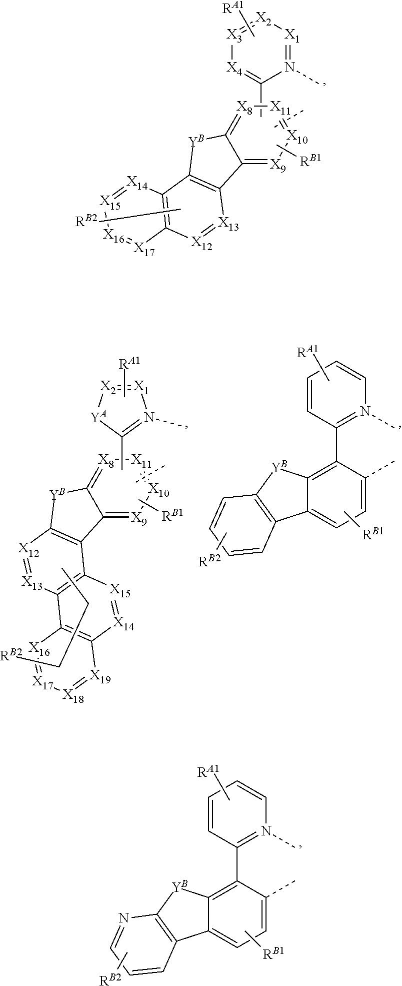 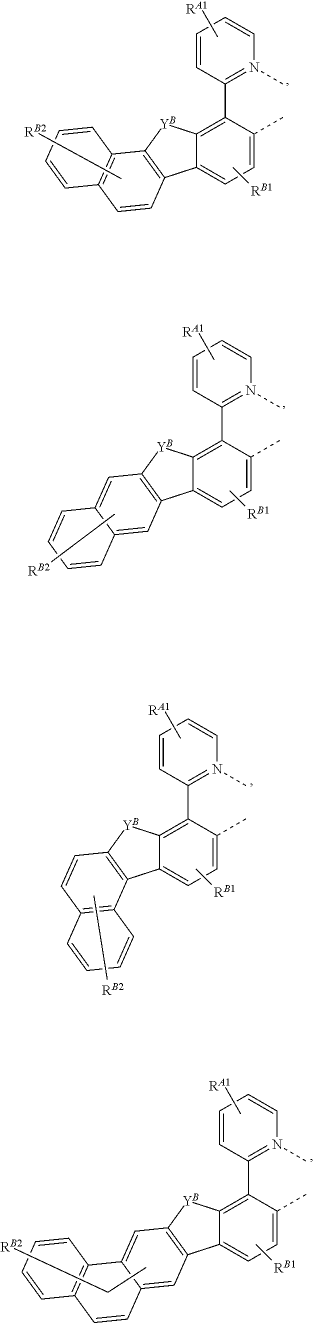 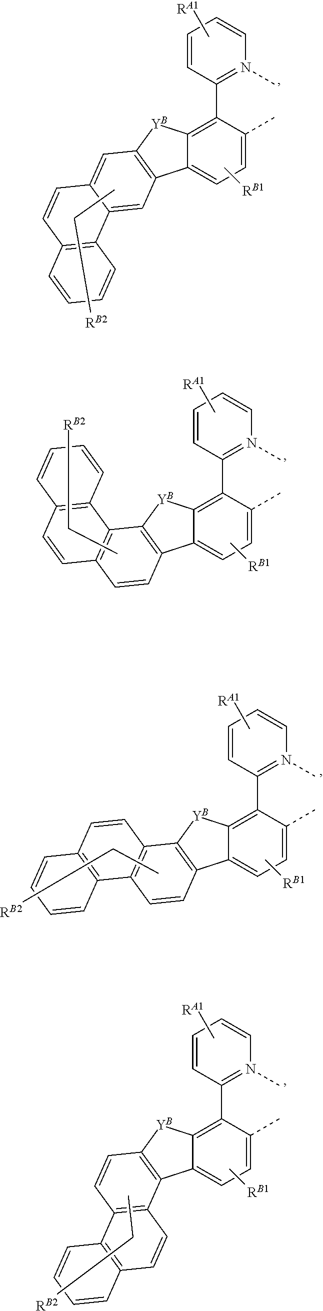 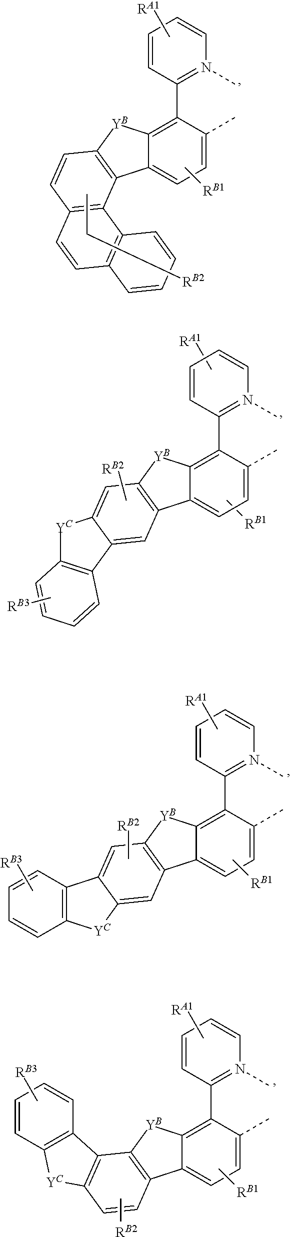 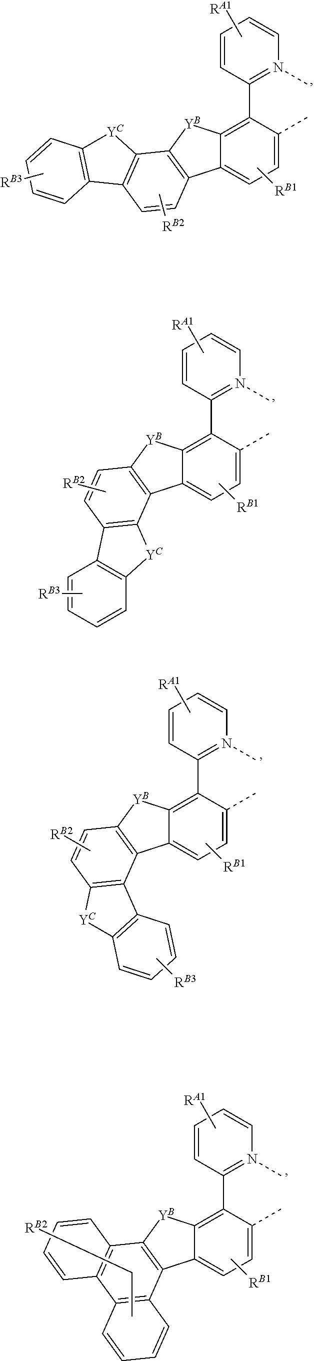 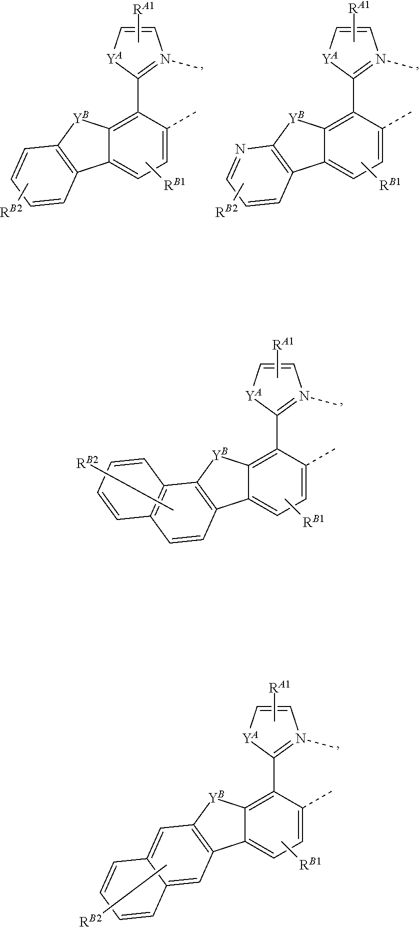 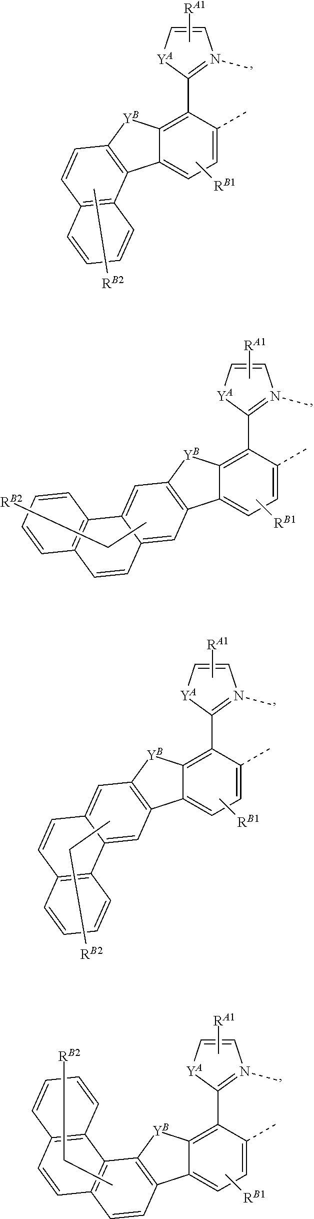 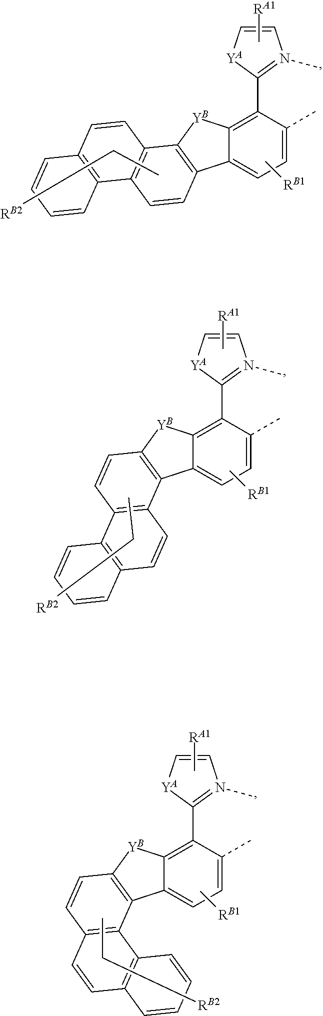 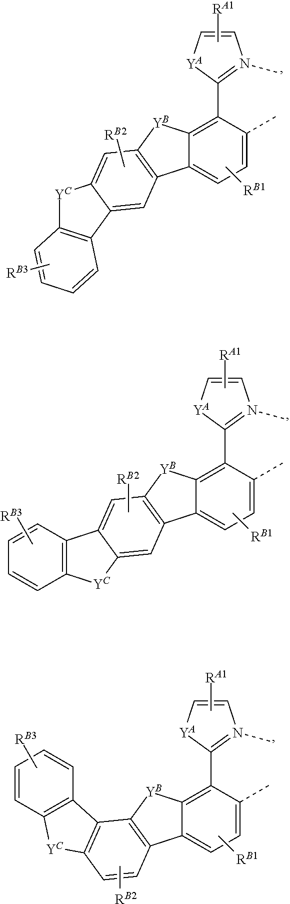 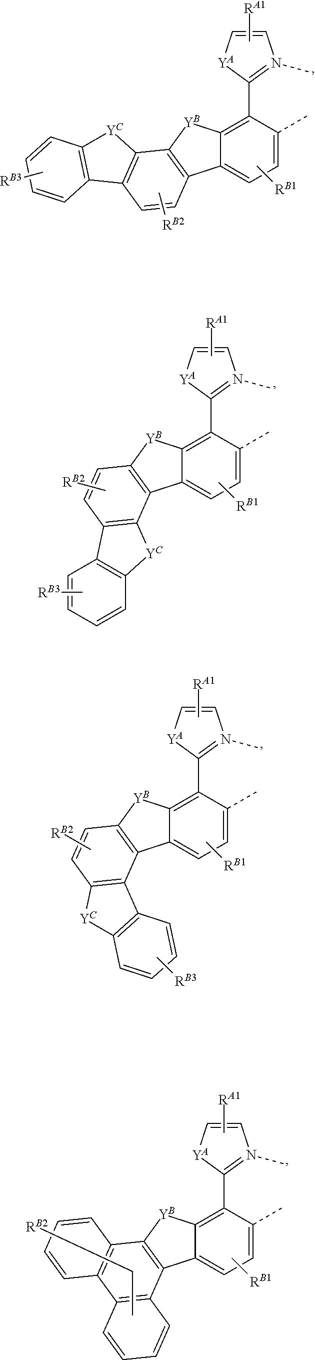 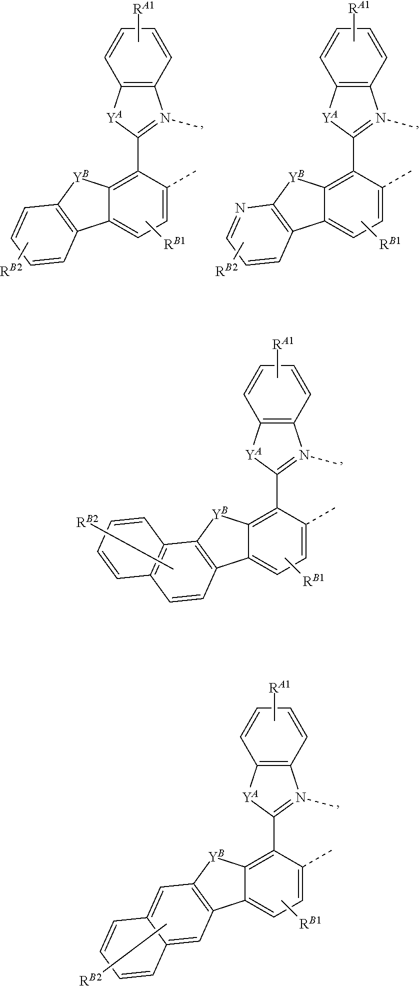 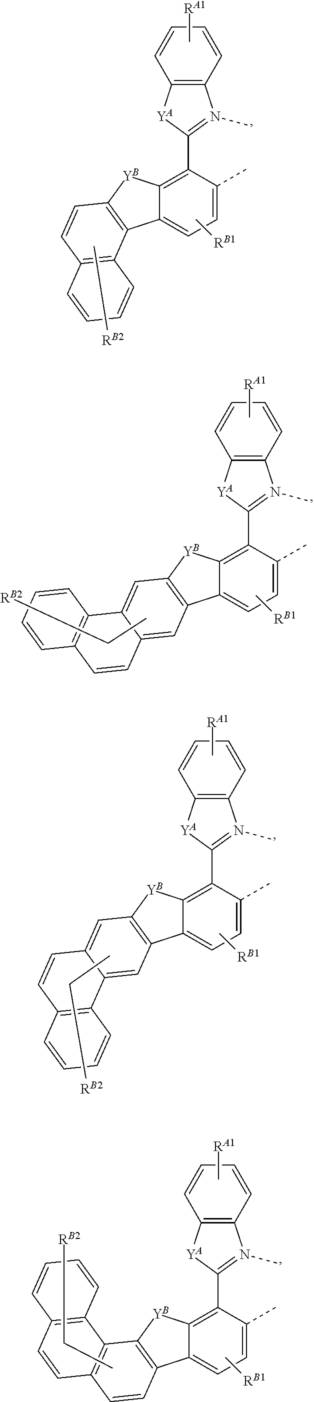 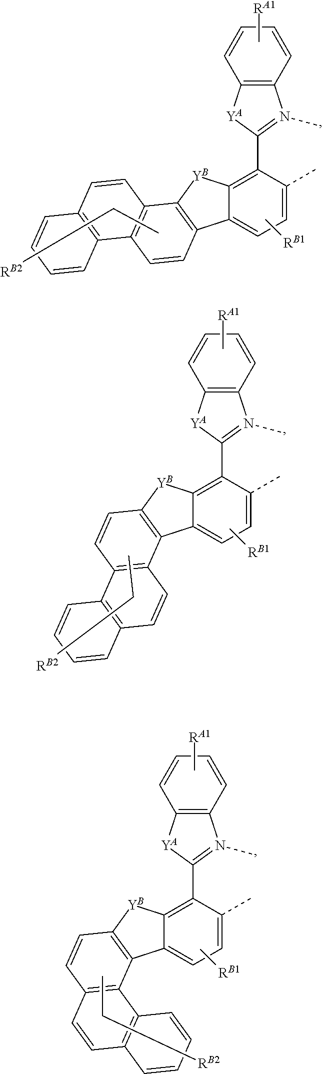 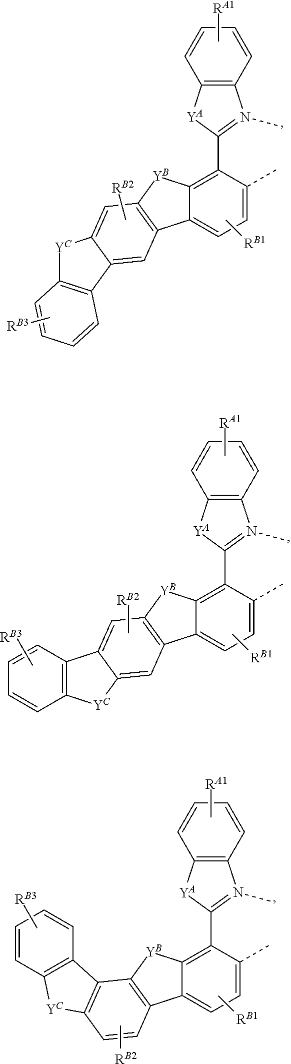 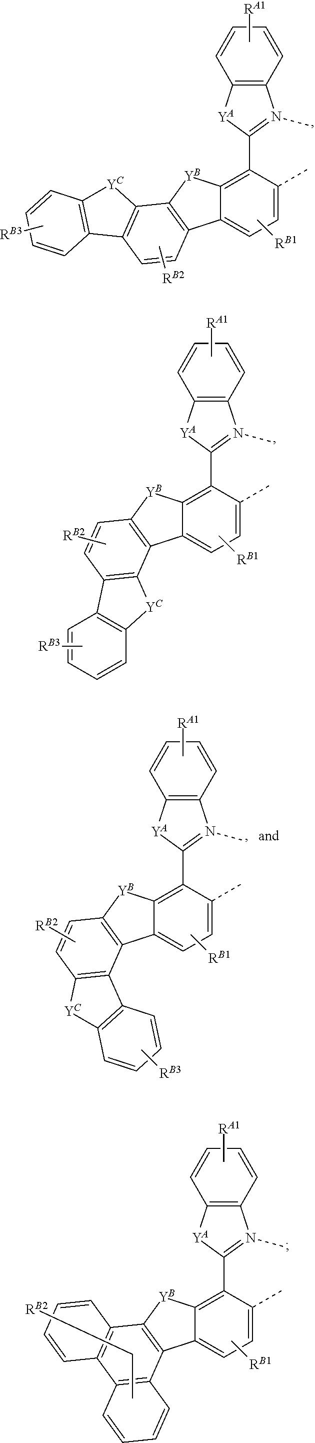
wherein:
each of X^{A1} to X^{A10} is independently C or N, and at least one of X^{A1} to X^{A10} is N;
each of X^{B1} to X^{B5} is independently C or N, and at least two of X^{B1} to X^{B5} are N;
if X^{B5} is C, then X^{B5} is a carbene carbon atom datively bound to the metal;
each of Y^{A} and Y^{B} is independently selected from the group consisting of BR, BRR′, NR, PR, P(O)R, O, S, Se, C═O, C═S, C═Se, C═NR, C═CRR′, S═O, SO₂, CR, CRR′, SiRR′, and GeRR′;
Ar¹ is independently selected from the group consisting of a substituted or unsubstituted aryl, substituted or unsubstituted heteroaryl, and an electron withdrawing group; and
each of R^{AA}, R^{BB}, and R^{DD} independently represents mono-, up to the maximum substitutions, or no substitutions;
each R, R′, R^{AA}, R^{BB}, R^{CC}, and R^{DD} is independently a hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof; and
any two adjacent R, R′, R^{AA}, R^{BB}, R^{CC}, R^{DD}, and Ar¹ are optionally joined or fused to form a ring;
wherein:
X₁ to X₁₉ are each independently C or N;
each of Y₁, Y^{A}, Y^{B}, and Y^{C} is independently selected from the group consisting of BRₑ, NRₑ, PRₑ, O, S, Se, C═O, S═O, SO₂, CRₑR_{f}, SiRₑR_{f}, and GeRₑR_{f};
each R^{A1}, R^{B1}, R^{B2}, and R^{B3} independently represent from mono to the maximum possible number of substitutions, or no substitution;
each R^{A1}, R^{B1}, R^{B2}, R^{B3}, Rₑ, and R_{f} is independently a hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof; and
any two substituents can be joined or fused to form a ring.

9. A compound E1′ capable of functioning as a phosphorescent emitter in an organic light emitting device at room temperature, wherein:
the compound is a metal coordination complex comprising a metal and a first group;
the first group comprises a continuous moiety comprising at least three rings; and
the first group contains at least 70% of the electron density of a LUMO of the compound.

10. The compound of claim 9, wherein the first group contains at least 75% of the electron density of the LUMO of the compound; and/or
wherein the compound has a triplet emission spectrum with a full width at half maximum (FWHM) value of 45 nm or less at 22° C.; and/or
wherein the compound has a highest occupied molecular orbital (HOMO) and a combination of the metal and the first group contains at least 70% of the electron density of the HOMO; and/or
wherein the first group has HOMO energy less than −5.0 eV; and/or
wherein the first group comprises at least one electron-withdrawing group.

11. The compound of claim 9, wherein the compound comprises a first ligand coordinated to the metal, and the first ligand comprises the first group;
wherein a free-state of the first ligand has a first triplet energy T₁ of E_{L} at 77K;
wherein the compound has a first triplet energy T₁ of E at 77K;
wherein the difference in energy between E and E_{L} is ΔE; and ΔE is 250 meV or less.

12. The compound of claim 9, wherein a transition dipole moment (TDM) of the emissive state of the compound has a vector, wherein the angle formed between the TDM vector and the covalent bond between the metal and the first group is less than or equal to 20°, and wherein an excited state of the compound has a LC character localized on the first group of greater than or equal to 45%; and/or
wherein the metal coordination complex has a rod-like parameter, R^{R}, of at least 50%; and/or wherein the metal coordination complex has a HOMO energy lower than −5.15 eV; and/or
wherein the metal coordination complex has a Q parameter less than 1×10⁻⁹ C.

13. The compound of claim 9, wherein the compound has a formula of M(L_{A})ₓ(L_{B})_{y}(L_{C})_{z} wherein M is the metal; L_{A}, L_{B} and L_{C} are each a bidentate ligand; and
wherein x is 1, 2, or 3; y is 0, 1, or 2; z is 0, 1, or 2; and
x+y+z is the oxidation state of the metal M.

14. The compound of claim 13, wherein the compound has a formula selected from the group consisting of Ir(L_{A})₃, Ir(L_{A})(L_{B})₂, Ir(L_{A})₂(L_{B}), Ir(L_{A})₂(L_{C}), and Ir(L_{A})(L_{B})(L_{C}); and
wherein L_{A}, L_{B}, and L_{C} are different from each other; or a formula of Pt(L_{A})(L_{B}); and
wherein L_{A} and L_{B} can be same or different.

15. The compound of claim 13, wherein L_{A} is selected from the group consisting of the structures of the following LIGAND List 1:: 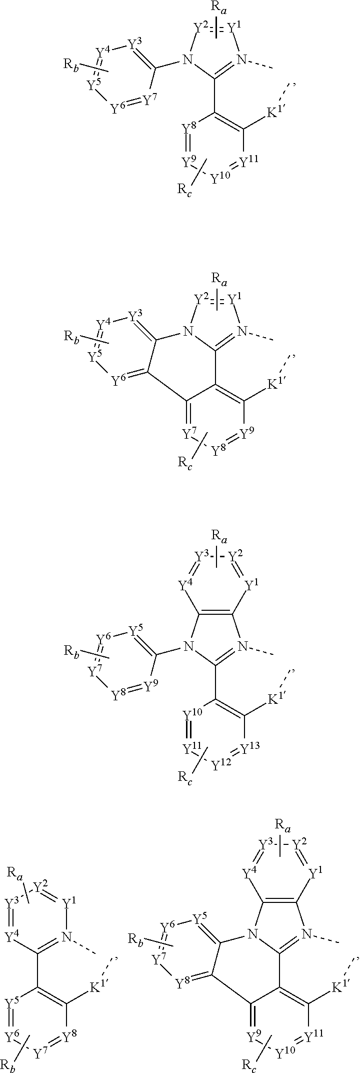 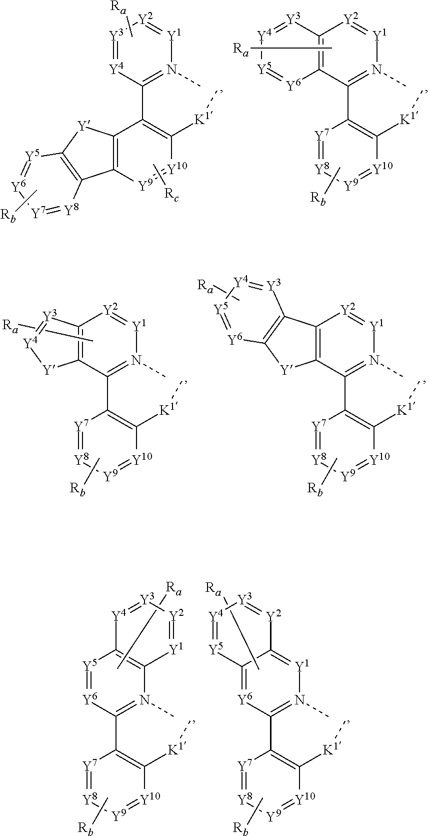 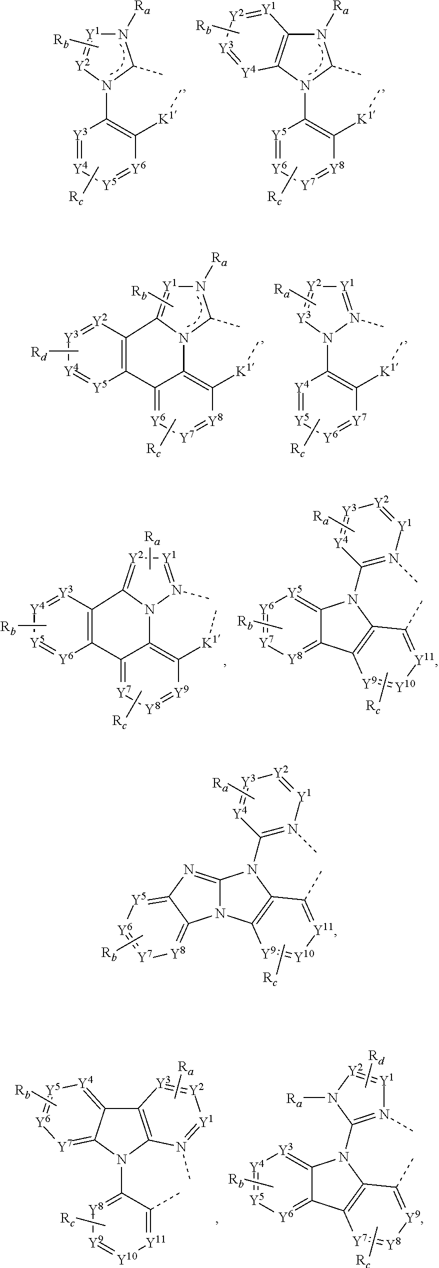 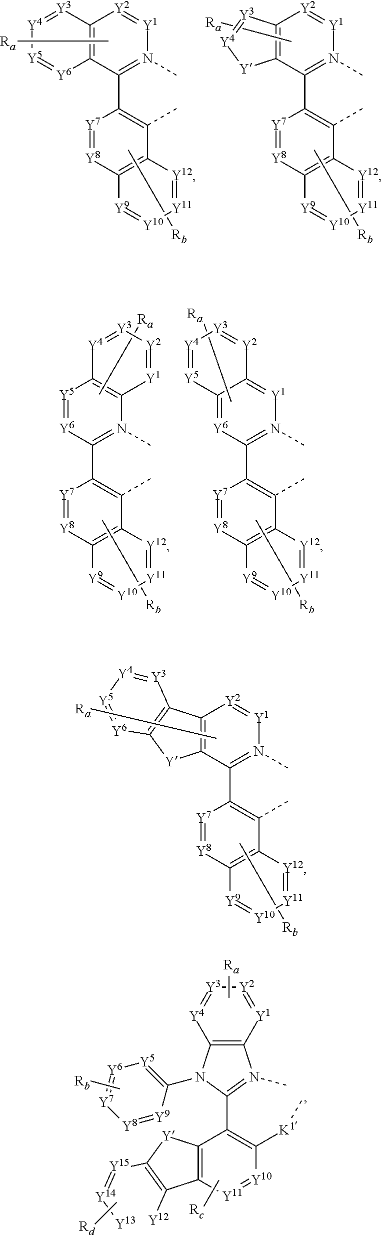 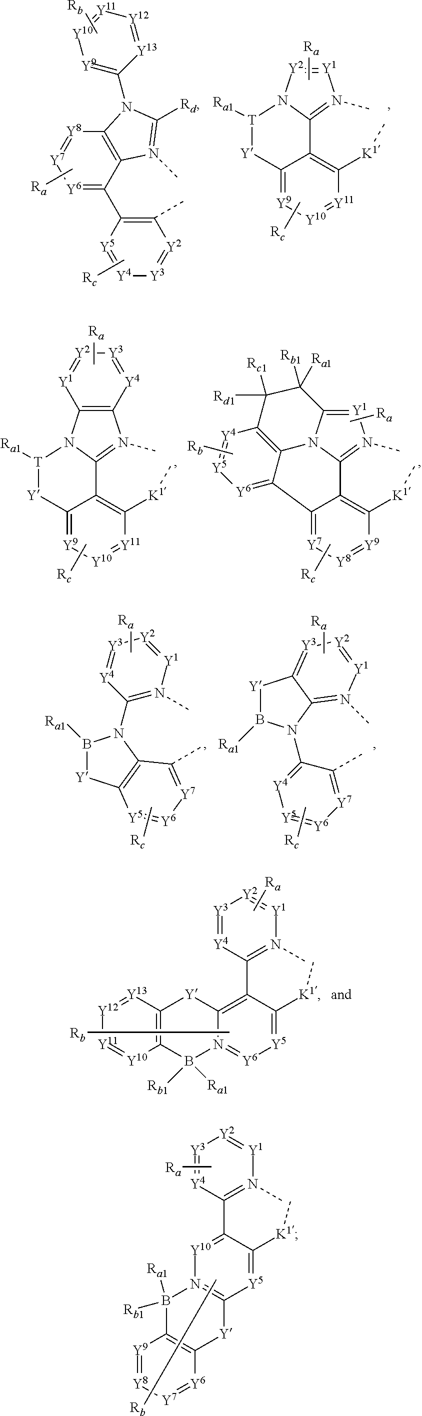
wherein L_{B} and L_{C} are each independently selected from the group consisting of 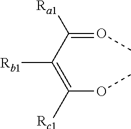
and the structures of the LIGAND List 1;
wherein:
T is selected from the group consisting of B, Al, Ga, and In;
K^{1′} is selected from the group consisting of a single bond, O, S, NRₑ, PRₑ, BRₑ, CRₑR_{f}, and SiRₑR_{f};
each of Y¹ to Y¹³ is independently selected from the group consisting of C and N;
Y′ is selected from the group consisting of BRₑ, BRₑR_{f}, NRₑ, PRₑ, P(O)Rₑ, O, S, Se, C═O, C═S, C═Se, C═NRₑ, C═CRₑR_{f}, S═O, SO₂, CRₑR_{f}, SiRₑR_{f}, and GeRₑR_{f};
Rₑ and R_{f} can be fused or joined to form a ring;
each Rₐ, R_{b}, R_{c}, and R_{d} independently represents from mono to the maximum allowed number of substitutions, or no substitution;
each of Rₐ₁, R_{b1}, R_{c1}, R_{d1}, Rₐ, R_{b}, R_{c}, R_{d}, Rₑ, and R_{f} is independently a hydrogen or a substituent selected from the group consisting of deuterium, halide, alkyl, cycloalkyl, heteroalkyl, arylalkyl, alkoxy, aryloxy, amino, silyl, germyl, boryl, alkenyl, cycloalkenyl, heteroalkenyl, alkynyl, aryl, heteroaryl, acyl, carbonyl, carboxylic acid, ester, nitrile, isonitrile, sulfanyl, selenyl, sulfinyl, sulfonyl, phosphino, and combinations thereof; and
any two substituents of Rₐ₁, R_{b1}, R_{c1}, R_{d1}, Rₐ, R_{b}, R_{c}, and R_{d} can be fused or joined to form a ring or form a multidentate ligand.

16. The compound of claim 13, wherein the compound has a structure selected from the group consisting of: 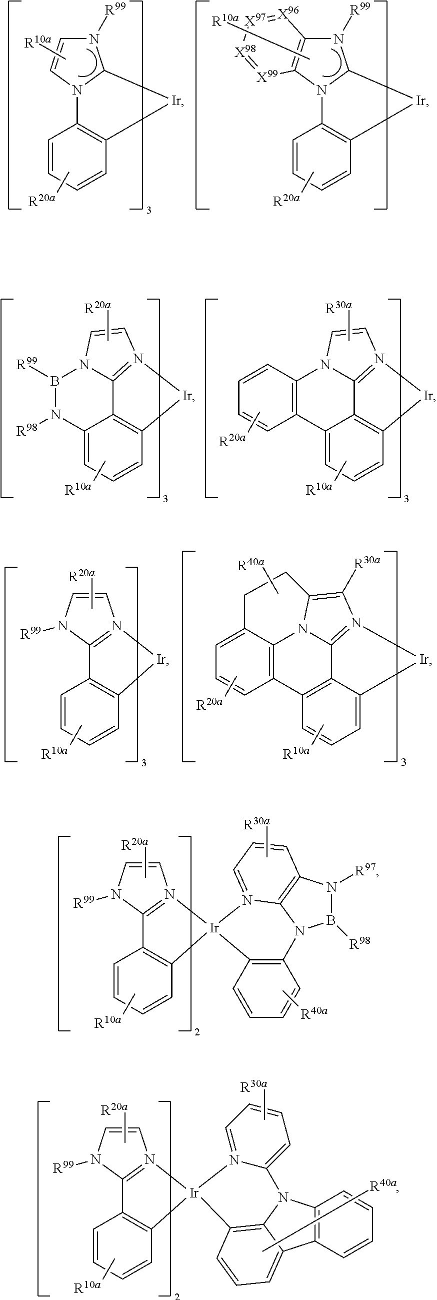 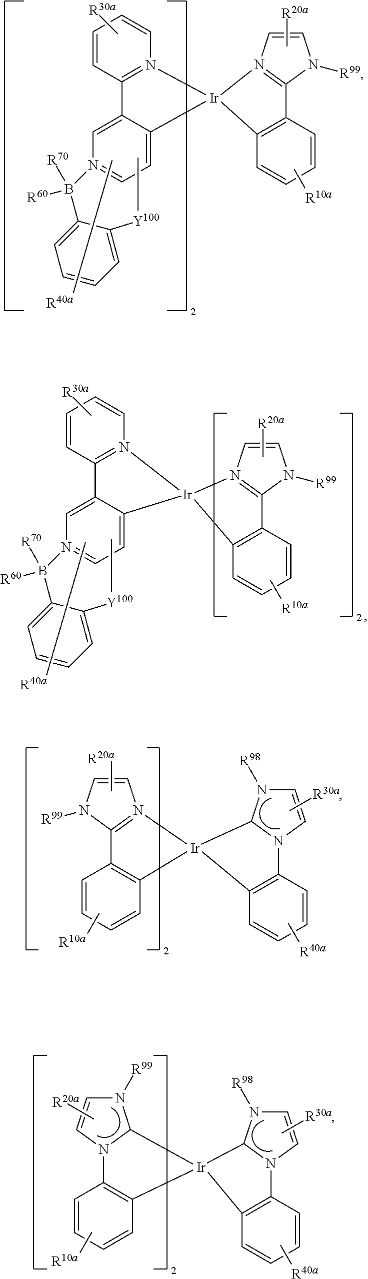 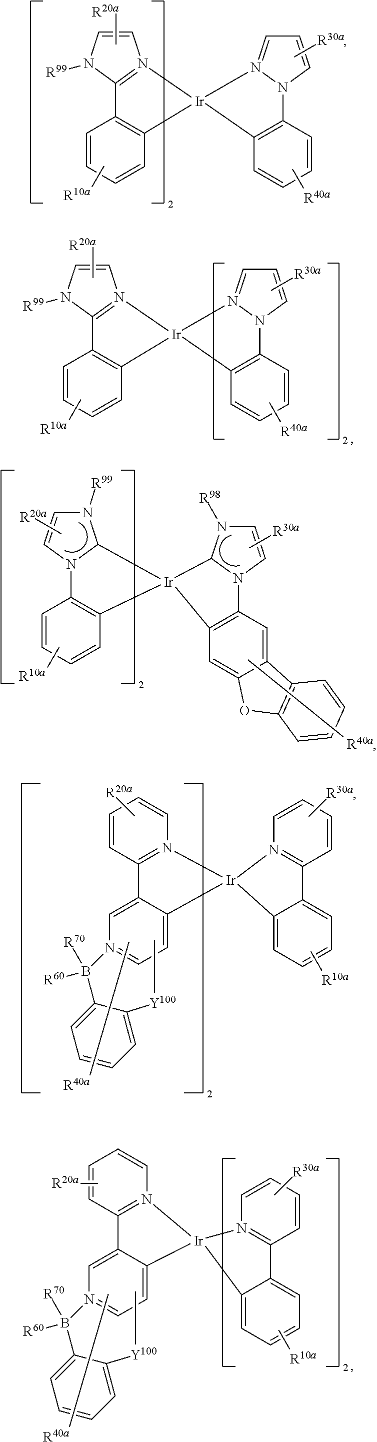 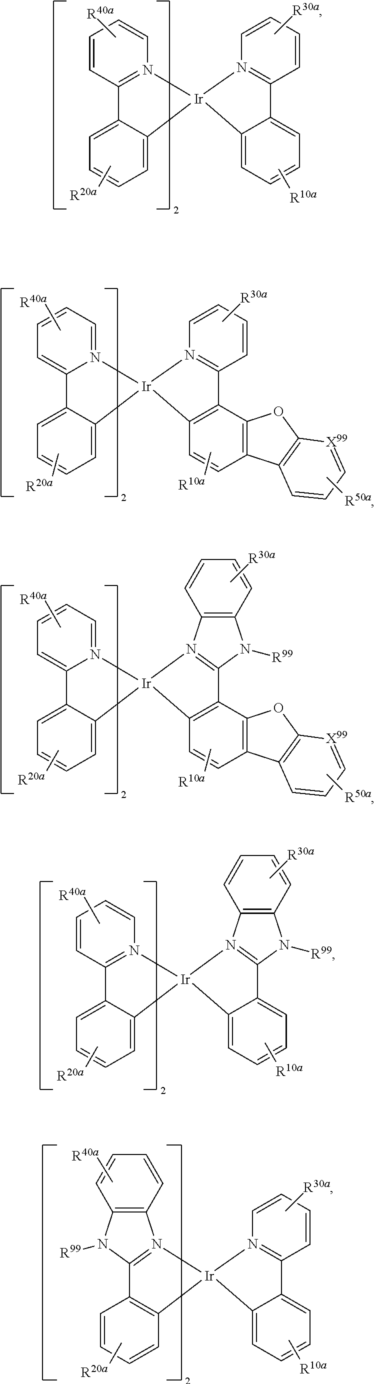 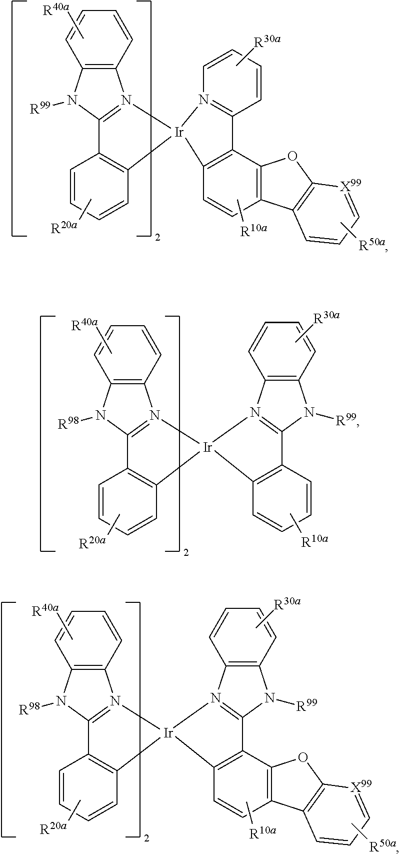 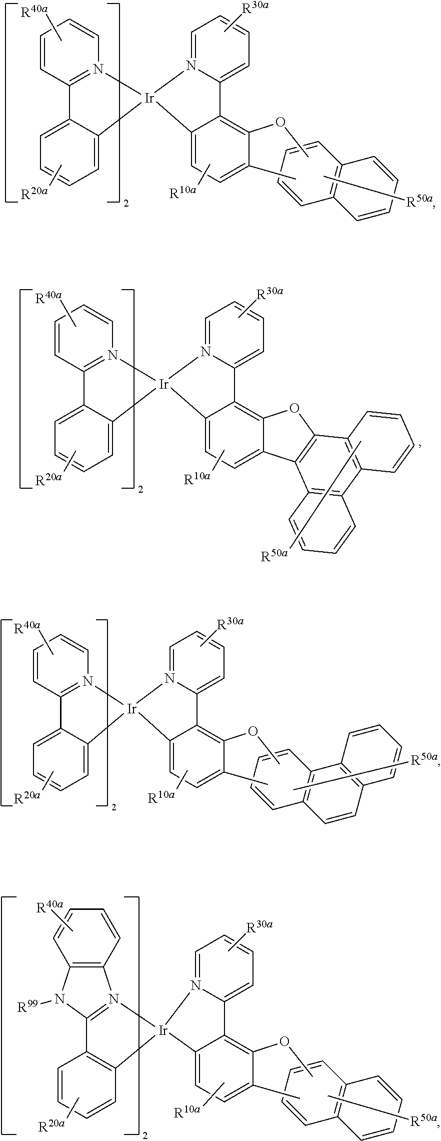 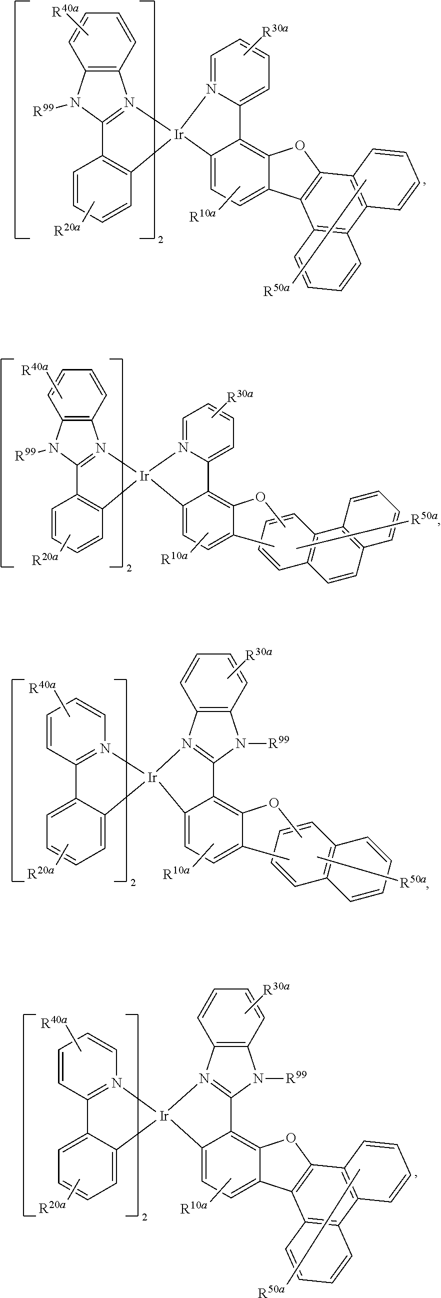 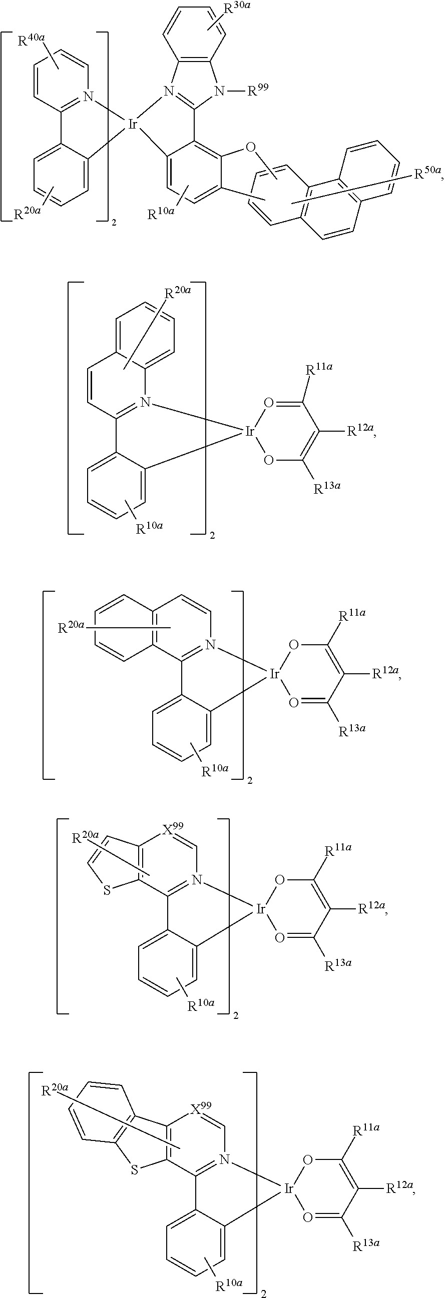 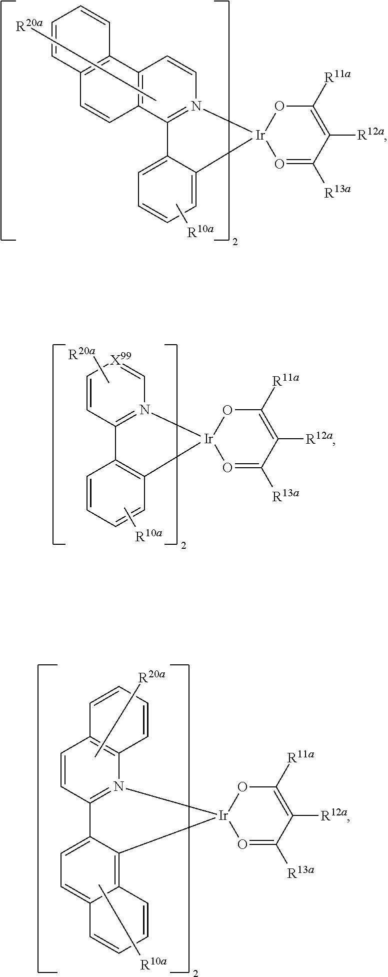 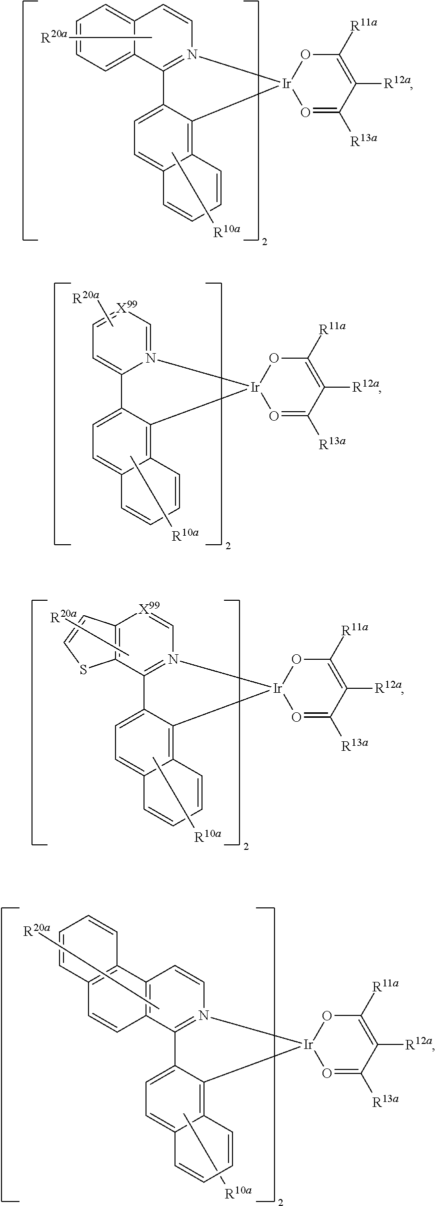 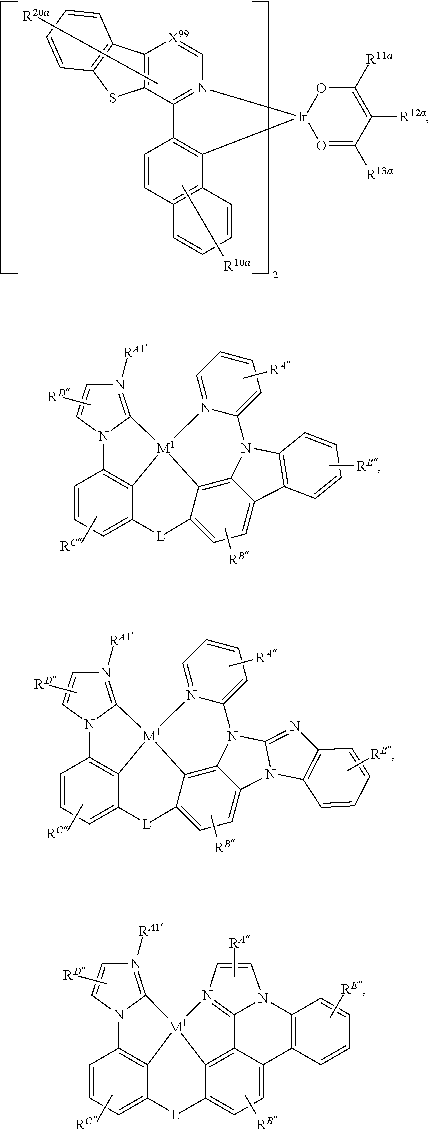 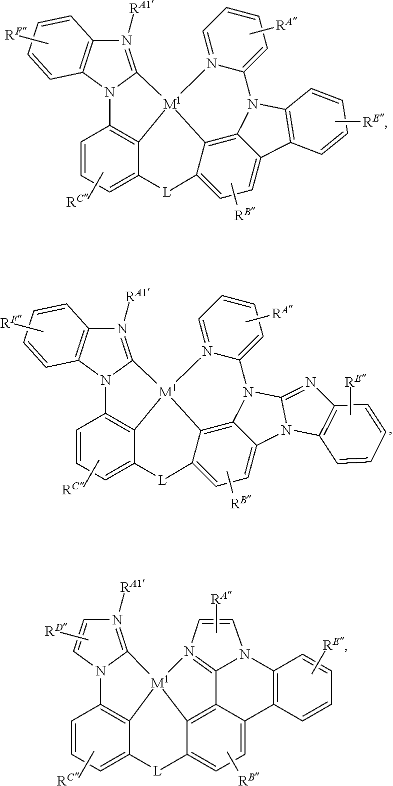 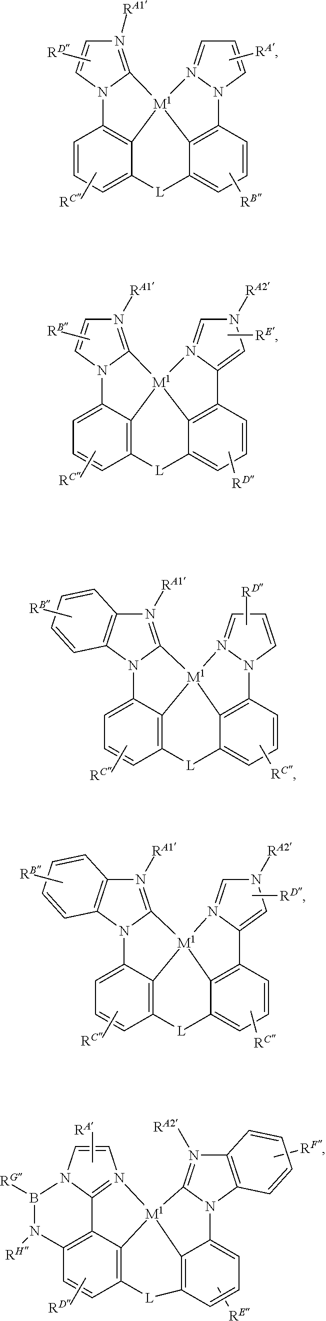 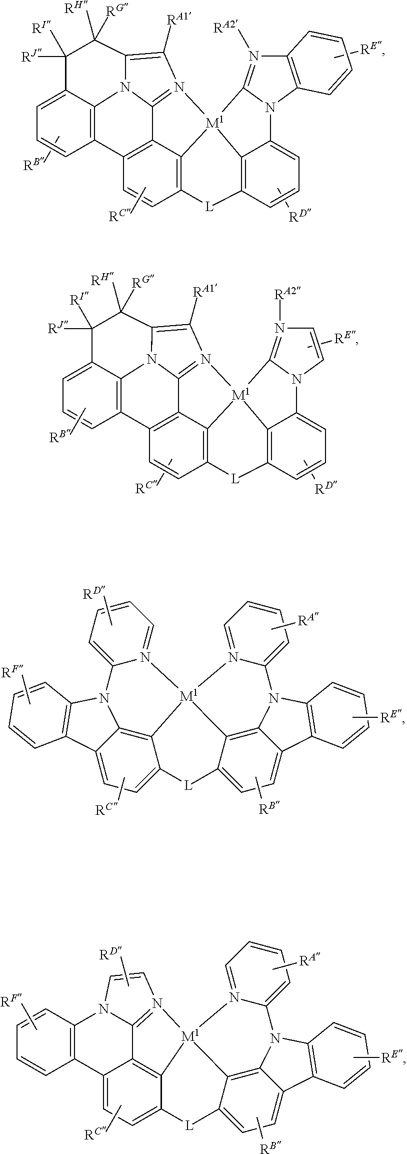 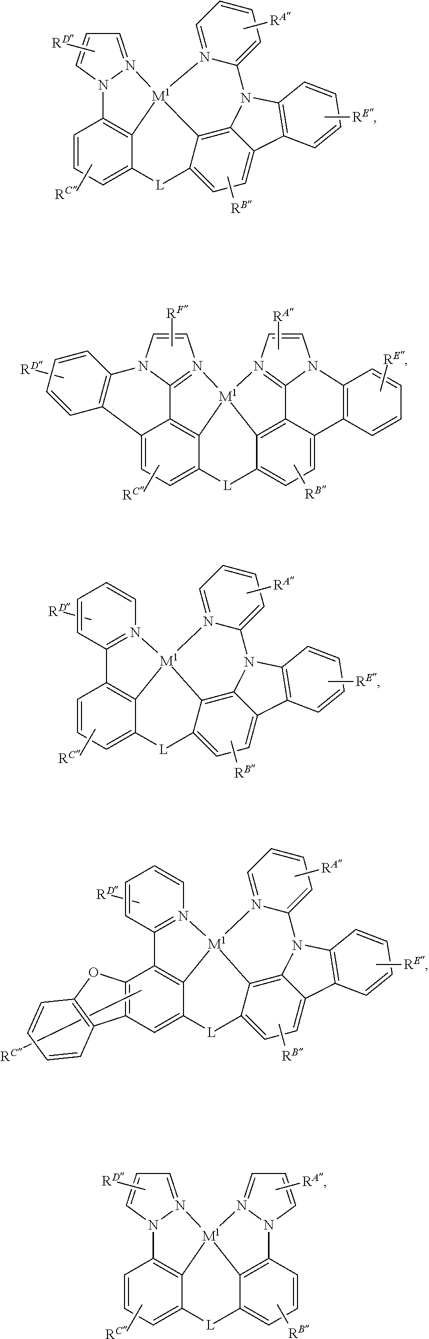 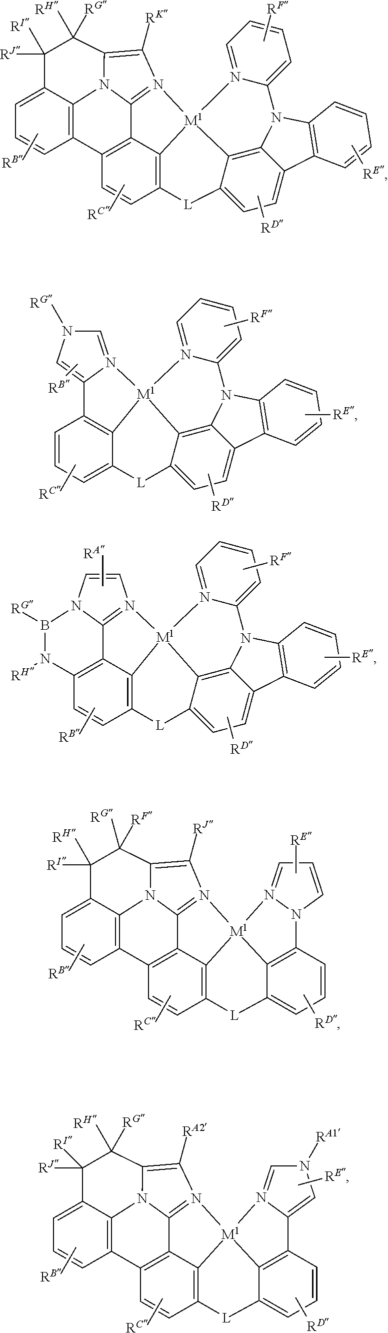 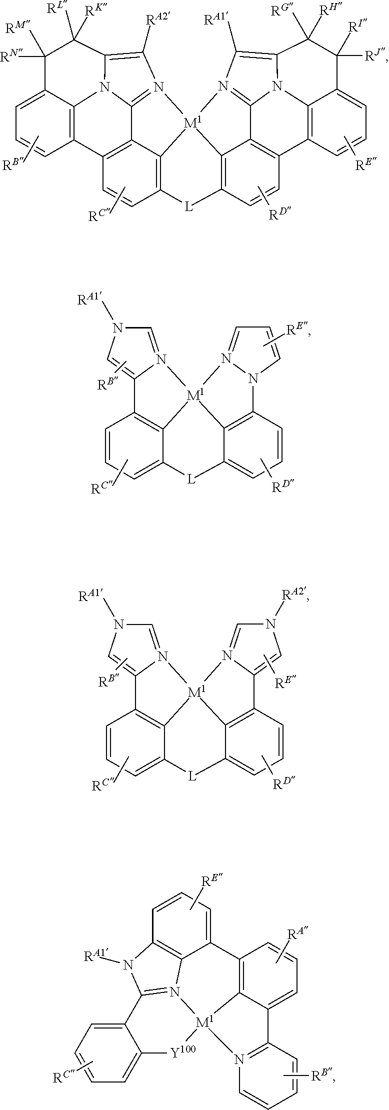 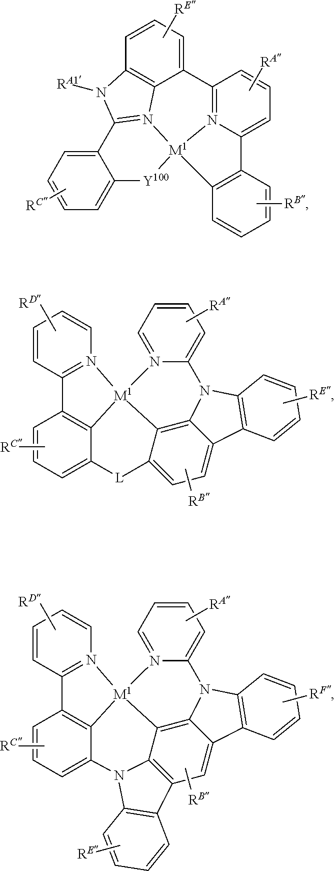 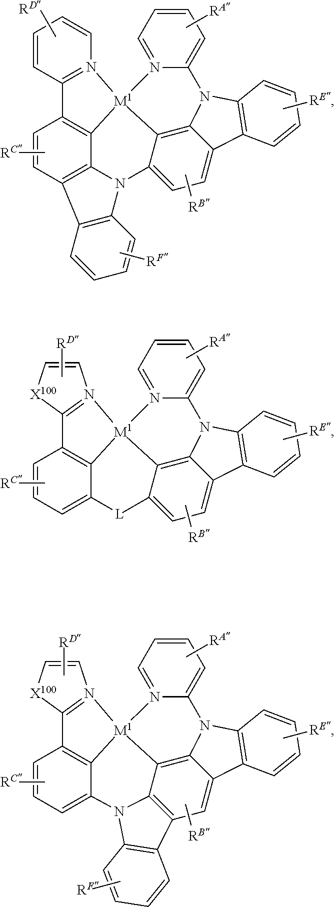 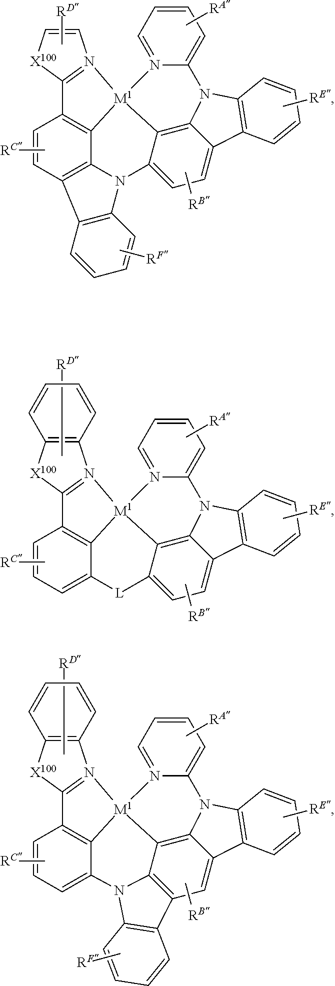 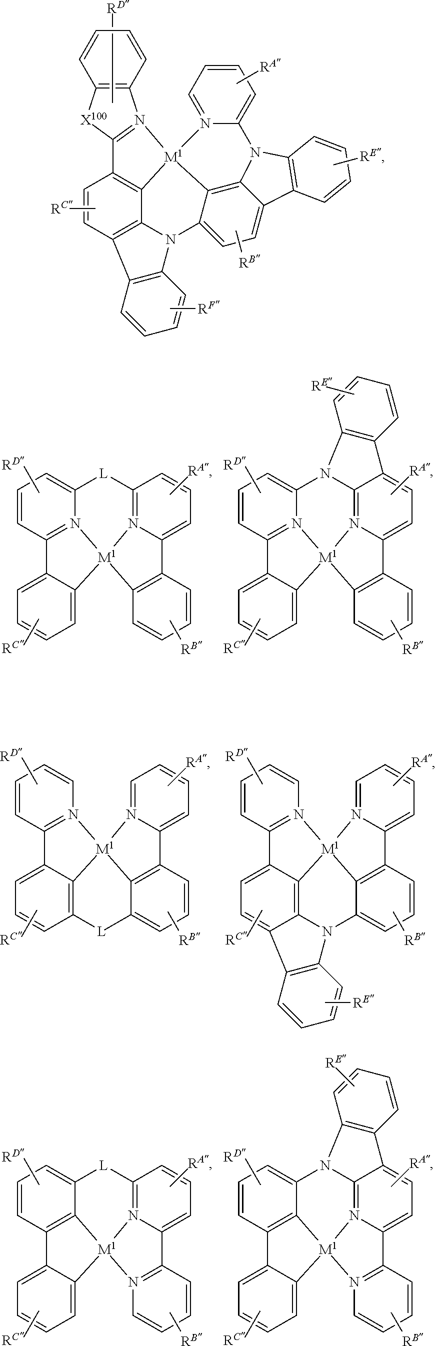 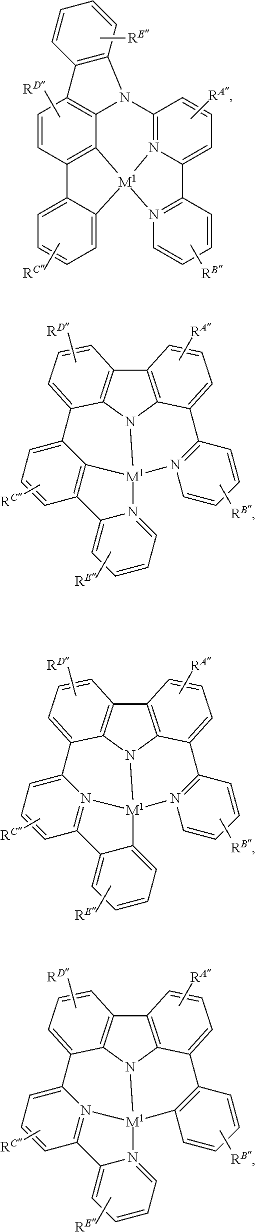 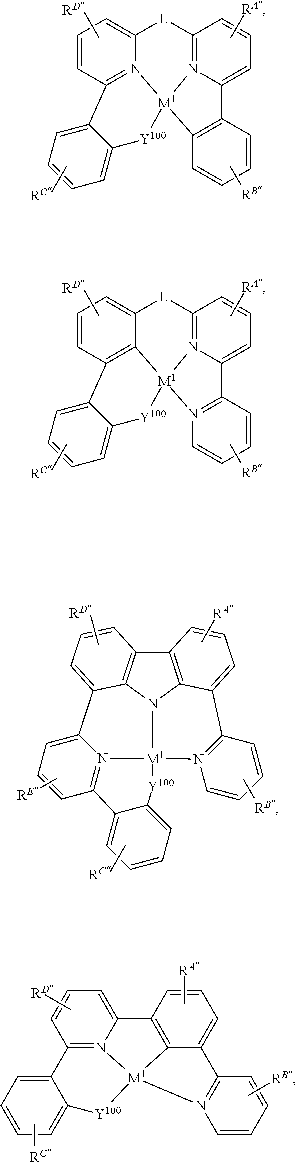 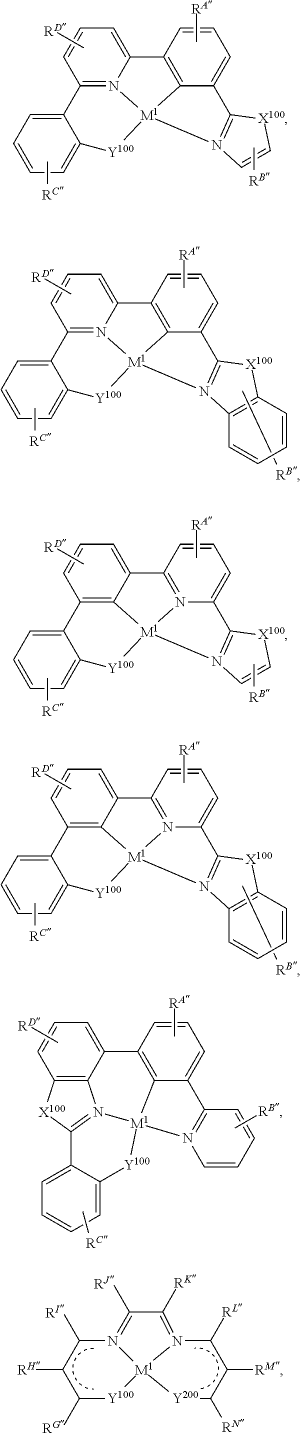 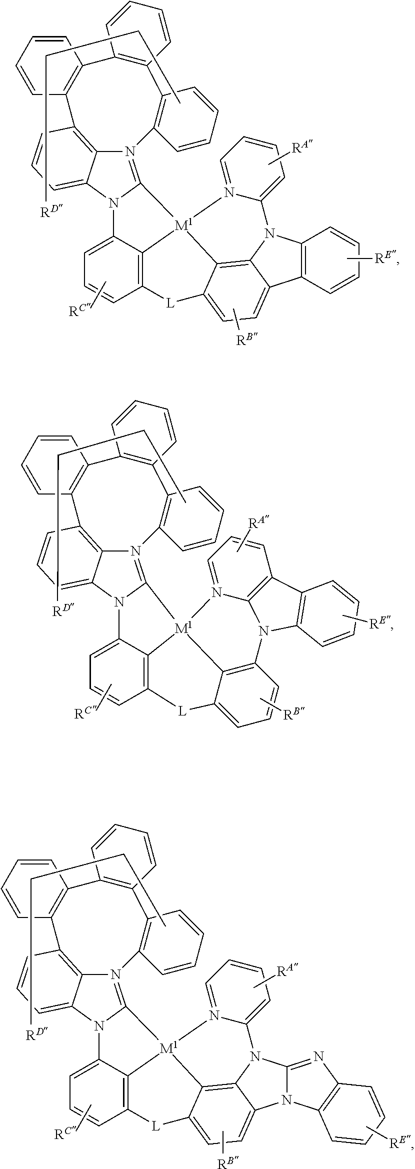 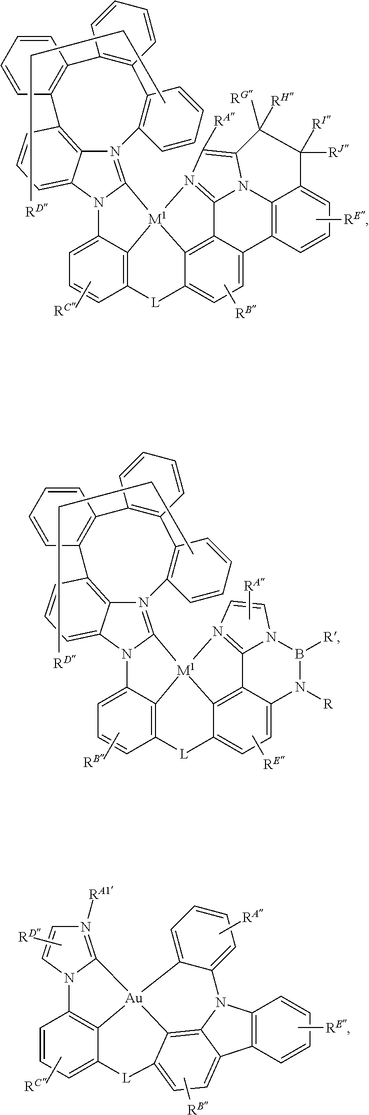 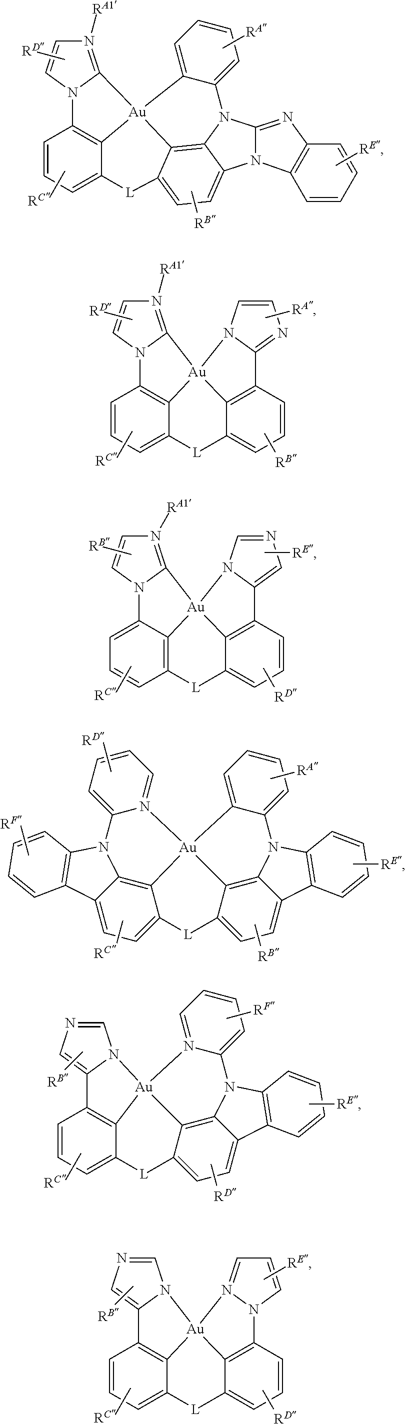 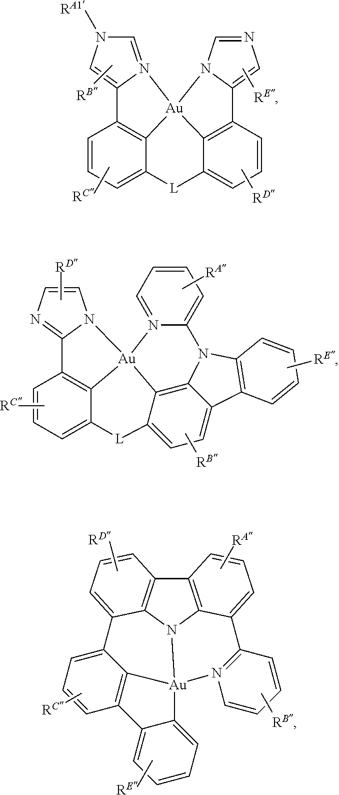 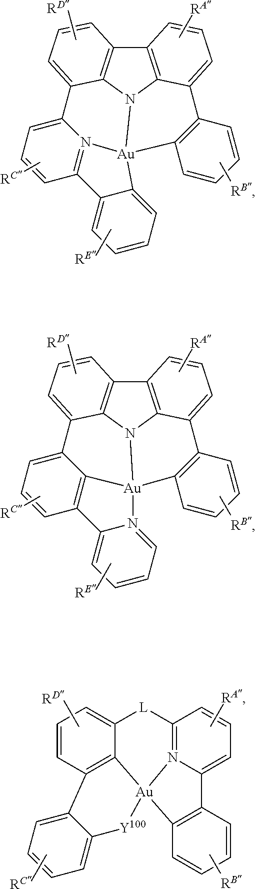 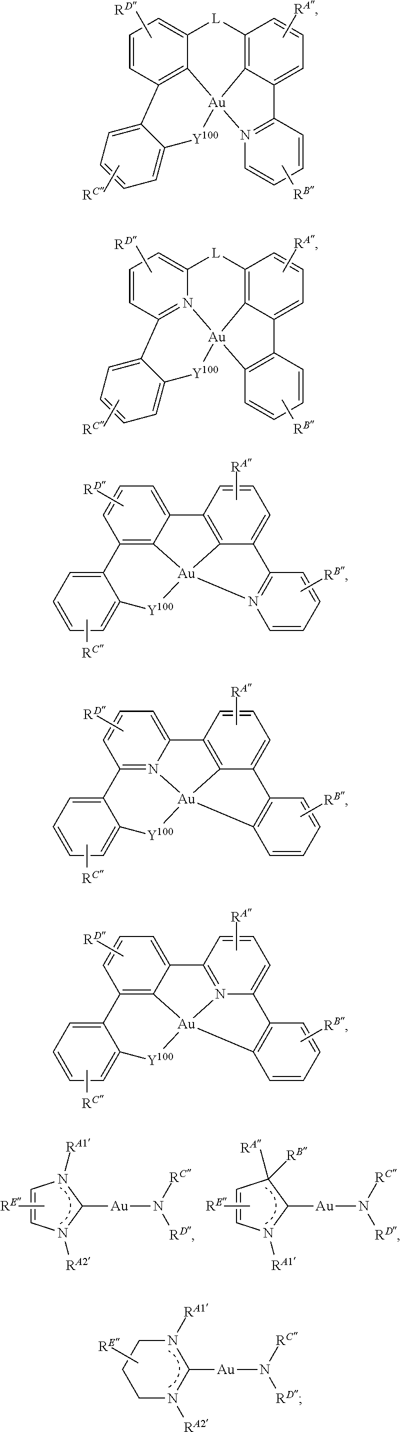
wherein:
M1 is selected from the group consisting of Pt, Pd, and Ni;
each of X⁹⁶ to X⁹⁹ is independently C or N;
each of Y¹⁰⁰ and Y²⁰⁰ is independently selected from the group consisting of a NR″, O, S, and Se;
L is independently selected from the group consisting of a direct bond, BR″, BR″R″′, NR″, PR″, O, S, Se, C═O, C═S, C═Se, C═NR″, C═CR″R″′, S═O, SO₂, CR″, CR″R″′, SiR″R″′, GeR″R″′, alkyl, cycloalkyl, aryl, heteroaryl, and combinations thereof;
X¹⁰⁰ for each occurrence is selected from the group consisting of O, S, Se, NR″, and CR″R″′;
each R^{10a}, R^{20a}, R^{30a}, R^{40a}, R^{50a}, R^{A″}, R^{B″}, R″, R^{D′}, R^{E″}, and R^{F}″ independently represents mono-, up to the maximum substitutions, or no substitutions;
each R, R′, R″, R″′, R^{10a}, R^{11a}, R^{12a}, R^{13a}, R^{20a}, R^{30a}, R^{40a}, R^{50a}, R⁶⁰, R⁷⁰, R⁹⁷, R⁹⁸, R⁹⁹, R^{A1′}, R^{A2′}, R^{A″}, R^{B″}, R^{C″}, R^{D″}, R^{E″}, R^{F″}, R^{G″}, R^{H″}, R^{I″}, R^{J″}, R^{K″}, R^{L″}, R^{M″}, and R^{N″} is independently a hydrogen or a substituent selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof; and
any two adjacent R, R′, R″, R″′, R^{10a}, R^{11a}, R^{12a}, R^{13a}, R^{20a}, R^{30a}, R^{40a}, R^{50a}, R⁶⁰, R⁷⁰, R⁹⁷, R⁹⁸, R⁹⁹, R^{A1′}, R^{A2′}, R^{A″}, R^{B″}, R^{C″}, R^{D″}, R^{E″}, R^{F″}, R^{G″}, R^{H″}, R^{I″}, R^{J″}, R^{K″}, R^{L″}, R^{M″}, and R^{N″} are optionally joined or fused to form a ring.

17. An organic light emitting device (OLED) comprising:
an anode;
a cathode; and
an organic layer disposed between the anode and the cathode, wherein the organic layer comprises a compound according to claim 1.

18. The OLED of claim 17, wherein the organic layer further comprises a host, wherein the host is selected from the group consisting of: 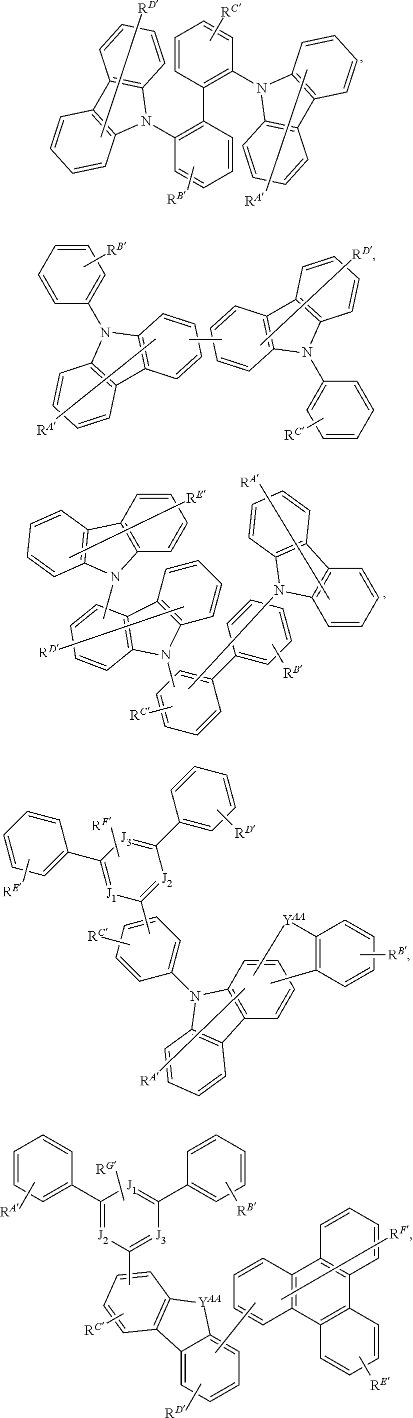 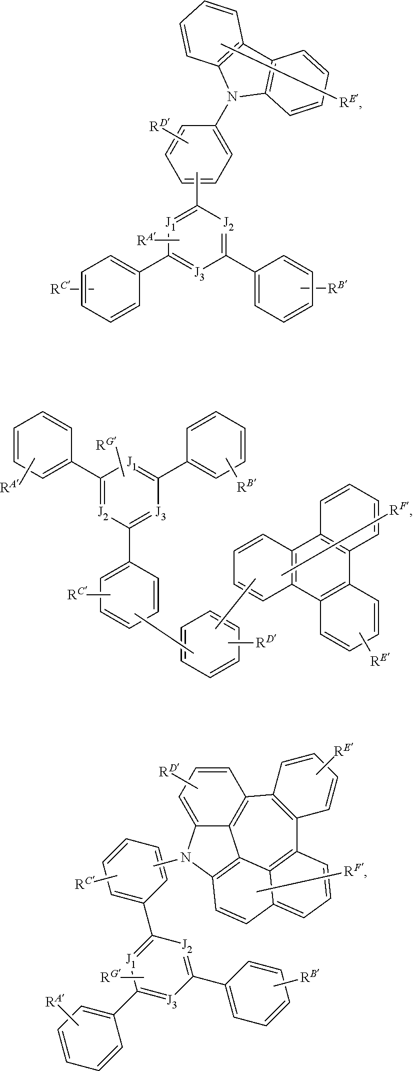 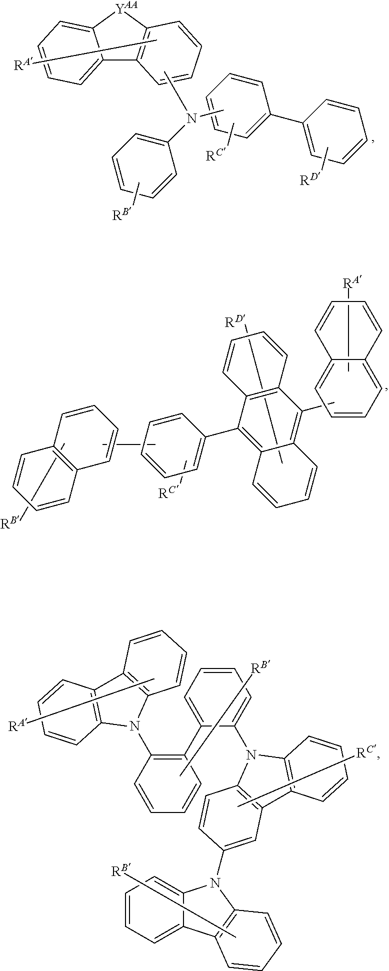 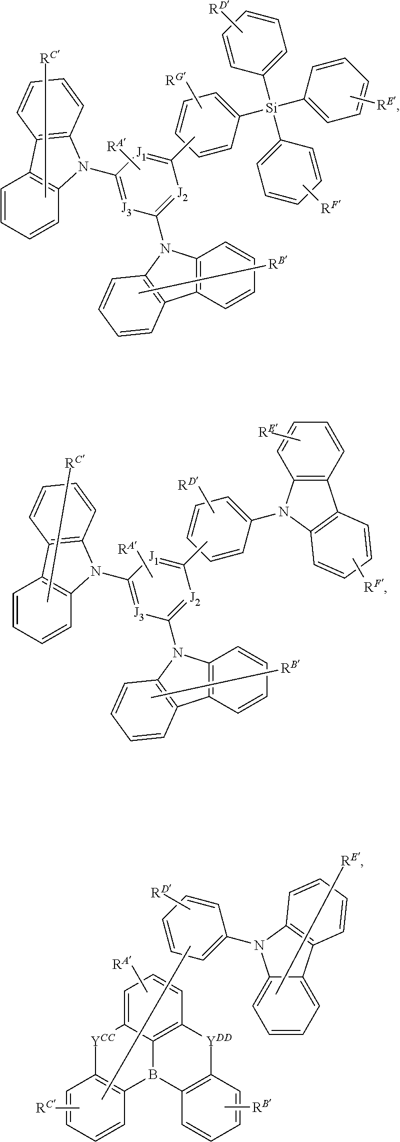 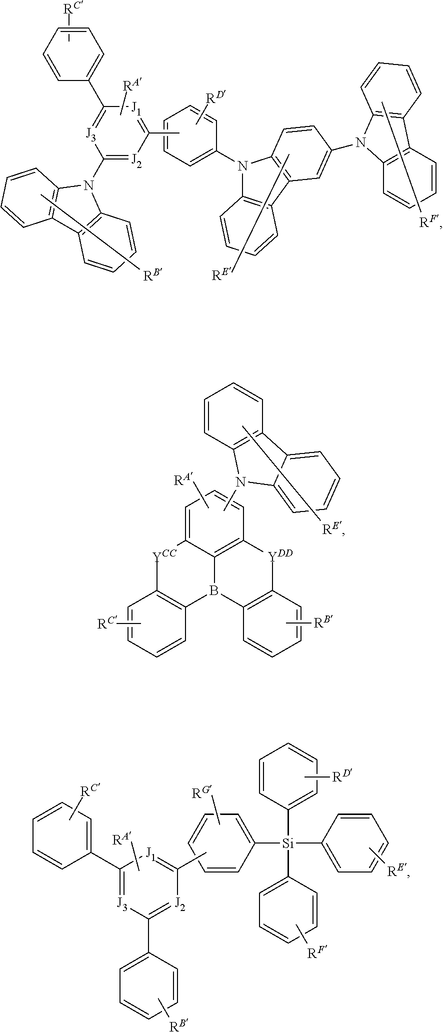 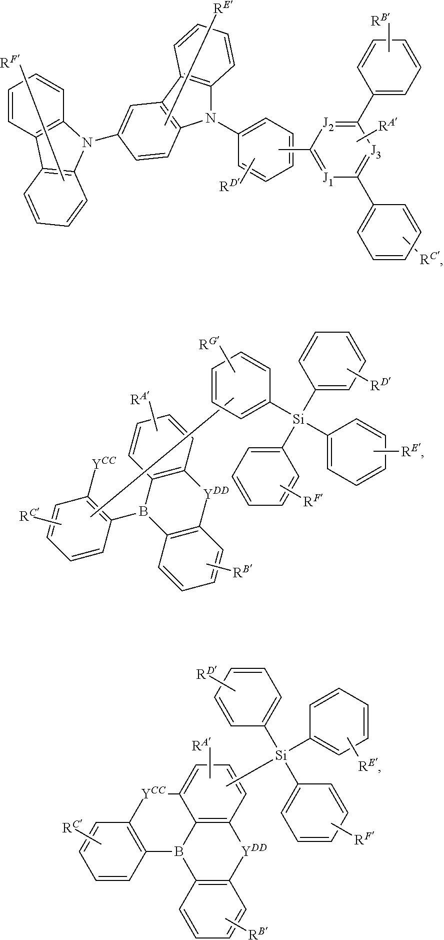 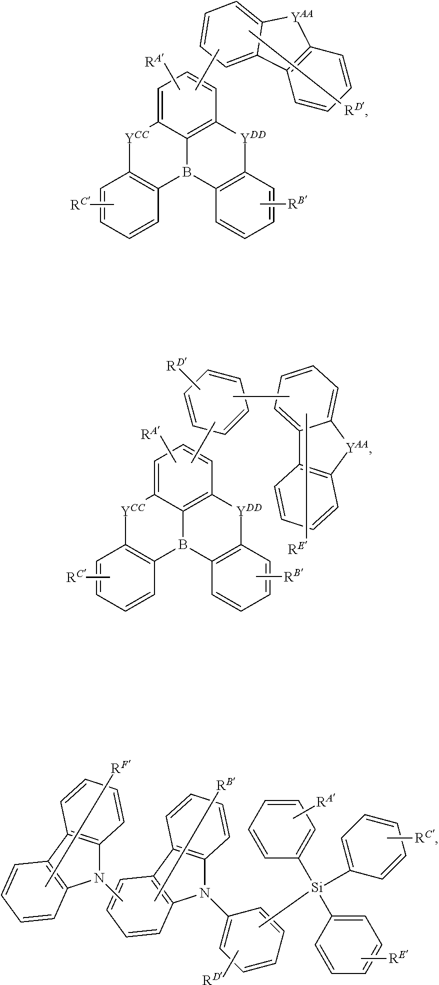 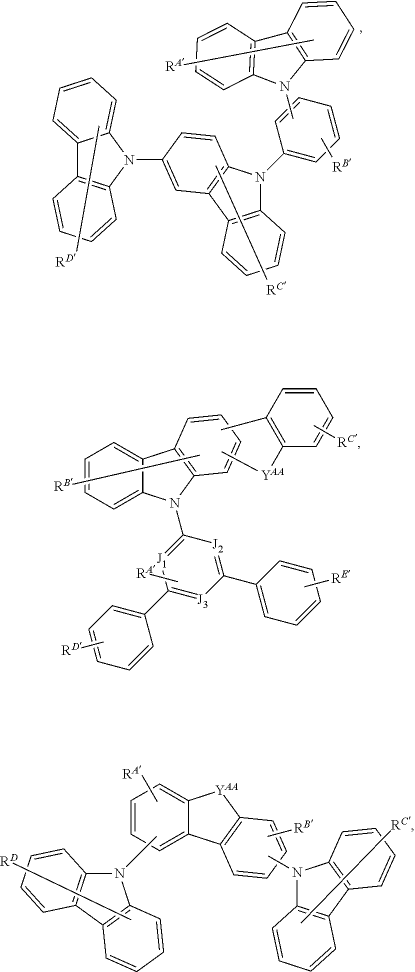 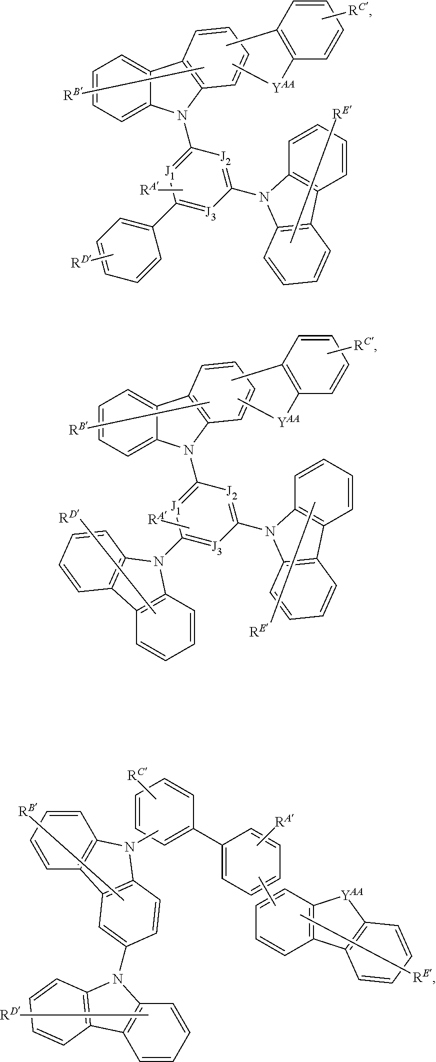 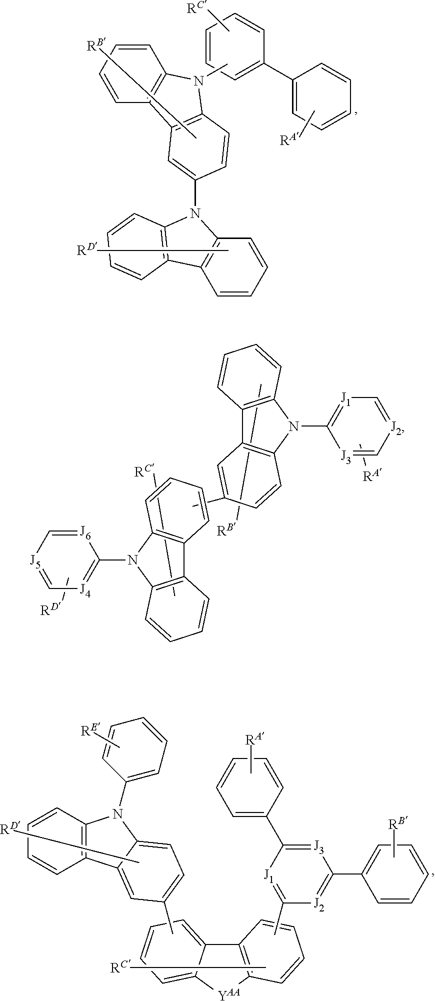 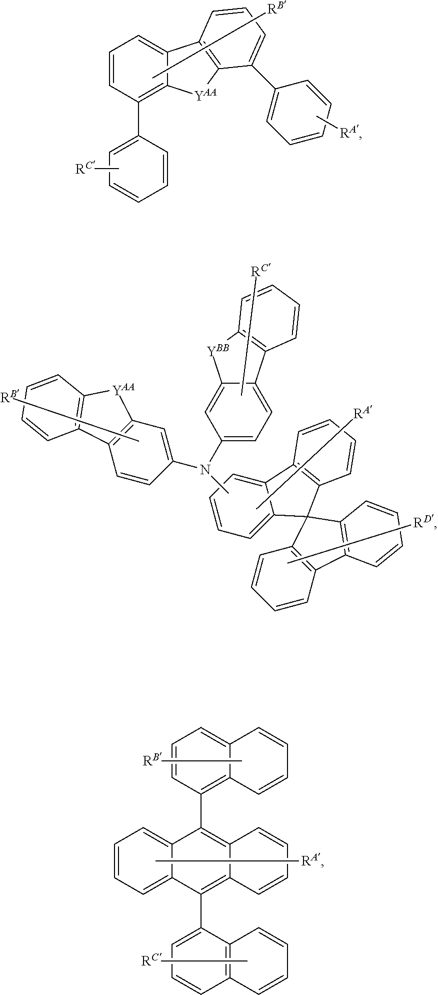 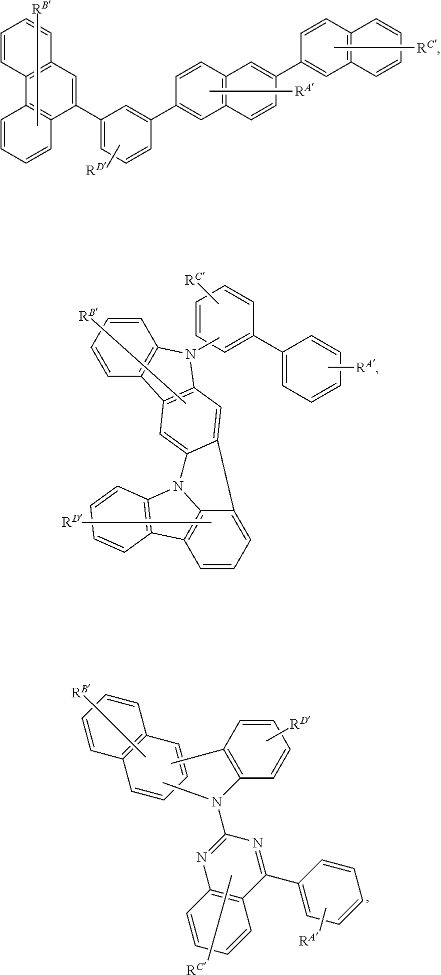 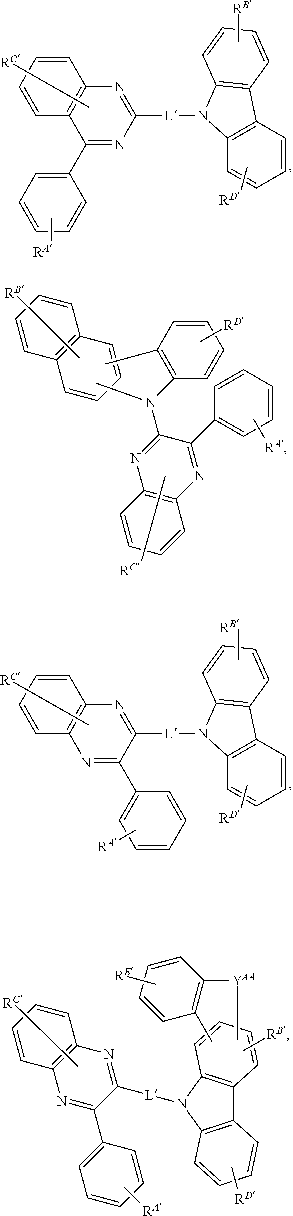 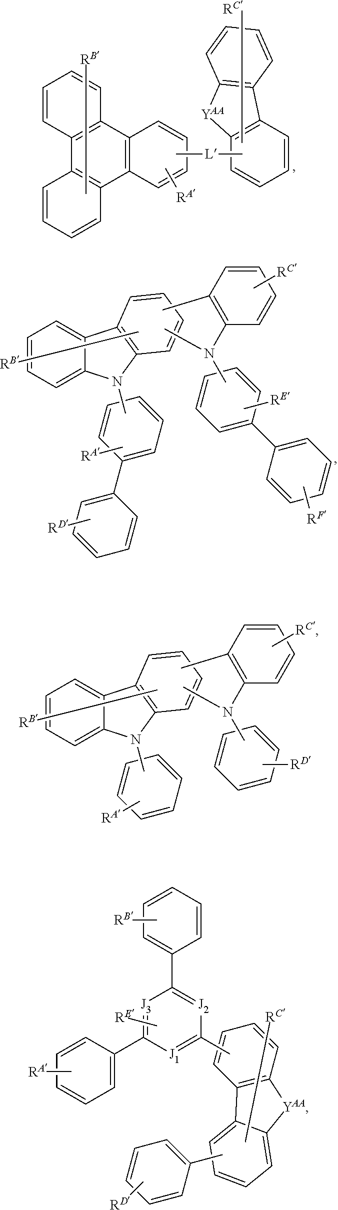 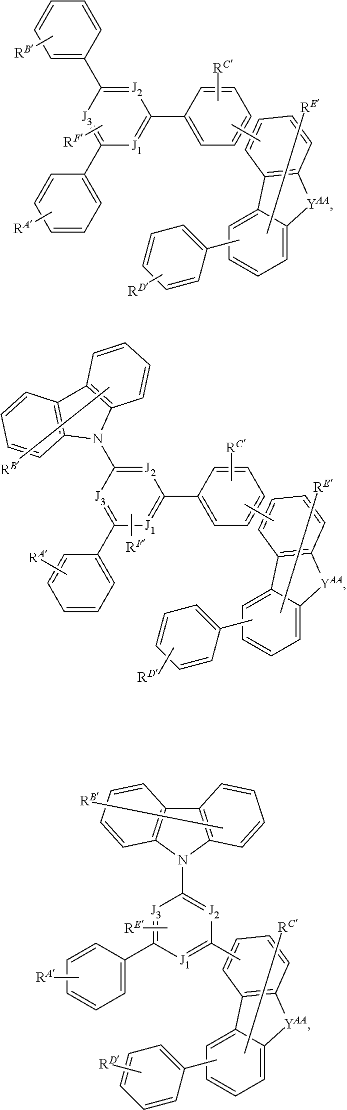 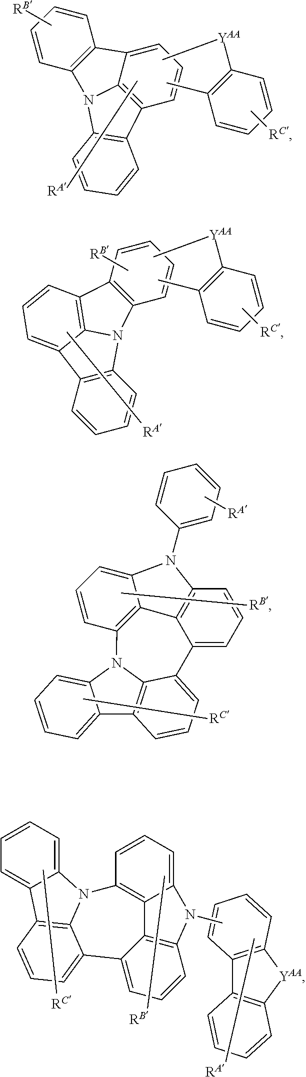 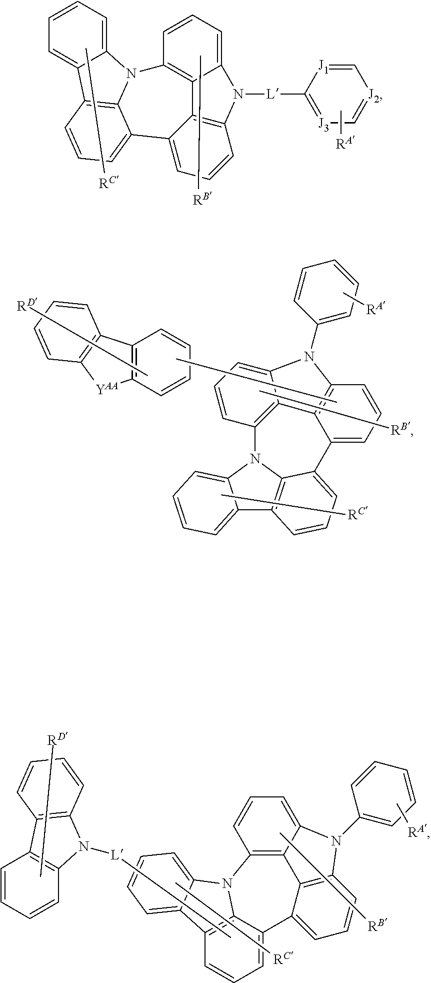 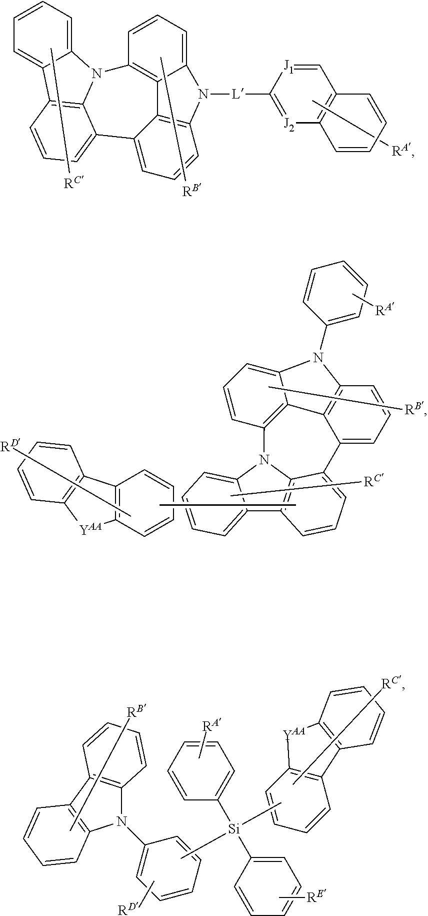 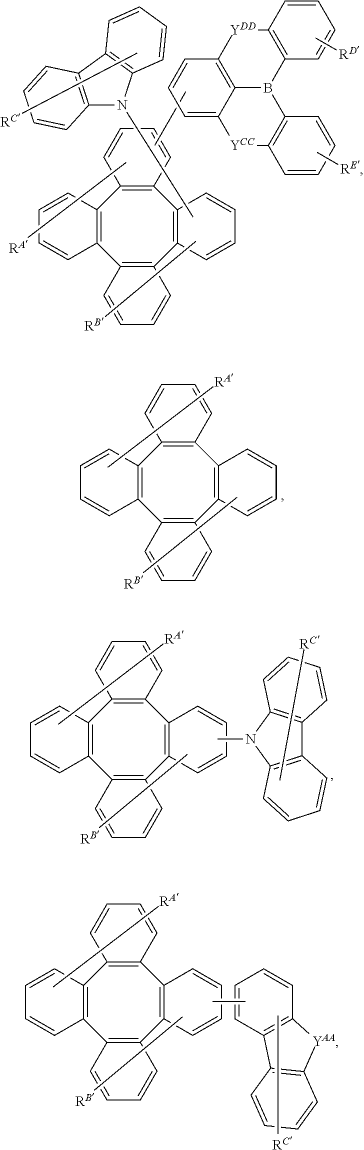 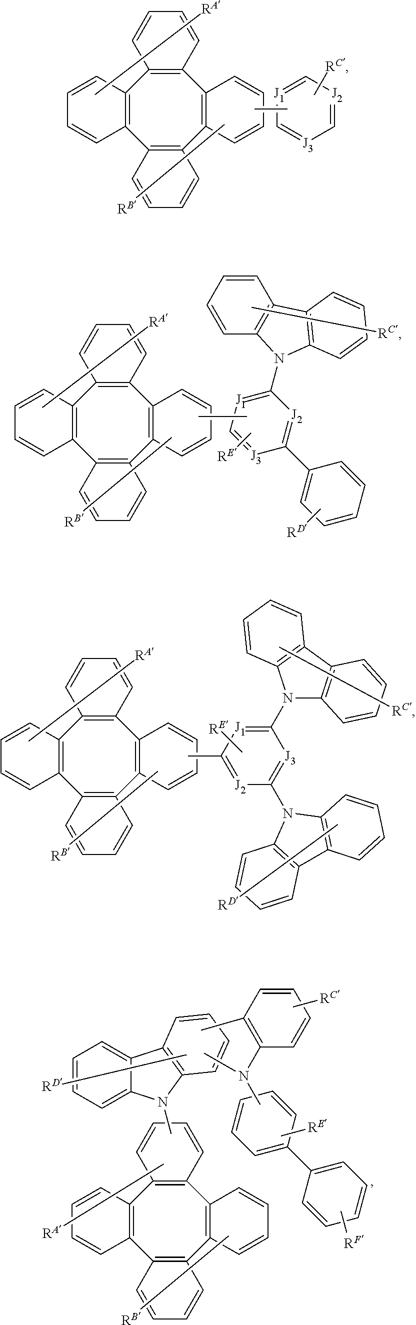 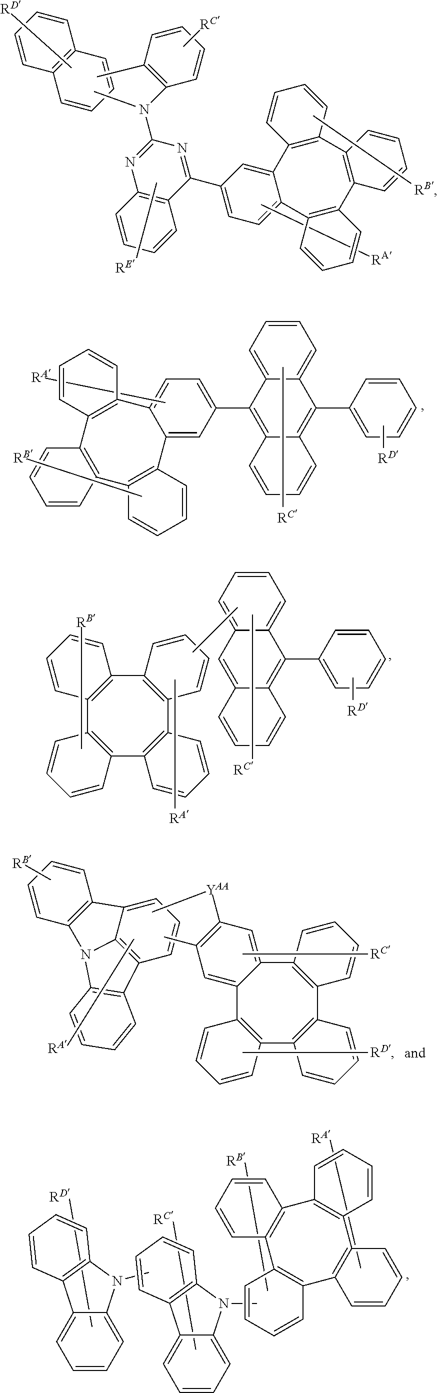
wherein:
each of J₁ to J₆ is independently C or N;
L′ is a direct bond or an organic linker;
each Y^{AA}, Y^{BB}, Y^{CC} and Y^{DD} is independently selected from the group consisting of absent a bond, direct bond, O, S, Se, CRR′, SiRR′, GeRR′, NR, BR, BRR′;
each of R^{A′}, R^{B′}, R^{C′}, R^{D′}, R^{E′}, R^{F′}, and R^{G′} independently represents mono, up to the maximum substitutions, or no substitutions;
each R, R′, R^{A′}, R^{B′}, R^{C′}, R^{D′}, R^{E′}, R^{F′}, and R^{G′} is independently a hydrogen or a substituent selected from the group consisting of the General Substituents as defined herein; any two substituents can be joined or fused to form a ring;
and where possible, each unsubstituted aromatic carbon atom is optionally replaced with N to form an aza-substituted ring.

19. The OLED of claim 17, wherein the compound is a sensitizer, and the OLED further comprises an acceptor selected from the group consisting of a fluorescent emitter, a delayed fluorescence emitter, and combination thereof.

20. A consumer product comprising an organic light-emitting device comprising:
an anode;
a cathode; and
an organic layer disposed between the anode and the cathode, wherein the organic layer comprises a compound according to claim 1.
